(19) United States
(12) Patent Application Publication
(10) Pub. No.: US 2026/0262443 A1
(43) Pub. Date: Sep. 3, 2026

(54) ORGANIC ELECTROLUMINESCENT ELEMENT AND ELECTRONIC DEVICE COMPRISING THE SAME

(71) Applicants: IDEMITSU KOSAN CO.,LTD., Tokyo (JP); University-Industry Cooperation Group of Kyung Hee University, Gyeonggi-do (KR)

(72) Inventors: Jang Hyuk KWON, Seoul (KR); Mi Young CHAE, Seoul (KR); Pavan Kumar ODUGU, Seoul (KR); Hae Ung KIM, Seoul (KR)

(73) Assignees: IDEMITSU KOSAN CO.,LTD., Tokyo (JP); University-Industry Cooperation Group of Kyung Hee University, Gyeonggi-do (KR)

(21) Appl. No.: 19/551,861

(22) Filed: Feb. 27, 2026

(30) Foreign Application Priority Data
Feb. 28, 2025 (KR) 10-2025-0026640
Feb. 13, 2026 (KR) 10-2026-0030160

(51) Int. Cl. H10K 85/60; C09K 11/02; H10K 50/12; H10K 101/00; H10K 101/25; H10K 101/30

(52) U.S. Cl. CPC H10K 85/633; C09K 11/02; H10K 85/615; H10K 85/636; H10K 85/654; H10K 85/6574; H10K 50/12; H10K 85/626; H10K 85/6572; H10K 2101/25; H10K 2101/30; H10K 2101/90

(57) ABSTRACT

According to the present invention, there are provided an organic electroluminescent element, which comprises an anode, a cathode, and an organic layer disposed between the anode and the cathode, wherein the organic layer comprises: a first host compound having a HOMO level of −5.5 eV or higher and a triplet energy level of 2.5 eV or lower; a second host compound having a LUMO level of −4.0 eV to −3.0 eV; and a dopant compound, wherein the first host compound and the second host compound can recombine with each other to form an exciplex, the triplet energy level of the exciplex is greater than 1.5 eV, and the first host compound, the second host compound, and the dopant compound satisfy Relationships 1 to 3, and an electronic device, which comprises the organic electroluminescence element.

### TECHNICAL FIELD

The present invention relates to an organic electroluminescent element and an electronic device.

### BACKGROUND ART OF THE INVENTION

Organic luminescence refers to a phenomenon in which electrical energy is converted into light energy by using an organic material. An organic electroluminescent element (hereinafter, may be abbreviated as an “organic EL element”) is an element that utilizes such organic luminescence. It is generally composed of an anode, a cathode, and an organic layer interposed between the anode and the cathode. When a voltage is applied between the anode and the cathode, holes may be injected from the anode into the organic layer, and electrons may be injected from the cathode into the organic layer. The holes and electrons injected into the organic layer recombine within the organic layer to form an excited state, and light may be emitted in the procedure of returning from the excited state to a ground state. For example, the light emission mechanism may comprise fluorescence derived from a singlet excited state of electrons and phosphorescence derived from a triplet excited state of electrons.

The organic layer may comprise a light-emitting material, an electron transporting material, or a charge transporting material. The light-emitting material may be classified into a fluorescent material or a phosphorescent material depending on the light emission mechanism, and it may be classified into a blue material, a green material, or a red material depending on the emitted color.

Examples of performance characteristics of an organic EL element include a driving voltage, a turn-on voltage, luminous efficiency, luminance, chromaticity, emission wavelength, and lifespan. In order to improve the performance of an organic EL element, it is required to obtain a combination of materials that facilitates the recombination of electrons and holes and enables excitons to emit light with high efficiency.

For example, Patent Documents 1 and 2 disclose organic EL elements comprising combinations of specific compounds.

### PRIOR ART DOCUMENTS

### Patent Documents

[Patent Document 1] Korean Laid-open Patent Publication No. 10-2023-0165292
[Patent Document 2] International Patent Publication No. 2023/249092

### DISCLOSURE OF THE INVENTION

### Technical Problem to be Solved

Conventionally, a lot of compounds have been reported as materials for preparing organic electroluminescent elements; however, there is still a demand for compounds that further enhance the characteristics of organic electroluminescent elements.

The present invention has been made in view of the above task. An object thereof is to provide an organic electroluminescent element having further improved element performance as it comprises a specific combination of compounds, and an electronic device comprising such an organic electroluminescent element.

### Solution to the Problem

According to an aspect of the present invention, there is provided an organic electroluminescent element, which comprises an anode, a cathode, and an organic layer interposed between the anode and the cathode,
wherein the organic layer comprises a first host compound having a HOMO energy level of −5.5 eV or higher and a triplet energy level of 2.5 eV or lower, a second host compound having a LUMO energy level of −4.0 eV to −3.0 eV, and a dopant compound,
wherein the first host compound and the second host compound are capable of recombining with each other to form an exciplex,
the exciplex has a triplet energy level of greater than 1.5 eV, and
the first host compound, the second host compound, and the dopant compound satisfy the following Relationships 1 to 4.

$${H}_{1} {S}_{1} > D {S}_{1} \qquad [ Relationship 1 ]$$

$${H}_{1} {T}_{1} > D {T}_{1} \qquad [ Relationship 2 ]$$

$${H}_{2} {S}_{1} > D {S}_{1} \qquad [ Relationship 3 ]$$

$${H}_{2} {T}_{1} > D {T}_{1} \qquad [ Relationship 4 ]$$

In Relationships 1 to 4,
H₁S₁ is a singlet energy level of the first host compound,
H₁T₁ is a triplet energy level of the first host compound,
H₂S₁ is a singlet energy level of the second host compound,
H₂T₁ is a triplet energy level of the second host compound,
DS₁ is a singlet energy level of the dopant compound, and
DT₁ is a triplet energy level of the dopant compound.

According to another aspect of the present invention, there is provided an organic electroluminescent element, which comprises an anode, a cathode, and an organic layer interposed between the anode and the cathode,
wherein the organic layer comprises a first host compound having a HOMO energy level of −5.5 eV or higher and a triplet energy level of 2.5 eV or lower, a second host compound having a LUMO energy level of −4.0 eV to −3.0 eV, and a dopant compound,
wherein the first host compound and the second host compound are capable of recombining with each other to form an exciplex,
the exciplex has a triplet energy level of greater than 1.5 eV, and
the first host compound, the second host compound, and the dopant compound satisfy the following Relationships 1 to 3 and 5.

$${H}_{1} {S}_{1} > D {S}_{1} \qquad [ Relationship 1 ]$$

$${H}_{1} {T}_{1} > D {T}_{1} \qquad [ Relationship 2 ]$$

$${H}_{2} {S}_{1} > D {S}_{1} \qquad [ Relationship 3 ]$$

$$D {T}_{1} > {H}_{2} {T}_{1} \qquad [ Relationship 4 ]$$

In Relationships 1 to 3 and 5,
H₁S₁ is a singlet energy level of the first host compound,
H₁T₁ is a triplet energy level of the first host compound,
H₂S₁ is a singlet energy level of the second host compound,
H₂T₁ is a triplet energy level of the second host compound,
DS₁ is a singlet energy level of the dopant compound, and
DT₁ is a triplet energy level of the dopant compound.

According to another aspect of the present invention, there is provided an organic electroluminescent element, which comprises an anode, a cathode, and an organic layer interposed between the anode and the cathode,
wherein the organic layer comprises:
a first host compound having a HOMO energy level of −5.5 eV or higher and a triplet energy level of 2.5 eV or lower,
a second host compound having a LUMO energy level of −4.0 eV to −3.0 eV,
a dopant compound, and
a third host compound having a triplet energy level greater than 1.5 eV to less than 1.9 e V,
wherein the first host compound and the second host compound are capable of recombining with each other to form an exciplex,
the exciplex has a triplet energy level of greater than 1.5 eV, and
the first host compound, the second host compound, and the dopant compound satisfy the above Relationships 1 to 4.

According to another aspect of the present invention, there is provided an electronic device that comprises the above organic electroluminescent element.

### Advantageous Effects of the Invention

According to the present invention, the organic electroluminescent element in which an organic layer disposed between an anode and a cathode comprises a first host compound and a second host compound capable of forming an exciplex having a triplet energy level within a predetermined range, and a dopant compound, wherein the first host compound has a HOMO energy level and a triplet energy level within predetermined ranges, the second host compound has a LUMO energy level within a predetermined range, and the singlet energy levels and the triplet energy levels of the first host compound, the second host compound, and the dopant compound satisfy the above Relationships 1 to 3, whereby it exhibits improved element performance. Specifically, a longer lifespan can be achieved, and a lower driving voltage and higher luminous efficiency can be accomplished.

### BRIEF DESCRIPTION OF THE DRAWING

FIG. 1 is a diagram illustrating an example of energy levels and energy transfer relationships of a fluorescent material in a conventional organic electroluminescent element.

FIG. 2 is a diagram illustrating an example of energy levels and energy transfer relationships of a fluorescent material in an organic electroluminescent element.

FIG. 3 is a schematic diagram illustrating an example of a configuration of an organic electroluminescent element according to an embodiment of the present invention.

FIG. 4 is a schematic diagram illustrating an example of a configuration of an organic electroluminescent element according to another embodiment of the present invention.

FIG. 5 is a schematic diagram illustrating an example of a configuration of an organic electroluminescent element according to another embodiment of the present invention.

FIG. 6 is a graph showing luminous efficiency as a function of luminance in the organic electroluminescent elements of Example 2 and Example 3.

FIG. 7 is a diagram illustrating an example of energy levels and energy transfer relationships of respective compounds in the light-emitting layer of the organic electroluminescent element of Example 2.

FIG. 8 is a diagram illustrating an example of energy levels and energy transfer relationships of respective compounds in the light-emitting layer of the organic electroluminescent element of Example 3.

### DETAILED DESCRIPTION FOR CARRYING OUT THE INVENTION

### [Definitions]

In the present specification, the term “hydrogen atom” encompasses isotopes having different numbers of neutrons, that is, a protium atom, a deuterium atom, and a tritium atom.

In the present specification, in chemical structural formulae, at bonding positions where symbols such as “R” or “D” representing a deuterium atom are not explicitly indicated, it is to be understood that a hydrogen atom, that is, a protium atom, a deuterium atom, or a tritium atom, is bonded.

In the present specification, the term “ring carbon atoms” refers to the number of carbon atoms among atoms that constitute a ring itself in a compound (e.g., a monocyclic ring compound, a fused ring compound, a cross-linking compound, a carbocyclic compound, and a heterocyclic compound) having a structure in which atoms are bonded in a ring. When the ring is substituted with a substituent, the carbon atoms contained in the substituent do not fall under the ring carbon atoms. Unless otherwise specified, the same applies to the “ring carbon atoms” described hereinafter. For example, a benzene ring has 6 ring carbon atoms, a naphthalene ring has 10 ring carbon atoms, a pyridine ring has 5 ring carbon atoms, and a furan ring has 4 ring carbon atoms. In addition, for example, a 9,9-diphenylfluorenyl group has 13 ring carbon atoms, and a 9,9′-spirobifluorenyl group has 25 ring carbon atoms.

In addition, when a benzene ring is substituted with, for example, an alkyl group, the number of carbon atoms in the alkyl group does not fall under the ring carbon atoms of the benzene ring. Therefore, a benzene ring substituted with an alkyl group has 6 ring carbon atoms. In addition, when a naphthalene ring is substituted with, for example, an alkyl group, the number of carbon atoms in the alkyl group does not fall under the ring carbon atoms of the naphthalene ring. Therefore, a naphthalene ring substituted with an alkyl group has 10 ring carbon atoms.

In the present specification, the term “ring atoms” refers to the number of atoms that constitute a ring itself in a compound (e.g., a monocyclic ring compound, a fused ring compound, a cross-linking compound, a carbocyclic compound, and a heterocyclic compound) having a structure (e.g., a monocyclic ring, a fused ring, and a set of rings) in which atoms are bonded in a ring. Atoms that do not constitute a ring (e.g., hydrogen atoms that terminate bonds of atoms that constitute a ring) or atoms contained in a substituent when the ring is substituted by the substituent do not fall under the ring atoms. Unless otherwise specified, the same applies to the “ring atoms” described hereinafter. For example, a pyridine ring has 6 ring atoms, a quinazoline ring has 10 ring atoms, and a furan ring has 5 ring atoms. For example, the number of hydrogen atoms bonded to a pyridine ring, or the number of atoms that constitute a substituent, does not fall under the ring atoms of a pyridine ring. Therefore, a pyridine ring bonded with hydrogen atoms or a substituent has 6 ring atoms. In addition, for example, the number of hydrogen atoms bonded to the carbon atoms of a quinazoline ring, or the number of atoms that constitute a substituent, does not fall under the ring atoms of a quinazoline ring. Therefore, a quinazoline ring bonded with hydrogen atoms or a substituent has 10 ring atoms.

In the present specification, in the expression “substituted or unsubstituted ZZ group having XX to YY carbon atoms,” the term “XX to YY carbon atoms” refers to the number of carbon atoms when the ZZ group is unsubstituted. When it is substituted, the number of carbon atoms in the substituent does not fall thereunder. Here, “YY” is greater than “XX.” “XX” is an integer of 1 or more, and “YY” is an integer of 2 or more.

In the present specification, in the expression “substituted or unsubstituted ZZ group having XX to YY ring atoms,” the term “XX to YY ring atoms” refers to the number of atoms when the ZZ group is unsubstituted. When it is substituted, the number of atoms in the substituent does not fall thereunder. Here, “YY” is greater than “XX.” “XX” is an integer of 1 or more, and “YY” is an integer of 2 or more.

In the present specification, an unsubstituted ZZ group refers to a case where a “substituted or unsubstituted ZZ group” is an “unsubstituted ZZ group,” and a substituted ZZ group refers to a case where a “substituted or unsubstituted ZZ group” is a “substituted ZZ group.”

In the present specification, in the expression “substituted or unsubstituted ZZ group,” the term “unsubstituted” refers to a case where the hydrogen atoms in the ZZ group are not substituted with a substituent. The hydrogen atoms in an “unsubstituted ZZ group” are protium atoms, deuterium atoms, and tritium atoms.

In addition, in the present specification, in the expression “substituted or unsubstituted ZZ group,” the term “substituted” refers to a case where one or more hydrogen atoms in the ZZ group are substituted with a substituent. In the expression “BB group substituted with an AA group,” the term “substituted” also refers to a case where one or more hydrogen atoms in the BB group are substituted with the AA group.

### “Substituents Described in the Present Specification”

Hereinafter, the substituents described in the present specification are described. Unless otherwise stated, each substituent described in the present specification is defined as follows.

### “Substituted or Unsubstituted Aryl Group”

Specific examples (specific example group G1) of the “substituted or unsubstituted aryl group” described in the present specification include the unsubstituted aryl groups (specific example group G1A) and substituted aryl groups (specific example group G1B), listed below. (Here, an unsubstituted aryl group refers to a case where the “substituted or unsubstituted aryl group” is an “unsubstituted aryl group,” and a substituted aryl group refers to a case where the “substituted or unsubstituted aryl group” is a “substituted aryl group.”) In the present specification, when simply referred to as an “aryl group,” it covers both an “unsubstituted aryl group” and a “substituted aryl group.”

The “substituted aryl group” refers to a group in which one or more hydrogen atoms in an “unsubstituted aryl group” are substituted with a substituent. Examples of the “substituted aryl group” include a group in which one or more hydrogen atoms in the “unsubstituted aryl group” of the following specific example group GIA are substituted with a substituent, and the substituted aryl groups of the following specific example group G1B. Meanwhile, the examples of the “unsubstituted aryl group” and the “substituted aryl group” listed herein are non-limiting examples. The term “substituted aryl group” described in the present specification covers a group in which a hydrogen atom bonded to a carbon atom of the aryl group itself in the “substituted aryl group” of the following specific example group G1B is further substituted with a substituent, and a group in which a hydrogen atom of a substituent in the “substituted aryl group” of the following specific example group G1B is further substituted with a substituent.

Unsubstituted aryl group (specific example group GIA):
phenyl group,
p-biphenyl group,
m-biphenyl group,
o-biphenyl group,
p-terphenyl-4-yl group,
p-terphenyl-3-yl group,
p-terphenyl-2-yl group,
m-terphenyl-4-yl group,
m-terphenyl-3-yl group,
m-terphenyl-2-yl group,
m-terphenyl-3′-yl group,
o-terphenyl-4-yl group,
o-terphenyl-3-yl group,
o-terphenyl-2-yl group,
1-naphthyl group,
2-naphthyl group,
anthryl group,
benzanthryl group,
phenanthryl group,
benzophenanthryl group,
phenalenyl group,
pyrenyl group,
chrysenyl group,
benzochrysenyl group,
triphenylenyl group,
benzotriphenylenyl group,
tetracenyl group,
pentacenyl group,
fluorenyl group,
9,9′-spirobifluorenyl group,
benzofluorenyl group,
dibenzofluorenyl group,
fluoranthenyl group,
benzofluoranthenyl group,
perylenyl group, and
a monovalent aryl group derived by removing one hydrogen atom from a ring structure represented by the following formulae (TEMP-1) to (TEMP-15).

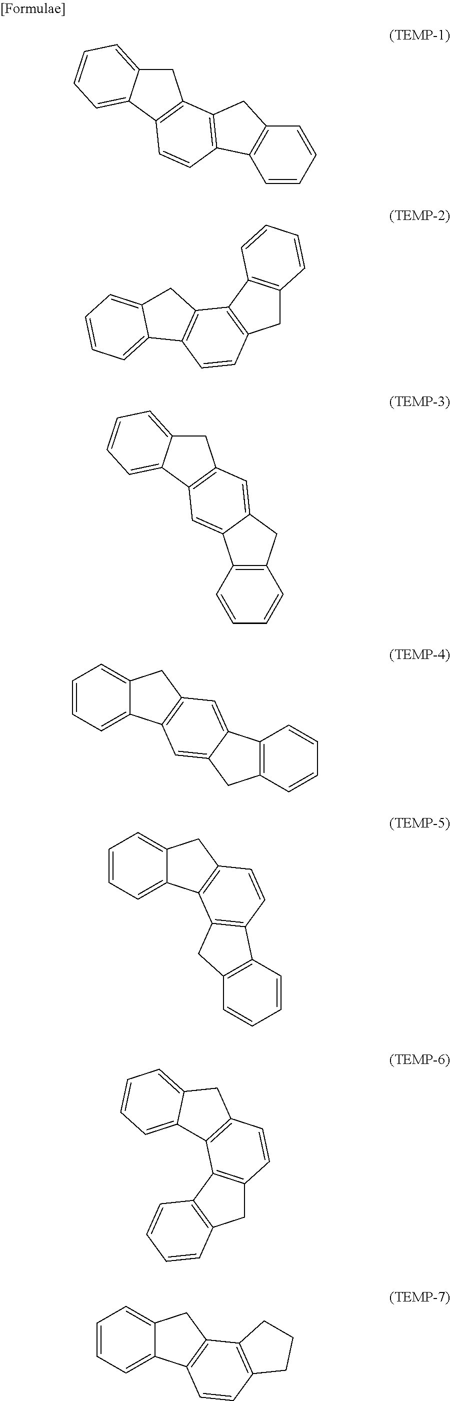

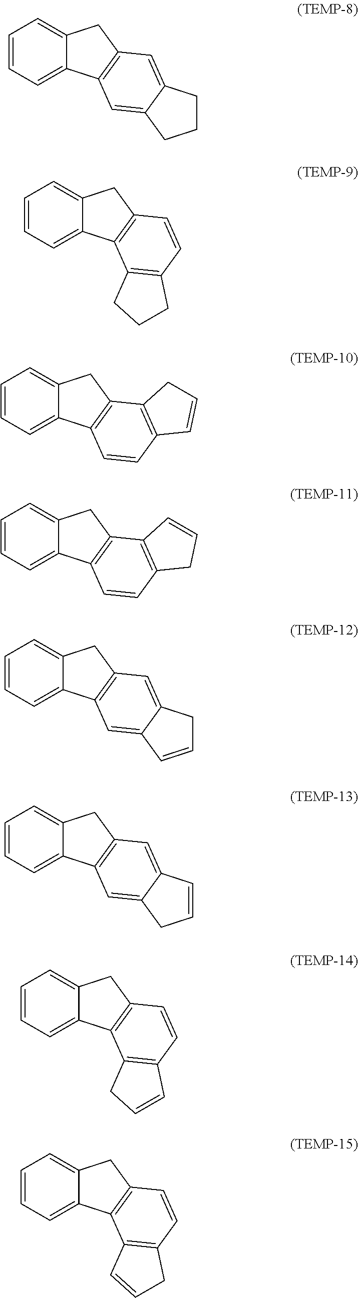

Substituted aryl group (specific example group G1B):
o-tolyl group,
m-tolyl group,
p-tolyl group,
para-xylyl group,
meta-xylyl group,
ortho-xylyl group,
para-isopropylphenyl group,
meta-isopropylphenyl group,
ortho-isopropylphenyl group,
para-t-butylphenyl group,
meta-t-butylphenyl group,
ortho-t-butylphenyl group,
3,4,5-trimethylphenyl group,
9,9-dimethylfluorenyl group,
9,9-diphenylfluorenyl group,
9,9-bis(4-methylphenyl) fluorenyl group,
9,9-bis(4-isopropylphenyl) fluorenyl group,
9,9-bis(4-t-butylphenyl) fluorenyl group,
cyanophenyl group,
griphenylsilylphenyl group,
trimethylsilylphenyl group,
phenylnaphthyl group,
naphthylphenyl group, and
a group in which one or more hydrogen atoms of a monovalent group derived from a ring structure represented by the above formulae (TEMP-1) to (TEMP-15) are substituted with a substituent.

### “Substituted or Unsubstituted Heterocyclic Group”

The term “heterocyclic group” described in the present specification is a cyclic group that contains at least one heteroatom in the ring atoms. Specific examples of heteroatoms include nitrogen atoms, oxygen atoms, sulfur atoms, silicon atoms, phosphorus atoms, and boron atoms. The “heterocyclic group” described in the present specification is a monocyclic ring group or a fused ring group.

The “heterocyclic group” described in the present specification is an aromatic heterocyclic group or a non-aromatic heterocyclic group.

Specific examples (specific example group G2) of the “substituted or unsubstituted heterocyclic group” described in the present specification include the unsubstituted heterocyclic groups (specific example group G2A) and substituted heterocyclic groups (specific example group G2B), listed below. (Here, an unsubstituted heterocyclic group refers to a case where the “substituted or unsubstituted heterocyclic group” is an “unsubstituted heterocyclic group,” and a substituted heterocyclic group refers to a case where the “substituted or unsubstituted heterocyclic group” is a “substituted heterocyclic group.”) In the present specification, when simply referred to as a “heterocyclic group,” it covers both an “unsubstituted heterocyclic group” and a “substituted heterocyclic group.”

The “substituted heterocyclic group” refers to a group in which one or more hydrogen atoms in an “unsubstituted heterocyclic group” are substituted with a substituent. Examples of the “substituted heterocyclic group” include a group in which one or more hydrogen atoms in the “unsubstituted heterocyclic group” of the following specific example group G2A are substituted, and the substituted aryl groups of the following specific example group G2B. Meanwhile, the examples of the “unsubstituted heterocyclic group” and the “substituted heterocyclic group” listed herein are non-limiting examples. The term “substituted heterocyclic group” described in the present specification covers a group in which a hydrogen atom bonded to a ring-forming atom of the aryl group itself in the “substituted heterocyclic group” of the following specific example group G2B is further substituted with a substituent, and a group in which a hydrogen atom of a substituent in the “substituted heterocyclic group” of the following specific example group G2B is further substituted with a substituent.

The specific example group G2A includes, for example, an unsubstituted heterocyclic group that contains a nitrogen atom (specific example group G2A1), an unsubstituted heterocyclic group that contains an oxygen atom (specific example group G2A2), an unsubstituted heterocyclic group that contains a sulfur atom (specific example group G2A3), and a monovalent heterocyclic group derived by removing one hydrogen atom from a ring structure represented by the following formulae (TEMP-16) to (TEMP-33) (specific example group G2A4).

The specific example group G2B includes, for example, a substituted heterocyclic group that contains a nitrogen atom (specific example group G2B1), a substituted heterocyclic group that contains an oxygen atom (specific example group G2B2), a substituted heterocyclic group that contains a sulfur atom (specific example group G2B3), and a group in which one or more hydrogen atoms of a monovalent heterocyclic group derived from a ring structure represented by the following formulae (TEMP-16) to (TEMP-33) are substituted with a substituent (specific example group G2B4).

Unsubstituted heterocyclic group that contains a nitrogen atom (specific example group G2A1):
pyrrolyl group,
imidazolyl group,
pyrazolyl group,
triazolyl group,
tetrazolyl group,
oxazolyl group,
isoxazolyl group,
oxadiazolyl group,
thiazolyl group,
isothiazolyl group,
thiadiazolyl group,
pyridyl group,
pyridazinyl group,
pyrimidinyl group,
pyrazinyl group,
triazinyl group,
indolyl group,
isoindolyl group,
indolizinyl group,
quinolizinyl group,
quinolyl group,
isoquinolyl group,
cinnolyl group,
phthalazinyl group,
quinazolinyl group
quinoxalinyl group
benzimidazolyl group,
indazolyl group,
phenanthrolinyl group,
phenanthridinyl group,
acridinyl group,
phenazinyl group,
carbazolyl group,
benzocarbazolyl group,
morpholino group,
phenoxazinyl group,
phenothiazinyl group,
azacarbazolyl group, and
diazacarbazolyl group.

Unsubstituted heterocyclic group that contains an oxygen atom (specific example group G2A2):
furyl group,
oxazolyl group,
isoxazolyl group,
oxadiazolyl group,
xanthenyl group,
benzofuranyl group,
isobenzofuranyl group,
dibenzofuranyl group,
naphthobenzofuranyl group,
benzoxazolyl group,
benzisoxazolyl group,
phenoxazinyl group,
morpholino group,
dinotefuranyl group,
azadibenzofuranyl group,
diazadibenzofuranyl group,
azanaphthobenzofuranyl group, and
diazanaphthobenzofuranyl group.

Unsubstituted heterocyclic group that contains a sulfur atom (specific example group G2A3):
thienyl group,
thiazolyl group,
isothiazolyl group,
thiadiazolyl group,
benzothiophenyl group (benzothienyl group),
isobenzothiophenyl group (isobenzothienyl group),
dibenzothiophenyl group (dibenzothienyl group),
naphthobenzothiophenyl group (naphthobenzothienyl group),
benzothiazolyl group,
benzisothiazolyl group,
phenothiazinyl group,
dinaphthothiophenyl group (dinaphthothienyl group),
azadibenzothiophenyl group (azadibenzothienyl group),
diazadibenzothiophenyl group (diazadibenzothienyl group),
azanaphthobenzothiophenyl group (azanaphthobenzothienyl group), and
diazanaphthobenzothiophenyl group (diazanaphthobenzothienyl group).

A monovalent heterocyclic group derived by removing one hydrogen atom from a ring structure represented by the following formulae (TEMP-16) to (TEMP-33) (specific example group G2A4):

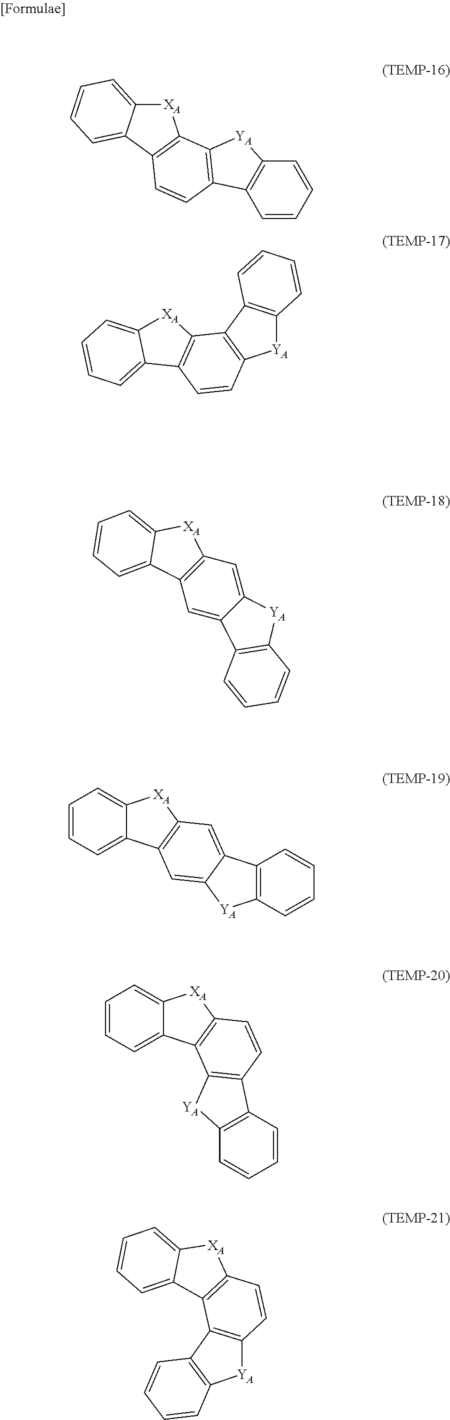

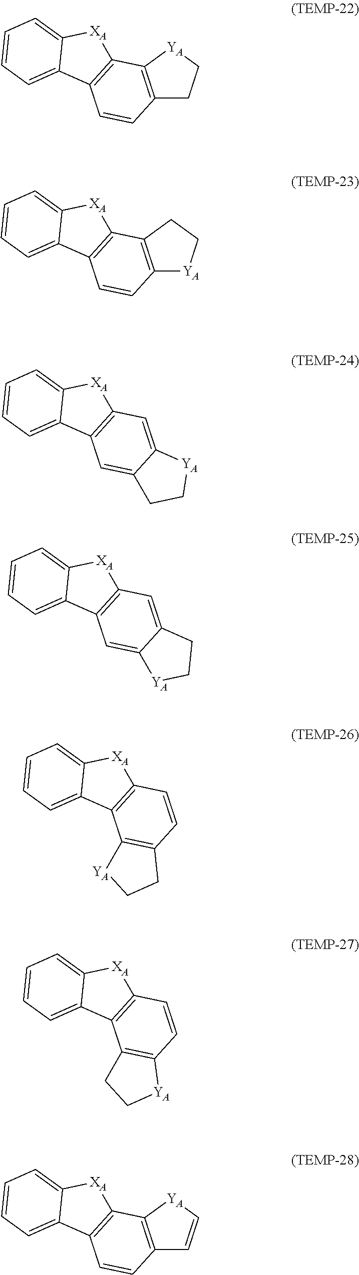

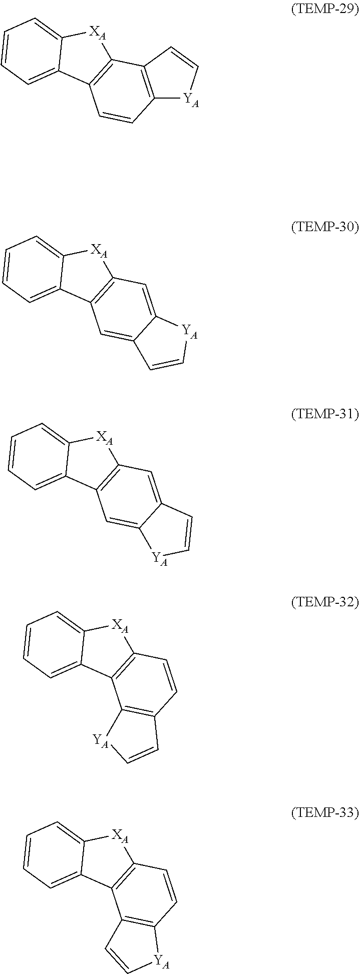

In the above Formulae (TEMP-16) to (TEMP-33), X_{A} and Y_{A} are each independently an oxygen atom, a sulfur atom, NH, or CH₂, provided that at least one of X_{A} and Y_{A} is an oxygen atom, a sulfur atom, or NH.

In the above Formulae (TEMP-16) to (TEMP-33), when at least one of X_{A} and Y_{A} is NH or CH₂, a monovalent heterocyclic group derived from a ring structure represented by the above Formulae (TEMP-16) to (TEMP-33) covers a monovalent group obtained by removing one hydrogen atom from NH or CH₂.

Substituted heterocyclic group that contains a nitrogen atom (specific example group G2B1):
(9-phenyl) carbazolyl group,
(9-biphenylyl) carbazolyl group,
(9-phenyl)phenylcarbazolyl group,
(9-naphthyl) carbazolyl group,
diphenylcarbazol-9-yl group,
phenylcarbazol-9-yl group,
methylbenzimidazolyl group,
ethylbenzimidazolyl group,
phenyltriazinyl group,
biphenylyltriazinyl group,
diphenyltriazinyl group,
phenylquinazolinyl group, and
biphenylylquinazolinyl group.

Substituted heterocyclic group that contains an oxygen atom (specific example group G2B2):
phenyldibenzofuranyl group,
methyldibenzofuranyl group,
t-butyldibenzofuranyl group, and
a monovalent residue of spiro[9H-xanthene-9,9′-[9H]fluorene].

Substituted heterocyclic group that contains a sulfur atom (specific example group G2B3):
phenyldibenzothiophenyl group,
methyldibenzothiophenyl group,
t-butyldibenzothiophenyl group, and
a monovalent residue of spiro[9H-thioxanthene-9,9′-[9H]fluorene].

A group in which one or more hydrogen atoms of a monovalent heterocyclic group derived from a ring structure represented by the above formulae (TEMP-16) to (TEMP-33) are substituted with a substituent (specific example group G2B4):

The “one or more hydrogen atoms of a monovalent heterocyclic group” refers to one or more hydrogen atoms selected from a hydrogen atom bonded to a ring carbon atom of the monovalent heterocyclic group, a hydrogen atom bonded to a nitrogen atom when at least one of X_{A} and Y_{A} is NH, and a hydrogen atom of a methylene group when one of X_{A} and Y_{A} is CH₂.

### “Substituted or Unsubstituted Alkyl Group”

Specific examples (specific example group G3) of the “substituted or unsubstituted alkyl group” described in the present specification include the unsubstituted alkyl groups (specific example group G3A) and substituted alkyl groups (specific example group G3B), listed below. (Here, an unsubstituted alkyl group refers to a case where the “substituted or unsubstituted alkyl group” is an “unsubstituted alkyl group,” and a substituted alkyl group refers to a case where the “substituted or unsubstituted alkyl group” is a “substituted alkyl group.”) Hereinafter, when simply referred to as an “alkyl group,” it covers both an “unsubstituted alkyl group” and a “substituted alkyl group.”

The “substituted alkyl group” refers to a group in which one or more hydrogen atoms in an “unsubstituted alkyl group” are substituted with a substituent. Specific examples of the “substituted alkyl group” include a group in which one or more hydrogen atoms of the following “unsubstituted alkyl groups” (specific example group G3A) are substituted with a substituent, and the substituted alkyl groups (specific example group G3B). In the present specification, the alkyl group in the “unsubstituted alkyl group” refers to a chain-type alkyl group. Therefore, the “unsubstituted alkyl group” covers a straight-chain “unsubstituted alkyl group” and a branched “unsubstituted alkyl group.” Meanwhile, the examples of the “unsubstituted alkyl group” and the “substituted alkyl group” listed herein are non-limiting examples. The term “substituted alkyl group” described in the present specification covers a group in which a hydrogen atom of the alkyl group itself in the “substituted alkyl group” of the specific example group G3B is further substituted with a substituent, and a group in which a hydrogen atom of a substituent in the “substituted alkyl group” of the following specific example group G3B is further substituted with a substituent.

Unsubstituted alkyl group (specific example group G3A):
Methyl group,
ethyl group,
n-propyl group,
isopropyl group,
n-butyl group,
isobutyl group,
s-butyl group, and
t-butyl group.

Substituted alkyl group (specific example group G3B):
heptafluoropropyl group (including isomers),
pentafluoroethyl group,
2,2,2-trifluoroethyl group, and
trifluoromethyl group.

### “Substituted or Unsubstituted Alkenyl Group”

Specific examples (specific example group G4) of the “substituted or unsubstituted alkenyl group” described in the present specification include the unsubstituted alkenyl groups (specific example group G4A) and substituted alkenyl groups (specific example group G4B), listed below. (Here, an unsubstituted alkenyl group refers to a case where the “substituted or unsubstituted alkenyl group” is an “unsubstituted alkenyl group,” and a substituted alkenyl group refers to a case where the “substituted or unsubstituted alkenyl group” is a “substituted alkenyl group.”) In the present specification, when simply referred to as an “alkenyl group,” it covers both an “unsubstituted alkenyl group” and a “substituted alkenyl group.”

The “substituted alkenyl group” refers to a group in which one or more hydrogen atoms in an “unsubstituted alkenyl group” are substituted with a substituent. Specific examples of the “substituted alkenyl group” include a group in which the following “unsubstituted alkenyl groups” (specific example group G4A) have a substituent, and the substituted alkenyl groups (specific example group G4B). Meanwhile, the examples of the “unsubstituted alkenyl group” and the “substituted alkenyl group” listed herein are non-limiting examples. The term “substituted alkenyl group” described in the present specification covers a group in which a hydrogen atom of the alkenyl group itself in the “substituted alkenyl group” of the specific example group G4B is further substituted with a substituent, and a group in which a hydrogen atom of a substituent in the “substituted alkenyl group” of the following specific example group G4B is further substituted with a substituent.

Unsubstituted alkenyl group (specific example group G4A):
vinyl group,
allyl group,
1-butenyl group,
2-butenyl group, and
3-butenyl group.

Substituted alkenyl group (specific example group G4B):
1,3-butanediene diary,
1-methylvinyl group,
1-methylallyl group,
1,1-dimethylallyl group,
2-methylallyl group, and
1,2-dimethylallyl group.

### “Substituted or Unsubstituted Alkynyl Group”

Specific examples (specific example group G5) of the “substituted or unsubstituted alkynyl group” described in the present specification include the unsubstituted alkynyl groups (specific example group G5A), listed below. (Here, an unsubstituted alkynyl group refers to a case where the “substituted or unsubstituted alkynyl group” is an “unsubstituted alkynyl group.”) Hereinafter, when simply referred to as an “alkynyl group,” it covers both an “unsubstituted alkynyl group” and a “substituted alkynyl group.”

The “substituted alkynyl group” refers to a group in which one or more hydrogen atoms in an “unsubstituted alkynyl group” are substituted with a substituent. Specific examples of the “substituted alkynyl group” include a group in which one or more hydrogen atoms of the following “unsubstituted alkynyl groups” (specific example group G5A) are substituted with a substituent.

Unsubstituted alkynyl group (specific example group G5A):
ethynyl group.

### “Substituted or Unsubstituted Cycloalkyl Group”

Specific examples (specific example group G6) of the “substituted or unsubstituted cycloalkyl group” described in the present specification include the unsubstituted cycloalkyl groups (specific example group G6A) and substituted cycloalkyl groups (specific example group G6B), listed below. (Here, an unsubstituted cycloalkyl group refers to a case where the “substituted or unsubstituted cycloalkyl group” is an “unsubstituted cycloalkyl group,” and a substituted cycloalkyl group refers to a case where the “substituted or unsubstituted cycloalkyl group” is a “substituted cycloalkyl group.”) In the present specification, when simply referred to as a “cycloalkyl group,” it covers both an “unsubstituted cycloalkyl group” and a “substituted cycloalkyl group.”

The “substituted cycloalkyl group” refers to a group in which one or more hydrogen atoms in an “unsubstituted cycloalkyl group” are substituted with a substituent. Specific examples of the “substituted cycloalkyl group” include a group in which one or more hydrogen atoms of the following “unsubstituted cycloalkyl groups” (specific example group G6A) are substituted with a substituent, and the substituted cycloalkyl groups (specific example group G6B). Meanwhile, the examples of the “unsubstituted cycloalkyl group” and the “substituted cycloalkyl group” listed herein are non-limiting examples. The term “substituted aryl group” described in the present specification covers a group in which one or more hydrogen atoms bonded to a carbon atom of the cycloalkyl group itself in the “substituted cycloalkyl group” of the following specific example group G6B is further substituted with a substituent, and a group in which a hydrogen atom of a substituent in the “substituted cycloalkyl group” of the following specific example group G6B is further substituted with a substituent.

Unsubstituted cycloalkyl group (specific example group G6A):
cyclopropyl group,
cyclobutyl group,
cyclopentyl group,
cyclohexyl group,
1-adamantyl group,
2-adamantyl group,
1-norbornyl group, and
2-norbornyl group.

Substituted cycloalkyl group (specific example group G6B):
4-methylcyclohexyl group.
   “Group Represented by —Si(R₉₀₁)(R₉₀₂)(R₉₀₃)”

Specific examples (specific example group G7) of the group represented by —Si(R₉₀₁)(R₉₀₂)(R₉₀₃) described in the present specification include:
—Si(G1)(G1)(G1),
—Si(G1)(G2)(G2),
—Si(G1)(G1)(G2),
—Si(G2)(G2)(G2),
—Si(G3)(G3)(G3), and
—Si(G6)(G6)(G6).

Here,

G1 is a “substituted or unsubstituted aryl group” described in the specific example group G1.

G2 is a “substituted or unsubstituted heterocyclic group” described in the specific example group G2.

G3 is a “substituted or unsubstituted alkyl group” described in the specific example group G3.

G6 is a “substituted or unsubstituted cycloalkyl group” described in the specific example group G6.

A plurality of G1 in —Si(G1)(G1)(G1) are the same as or different from each other.

A plurality of G2 in —Si(G1)(G2)(G2) are the same as or different from each other.

A plurality of G1 in —Si(G1)(G1)(G2) are the same as or different from each other.

A plurality of G2 in —Si(G2)(G2)(G2) are the same as or different from each other.

A plurality of G3 in —Si(G3)(G3)(G3) are the same as or different from each other.

A plurality of G6 in —Si(G6)(G6)(G6) are the same as or different from each other.

### “Group Represented by —O—(R₉₀₄)”

Specific examples (specific example group G8) of the group represented by —O—(R₉₀₄) described in the present specification include:
—O(G1),
—O(G2),
—O(G3), and
—O(G6).

Here,

G1 is a “substituted or unsubstituted aryl group” described in the specific example group G1.

G2 is a “substituted or unsubstituted heterocyclic group” described in the specific example group G2.

G3 is a “substituted or unsubstituted alkyl group” described in the specific example group G3.

G6 is a “substituted or unsubstituted cycloalkyl group” described in the specific example group G6.

“Group represented by —S—(R₉₀₅)”

Specific examples (specific example group G9) of the group represented by —S—(R₉₀₅) described in the present specification include:
—S(G1),
—S(G2),
—S(G3), and
—S(G6).

Here,

G1 is a “substituted or unsubstituted aryl group” described in the specific example group G1.

G2 is a “substituted or unsubstituted heterocyclic group” described in the specific example group G2.

G3 is a “substituted or unsubstituted alkyl group” described in the specific example group G3.

G6 is a “substituted or unsubstituted cycloalkyl group” described in the specific example group G6.

“Group Represented by —N(R₉₀₆)(R₉₀₇)”

Specific examples (specific example group G10) of the group represented by —N(R₉₀₆)(R₉₀₇) described in the present specification include:
—N(G1)(G1),
—N(G2)(G2),
—N(G1)(G2),
—N(G3)(G3), and
—N(G6)(G6)

Here,

G1 is a “substituted or unsubstituted aryl group” described in the specific example group G1.

G2 is a “substituted or unsubstituted heterocyclic group” described in the specific example group G2.

G3 is a “substituted or unsubstituted alkyl group” described in the specific example group G3.

G6 is a “substituted or unsubstituted cycloalkyl group” described in the specific example group G6.

A plurality of G1 in —N(G1)(G1) are the same as or different from each other.

A plurality of G2 in —N(G2)(G2) are the same as or different from each other.

A plurality of G3 in —N(G3)(G3) are the same as or different from each other.

A plurality of G6 in —N(G6)(G6) are the same as or different from each other.

“Group Represented by —Si(R′₉₀₁)(R′₉₀₂)(R′₉₀₃)”

Specific examples (specific example group G11) of the group represented by —Si(R′₉₀₁)(R′₉₀₂)(R′₉₀₃) described in the present specification include: Si(G1)(G1)(G1).

Here,

G1 is a “substituted or unsubstituted aryl group” described in the specific example group G1.

A plurality of G1 in —Si(G1)(G1)(G1) are the same as or different from each other.

“Group Represented by —Si(R′₉₀₄)(R′₉₀₅)(R′₉₀₆)”

Specific examples (specific example group G12) of the group represented by —Si(R′₉₀₄)(R′₉₀₅)(R′₉₀₆) described in the present specification include:
—Si(G1)(G1)(G1).

Here,

G1 is a “substituted or unsubstituted aryl group” described in the specific example group G1.

A plurality of G1 in —Si(G1)(G1)(G1) are the same as or different from each other.

### “Halogen Atom”

Specific examples (specific example group G13) of the “halogen atom” described in the present specification include a fluorine atom, a chlorine atom, a bromine atom, and an iodine atom.

### “Substituted or Unsubstituted Arylene Group”

The “substituted or unsubstituted arylene group” described in the present specification is, unless otherwise stated, a divalent group derived by removing one hydrogen atom from an aryl ring of the “substituted or unsubstituted aryl group.” Specific examples (specific example group G14) of the “substituted or unsubstituted arylene group” include a divalent group derived by removing one hydrogen atom from an aryl ring of the “substituted or unsubstituted aryl group” described in the specific example group G1.

The substituted or unsubstituted arylene group described in the present specification is preferably any one of the groups represented by the following Formulae (TEMP-42) to (TEMP-68), unless otherwise stated in the present specification.

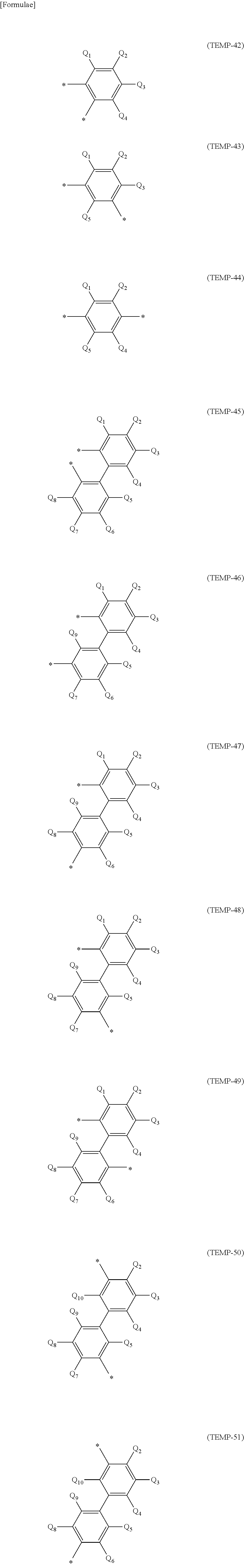

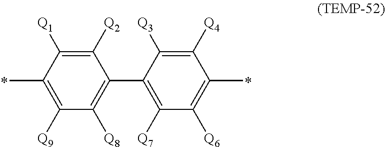

In the above Formulae (TEMP-42) to (TEMP-52), Q₁ to Q₁₀ are each independently a hydrogen atom or a substituent.

In the above Formulae (TEMP-42) to (TEMP-52), * represents a bonding position.

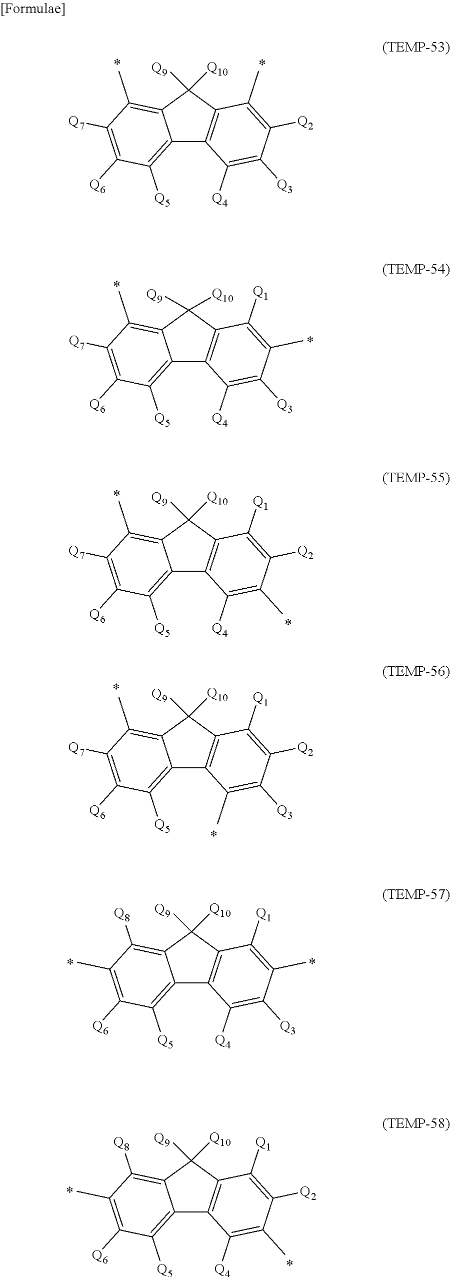

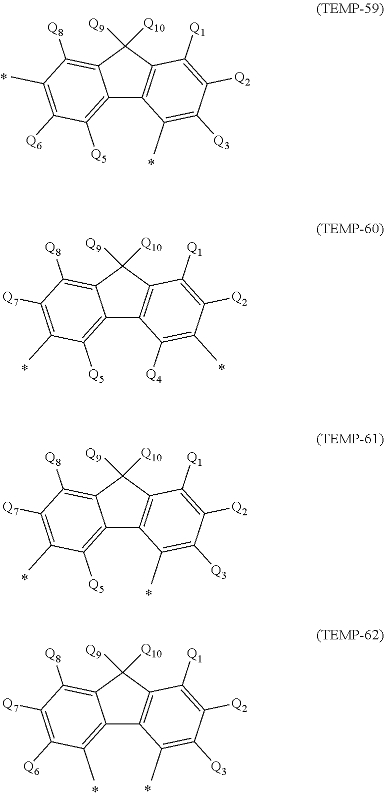

In the above Formulae (TEMP-53) to (TEMP-62), Q₁ to Q₁₀ are each independently a hydrogen atom or a substituent.

Q₉ and Q₁₀ may be bonded to each other via a single bond to form a ring.

In the above Formulae (TEMP-53) to (TEMP-62), * represents a bonding position.

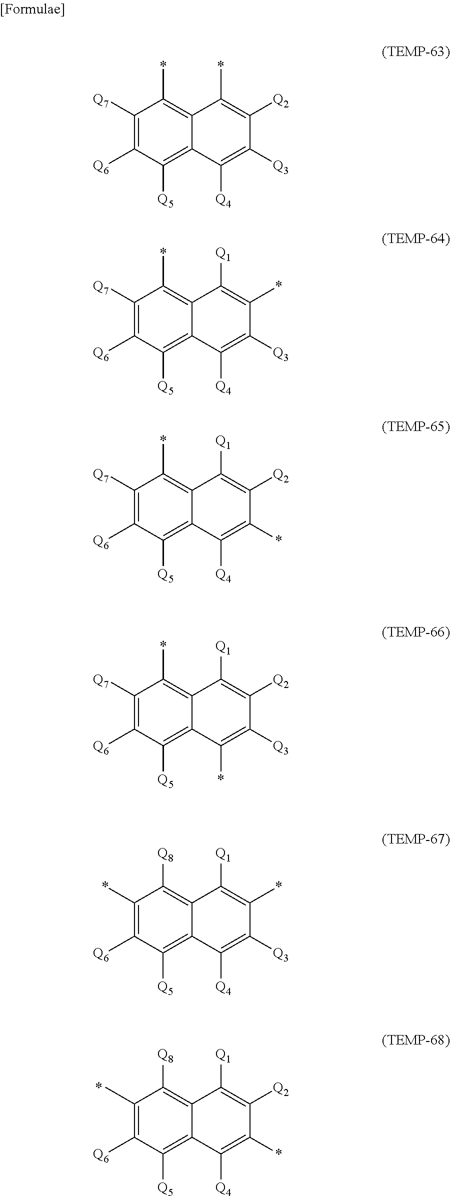

In the above Formulae (TEMP-63) to (TEMP-68), Q₁ to Q₈ are each independently a hydrogen atom or a substituent.

In the above Formulae (TEMP-63) to (TEMP-68), * represents a bonding position.

### “Substituted or Unsubstituted Divalent Heterocyclic Group”

The “substituted or unsubstituted divalent heterocyclic group” described in the present specification is, unless otherwise stated, a divalent group derived by removing one hydrogen atom from a heterocyclic ring of the “substituted or unsubstituted heterocyclic group.” Specific examples (specific example group G15) of the “substituted or unsubstituted arylene group” include a divalent group derived by removing one hydrogen atom from a heterocyclic ring of the “substituted or unsubstituted heterocyclic group” described in the specific example group G2.

The substituted or unsubstituted divalent heterocyclic group described in the present specification is preferably any of the groups represented by the following Formulae (TEMP-69) to (TEMP-102), unless otherwise stated in the present specification.

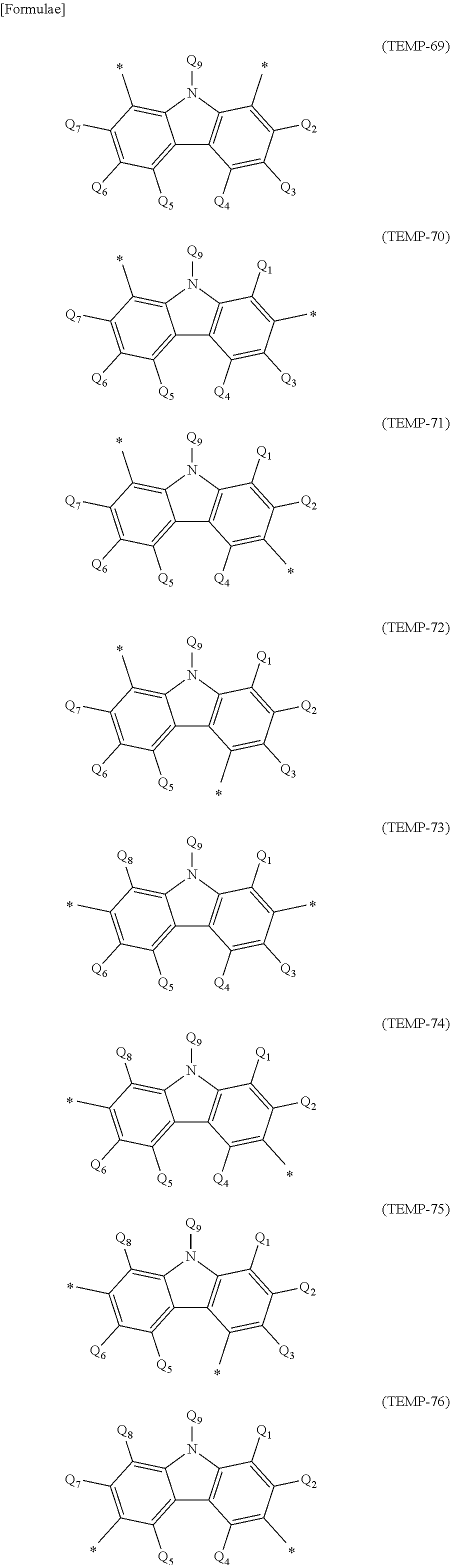

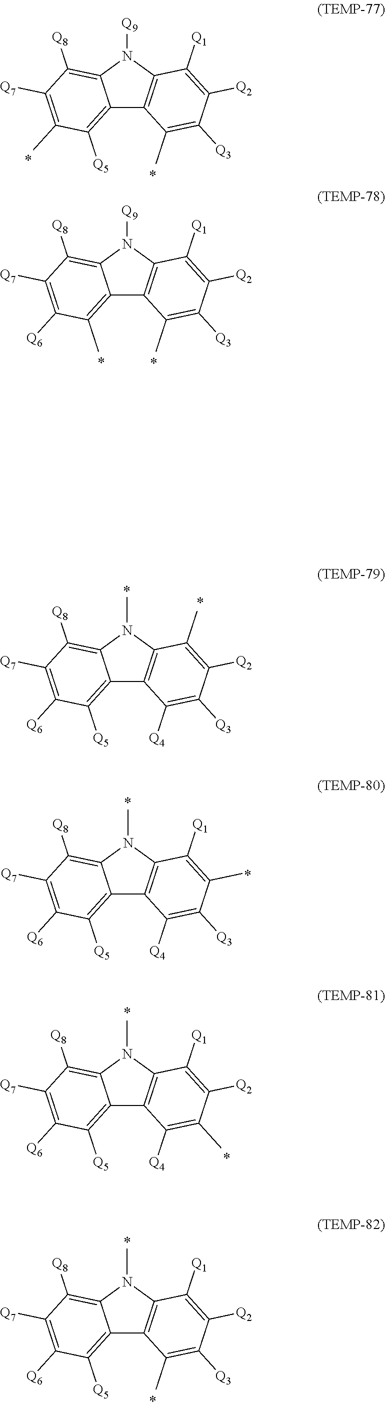

In the above Formulae (TEMP-69) to (TEMP-82), Q₁ to Q₉ are each independently a hydrogen atom or a substituent.

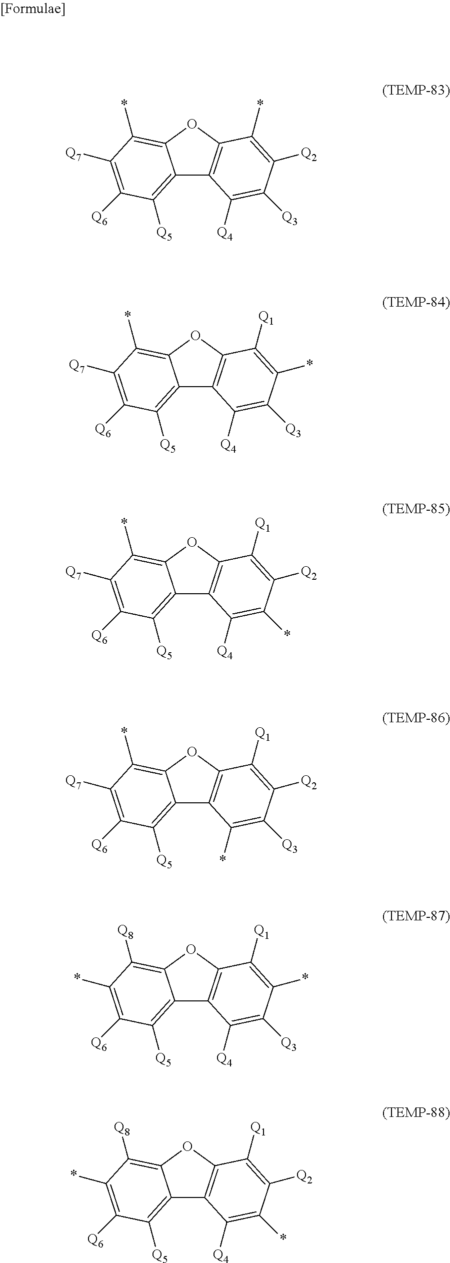

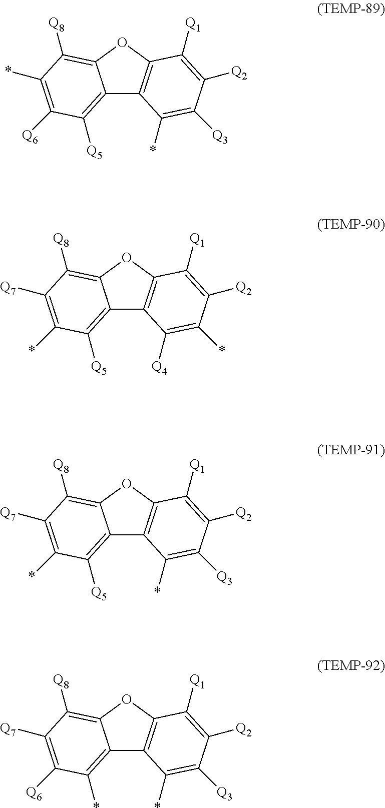

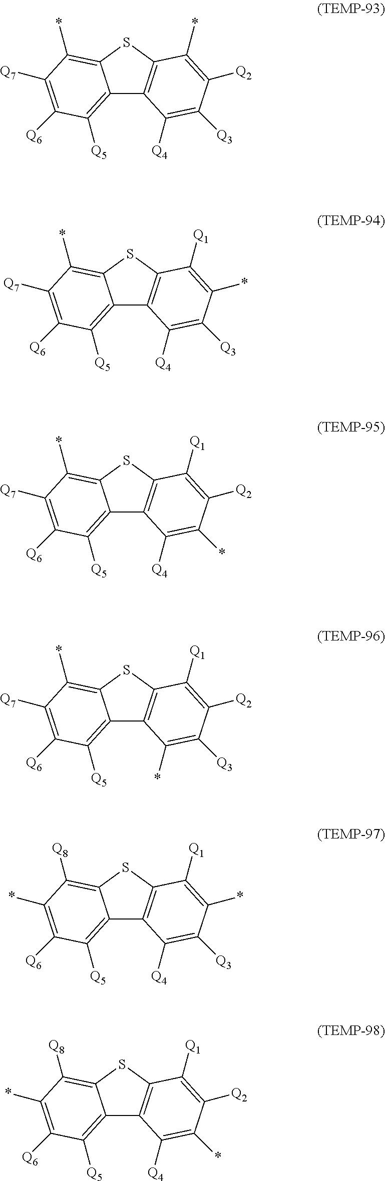

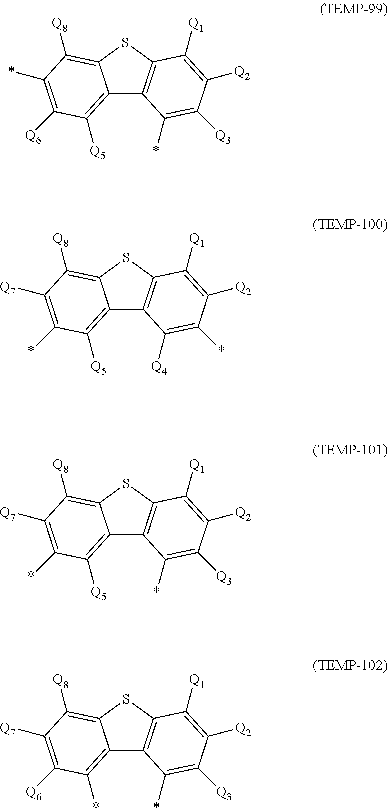

In the above Formulae (TEMP-83) to (TEMP-102), Q₁ to Q₈ are each independently a hydrogen atom or a substituent.

The above is the description of “substituents described in the present specification.”

### “Case of Bonding to Form a Ring”

In the present specification, the expression “one or more pairs of two or more adjacent groups bond to each other to form a substituted or unsubstituted monocyclic ring, bond to each other to form a substituted or unsubstituted fused ring, or do not bond to each other” refers to a case where “one or more pairs of two or more adjacent groups bond to each other to form a substituted or unsubstituted monocyclic ring,” a case where “one or more pairs of two or more adjacent groups bond to each other to form a substituted or unsubstituted fused ring,” and a case where “one or more pairs of two or more adjacent groups do not bond to each other.”

In the present specification, the case where “one or more pairs of two or more adjacent groups bond to each other to form a substituted or unsubstituted monocyclic ring” and the case where “one or more pairs of two or more adjacent groups bond to each other to form a substituted or unsubstituted fused ring” (hereinafter, these cases may be collectively referred to as “a case of bonding to form a ring”) will be described below. The case of an anthracene compound represented by the following Formula (TEMP-103), in which the parent skeleton is an anthracene ring, will be described as an example.

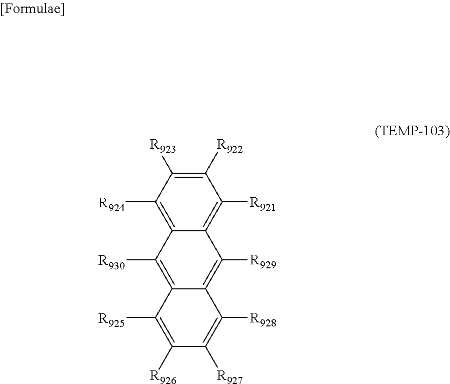

For example, in the case where “one or more pairs of two or more adjacent groups bond to each other to form a ring,” among R₉₂₁ to R₉₃₀, a pair of two adjacent groups refers to a pair of R⁹²¹ and R₉₂₂, a pair of R⁹²² and R₉₂₃, a pair of R⁹²³ and R₉₂₄, a pair of R₉₂₄ and R₉₃₀, a pair of R⁹³⁰ and R₉₂₅, a pair of R₉₂₅ and R₉₂₆, a pair of R⁹²⁶ and R₉₂₇, a pair of R₉₂₇ and R₉₂₈, a pair of R₉₂₈ and R₉₂₉, and a pair of R₉₂₉ and R₉₂₁.

The term “one or more pairs” means that two or more pairs of two or more adjacent groups may simultaneously form rings. For example, when R₉₂₁ and R₉₂₂ bond to each other to form a ring Q_{A}, and, at the same time, R₉₂₅ and R₉₂₆ bond to each other to form a ring Q_{B}, the anthracene compound represented by the Formula (TEMP-103) is represented by the following Formula (TEMP-104).

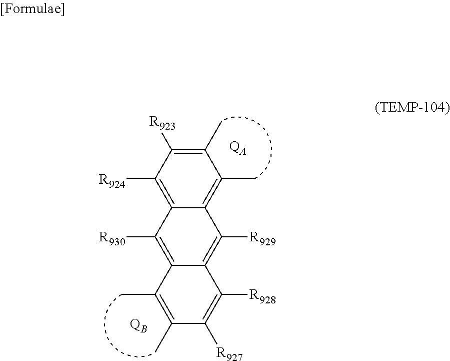

The case where “a pair of two or more adjacent groups” forms a ring covers not only the case where a pair of “two” adjacent groups bonds as in the above examples, but also the case where a pair of “three or more” adjacent groups bonds. For example, it refers to the case where R₉₂₁ and R₉₂₂ bond to each other to form a ring Q_{A}, and further R₉₂₂ and R₉₂₃ bond to each other to form a ring Q_{C}, and a pair of three adjacent groups (R₉₂₁, R₉₂₂ and R₉₂₃) bond to each other to form a ring to be fused to the anthracene parent skeleton, in which case the anthracene compound represented by the Formula (TEMP-103) is represented by the following Formula (TEMP-105). In the following Formula (TEMP-105), ring Q_{A} and ring Q_{C} share R₉₂₂.

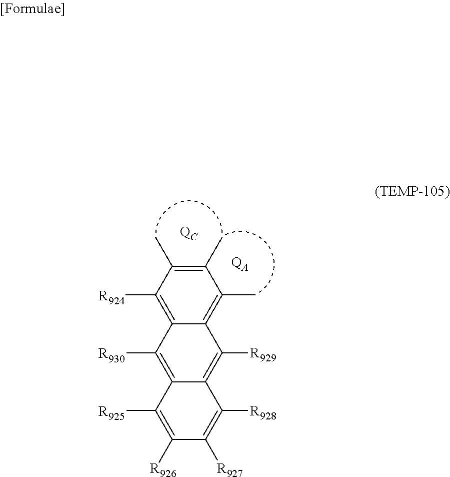

The “monocyclic ring” or “fused ring” to be formed may be a saturated ring or an unsaturated ring as the structure of the formed ring alone. Even when “one pair of two adjacent groups” forms a “monocyclic ring” or “fused ring,” the “monocyclic ring” or “fused ring” may form a saturated ring or an unsaturated ring. For example, ring Q_{A} and ring Q_{B} formed in the Formula (TEMP-104) are each a “monocyclic ring” or a “fused ring.” In addition, ring Q_{A} and ring Q_{C} formed in the Formula (TEMP-105) are a “fused ring.” Ring Q_{A} and ring Q_{C} in the Formula (TEMP-105) form a fused ring by fusion of ring Q_{A} and ring Q_{C}. If ring Q_{A} in the Formula (TEMP-104) is a benzene ring, ring Q_{A} is a monocyclic ring. If ring Q_{A} in the Formula (TEMP-104) is a naphthalene ring, ring Q_{A} is a fused ring.

The “unsaturated ring” refers to an aromatic hydrocarbon ring or an aromatic heterocyclic ring. The “saturated ring” refers to an aliphatic hydrocarbon ring or a non-aromatic heterocyclic ring.

Specific examples of the aromatic hydrocarbon ring include a structure in which the groups given as specific examples in the specific example group G1 are terminated with a hydrogen atom.

Specific examples of the aromatic heterocyclic ring include a structure in which the aromatic heterocyclic groups given as specific examples in the specific example group G2 are terminated with a hydrogen atom.

Specific examples of the aliphatic hydrocarbon ring include a structure in which the groups given as specific examples in the specific example group G6 are terminated with a hydrogen atom.

The term “forming a ring” refers to forming a ring with only a plurality of atoms of the parent skeleton, or forming a ring with a plurality of atoms of the parent skeleton and one or more arbitrary elements in addition. For example, ring Q_{A} formed by bonding R₉₂₁ and R₉₂₂ to each other as shown in the Formula (TEMP-104) refers to a ring formed with the carbon atom of the anthracene skeleton to which R₉₂₁ is bonded, the carbon atom of the anthracene skeleton to which R₉₂₂ is bonded, and one or more arbitrary elements. As a specific example, in the case where ring Q_{A} is formed with R₉₂₁ and R₉₂₂, when a monocyclic unsaturated ring is formed with the carbon atom of the anthracene skeleton to which R₉₂₁ is bonded, the carbon atom of the anthracene skeleton to which R₉₂₂ is bonded, and four carbon atoms, the ring formed with R₉₂₁ and R₉₂₂ is a benzene ring.

Here, the “arbitrary element” is preferably at least one element selected from the group consisting of a carbon element, a nitrogen element, an oxygen element, and a sulfur element, unless otherwise stated in the present specification. In the arbitrary element (for example, in the case of a carbon element or a nitrogen element), a bond that does not form a ring may be terminated with a hydrogen atom or the like, or it may be substituted with an “arbitrary substituent” described later. When an arbitrary element other than a carbon element is contained, the ring to be formed is a heterocyclic ring.

The number of the “one or more arbitrary elements” that constitute a monocyclic ring or a fused ring is preferably 2 to 15, more preferably 3 to 12, and still more preferably 3 to 5, unless otherwise stated in the present specification.

Unless otherwise stated in the present specification, among the “monocyclic ring” and “fused ring,” the “monocyclic ring” is preferred.

Unless otherwise stated in the present specification, among the “saturated ring” and “unsaturated ring,” the “unsaturated ring” is preferred.

Unless otherwise stated in the present specification, the “monocyclic ring” is preferably a benzene ring.

Unless otherwise stated in the present specification, the “unsaturated ring” is preferably a benzene ring.

When “one or more pairs of two or more adjacent groups” “bond to each other to form a substituted or unsubstituted monocyclic ring” or “bond to each other to form a substituted or unsubstituted fused ring,” unless otherwise stated in the present specification, preferably, one or more pairs of two or more adjacent groups bond to each other to form a substituted or unsubstituted “unsaturated ring” consisting of a plurality of atoms of the parent skeleton and at least one element selected from the group consisting of 1 to 15 carbon elements, nitrogen elements, oxygen elements, and sulfur elements.

When the “monocyclic ring” or “fused ring” has a substituent, the substituent is, for example, an “arbitrary substituent” described later. Specific examples of the substituent, when the above “monocyclic ring” or “fused ring” has a substituent, are the substituents described in the section “Substituents described in the present specification” described above.

When the “saturated ring” or “unsaturated ring” has a substituent, the substituent is, for example, an “arbitrary substituent” described later. Specific examples of the substituent, when the above “monocyclic ring” or “fused ring” has a substituent, are the substituents described in the section “Substituents described in the present specification” described above.

The above is the description of the case where “one or more pairs of two or more adjacent groups bond to each other to form a substituted or unsubstituted monocyclic ring” and the case where “one or more pairs of two or more adjacent groups bond to each other to form a substituted or unsubstituted fused ring” (hereinafter, “a case of bonding to form a ring”).

### Substituent in the Case of “Substituted or Unsubstituted”

In an embodiment of the present specification, the substituent in the case of the “substituted or unsubstituted” (which may be referred to as an “arbitrary substituent” in the present specification) is, for example, a group selected from the group consisting of:
an unsubstituted alkyl group having 1 to 50 carbon atoms,
an unsubstituted alkenyl group having 2 to 50 carbon atoms,
an unsubstituted alkynyl group having 2 to 50 carbon atoms,
an unsubstituted cycloalkyl group having 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇),
a halogen atom, a cyano group, a nitro group,
an unsubstituted aryl group having 6 to 50 ring carbon atoms, and
an unsubstituted heterocyclic group having 5 to 50 ring atoms,
wherein R₉₀₁ to R₉₀₇ are each independently:
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted heterocyclic group having 5 to 50 ring atoms.

When two or more of R₉₀₁ are present, the two or more of R₉₀₁ are the same as or different from each other,
when two or more of R₉₀₂ are present, the two or more of R₉₀₂ are the same as or different from each other,
when two or more of R₉₀₃ are present, the two or more of R₉₀₃ are the same as or different from each other,
when two or more of R₉₀₄ are present, the two or more of R₉₀₄ are the same as or different from each other,
when two or more of R₉₀₅ are present, the two or more of R₉₀₅ are the same as or different from each other,
when two or more of R₉₀₆ are present, the two or more of R₉₀₆ are the same as or different from each other, and
when two or more of R₉₀₇ are present, the two or more of R₉₀₇ are the same as or different from each other.

In an embodiment, the substituent in the case of the “substituted or unsubstituted” is a group selected from the group consisting of:
an alkyl group having 1 to 50 carbon atoms,
an aryl group having 6 to 50 ring carbon atoms,
a heterocyclic group having 5 to 50 ring atoms,
a halogen atom, and
a cyano group.

In an embodiment, the substituent in the case of the “substituted or unsubstituted” is a group selected from the group consisting of:
an alkyl group having 1 to 18 carbon atoms,
an aryl group having 6 to 18 ring carbon atoms,
a heterocyclic group having 5 to 18 ring atoms,
a halogen atom, and
a cyano group.

Specific examples of each group of the arbitrary substituents are the specific examples of the substituents described in the section “Substituents described in the present specification” described above.

Unless otherwise stated in the present specification, arbitrary substituents adjacent to each other may form a “saturated ring” or an “unsaturated ring,” and preferably form a substituted or unsubstituted saturated 5-membered ring, a substituted or unsubstituted saturated 6-membered ring, a substituted or unsubstituted unsaturated 5-membered ring, or a substituted or unsubstituted unsaturated 6-membered ring, and more preferably form a benzene ring.

Unless otherwise stated in the present specification, an arbitrary substituent may further have a substituent. The substituent that an arbitrary substituent further has is the same as the above arbitrary substituent.

In the present specification, a numerical range expressed as “AA to BB” refers to a range that encompasses AA as a lower limit and BB as an upper limit, wherein AA is the numerical value recited before “to,” and BB is the numerical value recited after “to.”

### <Organic Electroluminescent Element>

Hereinafter, an organic electroluminescent element according to an aspect of the present invention will be described.

### First Embodiment

An organic electroluminescent element according to the first embodiment of the present invention comprises an anode, a cathode, and an organic layer interposed between the anode and the cathode,
wherein the organic layer comprises:
a first host compound having a HOMO energy level of −5.5 eV or higher and a triplet energy level of 2.5 eV or lower,
a second host compound having a LUMO energy level of −4.0 eV to −3.0 eV, and
a dopant compound,
wherein the first host compound and the second host compound are capable of recombining with each other to form an exciplex,
the exciplex has a triplet energy level of greater than 1.5 eV, and
the first host compound, the second host compound, and the dopant compound satisfy the following Relationships 1 to 4.

$${H}_{1} {S}_{1} > D {S}_{1} \qquad [ Relationship 1 ]$$

$${H}_{1} {T}_{1} > D {T}_{1} \qquad [ Relationship 2 ]$$

$${H}_{2} {S}_{1} > D {S}_{1} \qquad [ Relationship 3 ]$$

$${H}_{2} {T}_{1} > D {T}_{1} \qquad [ Relationship 4 ]$$

In Relationships 1 to 4,
H₁S₁ is a singlet energy level of the first host compound,
H₁T₁ is a triplet energy level of the first host compound,
H₂S₁ is a singlet energy level of the second host compound,
H₂T₁ is a triplet energy level of the second host compound,
DS₁ is a singlet energy level of the dopant compound, and
DT₁ is a triplet energy level of the dopant compound.

The organic electroluminescent element according to an aspect of the present invention exhibits high element performance as it has the above configuration. Specifically, an organic electroluminescent element having a longer lifespan, a lower driving voltage, and higher luminous efficiency can be provided.

Conventionally, triplet-triplet annihilation (TTA) has been used as a technology for enhancing the luminous efficiency of organic electroluminescent elements. TTA refers to a mechanism in which heterogeneous molecules collide in a triplet excited state to create one singlet ground state molecule and one singlet excited state molecule.

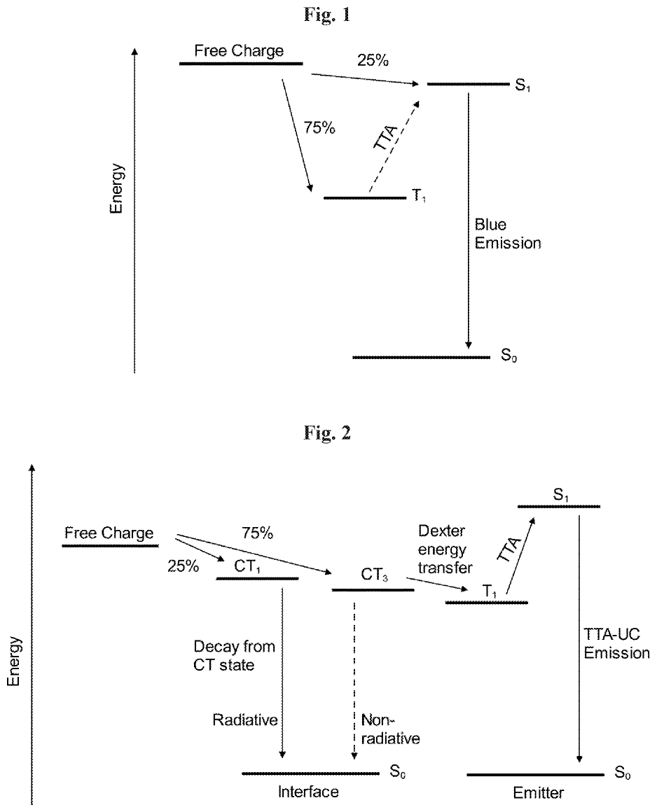

FIG. 1 is a diagram illustrating an example of energy levels and energy transfer relationships of a fluorescent material in a conventional organic electroluminescent element.

In FIG. 1, S₀ represents the ground state. S₁ represents the singlet excited state of a compound. T₁ represents the triplet excited state of a compound.

Referring to FIG. 1, when a voltage is applied to a conventional organic electroluminescent element, holes are injected from the anode into the light-emitting layer, and electrons are injected from the cathode into the light-emitting layer. In the light-emitting layer, the injected holes and electrons recombine to form excitons. In such an event, according to the statistical rule of electron spin, singlet state excitons are formed at a ratio of 25%, and triplet state excitons are formed at a ratio of 75%.

In conventional organic electroluminescent elements, the singlet excitons generate light while relaxing to the ground state, whereas the triplet excitons do not generate light and are extinguished by heat or vibration and return to the ground state. Therefore, in conventional organic electroluminescent elements, only singlet state excitons are used for light emission, providing a low internal quantum efficiency of 25%.

Meanwhile, depending on the behavior of the triplet excitons formed inside the light-emitting layer, when the density of triplet excitons increases in a local region, the triplet excitons collide with each other and are extinguished while some of the triplet excitons can be converted into singlet excitons. Therefore, excitons that generate light are formed by triplet-triplet annihilation (TTA), and the luminous efficiency of the organic electroluminescent element can increase.

However, the TTA mechanism occurs when specific conditions are satisfied. Since only some of the triplet excitons are converted into singlet excitons, there has been a problem in that the internal quantum efficiency is still low. In addition, in the case of blue organic electroluminescent elements, the energy band gap of the light-emitting material is wide, which increases the turn-on voltage and driving voltage; thus, there has been a problem in that the power consumption of the organic electroluminescent element increases.

The organic electroluminescent element according to the present embodiment comprises a first host compound, a second host compound, and a dopant compound satisfying the above configuration in the organic layer, thereby increasing the quantum conversion efficiency to the singlet energy level of the light-emitting material to enhance luminous efficiency, and reducing the energy band gap to lower the turn-on voltage and driving voltage.

The first host compound and the second host compound recombine with each other to form an exciplex (excited state charge transfer complex).

An exciplex refers to a short-lived excited state complex formed by the interaction between heterogeneous molecules. For example, an exciplex can be easily formed between a molecule having a relatively deep LUMO energy level (e.g., an electron acceptor, an electron transporting material, or an n-type host) and a molecule having a relatively shallow HOMO energy level (e.g., an electron donor, a hole transporting material, or a p-type host). For example, the first host compound may be an electron donor compound, and the second host compound may be an electron acceptor compound.

In a procedure in which the exciplex is formed, an exciplex may be directly formed from the first host compound in the ground state and the second host compound in the ground state. For example, when the first host compound and the second host compound are present in the same light-emitting layer, an exciplex may be directly formed without forming excitons.

In another procedure in which the exciplex is formed, one of the first host compound and the second host compound forms an exciton, and the exciton interacts with another in the ground state to form an exciplex.

The state of the exciplex may be a charge transfer state or a local-excitation state. The charge transfer state refers to a state in which electrons are shared between two molecules, and the local-excitation state refers to a state in which the excited state exists locally in one of the two molecules. Preferably, the state of the exciplex may be a charge transfer state.

As the first host compound and the second host compound form an exciplex, the turn-on voltage can be lowered by the photoenergy up-conversion (UC) mechanism by triplet-triplet annihilation (TTA). In addition, the photoenergy up-conversion phenomenon by triplet-triplet annihilation (TTA-UC) can effectively convert triplet excitons that have not been utilized and have been extinguished into high-energy singlet excitons to emit fluorescent light, thereby enhancing energy conversion efficiency.

FIG. 2 is a diagram illustrating an example of energy levels and energy transfer relationships of a fluorescent material in an organic electroluminescent element.

Referring to FIG. 2, when the first host compound and the second host compound form an exciplex (CT₁, CT₃) at the interface, the energy gap is narrowed to lower the turn-on voltage, and the photoenergy up-conversion (UC) mechanism by triplet-triplet annihilation (TTA) can be utilized to increase luminous efficiency. Here, CT₁ refers to the singlet energy level (S₁) generated by charge transfer, and CT₃ may refer to the triplet energy level (T₁) generated by charge transfer.

For example, energy can be transferred from the exciplex in the charge transfer (CT) state formed by the recombination of the first host compound and the second host compound to the triplet energy level (T₁) of the dopant compound, which is a light-emitting material, by Dexter energy transfer. The Dexter energy transfer refers to energy transfer between triplet excitons appearing by direct electron exchange while maintaining the spin state of electrons as it is.

As photoenergy is directly transferred from the exciplex to the triplet energy level of the light-emitting material by Dexter energy transfer, electroluminescence is produced at a voltage lower than the band gap energy voltage of the light-emitting material while increasing luminous efficiency. As a result, the turn-on voltage can be lowered.

As compounds having a HOMO energy level within a specific range or a LUMO energy level within a specific range are used as the first host compound and the second host compound, the exciplex can be efficiently formed in the organic layer.

The first host compound has a HOMO energy level of −5.5 eV or higher, and the second host compound has a LUMO energy level of −4.0 eV to −3.0 eV. When the HOMO energy level of the first host compound and the LUMO energy level of the second host compound each satisfy the above range, an exciplex is effectively formed by the recombination of the first host compound and the second host compound, whereby the turn-on voltage and luminous efficiency can be further improved.

For example, if the first host compound has a deep HOMO energy level of less than −5.5 eV, or if the second host compound has a shallow LUMO energy level of greater than −3.0 eV, it becomes difficult to form an exciplex by recombination, or the energy band gap becomes wide, whereby the turn-on voltage reduction effect may be reduced.

The HOMO energy level of the first host compound may be −5.0 eV or lower, or −5.2 eV or lower. For example, the HOMO energy level of the first host compound may be −5.5 eV to −5.0 eV or −5.5 eV to −5.2 eV.

Meanwhile, when an exciplex is formed, the external quantum efficiency may decrease due to parasitic loss processes such as back charge separation (BCS) and singlet fusion (SF). However, the loss of external quantum efficiency caused by the parasitic loss can be suppressed by controlling the triplet energy level of the exciplex. In addition, the external quantum efficiency can be enhanced by adjusting the energy band gap of the exciplex, the type and doping position of the dopant compound, or the triplet energy of another host compound (e.g., third host compound) to be contained in the light-emitting layer.

The triplet energy level of the exciplex formed by the recombination of the first host compound and the second host compound is greater than 1.5 eV. Therefore, the turn-on voltage of the organic electroluminescent element can be lowered while the quantum efficiency can be increased.

The triplet energy level of the exciplex may be less than 2.5 eV, for example, 2.4 eV or lower, 2.3 eV or lower, or 2.1 eV or lower. For example, the triplet energy level of the exciplex may be greater than 1.5 eV to less than 2.5 eV, greater than 1.5 eV to 2.4 eV, greater than 1.5 eV to 2.3 eV, or greater than 1.5 eV to 2.1 eV.

The triplet energy level of the first host compound is 2.5 eV or lower. The smaller the difference between the triplet energy level of the exciplex and the triplet energy level of the first host compound, the easier the energy diffusion from the exciplex to the first host compound can be, whereby the turn-on voltage can be lowered, and the luminous efficiency can be increased.

The triplet energy level of the first host compound may be 1.5 eV or higher, 1.6 eV or higher, 1.8 eV or higher, 2.0 eV or higher, or 2.2 eV or higher. For example, the triplet energy level of the first host compound may be 1.5 eV to 2.5 eV, 1.6 eV to 2.5 eV, 1.8 eV to 2.5 eV, 2.0 eV to 2.5 eV, or 2.2 eV to 2.5 eV.

In an embodiment, the difference between the triplet energy level of the first host compound and the triplet energy level of the exciplex may be 1.0 eV or less. For example, the difference between the triplet energy level of the first host compound and the triplet energy level of the exciplex may be 0.8 eV or less, 0.5 eV or less, 0.3 eV or less, or 0.1 eV or less. Accordingly, energy transfer from the exciplex to the first host compound can be facilitated.

When energy is transferred from the exciplex to the light-emitting material, the light-emitting material may be in the triplet excited state, and the exciplex may return to the ground state to be separated into the first host compound and the second host compound. The light-emitting material that receives energy from the exciplex may be the first host compound or may be the dopant compound.

The triplet energy level of the exciplex and the energy band gap of the exciplex can mutually affect each other. As the energy band gap of the exciplex increases, the triplet energy level of the exciplex may increase. For example, the triplet energy level of the exciplex may be proportional to the energy band gap of the exciplex.

The energy band gap of the exciplex is calculated as the gap between the HOMO energy level of the first host compound and the LUMO energy level of the second host compound. Therefore, as the gap between the HOMO energy level of the first host compound and the LUMO energy level of the second host compound increases, the triplet energy level of the exciplex may increase.

Therefore, the turn-on voltage of the organic electroluminescent element changes with respect to the energy band gap between the HOMO energy level of the first host compound and the LUMO energy level of the second host compound. As the energy band gap decreases, the turn-on voltage may be lowered.

If the LUMO energy level of the second host compound is less than −4.0 eV, the gap with the HOMO energy level of the first host compound becomes too small, whereby the triplet energy level of the exciplex is excessively lowered, and the luminous efficiency may decrease.

If the LUMO energy level of the second host compound is greater than −3.0 eV, the gap with the HOMO energy level of the first host compound becomes too large, whereby the turn-on voltage may increase.

The gap between the HOMO energy level of the first host compound and the LUMO energy level of the second host compound, for example, the energy band gap of the exciplex, may be greater than 1.6 eV.

In an embodiment, the gap between the HOMO energy level of the first host compound and the LUMO energy level of the second host compound, for example, the energy band gap of the exciplex, may be 1.8 eV or more, or 2.0 eV or more, and it may be 2.7 eV or less, or 2.5 eV or less. The energy band gap may be greater than 1.6 eV to 2.7 eV, 1.8 eV to 2.7 eV, 2.0 eV to 2.7 eV, or 2.0 eV to 2.5 eV. Within the above range, the turn-on voltage of the organic electroluminescent element can be further lowered.

The smaller the difference between the energy band gap of the exciplex and the triplet energy level of the first host compound, the easier the energy diffusion from the exciplex to the first host compound can be, whereby the luminous efficiency can be further enhanced by the TTA-UC mechanism.

For example, the difference between the energy band gap of the exciplex and the triplet energy level of the first host compound may be 0.5 eV or less, 0.3 eV or less, or 0.1 eV or less. Accordingly, energy transfer from the exciplex to the first host compound can be facilitated.

In an embodiment, the triplet energy level of the first host compound and the energy band gap of the exciplex may be the same as each other.

High efficiency can be achieved when the first host compound and the dopant compound satisfy the above Relationships 1 and 2, and the second host compound and the dopant compound satisfy the above Relationships 3 and 4.

For example, when the singlet energy level or triplet energy level of the first host compound is lower than the singlet energy level or triplet energy level of the dopant compound, respectively, or when the singlet energy level or triplet energy level of the second host compound is lower than the singlet energy level or triplet energy level of the dopant compound, respectively, back energy transfer may occur between the host compound and the dopant compound, resulting in decreased efficiency.

In an embodiment, the dopant compound may be doped in the first host compound or may be doped in the second host compound. Preferably, the dopant compound may be doped in the first host compound. Accordingly, trap sites of the light-emitting material can be reduced, and the turn-on voltage of the organic electroluminescent element can be further lowered.

The singlet energy level of the first host compound may be 2.7 eV or higher, and it may be 3.5 eV or lower, 3.4 eV or lower, or 3.3 eV or lower, but it is not limited thereto.

The singlet energy level of the second host compound may be 2.7 eV or higher, and it may be 3.5 eV or lower, 3.4 eV or lower, or 3.3 eV or lower, but it is not limited thereto.

The triplet energy level of the second host compound may be 3.1 eV or lower, 3.0 eV or lower, or 2.9 eV or lower, but it is not limited thereto. The triplet energy level of the second host compound may be higher than the triplet energy level of the exciplex. For example, it may be 1.6 eV or higher, 1.8 eV or higher, or 2.0 eV or higher.

The singlet energy level of the dopant compound may be 2.68 eV or higher, or 2.7 eV or higher, and it may be 3.0 eV or lower, 2.9 eV or lower, or 2.8 eV or lower, but it is not limited thereto.

The triplet energy level of the dopant compound may be 1.2 eV or higher, 1.5 eV or higher, or 1.8 eV or higher, and it may be 2.3 eV or lower, 2.2 eV or lower, or 2.0 eV or lower, but it is not limited thereto.

When the singlet energy levels and triplet energy levels of the first host compound, the second host compound, and the dopant compound satisfy the above ranges, respectively, the driving voltage and turn-on voltage of the organic electroluminescent element can be further lowered, and the luminous efficiency and electrical efficiency can be further enhanced.

The method for measuring the triplet energy level is as follows.

A compound to be measured is dissolved in toluene to a concentration of 10 μmoles/L, and a sample is prepared by encapsulating the solution in a quartz cell. For the sample, a phosphorescence spectrum (vertical axis: phosphorescence emission intensity, horizontal axis: wavelength) is measured at a low temperature (e.g., 77 K). A tangent is drawn to the ascent on the short wavelength side of the phosphorescence spectrum, and the triplet energy level T₁ (unit: eV) is calculated from the Conversion Equation (F1) based on the wavelength value λ_{edge} (unit: nm) at the intersection of the tangent and the horizontal axis.

$${T}_{1} [ eV ] = 1 , 23 \; 9 \text{.85} / {λ}_{edge} \qquad Conversion Equation ( F1 )$$

The tangent to the ascent on the short wavelength side of the phosphorescence spectrum is drawn by the following method. First, when moving on the spectrum curve from the short wavelength side of the phosphorescence spectrum to the maximum on the shortest wavelength side among the maxima of the spectrum, the tangent at each point on the curve toward the long wavelength side is considered. The tangent increases in slope as the curve ascends (i.e., as the vertical axis increases). The tangent drawn at the point where this slope value takes a maximum value (i.e., the tangent at the inflection point) is taken as the tangent to the ascent on the short wavelength side of the phosphorescence spectrum.

Meanwhile, a maximum point having a peak intensity of 15% or less of the maximum peak intensity of the spectrum is not included in the maximum on the shortest wavelength side, and the tangent drawn at the point closest to the maximum on the shortest wavelength side where the slope value takes a maximum value is taken as the tangent to the ascent on the short wavelength side of the phosphorescence spectrum.

As a device for measuring a phosphorescence spectrum, for example, a spectrofluorometer main body from Hitachi High-Tech (device name: F-4500) may be used. Meanwhile, the measuring device is not limited thereto, and measurement may be performed by combining a cooling device, a low-temperature container, an excitation light source, and a light receiving device.

The method for measuring the singlet energy level is as follows.

A compound to be measured is dissolved in toluene to a concentration of 10 μmoles/L, and a sample is prepared by encapsulating the solution in a quartz cell. For the sample, an emission spectrum (vertical axis: emission intensity, horizontal axis: wavelength) is measured at room temperature (e.g., 300 K). A tangent is drawn to the ascent on the short wavelength side of the emission spectrum, and the singlet energy level S₁ (unit: eV) is calculated by substituting the wavelength value λ_{edge} (unit: nm) at the intersection of the tangent and the horizontal axis into the Conversion Equation (F2).

$${S}_{1} [ eV ] = 1 , 239.85 / {λ}_{edge} \qquad Conversion Equation ( F2 )$$

The tangent to the ascent on the short wavelength side of the emission spectrum is drawn by the following method. When moving on the spectrum curve in the short wavelength direction from the maximum on the shortest wavelength side among the maxima of the emission spectrum, the tangent at each point on the curve is considered. The tangent repeatedly increases and then decreases in slope as the curve ascends (i.e., as the value on the vertical axis increases). The tangent drawn at the point where the slope value takes a minimum value on the shortest wavelength side is taken as the tangent to the ascent on the short wavelength side of the emission spectrum.

As a device for measuring an emission spectrum, for example, a spectrofluorometer from Hitachi (device name: F-7000), a spectrofluorometer from JASCO (device name: FP-8300), or the like may be used, but it is not limited thereto.

The HOMO (highest occupied molecular orbital) energy level is the energy level of the highest occupied orbital and is measured by cyclic voltammetry.

Specifically, the value of the HOMO energy level (unit: eV) of a measurement object (a compound or a material) is calculated by Equation (F3).

$$HOMO = - 1.4 \times ( Eox - Efc ) - 4.6 eV \qquad Equation ( F3 )$$

In Equation (F3), Eox and Efc are as follows.
Eox: first oxidation potential (CV, positive scan)
Efc: first oxidation potential of ferrocene (CV, positive scan), (ca. +0.55 V vs Ag/AgCl)

The LUMO (lowest unoccupied molecular orbital) energy level is the energy level of the lowest unoccupied orbital and is calculated using the measured HOMO value and E_{g} value.

Specifically, the value of the LUMO energy level (unit: eV) of a calculation object (a compound or a material) is obtained by Equation (F4).

$$LUMO = HOMO - {E}_{g} \qquad Equation ( F4 )$$

In Equation (F4), E_{g} refers to the band gap (unit: eV) of the object.

E_{g} may be measured as follows. For a 10 μmoles/L toluene solution of a measurement object, an absorption spectrum (vertical axis: absorption intensity, horizontal axis: wavelength) is measured at room temperature (300 K) using a spectrophotometer (e.g., U3310 from Hitachi). A tangent is drawn to the descending point on the long wavelength side of the absorption spectrum, and the wavelength value λ_{edge} (unit: nm) at the intersection where the tangent and the horizontal axis meet is substituted into the Equation E_{g} [eV]=1,239.85/λ_{edge} to calculate E_{g}.

In the measurement of the HOMO energy level and LUMO energy level, the redox potential may be measured through cyclic voltammetry (CV) using an electrochemical analyzer.

A sample solution used for measuring the redox potential is prepared by dissolving a measurement object and a supporting electrolyte in a solvent. The concentration of the measurement object in the sample solution is 1.0 mmole/L, and the concentration of the supporting electrolyte is 100 mmoles/L. N,N-dimethylformamide (DMF) is used as the solvent. Tetrabutylammonium hexafluorophosphate (TBHP) is used as the supporting electrolyte. A glassy carbon electrode is used as the working electrode, and a platinum (Pt) electrode is used as the counter electrode.

As to the measurement of the redox potential, Reference 1 (M. E. Thompson, et al., Organic Electronics, 6 (2005), p. 11-20) and Reference 2 (Organic Electronics, 10 (2009), p. 515-520) may be referred to.

As an electrochemical analyzer used for measuring the redox potential, for example, CHI630B from ALS, or CHI852D from ALS may be used, but it is not limited thereto.

The triplet energy level of the exciplex may be calculated by the following Equation (F5). Specifically, the triplet energy level of the exciplex is equal to, or smaller than, the photon energy (Eₚ) calculated by Equation (F5). In general, the photon energy calculated by Equation (F5) may be regarded as the triplet energy level of the exciplex.

$${E}_{p} = 0.8 \times {E}_{g} + 0.2 \qquad Equation ( F5 )$$

In Equation (F5), Eₚ is the photon energy. E_{g} is the energy band gap of the exciplex, which is calculated as the gap between the HOMO energy level of the first host compound and the LUMO energy level of the second host compound.

As the first host compound, a compound that can recombine with the second host compound to form an exciplex, has a HOMO energy level and a triplet energy level within the above ranges, and satisfies Relationships 1 and 2 may be selected. In addition, the first host compound may have a singlet energy level within the above range.

The first host compound may comprise an amine compound.

In an embodiment, the first host compound may comprise at least one of the compounds represented by the following Formulae (2a) to (2d).

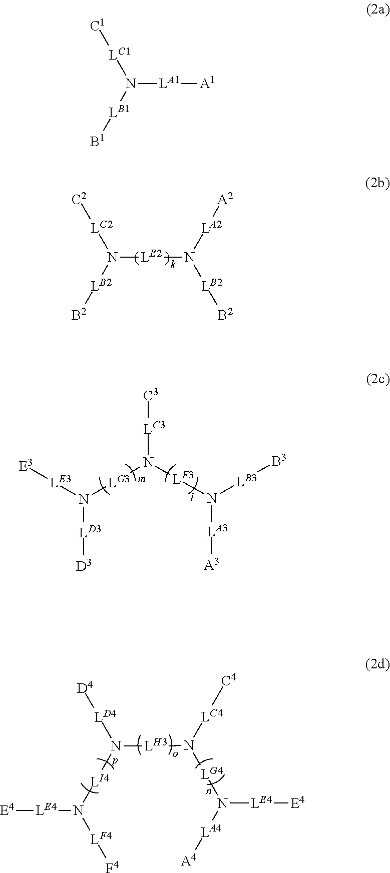

In Formulae (2a) to (2d),
L^{A1}, L^{B1}, L^{C1}, L^{A2}, L^{B2}, L^{C2}, L^{D2}, L^{A3}, L^{B3}, L^{C3}, L^{D3}, L^{E3}, L^{A4}, L^{B4}, L^{C4}, L^{D4}, L^{E4}, and L^{F4} are each independently a single bond, a substituted or unsubstituted arylene group having 6 to 50 ring carbon atoms, or a substituted or unsubstituted divalent heterocyclic group having 5 to 50 ring atoms,
k, l, m, n, o, and p are each independently 1, 2, 3, or 4,
when k, l, m, n, o, and p are 1, L^{E2}, L^{F3}, L^{G3}, L^{G4}, L_{H4}, and L^{I4} are each independently a substituted or unsubstituted arylene group having 6 to 50 ring carbon atoms, or a substituted or unsubstituted divalent heterocyclic group having 5 to 50 ring atoms,
when k, l, m, n, o, and p are 2, 3, or 4, a plurality of L^{E2}, L^{F3}, L^{G3}, L^{G4}, L^{H4}, and L^{I4} are the same as or different from each other,
when k, l, m, n, o, and p are 2, 3, or 4, a plurality of L^{E2}, L^{F3}, L^{G3}, L^{G4}, L^{H4}, and L^{I4} bond to each other to form a substituted or unsubstituted monocyclic or fused ring, or do not bond to each other,
L^{E2}, L^{F3}, L^{G3}, L^{G4}, L^{H4}, and L^{I4} that do not form the substituted or unsubstituted monocyclic ring and do not form the substituted or unsubstituted fused ring are a substituted or unsubstituted arylene group having 6 to 50 ring carbon atoms, or a substituted or unsubstituted divalent heterocyclic group having 5 to 50 ring atoms,
A¹, B¹, C¹, A², B², C², D², A³, B³, C³, D³, E³, A⁴, B⁴, C⁴, D⁴, E⁴, and F⁴ are each independently a substituted or unsubstituted aryl group having 6 to 50 ring carbon atoms, a substituted or unsubstituted heterocyclic group having 5 to 50 ring atoms, or —Si(R′₉₀₁)(R′₉₀₂)(R′₉₀₃),
R′₉₀₁, R′₉₀₂, and R′₉₀₃ are each independently a substituted or unsubstituted aryl group having 6 to 50 ring carbon atoms,
when two or more of R′₉₀₁ are present, the two or more of R′₉₀₁ are the same as or different from each other,
when two or more of R′₉₀₂ are present, the two or more of R′₉₀₂ are the same as or different from each other, and
when two or more of R′₉₀₃ are present, the two or more of R′₉₀₃ are the same as or different from each other.
Preferably, L^{A1}, L^{B1}, L^{C1}, L^{A2}, L^{B2}, L^{C2}, L^{D2}, L^{A3}, L^{B3}, L^{C3}, L^{D3}, L^{E3}, L^{A4}, L^{B4}, L^{C4}, L^{D4}, L^{E4}, and L^{F4} may each independently be a single bond or a substituted or unsubstituted arylene group having 6 to 12 ring carbon atoms.

Preferably, A¹, B¹, C¹, A², B², C², D², A³, B³, C³, D³, E³, A⁴, B⁴, C⁴, D⁴, E⁴, and F⁴ may each independently be a substituted or unsubstituted phenyl group, a substituted or unsubstituted biphenyl group, a substituted or unsubstituted terphenyl group, a substituted or unsubstituted naphthyl group, a substituted or unsubstituted fluorenyl group, a substituted or unsubstituted dibenzofuranyl group, a substituted or unsubstituted naphthobenzofuranyl group, a substituted or unsubstituted dibenzothiophenyl group, or a substituted or unsubstituted carbazolyl group.

More preferably, at least one of A¹, B¹, and C¹, at least one of A², B², C², and D², at least one of A³, B³, C³, D³, and E³, or at least one of A⁴, B⁴, C⁴, D⁴, E⁴, and F⁴ may be a substituted or unsubstituted biphenyl group, a substituted or unsubstituted terphenyl group, a substituted or unsubstituted naphthyl group, a substituted or unsubstituted fluorenyl group, a substituted or unsubstituted dibenzofuranyl group, a substituted or unsubstituted dibenzothiophenyl group, or a substituted or unsubstituted carbazolyl group.

In an embodiment, when A¹, B¹, C¹, A², B², C², D², A³, B³, C³, D³, E³, A⁴, B⁴, C⁴, D⁴, E⁴, or F⁴ is a substituted fluorenyl group, a substituent may be located at the 9-position of the fluorenyl group. For example, it may be a 9,9-dimethylfluorenyl group or a 9,9-diphenylfluorenyl group. In addition, the substituents located at the 9-position of the fluorenyl group may bond to each other to form a ring. For example, the substituents may bond to each other to form a fluorene skeleton or a xanthene skeleton.

Specific examples of the first host compound include the following compounds, but it is not limited to the following exemplary compounds.

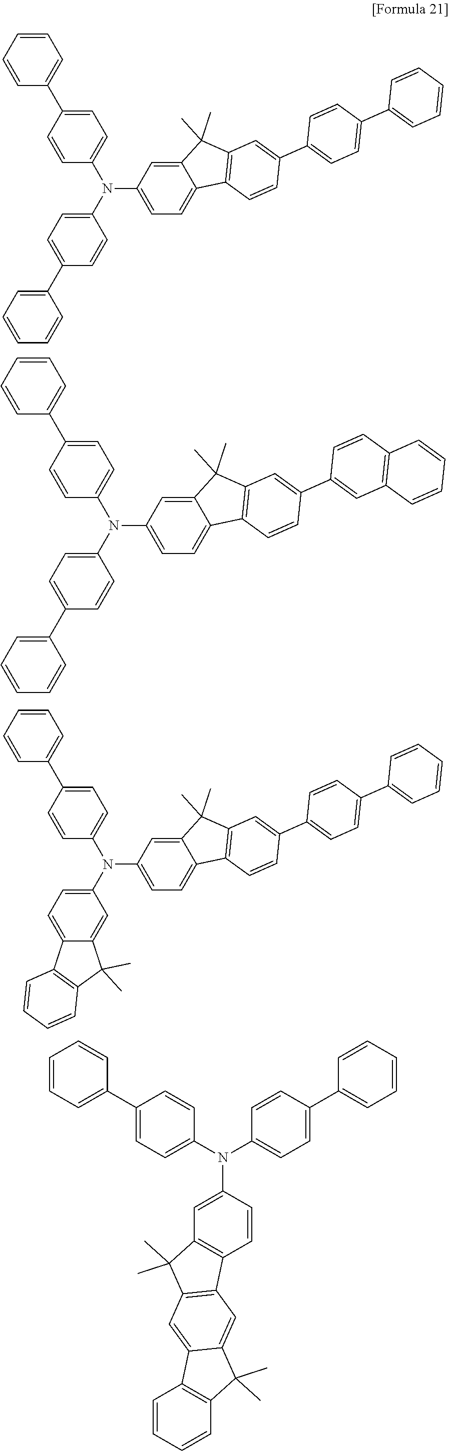

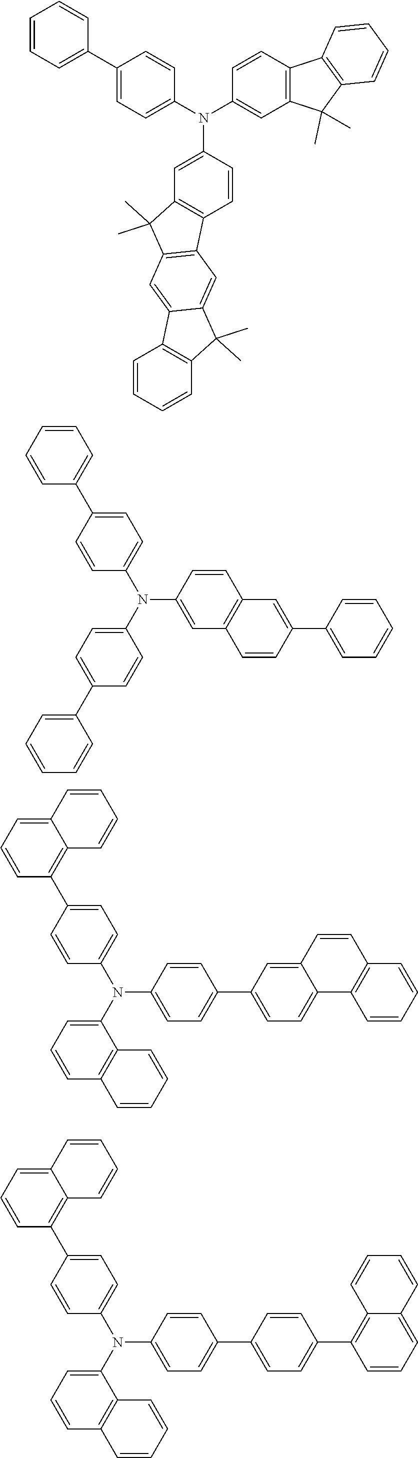

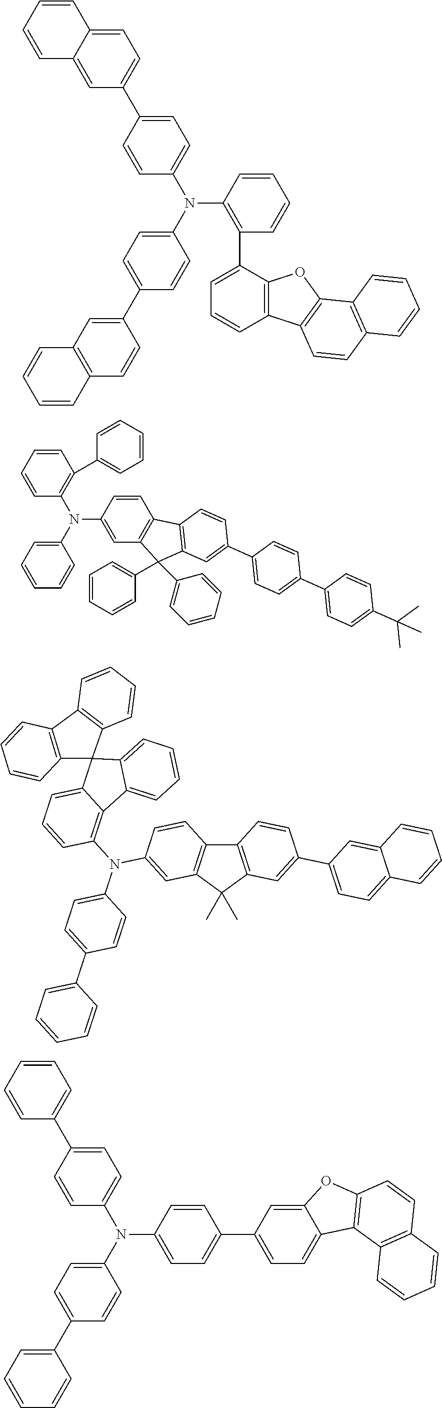

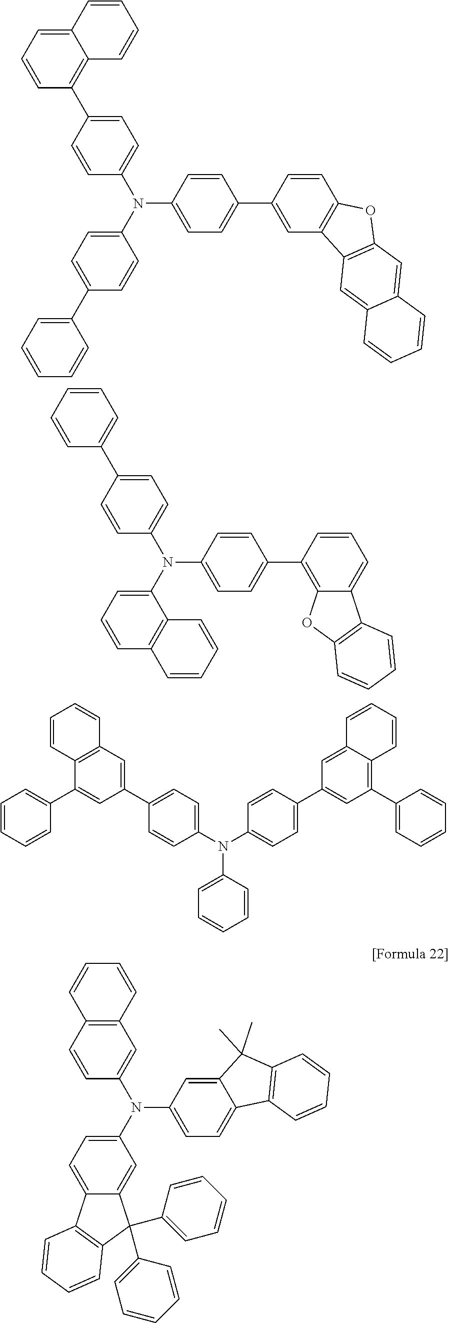

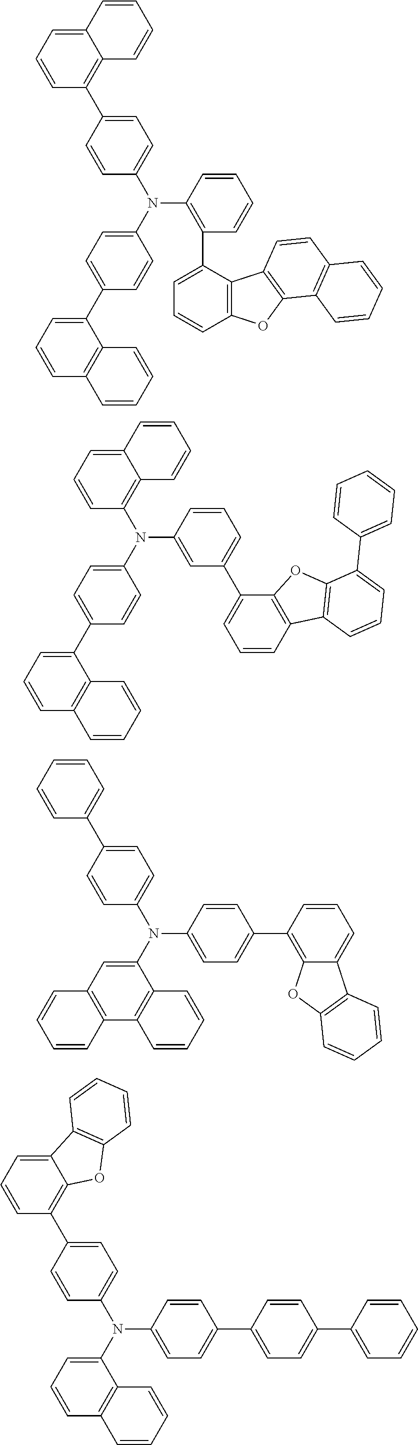

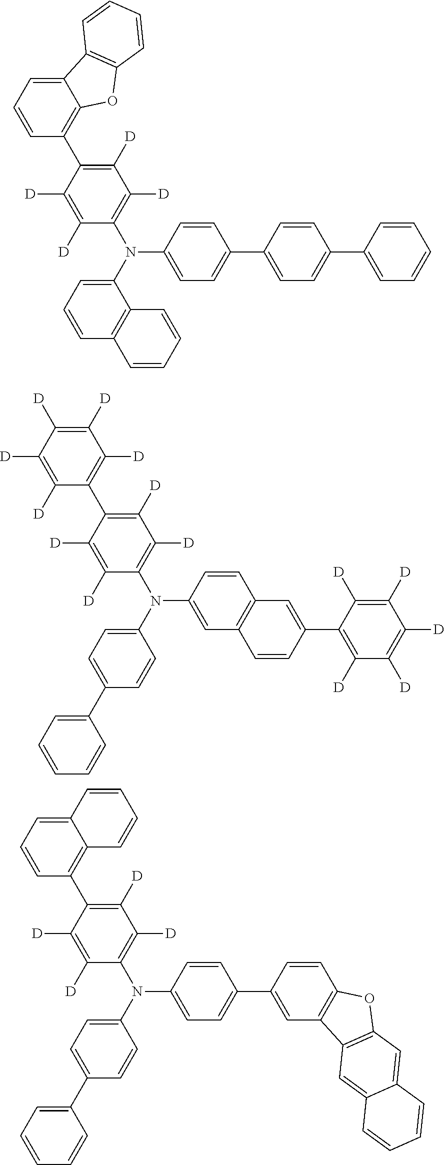

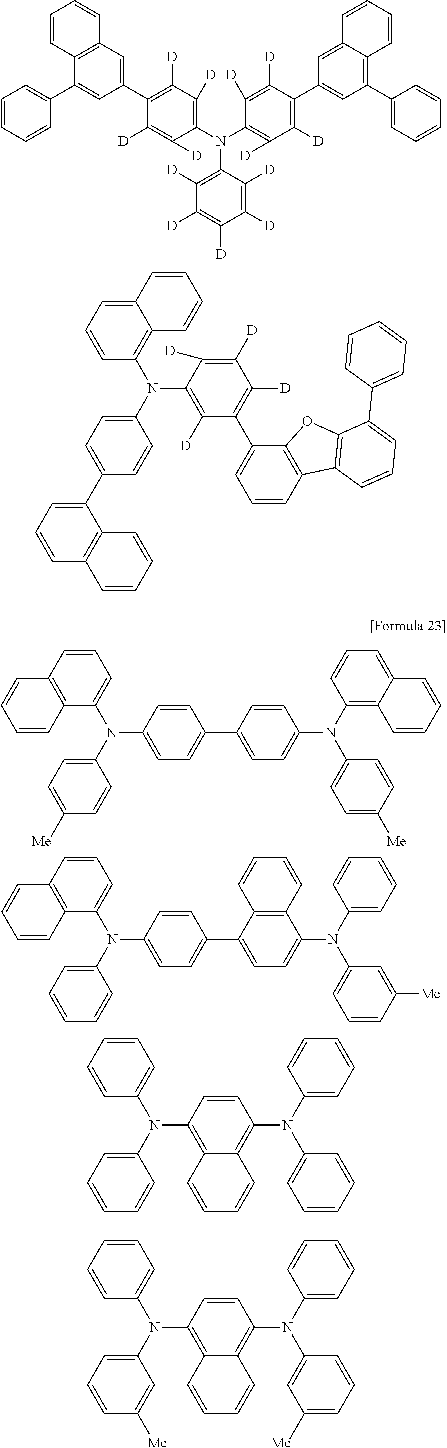

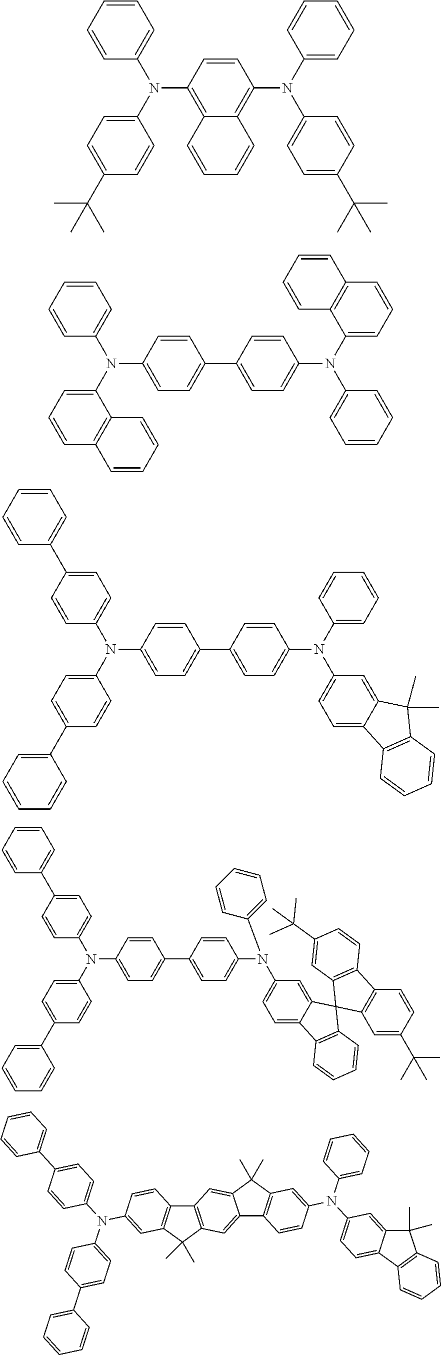

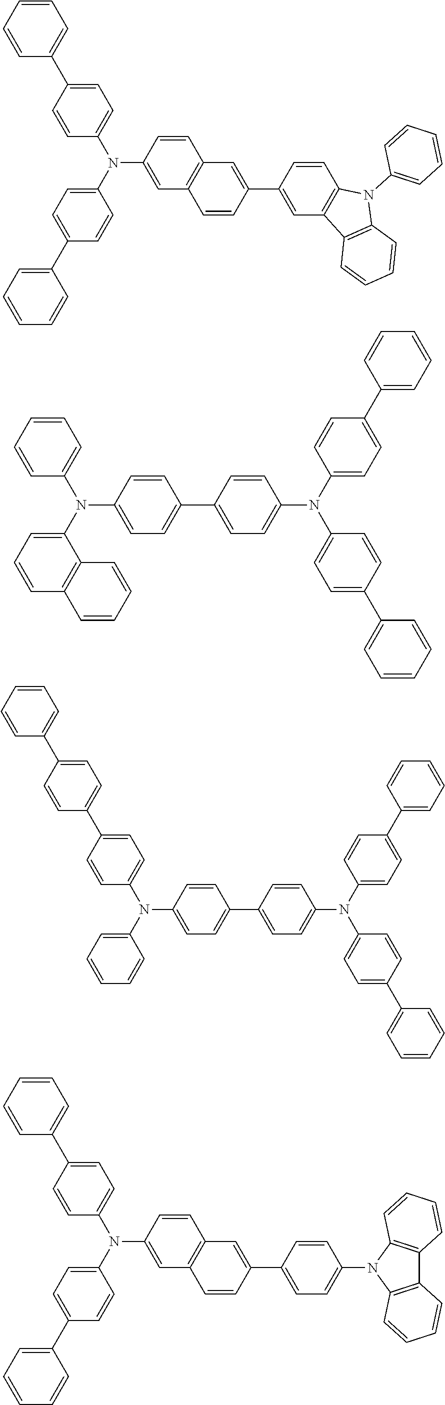 [SMILES: c1ccc(-c2ccc(N(c3ccc(-c4ccccc4)cc3)c3ccc4cc(-c5ccc6c(c5)c5ccccc5n6-c5ccccc5)ccc4c3)cc2)cc1 ; c1ccc(-c2ccc(N(c3ccc(-c4ccccc4)cc3)c3ccc(-c4ccc(N(c5ccccc5)c5cccc6ccccc56)cc4)cc3)cc2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(N(c3ccc(-c4ccccc4)cc3)c3ccc4cc(-c5ccc(-n6c7ccccc7c7ccccc76)cc5)ccc4c3)cc2)cc1]

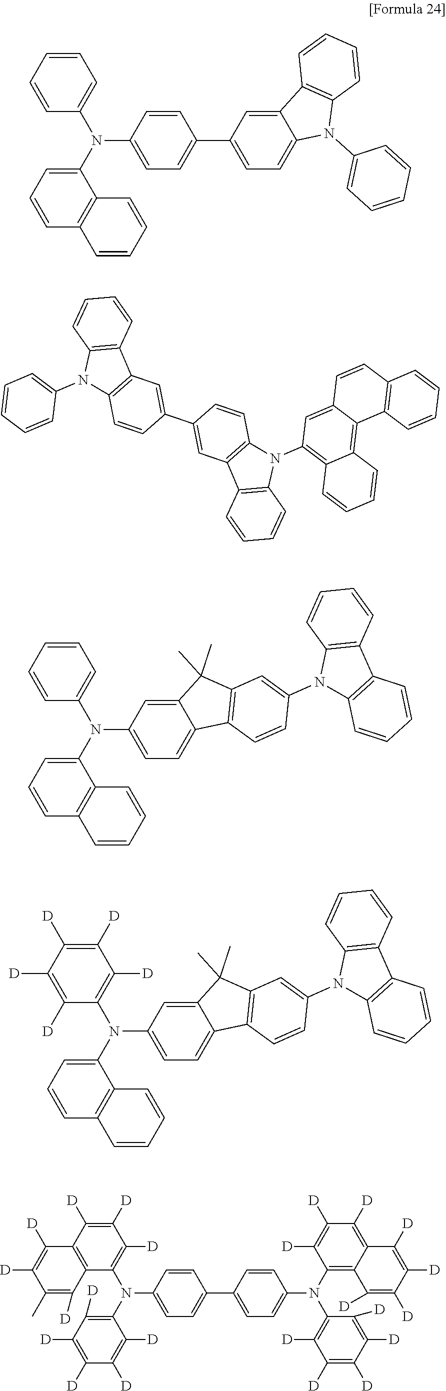

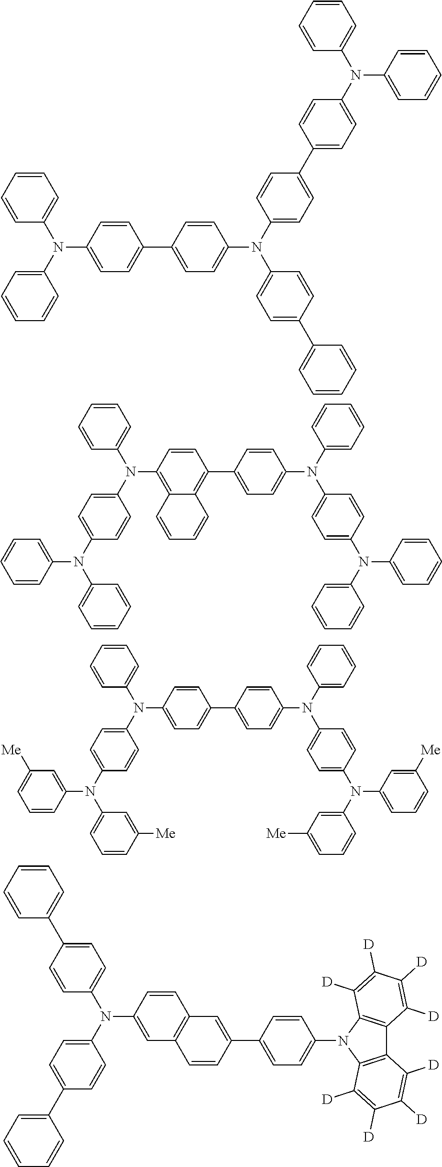

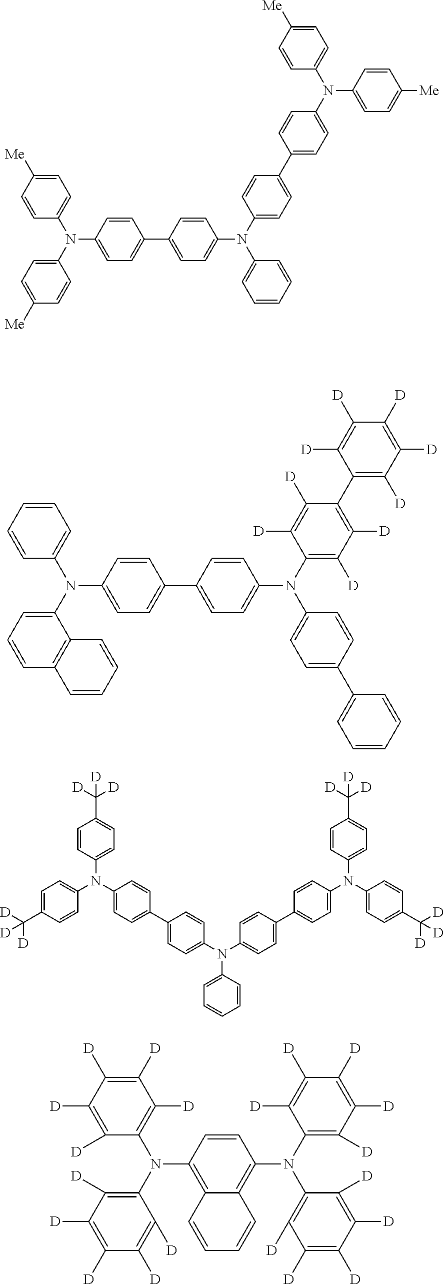

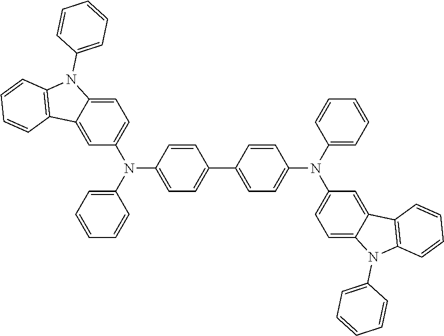 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

As the second host compound, a compound that can recombine with the first host compound to form an exciplex, has a LUMO energy level within the above range, and satisfies Relationships 3 and 4 may be selected. In addition, the second host compound may have a singlet energy level and a triplet energy level within the above ranges.

The second host compound may comprise a nitrogen-containing heterocyclic group. For example, the second host compound may comprise a nitrogen-containing 6-membered ring.

The second host compound may comprise an azine group. For example, the second host compound may comprise at least one moiety selected from the group consisting of pyridine, diazine, triazine, tetrazine, pentazine, and hexazine. Preferably, the second host compound may comprise a diazine moiety or a triazine moiety.

The second host compound may comprise at least one of the compounds represented by the following Formulae (3a) and (3b).

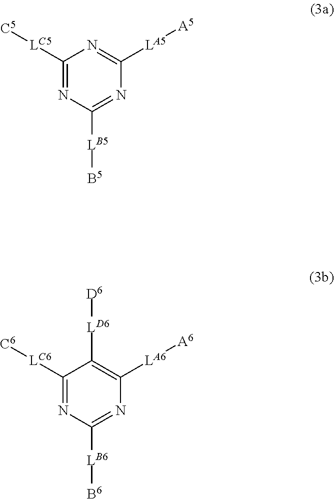

In Formulae (3a) and (3b),
L^{A5}, L^{B5}, L^{C5}, L^{A6}, L^{B6}, L^{C6}, and L^{D6} are each independently a single bond, a substituted or unsubstituted arylene group having 6 to 50 ring carbon atoms, or a substituted or unsubstituted divalent heterocyclic group having 5 to 50 ring atoms.

Preferably, L^{A5}, L^{B5}, L^{C5}, L^{A6}, L^{B6}, L^{C6}, and L^{D6} may each independently be a single bond or a substituted or unsubstituted arylene group having 6 to 12 ring carbon atoms.

In an embodiment, when L^{A5}, L^{B5}, L^{C5}, L^{A6}, L^{B6}, L^{C6}, or L^{D6} is a substituted arylene group having 6 to 50 ring carbon atoms or a substituted divalent heterocyclic group having 5 to 50 ring atoms, the substituent may comprise a cyano group or a halogen atom.

Preferably, the substituent may be a cyano group or a fluorine atom, and more preferably a cyano group. As a result, the LUMO energy level of the second host compound can be further lowered.

A⁵, B⁵, C⁵, A⁶, B⁶, C⁶, and D⁶ are each independently a substituted or unsubstituted aryl group having 6 to 50 ring carbon atoms, a substituted or unsubstituted heterocyclic group having 5 to 50 ring atoms, or —Si(R′₉₀₄)(R′₉₀₅)(R′₉₀₆).

Preferably, A⁵, B⁵, C⁵, A⁶, B⁶, C⁶, and D⁶ may each independently be a substituted or unsubstituted phenyl group, a substituted or unsubstituted biphenyl group, a substituted or unsubstituted terphenyl group, a substituted or unsubstituted naphthyl group, a substituted or unsubstituted fluorenyl group, a substituted or unsubstituted dibenzofuranyl group, a substituted or unsubstituted naphthobenzofuranyl group, a substituted or unsubstituted dibenzothiophenyl group, or a substituted or unsubstituted carbazolyl group.

More preferably, at least one of A⁵, B⁵, and C⁵, or at least one of A⁶, B⁶, C⁶, and D⁶ may be a substituted or unsubstituted biphenyl group, a substituted or unsubstituted terphenyl group, a substituted or unsubstituted naphthyl group, a substituted or unsubstituted fluorenyl group, a substituted or unsubstituted dibenzofuranyl group, a substituted or unsubstituted dibenzothiophenyl group, or a substituted or unsubstituted carbazolyl group.

In an embodiment, when A⁵, B⁵, C⁵, A⁶, B⁶, C⁶, or D⁶ is a substituted fluorenyl group, a substituent may be located at the 9-position of the fluorenyl group. For example, it may be a 9,9-dimethylfluorenyl group or a 9,9-diphenylfluorenyl group. In addition, the substituents located at the 9-position of the fluorenyl group may bond to each other to form a ring. For example, the substituents may bond to each other to form a fluorene skeleton or a xanthene skeleton.

R′₉₀₄, R′₉₀₅, and R′₉₀₆ are each independently a substituted or unsubstituted aryl group having 6 to 50 ring carbon atoms,
when two or more of R′₉₀₄ are present, the two or more of R′₉₀₄ are the same as or different from each other,
when two or more of R′₉₀₅ are present, the two or more of R′₉₀₅ are the same as or different from each other, and
when two or more of R′₉₀₆ are present, the two or more of R′₉₀₆ are the same as or different from each other.

Specific examples of the second host compound include the following compounds, but it is not limited to the following exemplary compounds.

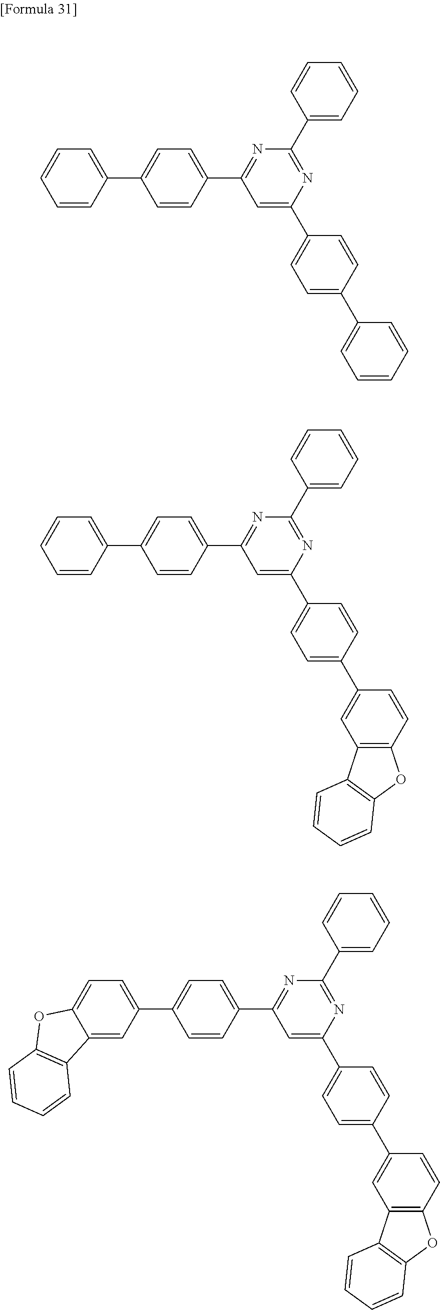 [SMILES: c1ccc(-c2ccc(-c3cc(-c4ccc(-c5ccccc5)cc4)nc(-c4ccccc4)n3)cc2)cc1 ; c1ccc(-c2ccc(-c3cc(-c4ccc(-c5ccc6oc7ccccc7c6c5)cc4)nc(-c4ccccc4)n3)cc2)cc1 ; c1ccc(-c2nc(-c3ccc(-c4ccc5oc6ccccc6c5c4)cc3)cc(-c3ccc(-c4ccc5oc6ccccc6c5c4)cc3)n2)cc1]

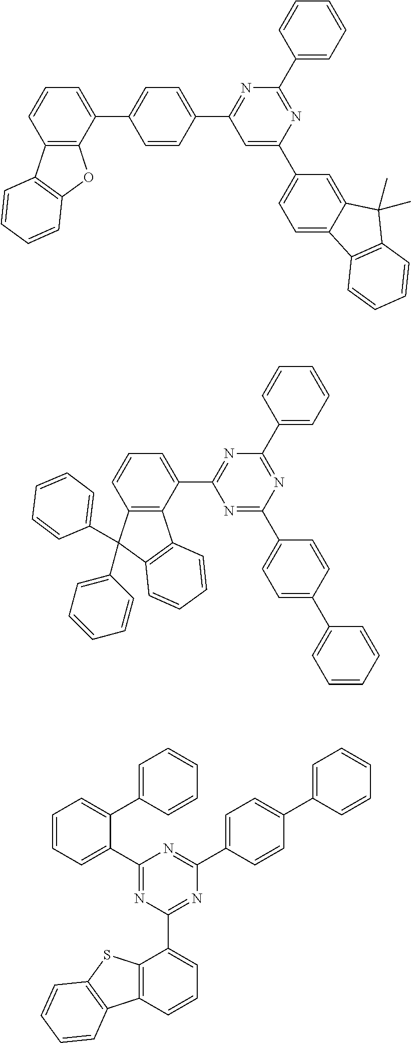 [SMILES: CC1(C)c2ccccc2-c2ccc(-c3cc(-c4ccc(-c5cccc6c5oc5ccccc56)cc4)nc(-c4ccccc4)n3)cc21 ; c1ccc(-c2ccc(-c3nc(-c4ccccc4)nc(-c4cccc5c4-c4ccccc4C5(c4ccccc4)c4ccccc4)n3)cc2)cc1 ; c1ccc(-c2ccc(-c3nc(-c4ccccc4-c4ccccc4)nc(-c4cccc5c4sc4ccccc45)n3)cc2)cc1]

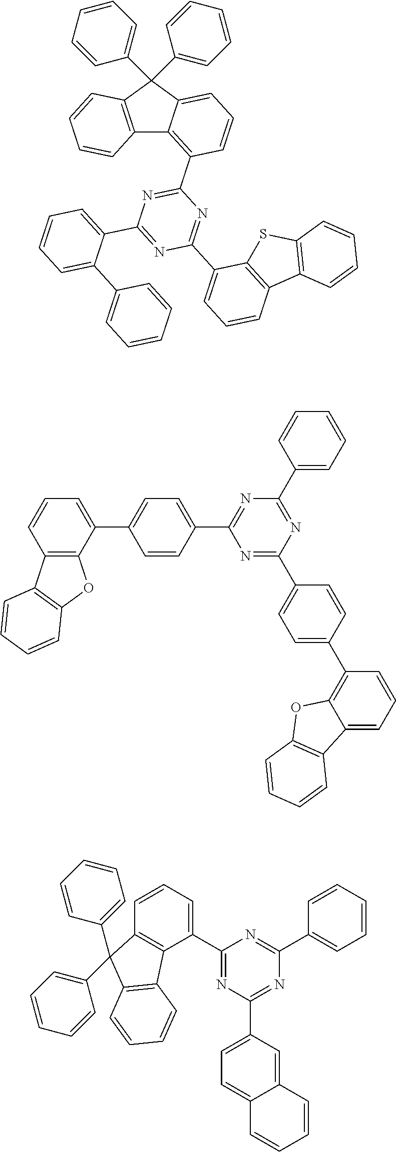 [SMILES: c1ccc(-c2ccccc2-c2nc(-c3cccc4c3-c3ccccc3C4(c3ccccc3)c3ccccc3)nc(-c3cccc4c3sc3ccccc34)n2)cc1 ; c1ccc(-c2nc(-c3ccc(-c4cccc5c4oc4ccccc45)cc3)nc(-c3ccc(-c4cccc5c4oc4ccccc45)cc3)n2)cc1 ; c1ccc(-c2nc(-c3ccc4ccccc4c3)nc(-c3cccc4c3-c3ccccc3C4(c3ccccc3)c3ccccc3)n2)cc1]

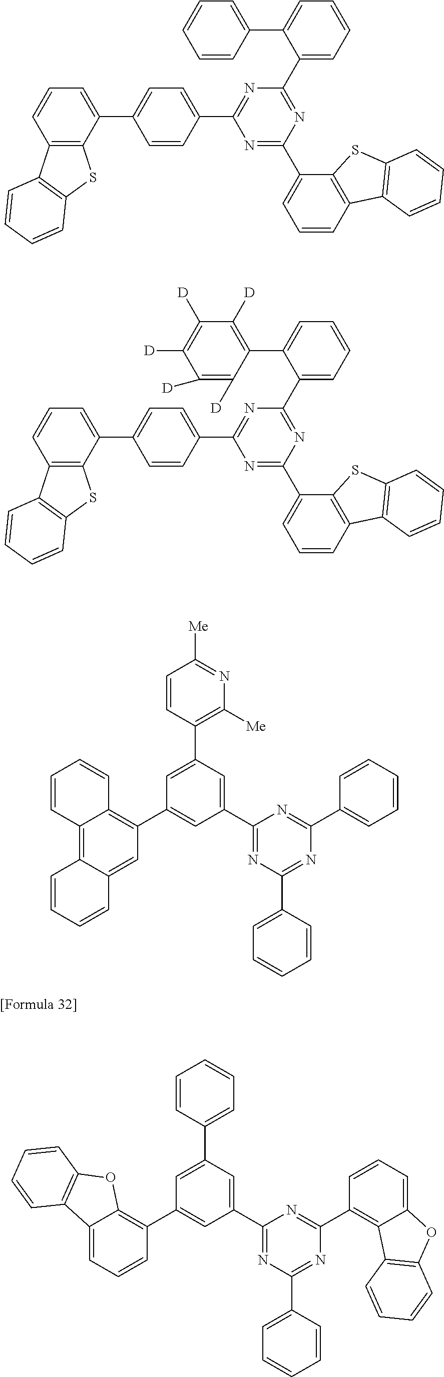 [SMILES: c1ccc(-c2ccccc2-c2nc(-c3ccc(-c4cccc5c4sc4ccccc45)cc3)nc(-c3cccc4c3sc3ccccc34)n2)cc1 ; [2H]c1c([2H])c([2H])c(-c2ccccc2-c2nc(-c3ccc(-c4cccc5c4sc4ccccc45)cc3)nc(-c3cccc4c3sc3ccccc34)n2)c([2H])c1[2H] ; Cc1ccc(-c2cc(-c3nc(-c4ccccc4)nc(-c4ccccc4)n3)cc(-c3cc4ccccc4c4ccccc34)c2)c(C)n1 ; c1ccc(-c2cc(-c3nc(-c4ccccc4)nc(-c4cccc5oc6ccccc6c45)n3)cc(-c3cccc4c3oc3ccccc34)c2)cc1]

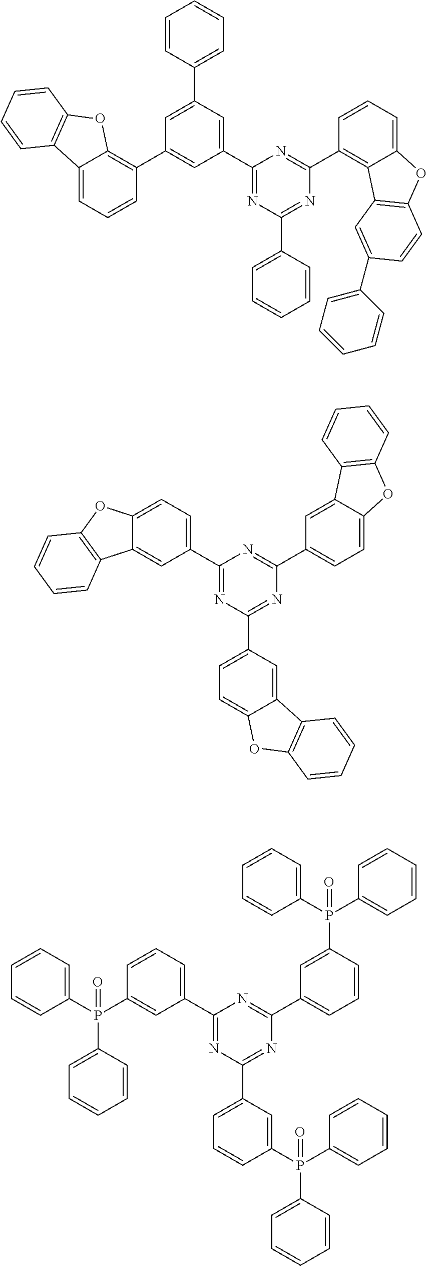 [SMILES: c1ccc(-c2cc(-c3nc(-c4ccccc4)nc(-c4cccc5oc6ccc(-c7ccccc7)cc6c45)n3)cc(-c3cccc4c3oc3ccccc34)c2)cc1 ; c1ccc2c(c1)oc1ccc(-c3nc(-c4ccc5oc6ccccc6c5c4)nc(-c4ccc5oc6ccccc6c5c4)n3)cc12 ; O=P(c1ccccc1)(c1ccccc1)c1cccc(-c2nc(-c3cccc(P(=O)(c4ccccc4)c4ccccc4)c3)nc(-c3cccc(P(=O)(c4ccccc4)c4ccccc4)c3)n2)c1]

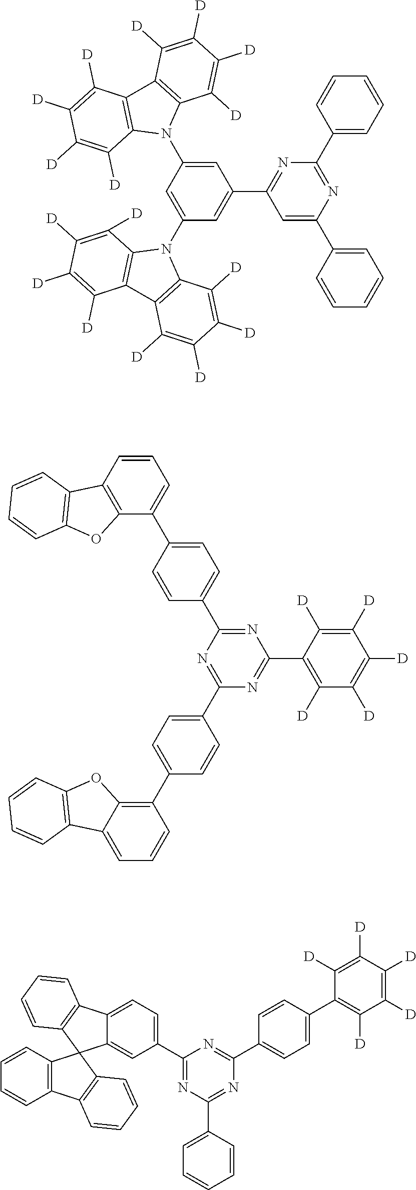 [SMILES: [2H]c1c([2H])c([2H])c2c(c1[2H])c1c([2H])c([2H])c([2H])c([2H])c1n2-c1cc(-c2cc(-c3ccccc3)nc(-c3ccccc3)n2)cc(-n2c3c([2H])c([2H])c([2H])c([2H])c3c3c([2H])c([2H])c([2H])c([2H])c32)c1 ; [2H]c1c([2H])c([2H])c(-c2nc(-c3ccc(-c4cccc5c4oc4ccccc45)cc3)nc(-c3ccc(-c4cccc5c4oc4ccccc45)cc3)n2)c([2H])c1[2H] ; [2H]c1c([2H])c([2H])c(-c2ccc(-c3nc(-c4ccccc4)nc(-c4ccc5c(c4)C4(c6ccccc6-c6ccccc64)c4ccccc4-5)n3)cc2)c([2H])c1[2H]]

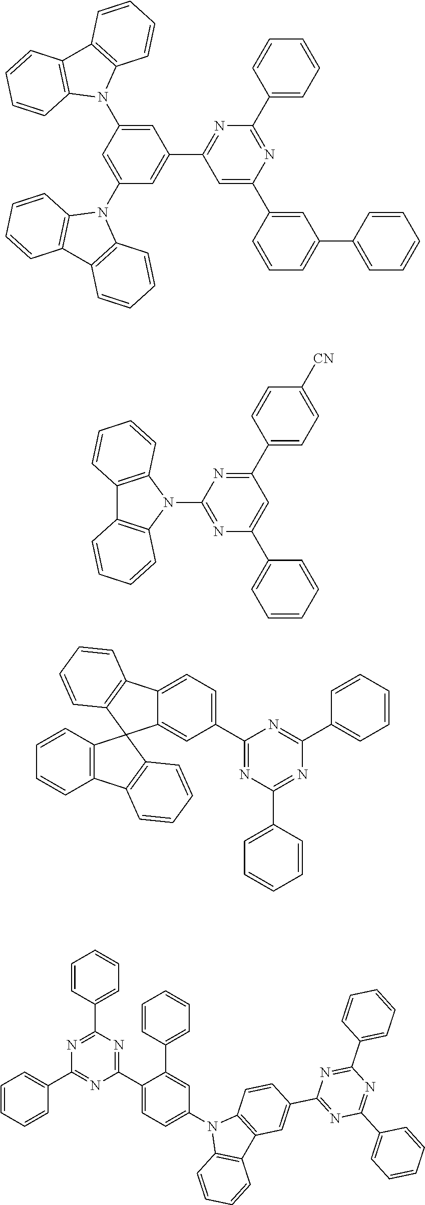 [SMILES: c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; N#Cc1ccc(-c2cc(-c3ccccc3)nc(-n3c4ccccc4c4ccccc43)n2)cc1 ; c1ccc(-c2nc(-c3ccccc3)nc(-c3ccc4c(c3)C3(c5ccccc5-c5ccccc53)c3ccccc3-4)n2)cc1 ; c1ccc(-c2nc(-c3ccccc3)nc(-c3ccc4c(c3)c3ccccc3n4-c3ccc(-c4nc(-c5ccccc5)nc(-c5ccccc5)n4)c(-c4ccccc4)c3)n2)cc1]

As the dopant compound, a compound satisfying the above Relationships 1 to 4 may be selected.

The dopant compound may comprise a fluorescent compound and/or a phosphorescent compound. Preferably, the dopant compound may comprise a fluorescent compound. For example, the dopant compound may be a compound that emits light from a singlet excited state.

In the conventional fluorescent light-emitting elements, due to the characteristics of fluorescent materials having lower efficiency as compared with phosphorescent materials, a high current was required to reach the desired brightness, resulting in low power efficiency. In the organic electroluminescent element according to the present invention, however, as it comprises a specific combination of the first host compound, the second host compound, and the dopant compound, high power and luminous efficiency can be achieved even when a fluorescent material is used.

The dopant compound may comprise a blue fluorescent material, a green fluorescent material, or a red fluorescent material.

As the blue fluorescent material, pyrene derivatives, styrylamine derivatives, chrysene derivatives, fluoranthene derivatives, fluorene derivatives, diamine derivatives, triarylamine derivatives, or the like may be used. Specifically, as the blue fluorescent material, N,N′-bis[4-(9H-carbazol-9-yl)phenyl]-N,N′-diphenylstilbene-4,4′-diamine (abbreviated as YGA2S), 4-(9H-carbazol-9-yl)-4′-(10-phenyl-9-anthryl)triphenylamine (abbreviated as YGAPA), 4-(10-phenyl-9-anthryl)-4′-(9-phenyl-9H-carbazol-3-yl)triphenylamine (abbreviated as PCBAPA), 2,5,8,11-tetra-tert-butylperylene (abbreviated as TBPe), or BPPya of the following formula, or the like may be used.

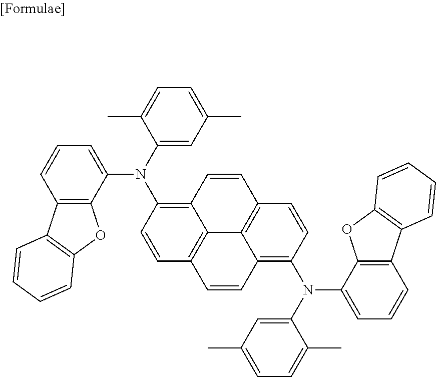 [SMILES: Cc1ccc(C)c(N(c2ccc3ccc4c(N(c5cc(C)ccc5C)c5cccc6c5oc5ccccc56)ccc5ccc2c3c54)c2cccc3c2oc2ccccc23)c1]

As the green fluorescent material, aromatic amine derivatives or the like may be used. Specifically, as the green fluorescent material, N-(9,10-diphenyl-2-anthryl)-N,9-diphenyl-9H-carbazol-3-amine (abbreviated as 2PCAPA), N-[9,10-bis(1,1′-biphenyl-2-yl)-2-anthryl]-N,9-diphenyl-9H-carbazol-3-amine (abbreviated as 2PCABPhA), N-(9,10-diphenyl-2-anthryl)-N,N′,N′-triphenyl-1,4-phenylenediamine (abbreviated as 2DPAPA), N-[9,10-bis(1,1′-biphenyl-2-yl)-2-anthryl]-N,N′,N′-triphenyl-1,4-phenylenediamine (abbreviated as 2DPABPhA), N-[9,10-bis(1,1′-biphenyl-2-yl)]-N-[4-(9H-carbazol-9-yl)phenyl]-N-phenylanthracen-2-amine (abbreviated as 2YGABPhA), N,N,9-triphenylanthracen-9-amine (abbreviated as DPhAPhA), or the like may be used.

As the red fluorescent material, tetracene derivatives, diamine derivatives, or the like may be used. Specifically, as the red fluorescent material, N,N,N′,N′-tetrakis(4-methylphenyl)tetracene-5,11-diamine (abbreviated as p-mPhTD), 7,14-diphenyl-N,N,N′,N′-tetrakis(4-methylphenyl) acenaphtho[1,2-a]fluoranthene-3,10-diamine (abbreviated as p-mPhAFD), or the like may be used.

Preferably, the dopant compound may comprise a blue fluorescent material. Blue fluorescent materials have a wider energy band gap than green and red fluorescent materials, so that, in the conventional blue light-emitting elements, the driving voltage and turn-on voltage were high. In the organic electroluminescent element according to the present invention, however, as it comprises a specific combination of the first host compound, the second host compound, and the dopant compound, the driving voltage and turn-on voltage can be lowered.

In an embodiment, the emission peak wavelength in the solution state of the dopant compound may be 430 nm to 480 nm.

The emission peak wavelength in the solution state of the dopant compound may be measured by the following method. A 10 μmoles/L toluene solution of a compound to be measured is prepared and placed in a quartz cell, and the emission spectrum (vertical axis: emission intensity, horizontal axis: wavelength) of the sample is measured at room temperature. The emission spectrum may be measured by a spectrofluorometer (Hitachi High-Tech Science, F-7000), but it is not limited thereto.

In the emission spectrum, the peak wavelength of the emission spectrum at which the emission intensity is maximum is taken as the emission peak wavelength. Meanwhile, in the present specification, the emission peak wavelength may be referred to as the maximum fluorescence peak wavelength (FL-peak).

The organic electroluminescent element may comprise an anode, an organic layer, and a cathode.

The organic layer comprises a light-emitting layer. The light-emitting layer is composed of a single layer or a plurality of layers. In addition, the organic layer may comprise an electron transporting zone or a hole transporting zone.

The light-emitting layer comprises the first host compound, the second host compound, and the dopant compound.

In an embodiment, the light-emitting layer may be composed of a single layer. For example, the first host compound, the second host compound, and the dopant compound may be contained together in the single layer.

In an embodiment, the light-emitting layer may be composed of a plurality of layers. The light-emitting layer may comprise a first layer comprising the first host compound and a second layer comprising the second host compound.

The first layer is disposed on the anode side, and the second layer is disposed on the cathode side. The second layer is disposed between the first layer and the cathode.

The dopant compound may be contained in the first layer or may be contained in the second layer.

Preferably, the dopant compound may be contained in the first layer. The light-emitting layer may comprise a first layer comprising the first host compound and the dopant compound, and a second layer comprising the second host compound. As the dopant compound is doped in the first host compound, trap sites in the light-emitting layer can be reduced, and the turn-on voltage can be further lowered.

The configuration of the organic electroluminescent element of the first embodiment is further described in “Common Configuration of Each Embodiment” to be described later.

### Second Embodiment

An organic electroluminescent element according to the second embodiment of the present invention comprises an anode, a cathode, and an organic layer interposed between the anode and the cathode,
wherein the organic layer comprises:
a first host compound having a HOMO energy level of −5.5 eV or higher and a triplet energy level of 2.5 eV or lower,
a second host compound having a LUMO energy level of −4.0 eV to −3.0 eV, and
a dopant compound,
wherein the first host compound and the second host compound are capable of recombining with each other to form an exciplex,
the exciplex has a triplet energy level of greater than 1.5 eV, and
the first host compound, the second host compound, and the dopant compound satisfy the following Relationships 1 to 3 and 5.

$${H}_{1} {S}_{1} > {DS}_{1} \qquad [ Relationship 1 ]$$

$${H}_{1} {T}_{1} > {DT}_{1} \qquad [ Relationship 2 ]$$

$${H}_{2} {S}_{1} > {DS}_{1} \qquad [ Relationship 3 ]$$

$${DT}_{1} > {H}_{2} {T}_{1} \qquad [ Relationship 5 ]$$

In Relationships 1 to 3 and 5,
H₁S₁ is a singlet energy level of the first host compound,
H₁T₁ is a triplet energy level of the first host compound,
H₂S₁ is a singlet energy level of the second host compound,
H₂T₁ is a triplet energy level of the second host compound,
DS₁ is a singlet energy level of the dopant compound, and
DT₁ is a triplet energy level of the dopant compound.

The first host compound, the dopant compound, and the exciplex formed by the recombination of the first host compound and the second host compound are as described above in the first embodiment.

In an embodiment, the second host compound may be a compound comprising anthracene. For example, as the second host compound, a compound that comprises anthracene, can recombine with the first host compound to form an exciplex, has a LUMO energy level within the above range, and satisfies the above Relationship 3 may be selected.

The second host compound may comprise a compound represented by the following Formula (4).

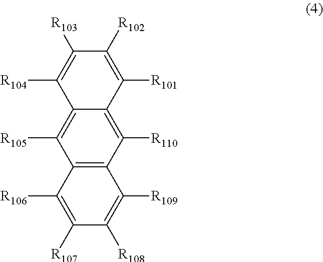

In Formula (4),
at least one of R¹⁰¹ to Rio is a group represented by the following Formula (5), and
R₁₀₁ to R₁₁₀ that are not the group represented by the following Formula (5) are each independently a hydrogen atom or a substituent R.

When two or more of the substituent R are present, the two or more of the substituent R are the same as or different from each other, and
when two or more of the group represented by Formula (5) are present, the two or more of the group represented by Formula (5) are the same as or different from each other.

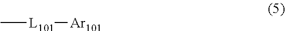

(In Formula (5),
L₁₀₁ is:
a single bond,
a substituted or unsubstituted arylene group having 6 to 50 ring carbon atoms, or
a substituted or unsubstituted divalent heterocyclic group having 5 to 50 ring atoms, and
Ar₁₀₁ is:
a substituted or unsubstituted aryl group having 6 to 50 ring carbon atoms, or
a substituted or unsubstituted monovalent heterocyclic group having 5 to 50 ring atoms.)
the substituent R is:
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇),
a halogen atom,
a cyano group,
a nitro group,
a substituted or unsubstituted aryl group having 6 to 50 ring carbon atoms, or
a substituted or unsubstituted monovalent heterocyclic group having 5 to 50 ring atoms,
wherein R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted monovalent heterocyclic group having 5 to 50 ring atoms, and
when two or more of R₉₀₁ to R₉₀₇ are present, the two or more of R₉₀₁ to R₉₀₇ are the same as or different from each other.

Specific examples of the second host compound include the following compounds, but it is not limited to the following exemplary compounds.

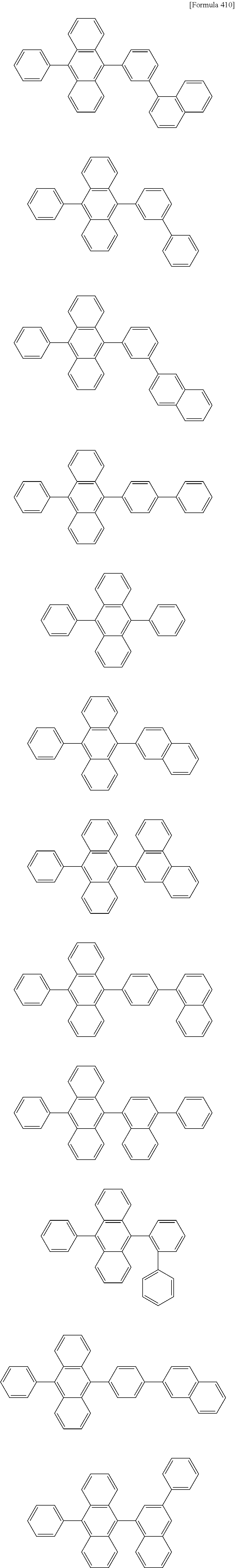

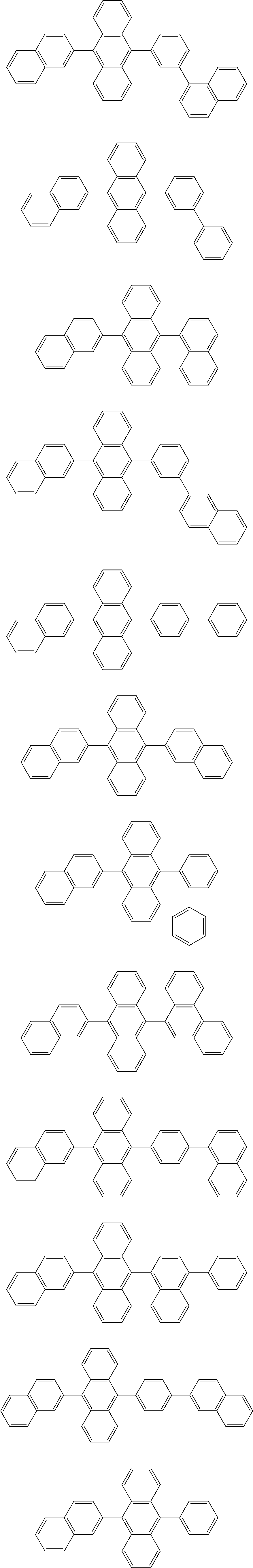

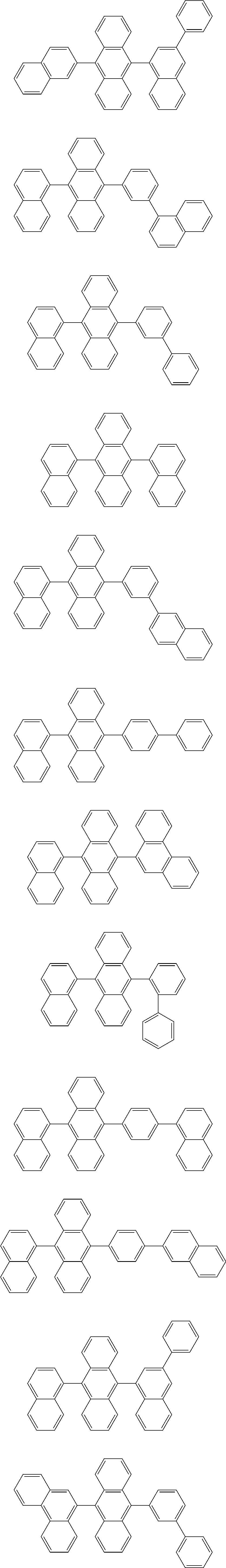

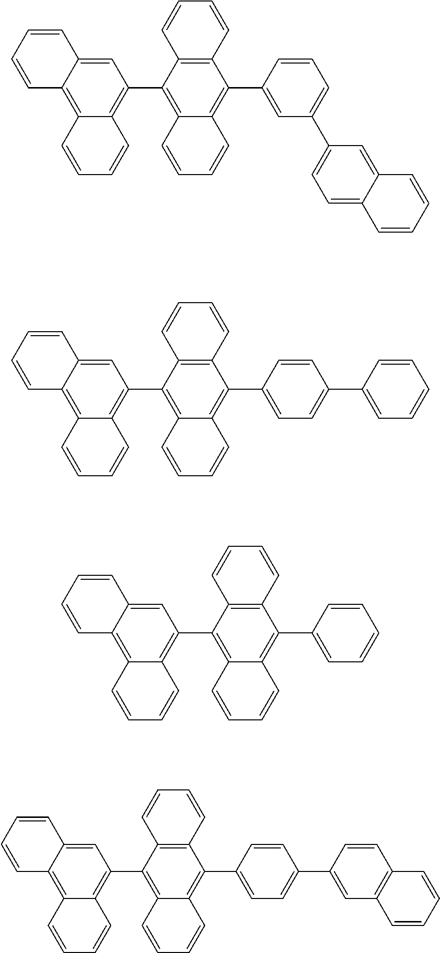

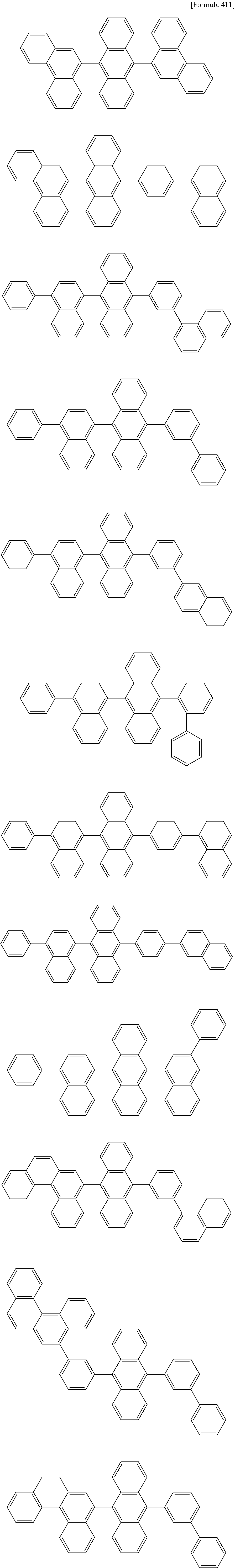

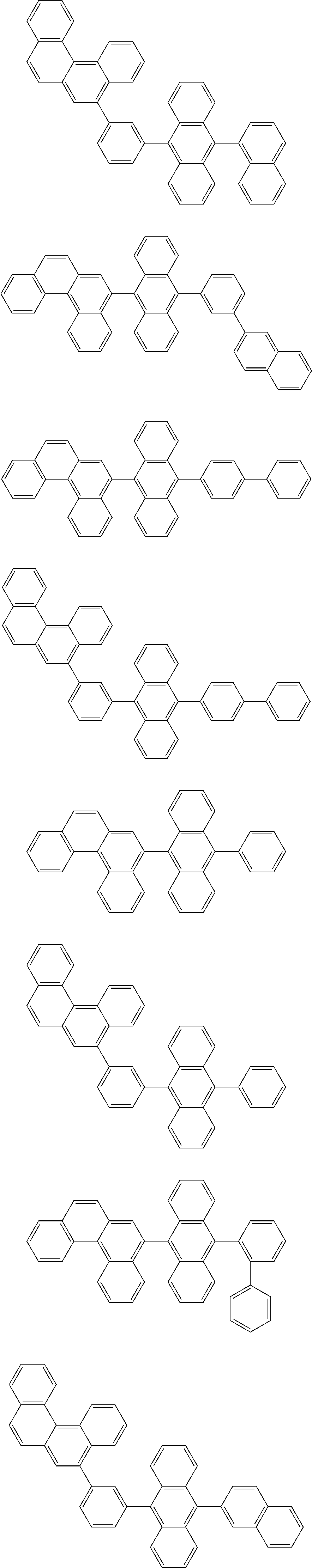

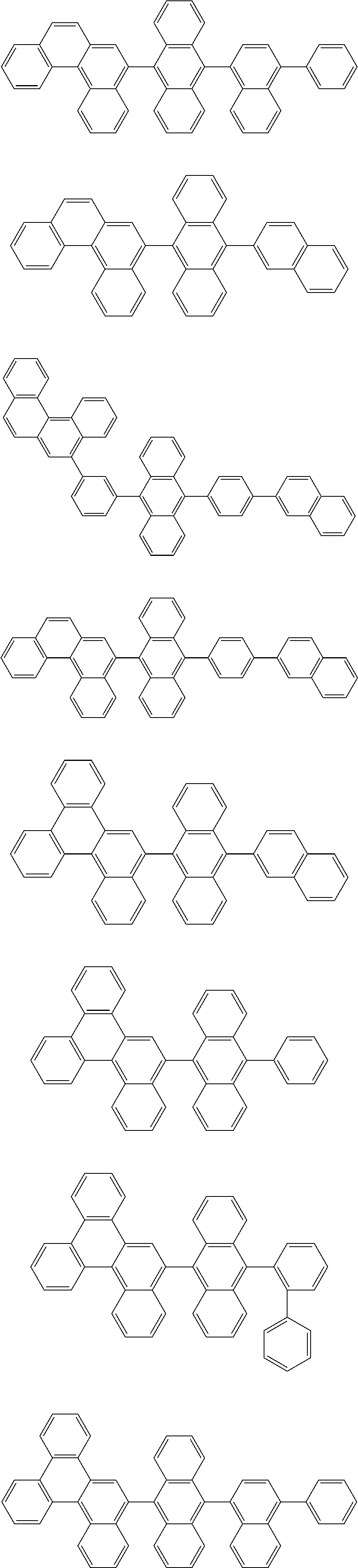

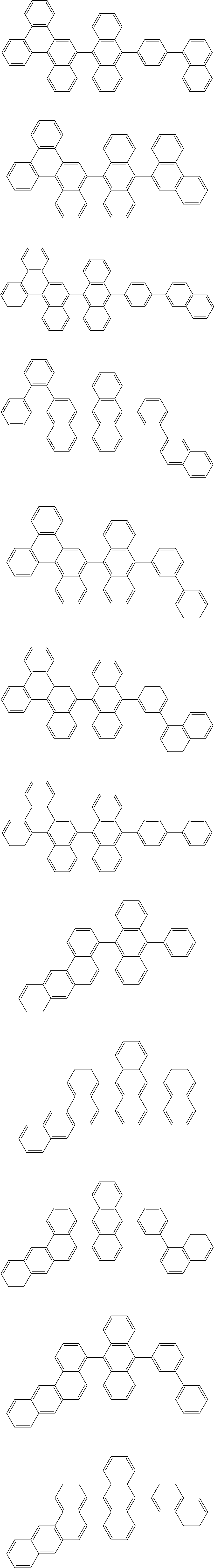

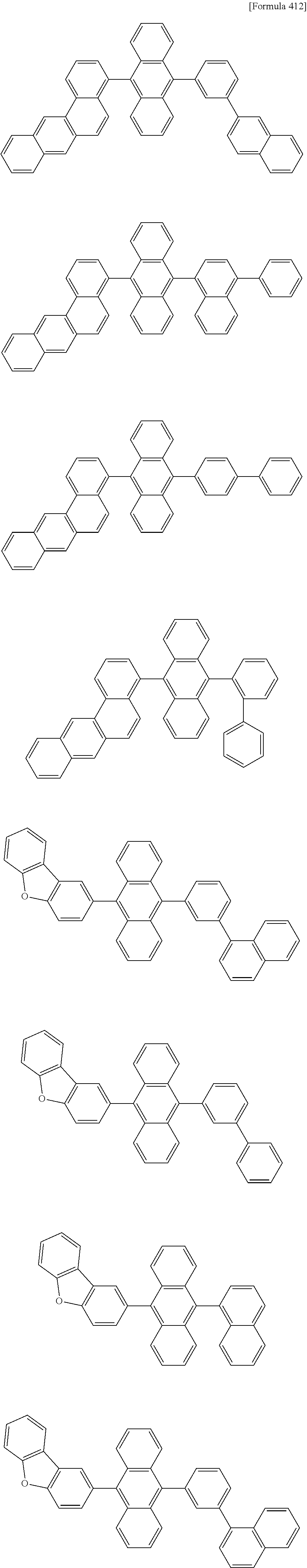

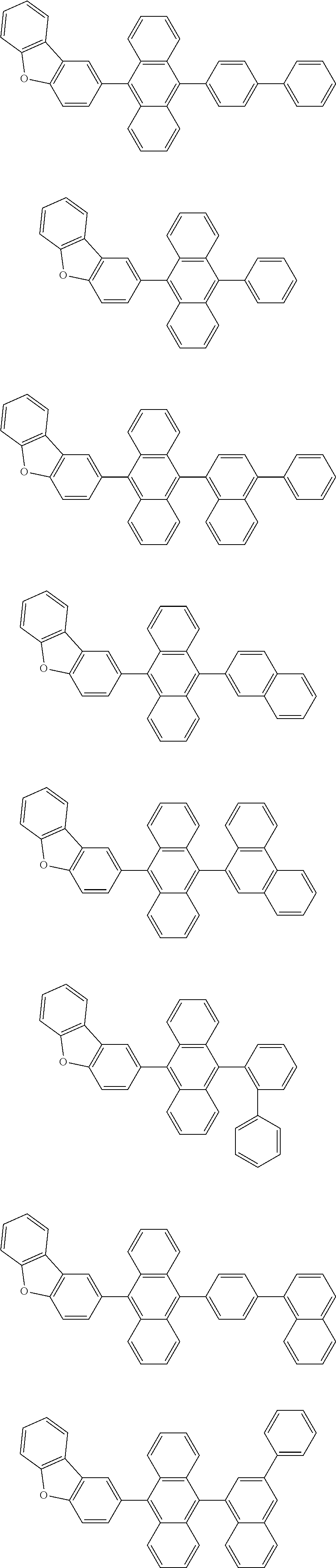

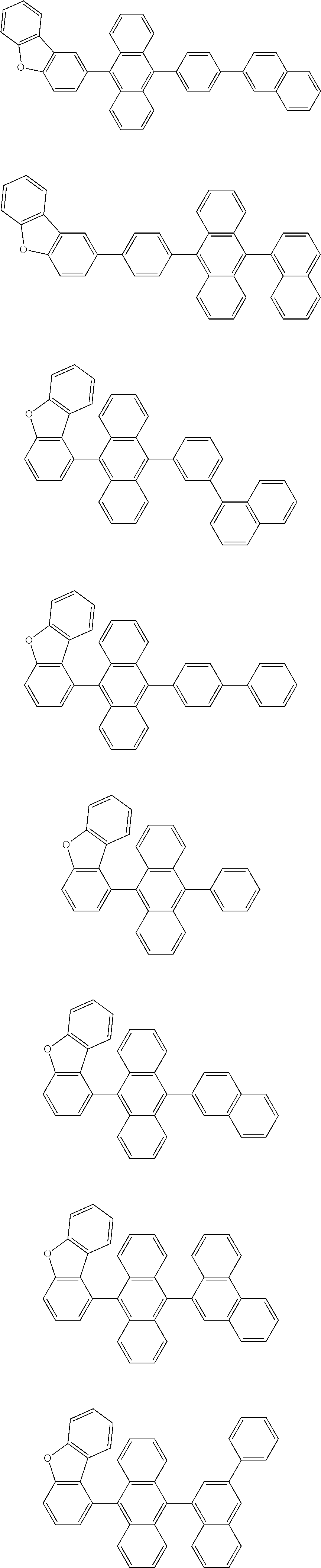

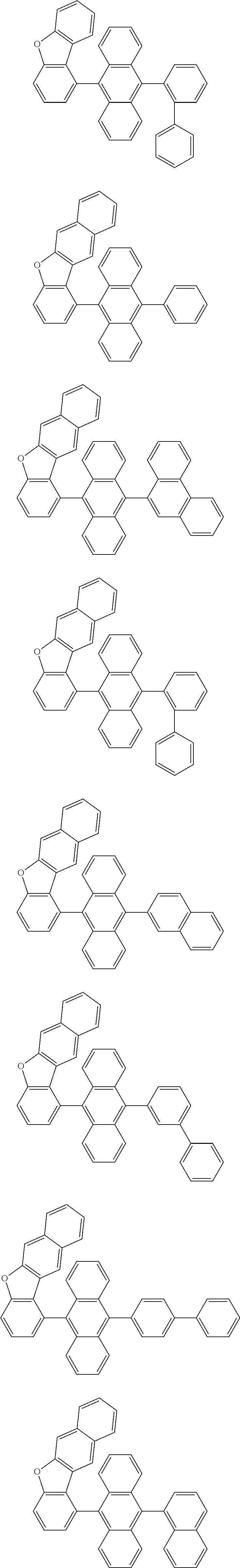

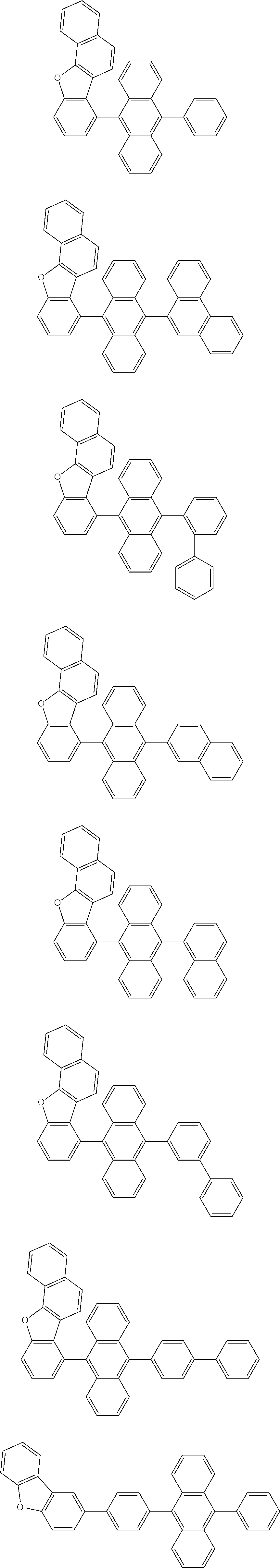

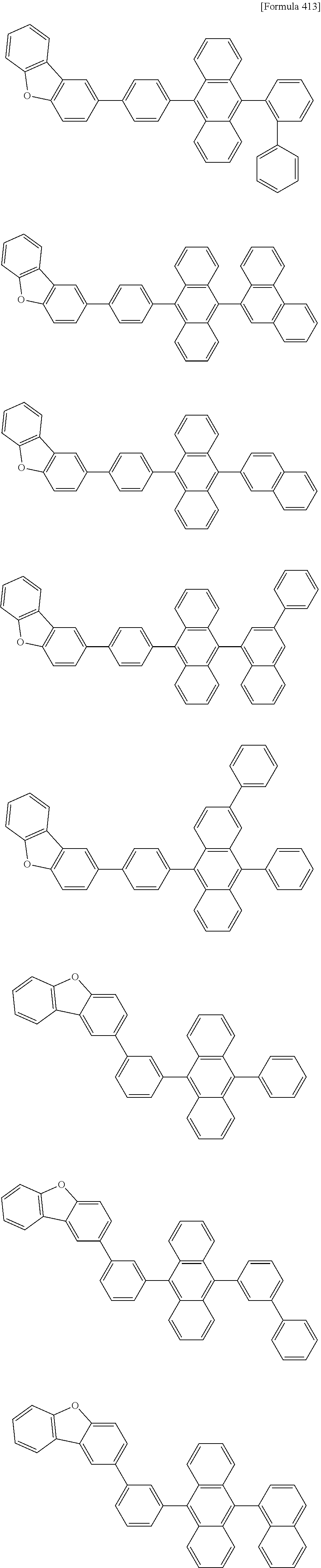

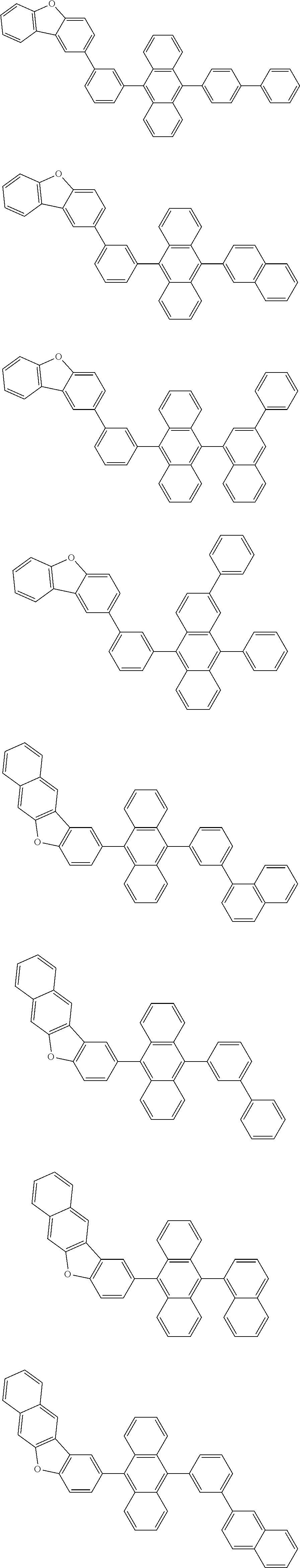

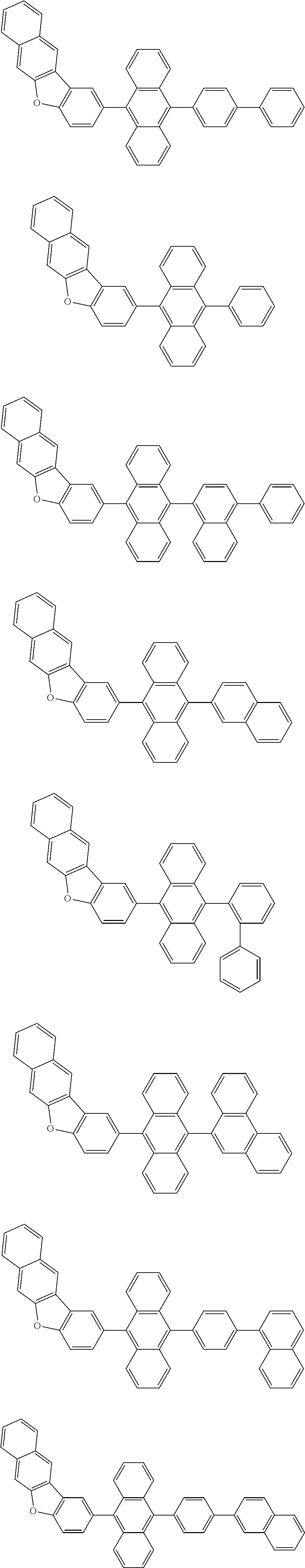

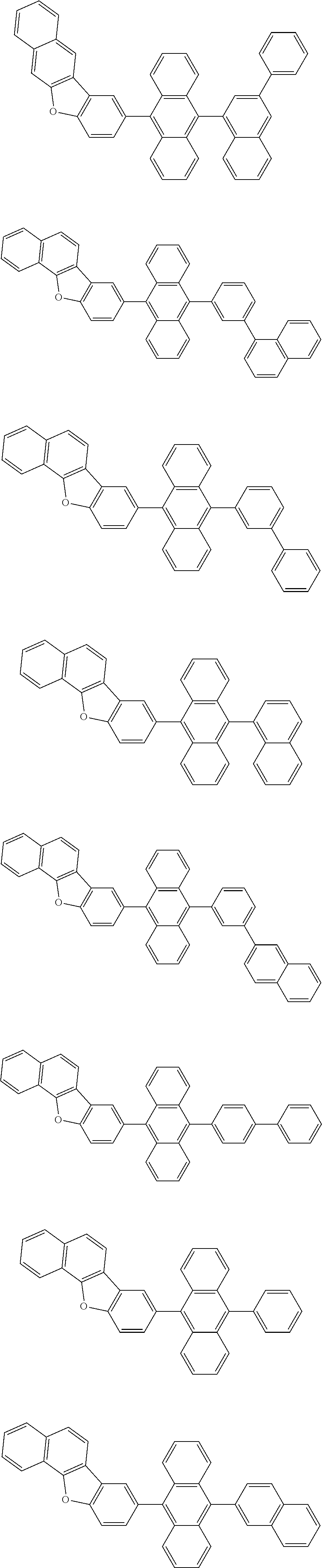

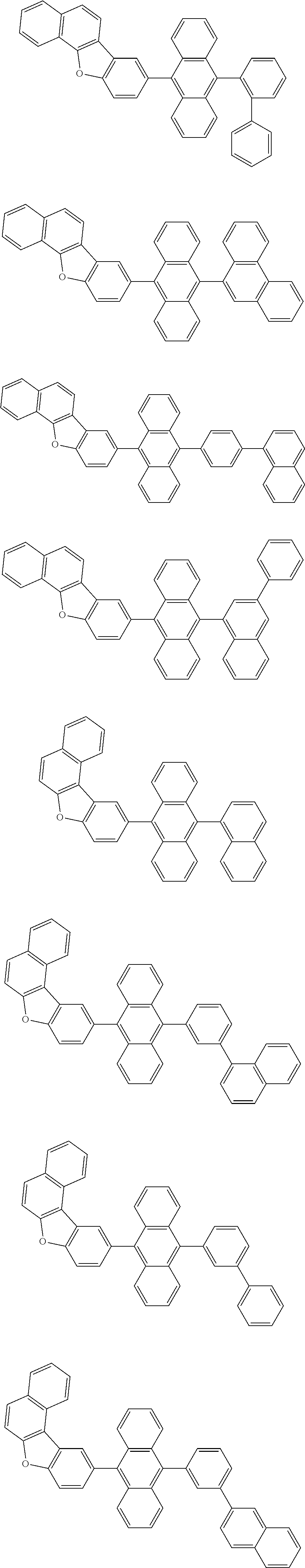

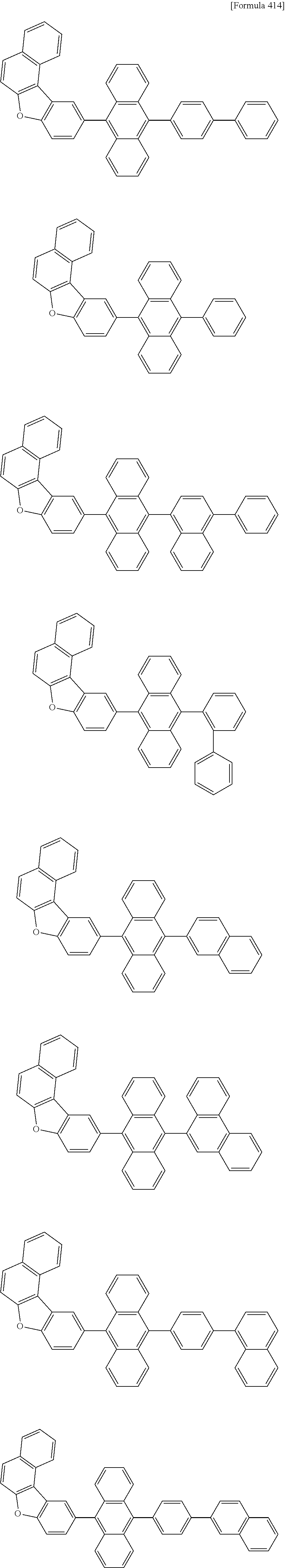

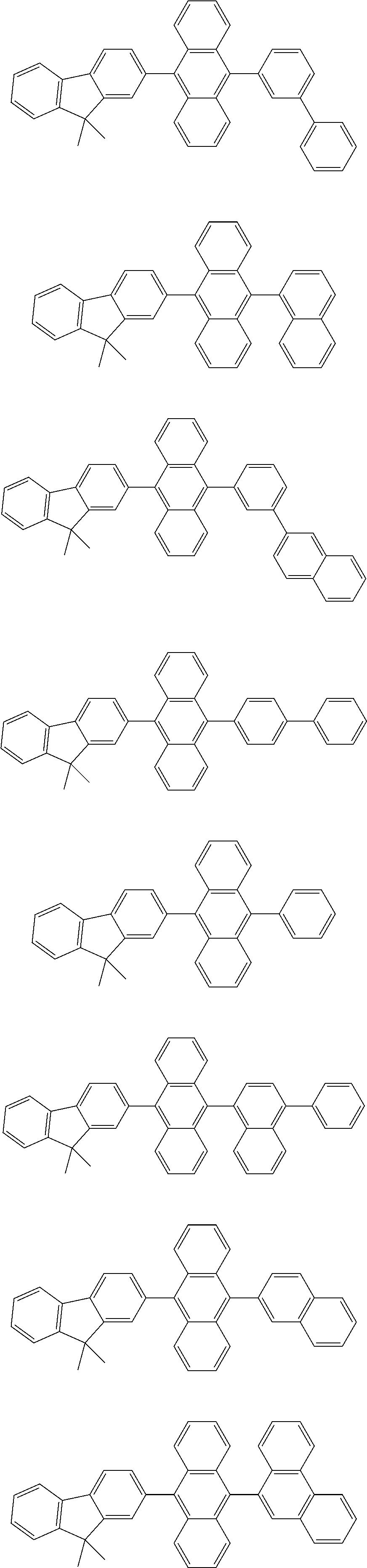

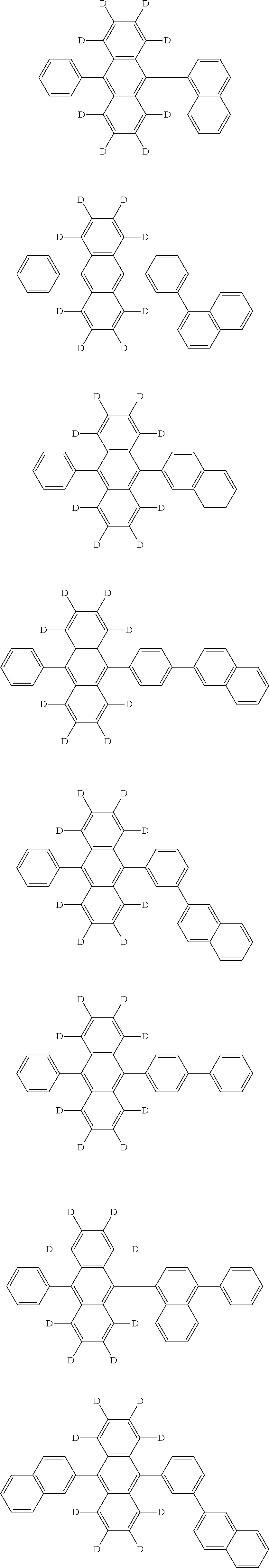

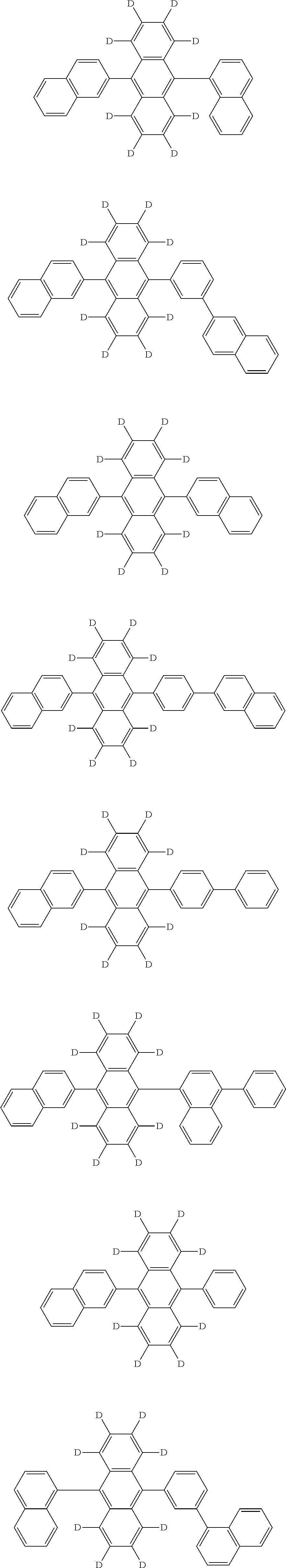

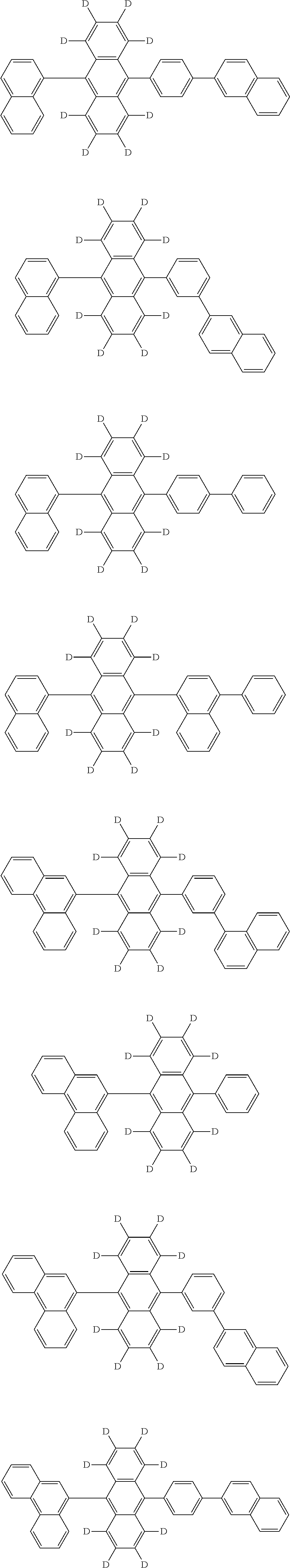

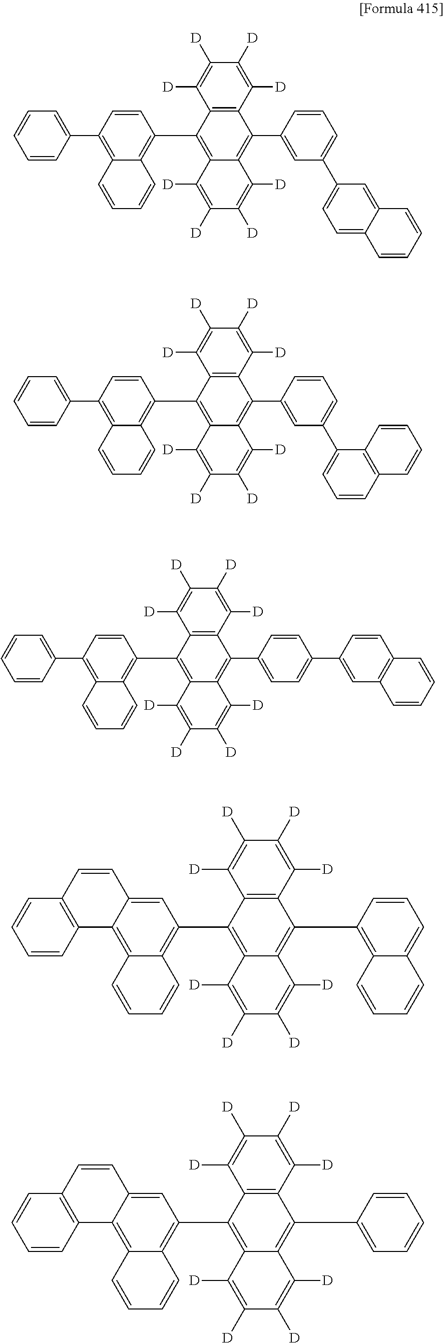

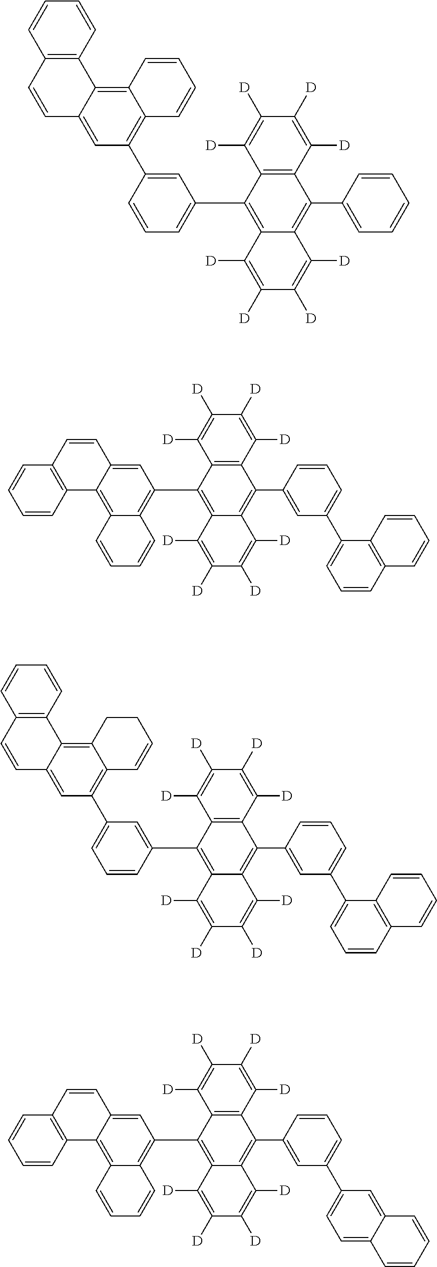 [SMILES: [2H]c1c([2H])c([2H])c2c(-c3cccc(-c4cc5ccc6ccccc6c5c5ccccc45)c3)c3c([2H])c([2H])c([2H])c([2H])c3c(-c3ccccc3)c2c1[2H] ; [2H]c1c([2H])c([2H])c2c(-c3cc4ccc5ccccc5c4c4ccccc34)c3c([2H])c([2H])c([2H])c([2H])c3c(-c3cccc(-c4cccc5ccccc45)c3)c2c1[2H] ; [2H]c1c([2H])c([2H])c2c(-c3cccc(-c4cccc5ccccc45)c3)c3c([2H])c([2H])c([2H])c([2H])c3c(-c3cccc(-c4cc5ccc6ccccc6c5c5c4C=CCC5)c3)c2c1[2H] ; [2H]c1c([2H])c([2H])c2c(-c3cc4ccc5ccccc5c4c4ccccc34)c3c([2H])c([2H])c([2H])c([2H])c3c(-c3cccc(-c4ccc5ccccc5c4)c3)c2c1[2H]]

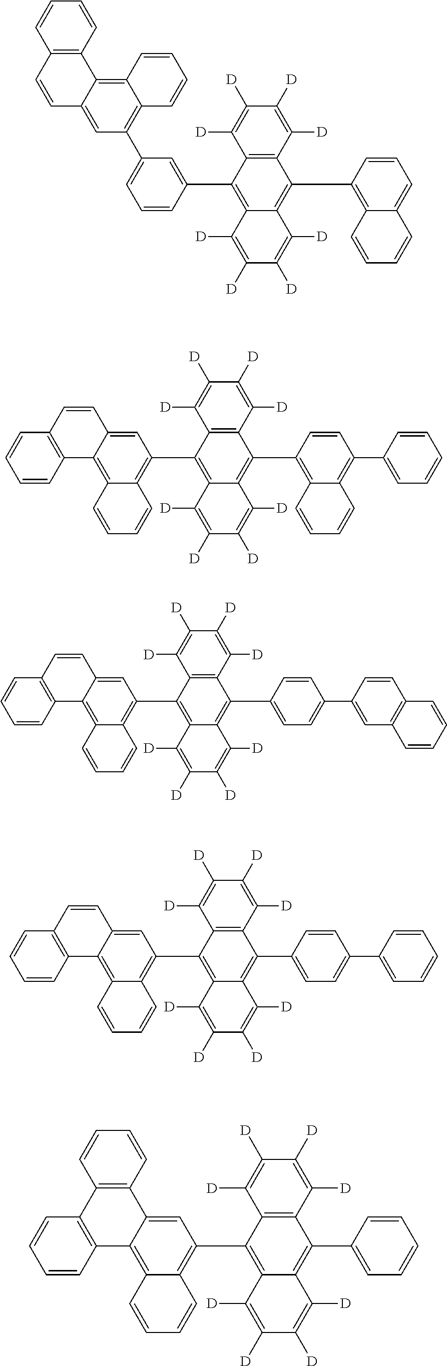

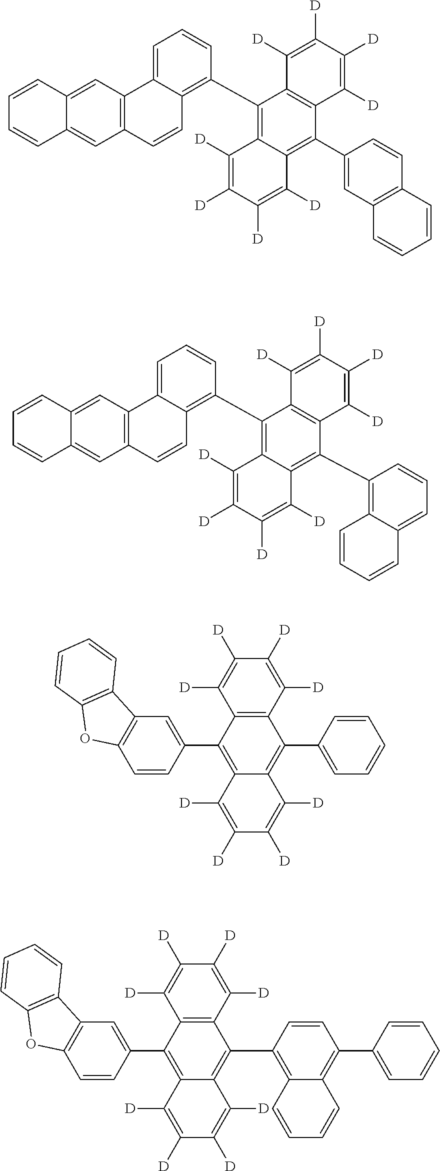 [SMILES: [2H]c1c([2H])c([2H])c2c(-c3cccc4c3ccc3cc5ccccc5cc34)c3c([2H])c([2H])c([2H])c([2H])c3c(-c3ccc4ccccc4c3)c2c1[2H] ; [2H]c1c([2H])c([2H])c2c(-c3cccc4c3ccc3cc5ccccc5cc34)c3c([2H])c([2H])c([2H])c([2H])c3c(-c3cccc4ccccc34)c2c1[2H] ; [2H]c1c([2H])c([2H])c2c(-c3ccc4oc5ccccc5c4c3)c3c([2H])c([2H])c([2H])c([2H])c3c(-c3ccccc3)c2c1[2H] ; [2H]c1c([2H])c([2H])c2c(-c3ccc(-c4ccccc4)c4ccccc34)c3c([2H])c([2H])c([2H])c([2H])c3c(-c3ccc4oc5ccccc5c4c3)c2c1[2H]]

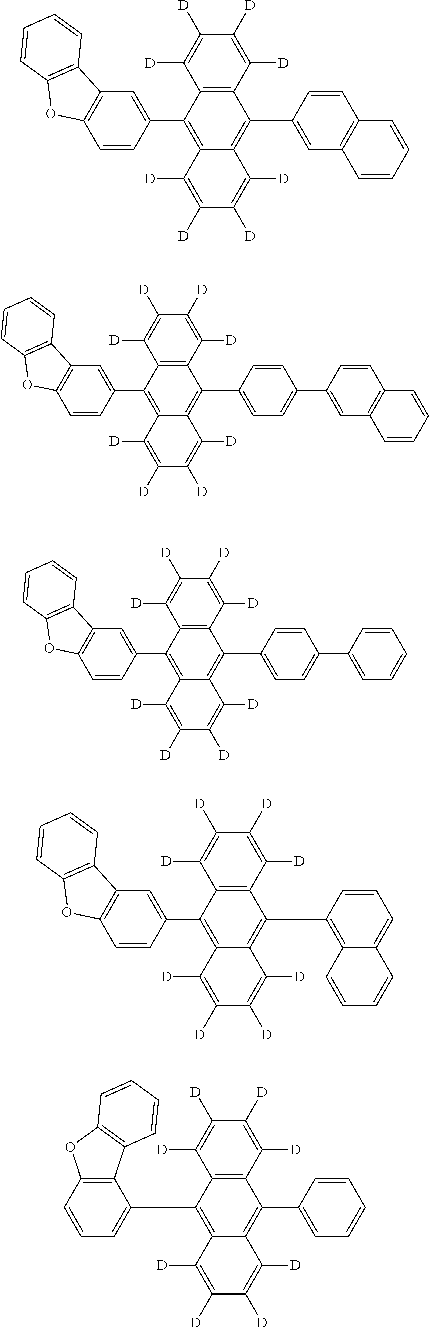

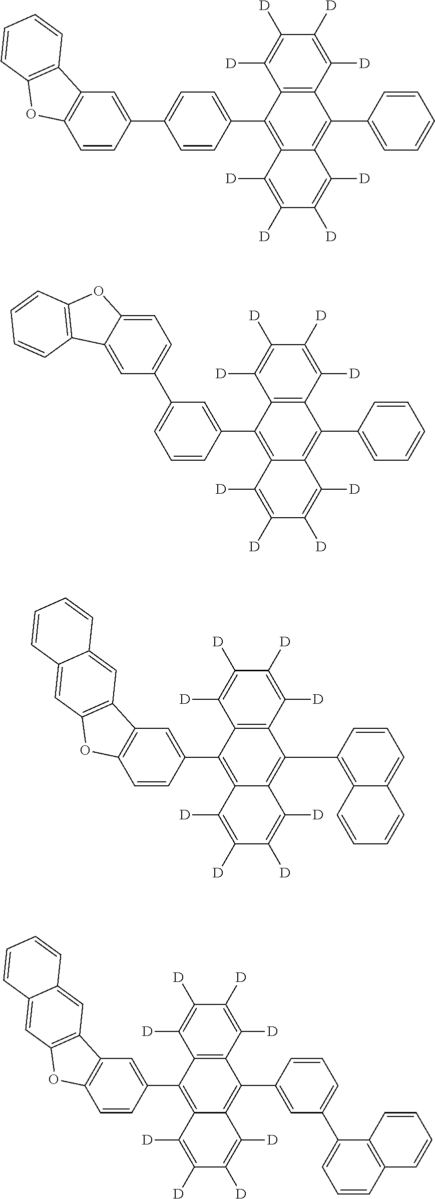 [SMILES: [2H]c1c([2H])c([2H])c2c(-c3ccc(-c4ccc5oc6ccccc6c5c4)cc3)c3c([2H])c([2H])c([2H])c([2H])c3c(-c3ccccc3)c2c1[2H] ; [2H]c1c([2H])c([2H])c2c(-c3cccc(-c4ccc5oc6ccccc6c5c4)c3)c3c([2H])c([2H])c([2H])c([2H])c3c(-c3ccccc3)c2c1[2H] ; [2H]c1c([2H])c([2H])c2c(-c3cccc4ccccc34)c3c([2H])c([2H])c([2H])c([2H])c3c(-c3ccc4oc5cc6ccccc6cc5c4c3)c2c1[2H] ; [2H]c1c([2H])c([2H])c2c(-c3ccc4oc5cc6ccccc6cc5c4c3)c3c([2H])c([2H])c([2H])c([2H])c3c(-c3cccc(-c4cccc5ccccc45)c3)c2c1[2H]]

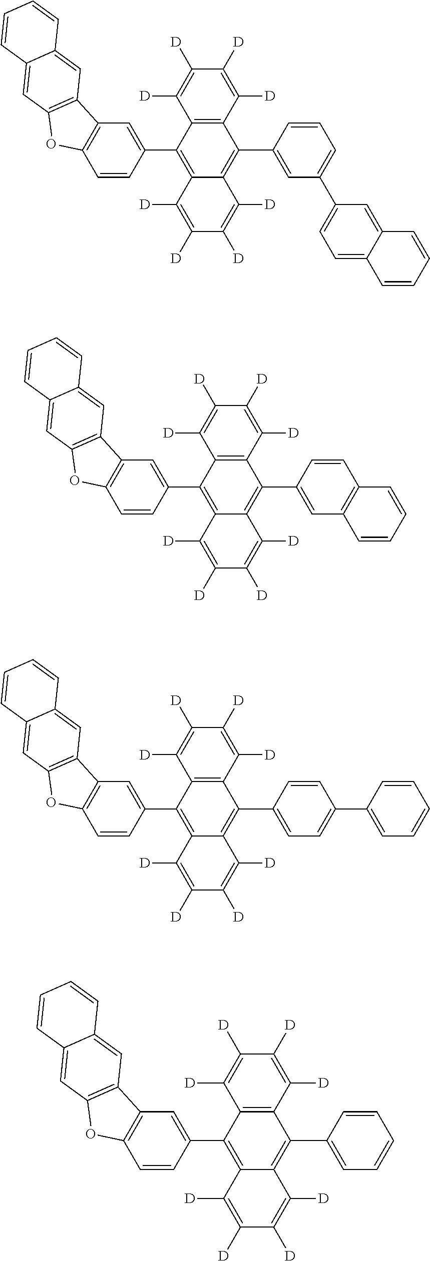 [SMILES: [2H]c1c([2H])c([2H])c2c(-c3ccc4oc5cc6ccccc6cc5c4c3)c3c([2H])c([2H])c([2H])c([2H])c3c(-c3cccc(-c4ccc5ccccc5c4)c3)c2c1[2H] ; [2H]c1c([2H])c([2H])c2c(-c3ccc4oc5cc6ccccc6cc5c4c3)c3c([2H])c([2H])c([2H])c([2H])c3c(-c3ccc4ccccc4c3)c2c1[2H] ; [2H]c1c([2H])c([2H])c2c(-c3ccc4oc5cc6ccccc6cc5c4c3)c3c([2H])c([2H])c([2H])c([2H])c3c(-c3ccc(-c4ccccc4)cc3)c2c1[2H] ; [2H]c1c([2H])c([2H])c2c(-c3ccc4oc5cc6ccccc6cc5c4c3)c3c([2H])c([2H])c([2H])c([2H])c3c(-c3ccccc3)c2c1[2H]]

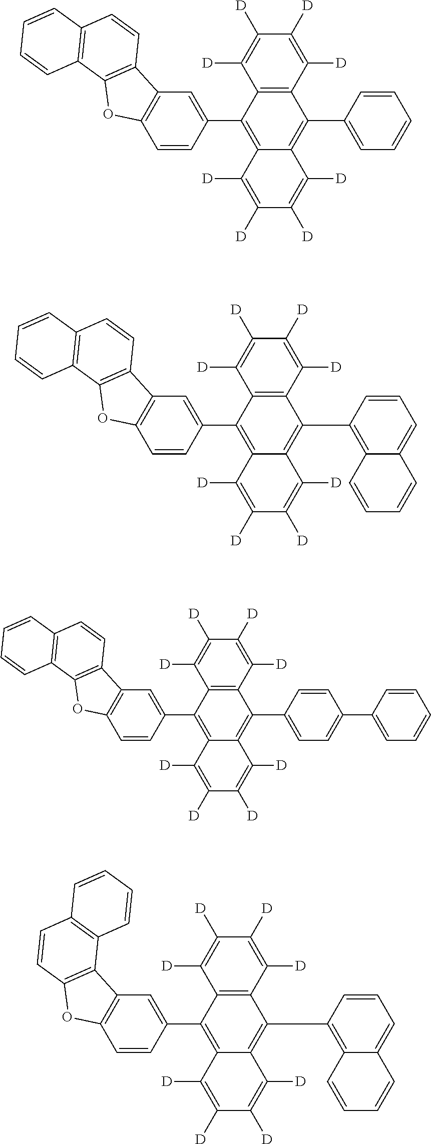 [SMILES: [2H]c1c([2H])c([2H])c2c(-c3ccc4oc5c6ccccc6ccc5c4c3)c3c([2H])c([2H])c([2H])c([2H])c3c(-c3ccccc3)c2c1[2H] ; [2H]c1c([2H])c([2H])c2c(-c3cccc4ccccc34)c3c([2H])c([2H])c([2H])c([2H])c3c(-c3ccc4oc5c6ccccc6ccc5c4c3)c2c1[2H] ; [2H]c1c([2H])c([2H])c2c(-c3ccc4oc5c6ccccc6ccc5c4c3)c3c([2H])c([2H])c([2H])c([2H])c3c(-c3ccc(-c4ccccc4)cc3)c2c1[2H] ; [2H]c1c([2H])c([2H])c2c(-c3cccc4ccccc34)c3c([2H])c([2H])c([2H])c([2H])c3c(-c3ccc4oc5ccc6ccccc6c5c4c3)c2c1[2H]]

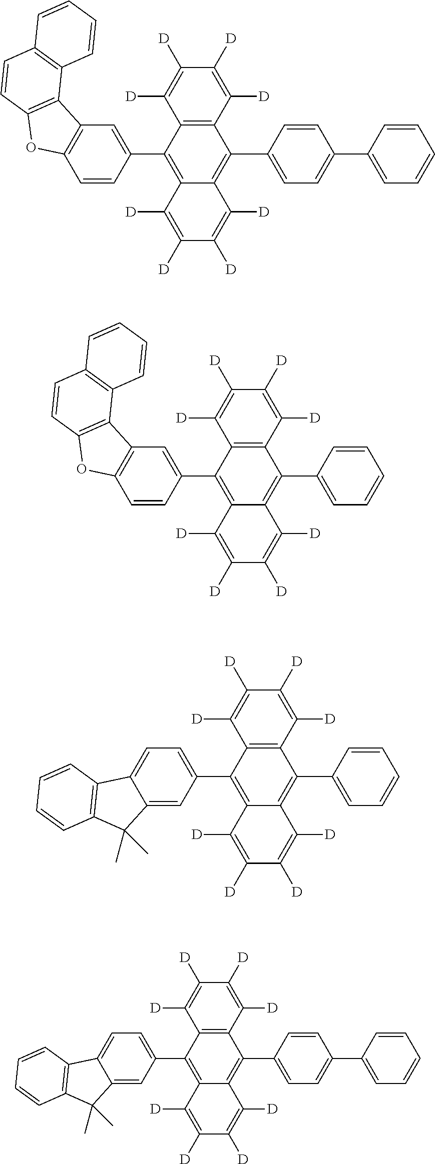 [SMILES: [2H]c1c([2H])c([2H])c2c(-c3ccc4oc5ccc6ccccc6c5c4c3)c3c([2H])c([2H])c([2H])c([2H])c3c(-c3ccc(-c4ccccc4)cc3)c2c1[2H] ; [2H]c1c([2H])c([2H])c2c(-c3ccc4oc5ccc6ccccc6c5c4c3)c3c([2H])c([2H])c([2H])c([2H])c3c(-c3ccccc3)c2c1[2H] ; [2H]c1c([2H])c([2H])c2c(-c3ccc4c(c3)C(C)(C)c3ccccc3-4)c3c([2H])c([2H])c([2H])c([2H])c3c(-c3ccccc3)c2c1[2H] ; [2H]c1c([2H])c([2H])c2c(-c3ccc4c(c3)C(C)(C)c3ccccc3-4)c3c([2H])c([2H])c([2H])c([2H])c3c(-c3ccc(-c4ccccc4)cc3)c2c1[2H]]

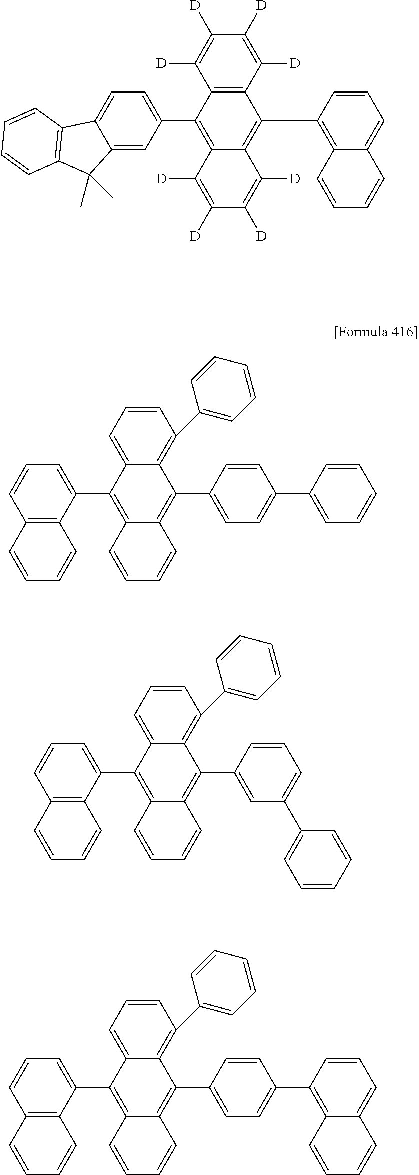

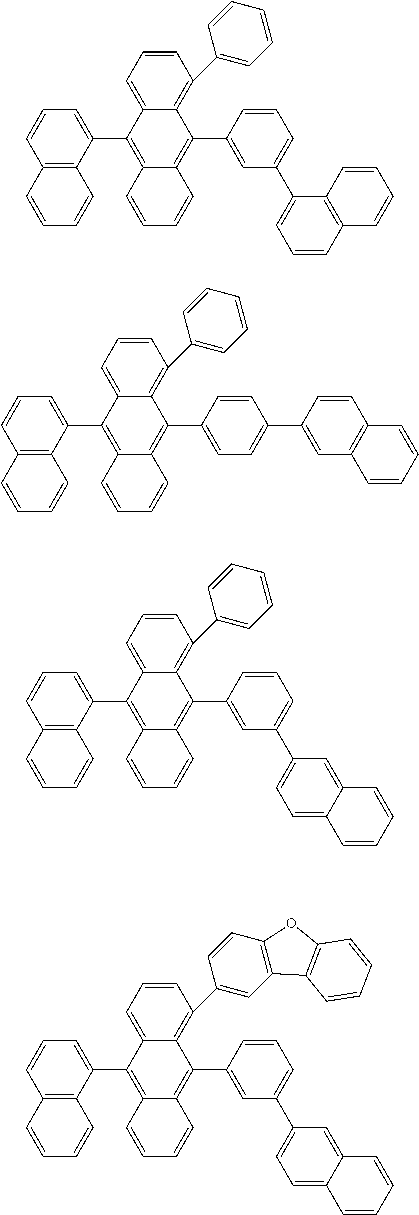

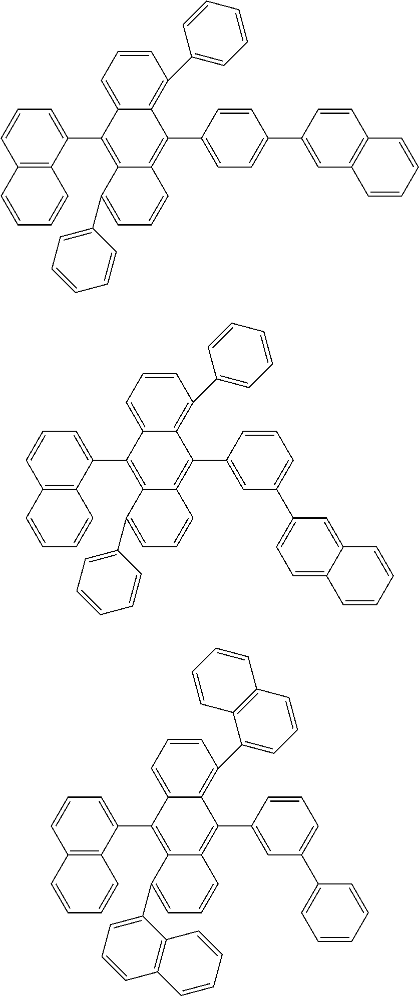

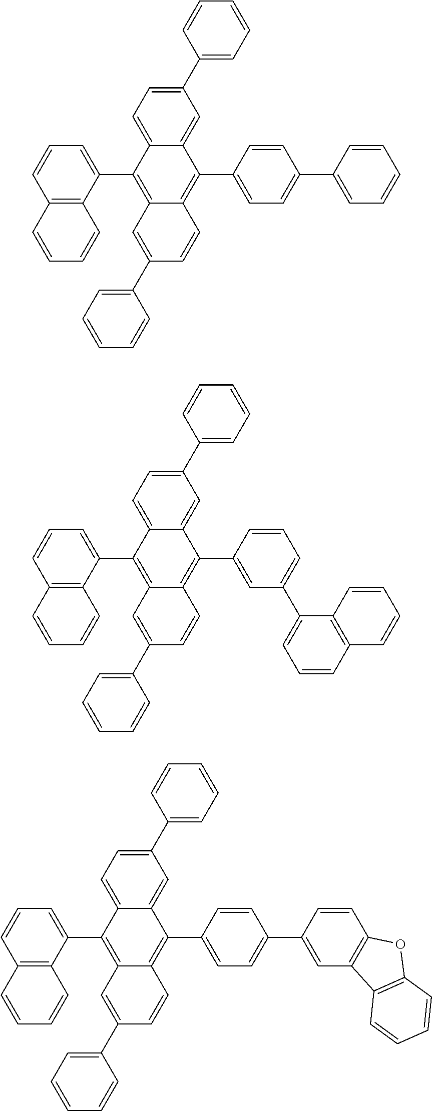

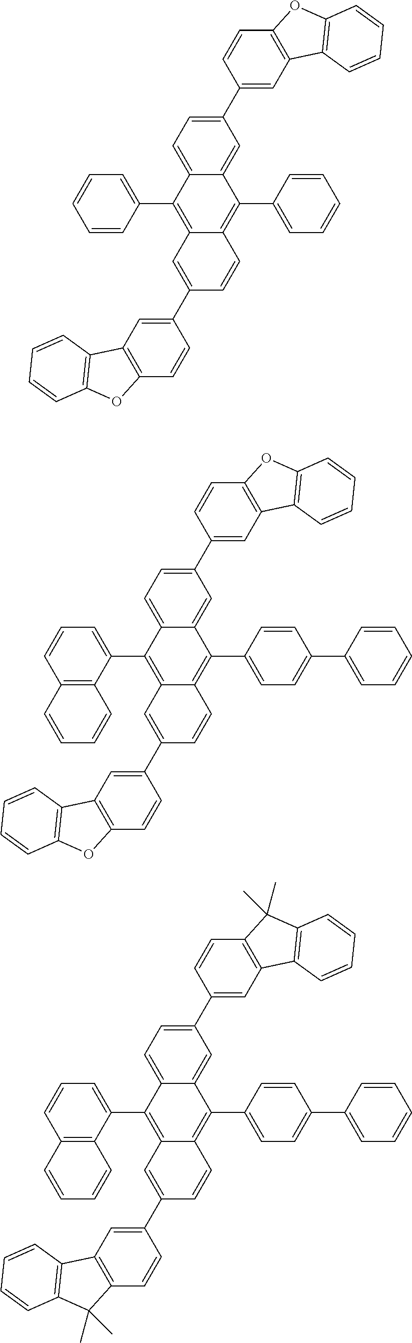

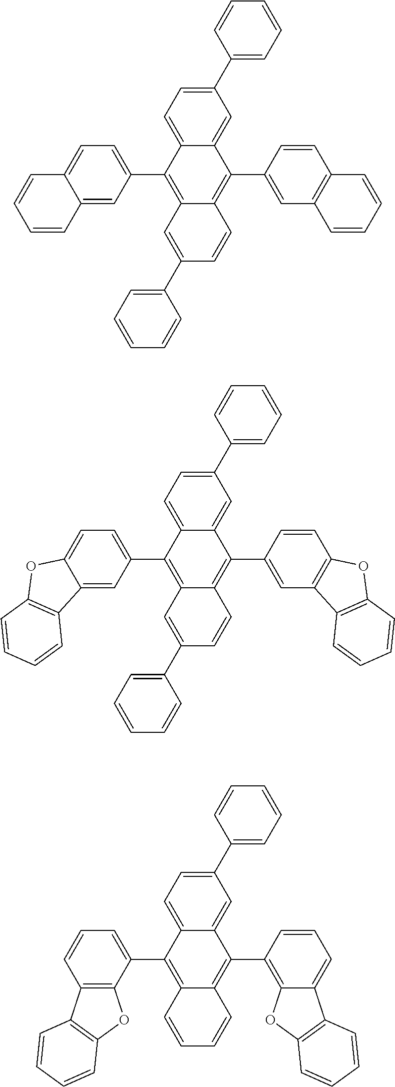

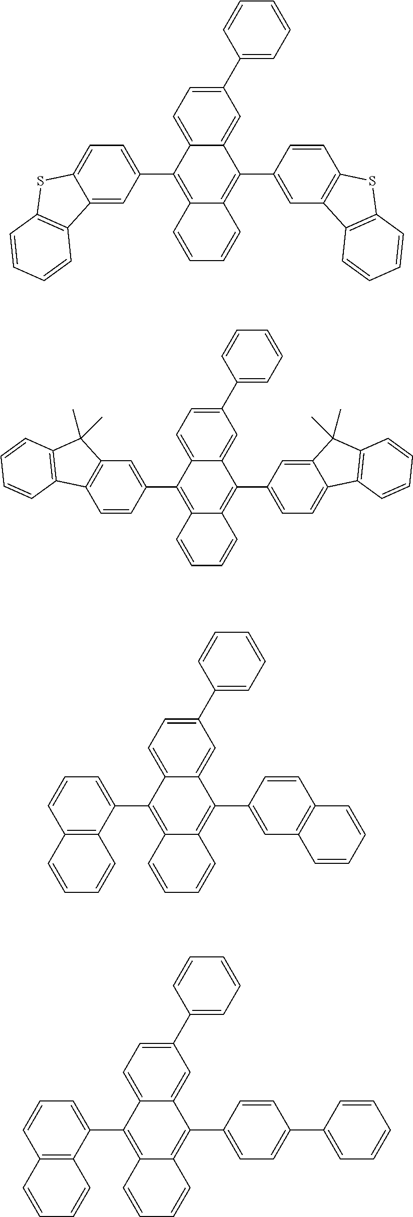

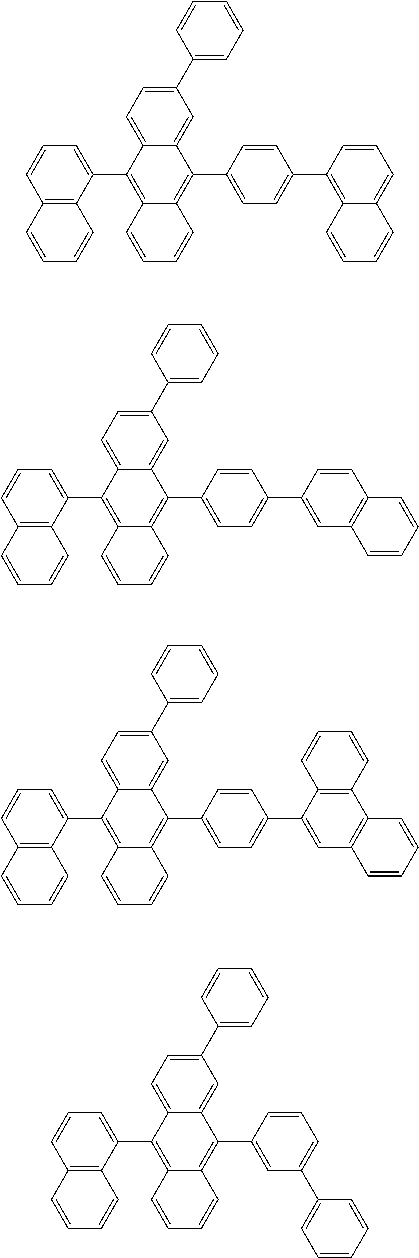

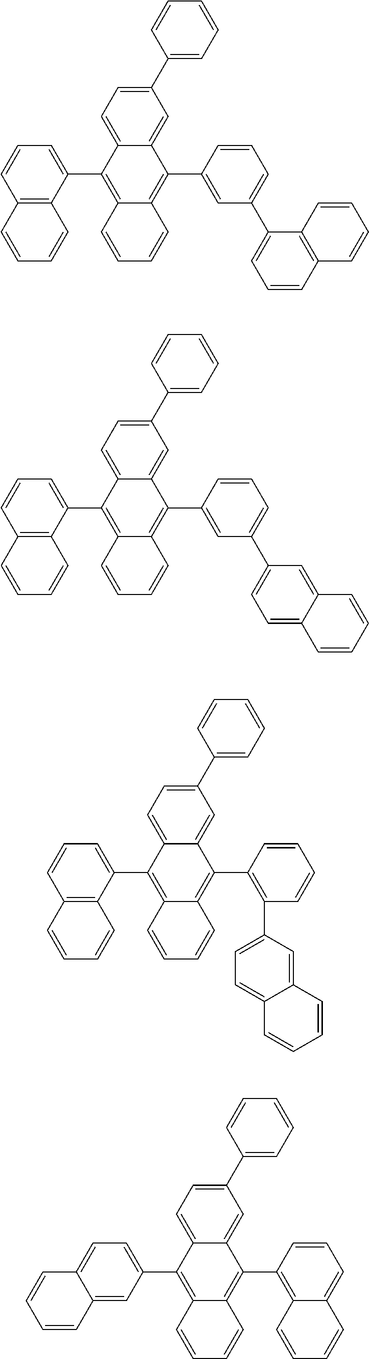

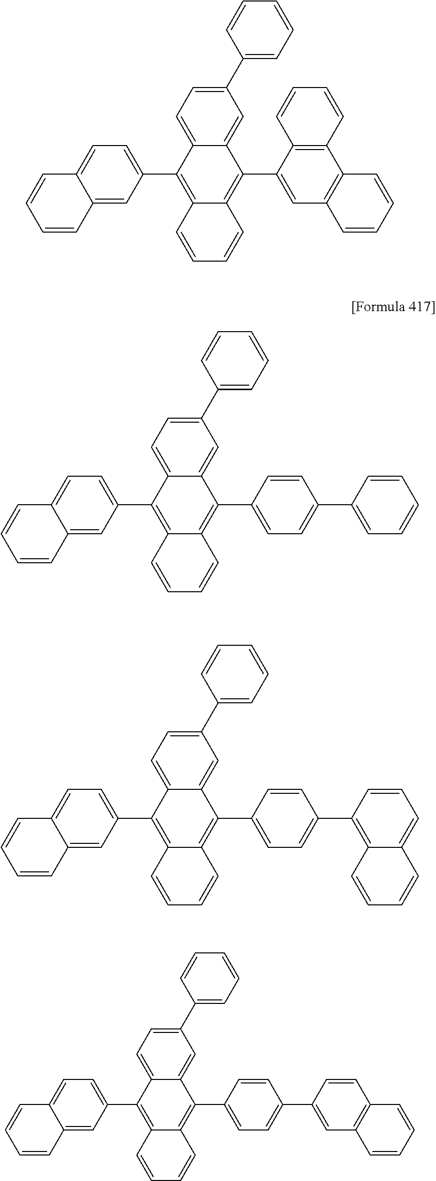

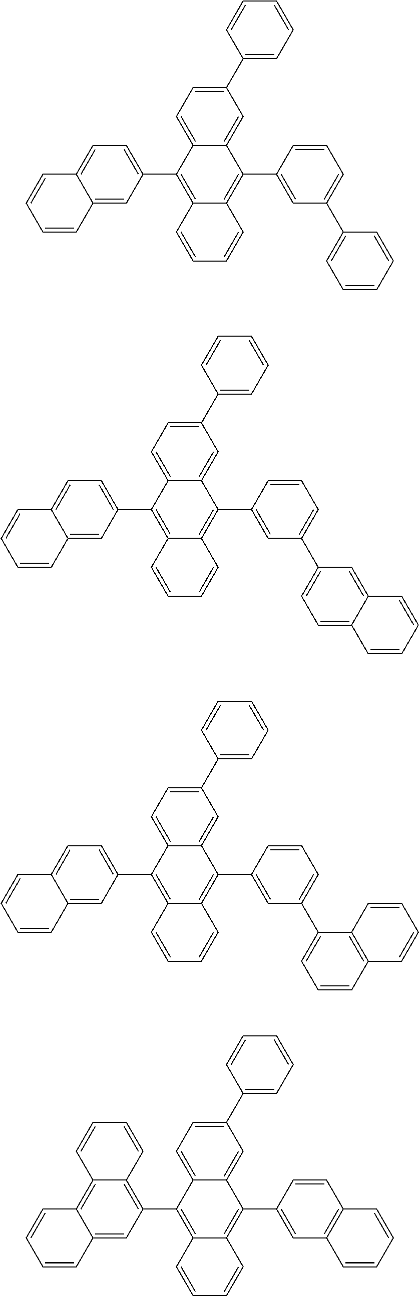

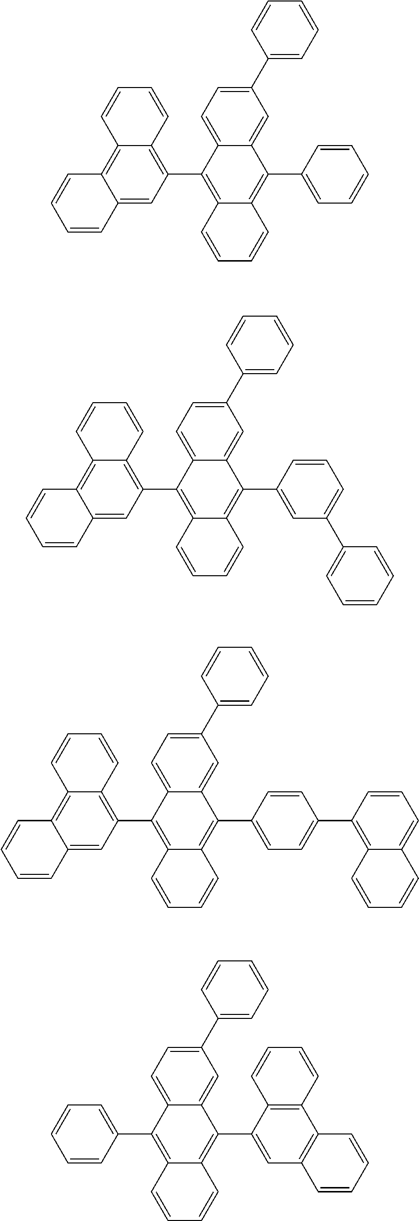

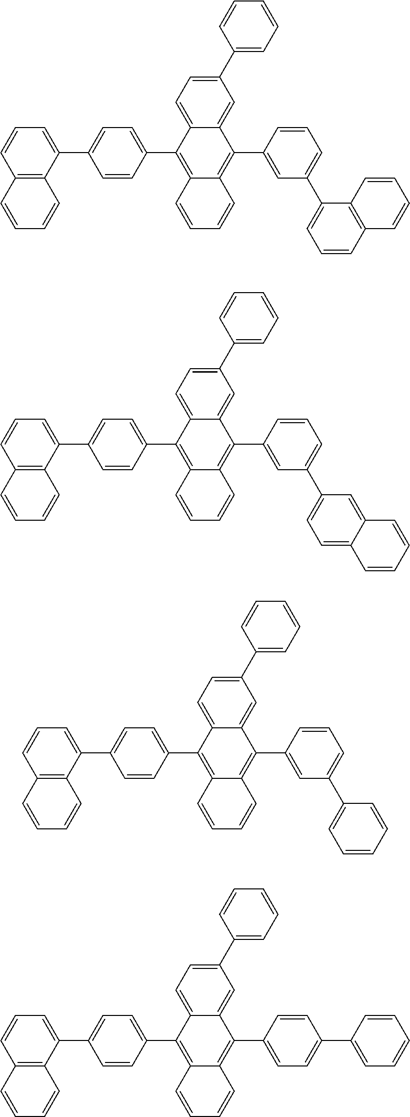

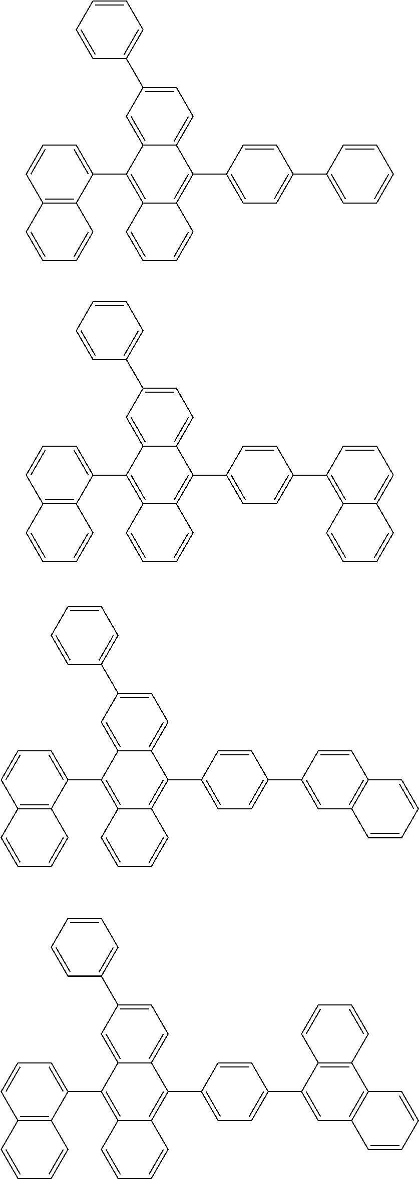

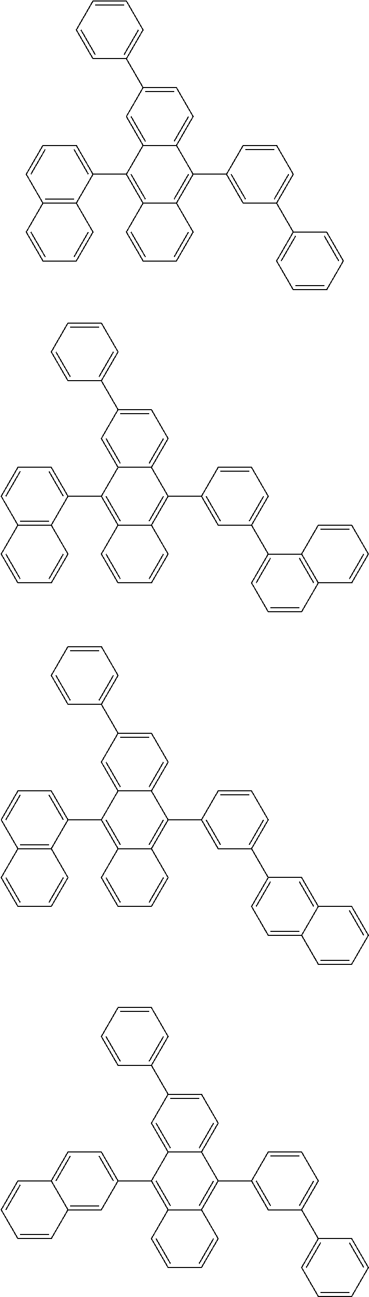

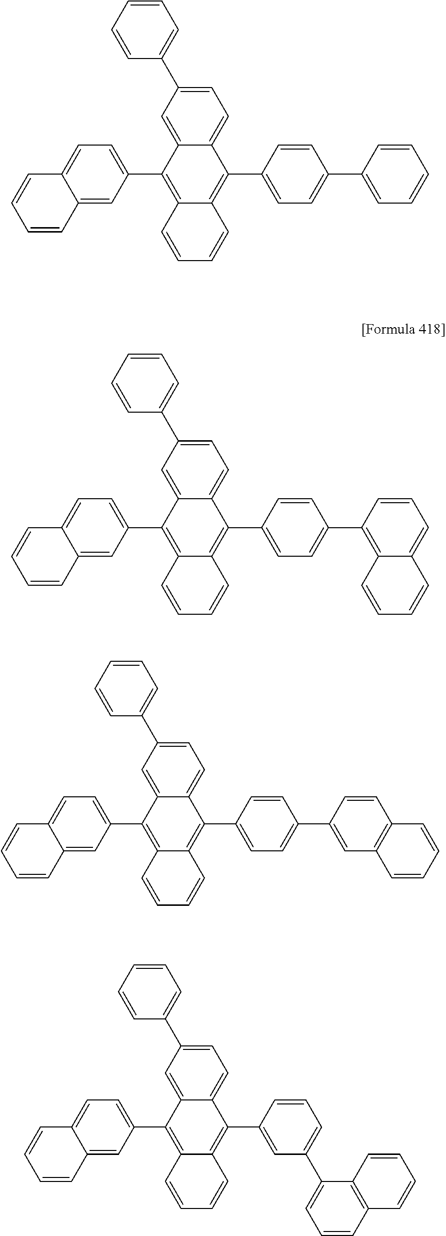

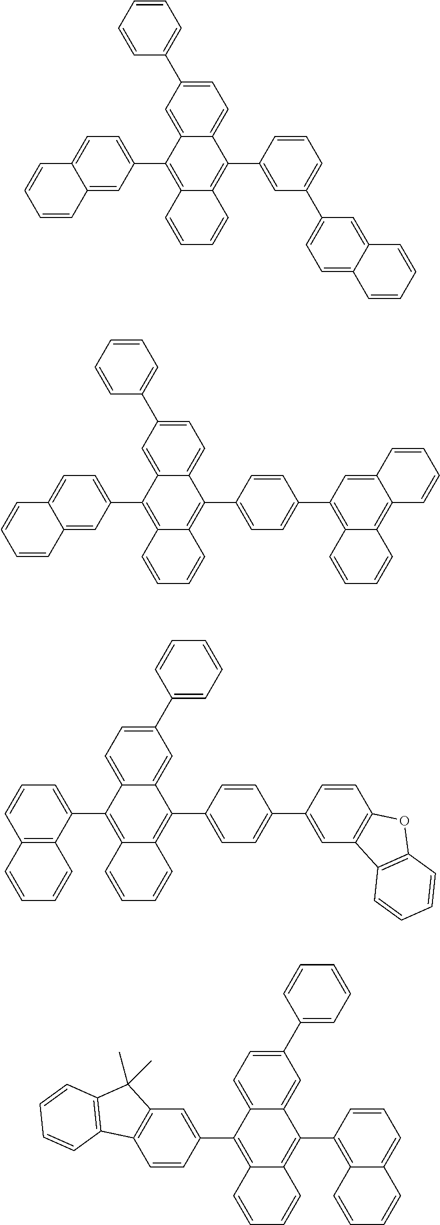

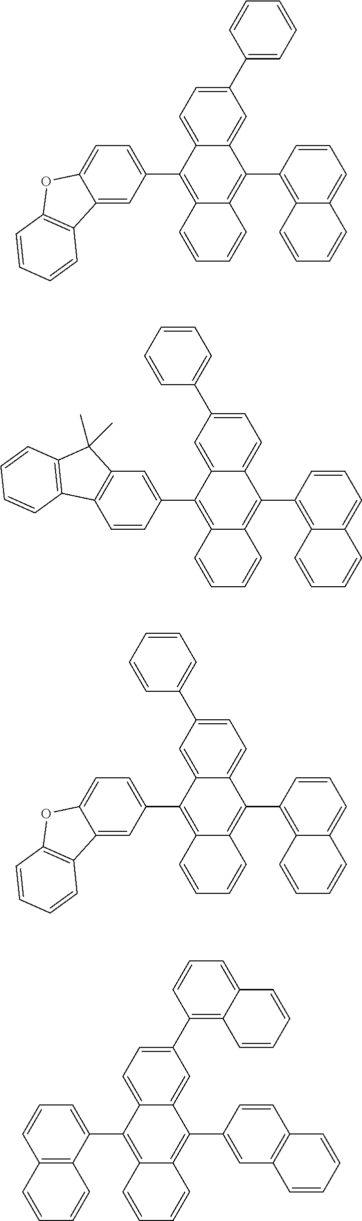

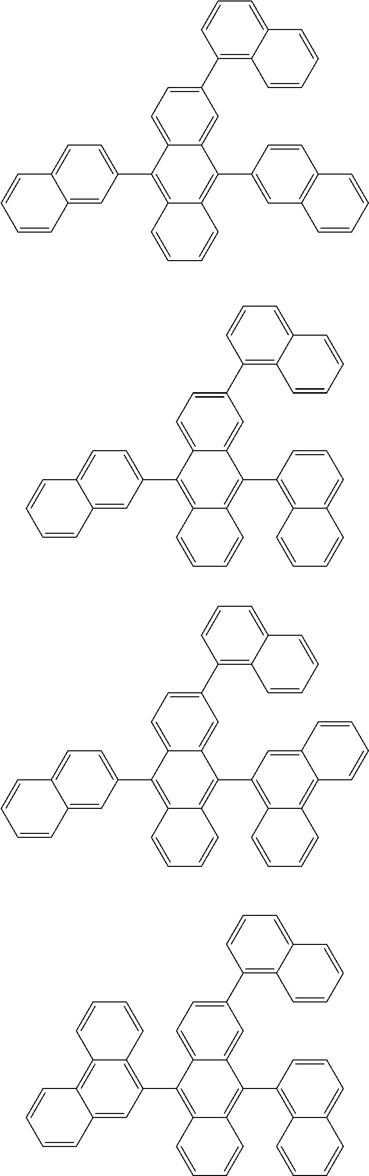

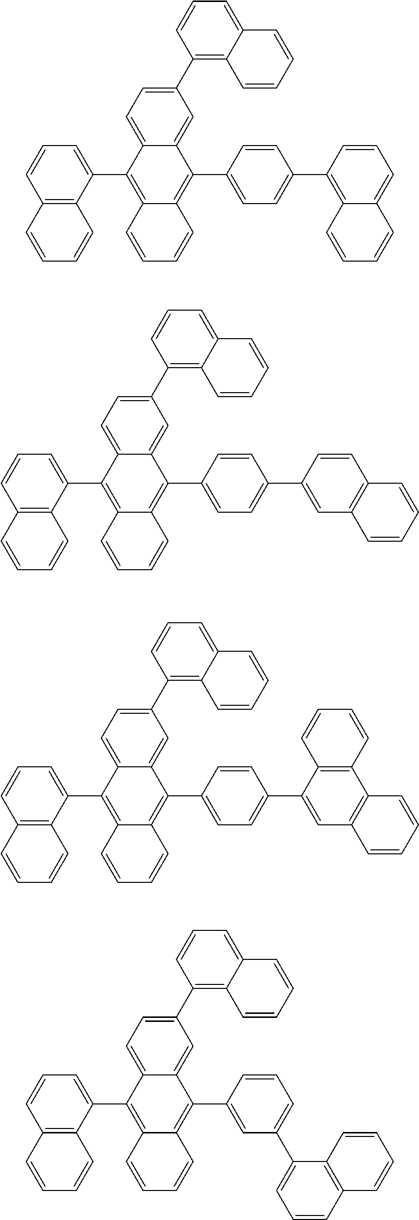

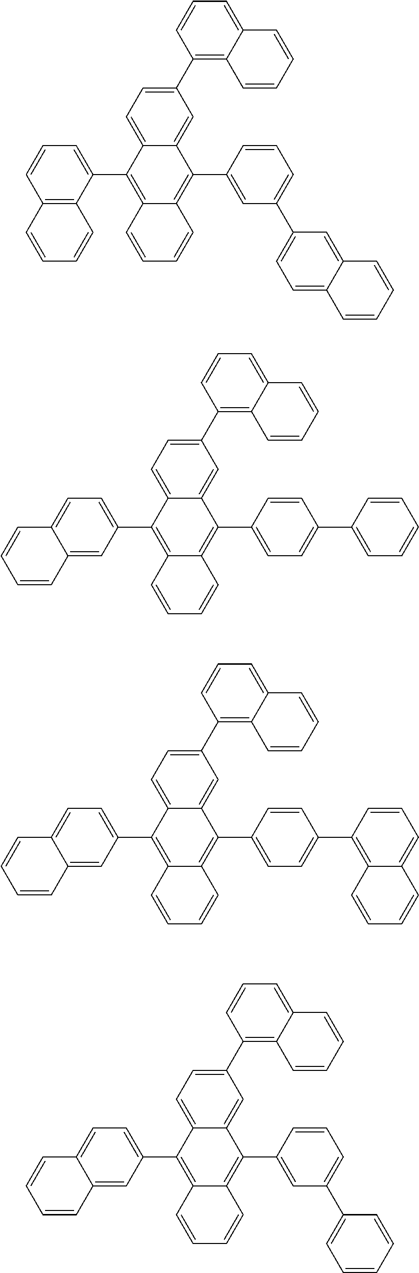

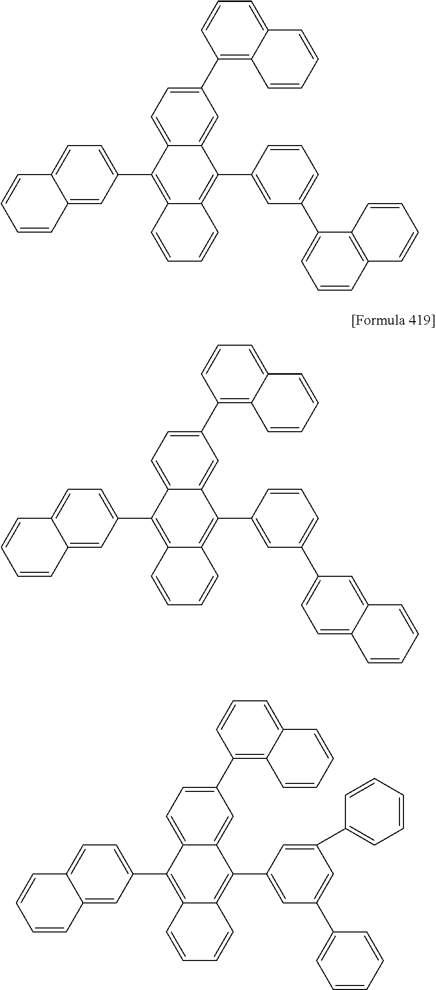

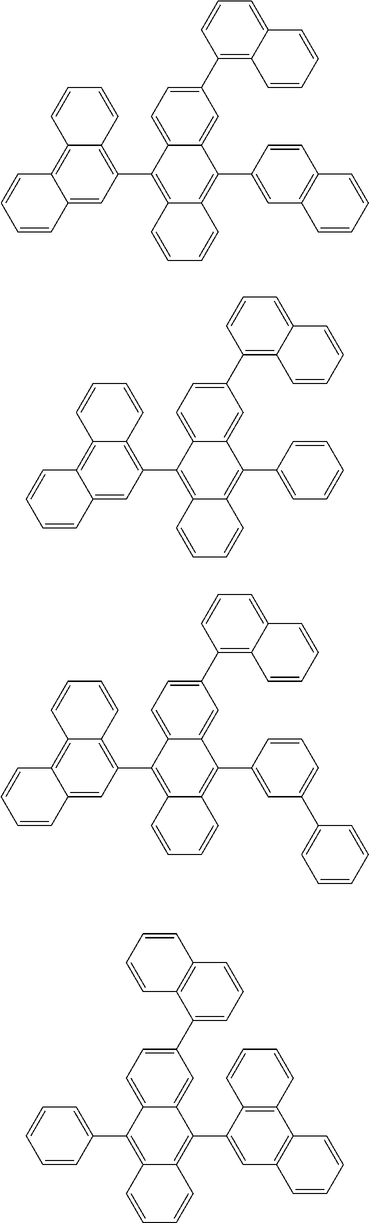

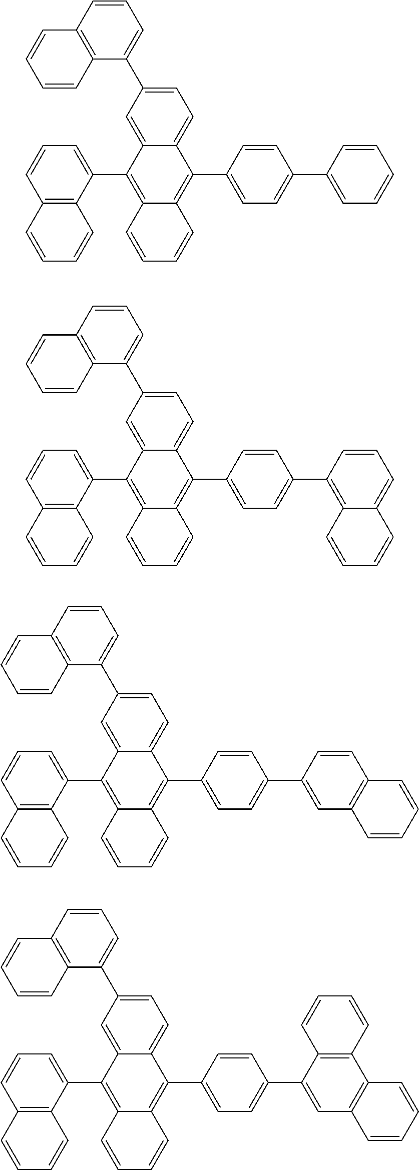

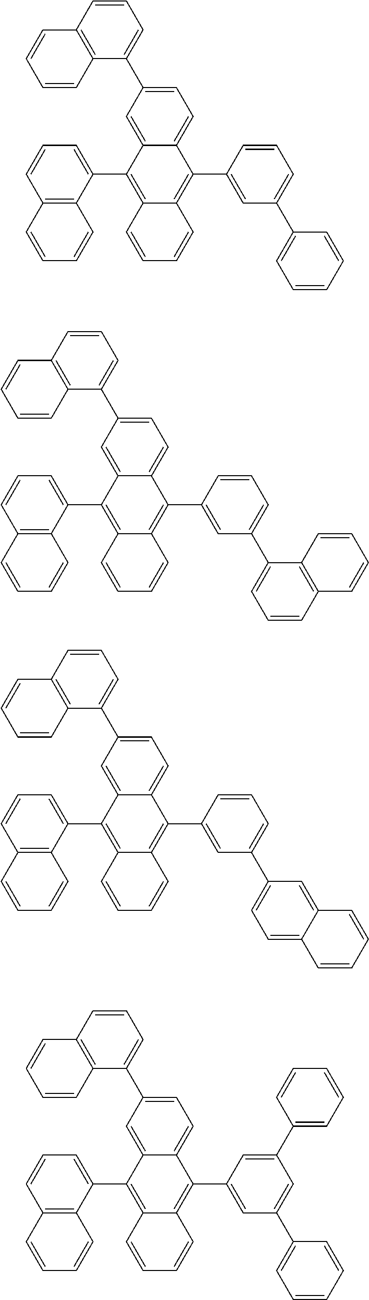

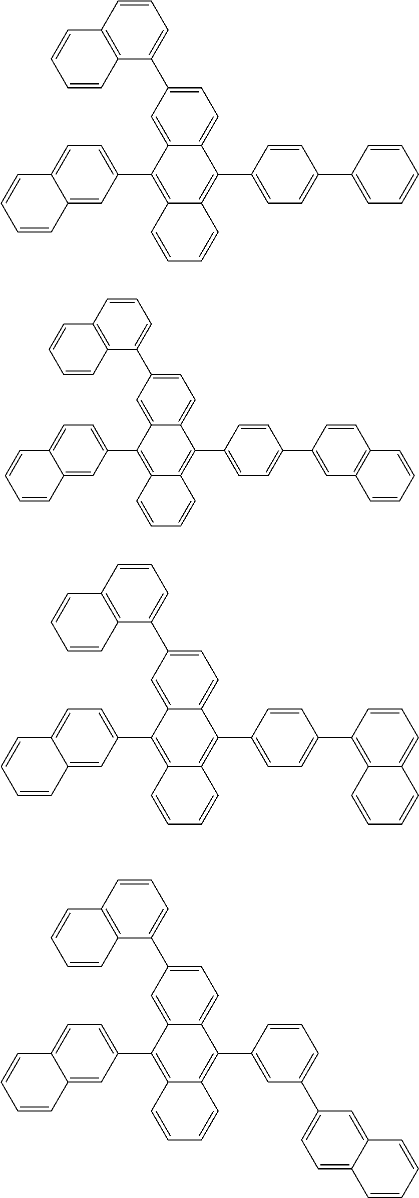

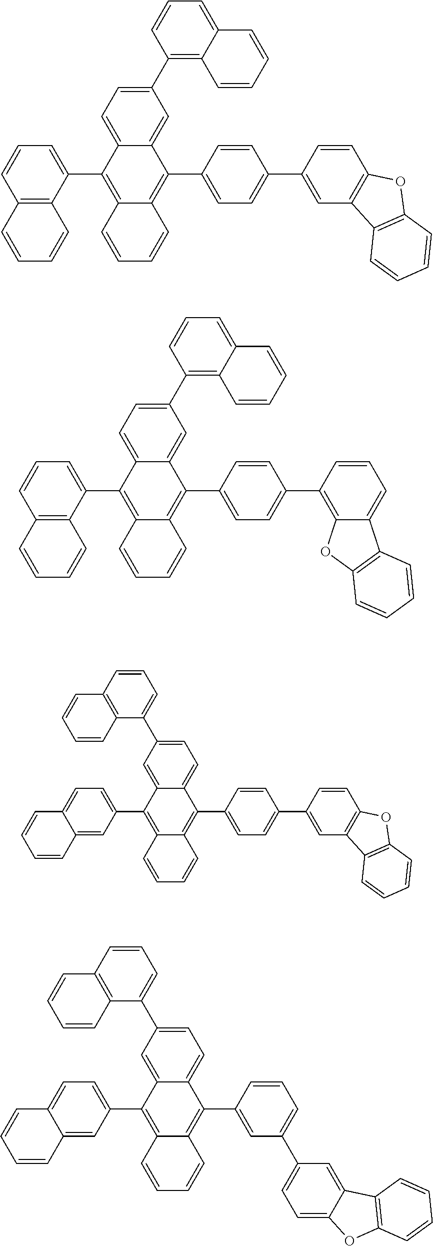 [SMILES: c1ccc2c(-c3ccc4c(-c5cccc6ccccc56)c5ccccc5c(-c5ccc(-c6ccc7oc8ccccc8c7c6)cc5)c4c3)cccc2c1 ; c1ccc2c(-c3ccc4c(-c5cccc6ccccc56)c5ccccc5c(-c5ccc(-c6cccc7c6oc6ccccc67)cc5)c4c3)cccc2c1 ; c1ccc2cc(-c3c4ccccc4c(-c4ccc(-c5ccc6oc7ccccc7c6c5)cc4)c4ccc(-c5cccc6ccccc56)cc34)ccc2c1 ; c1cc(-c2ccc3oc4ccccc4c3c2)cc(-c2c3ccccc3c(-c3ccc4ccccc4c3)c3cc(-c4cccc5ccccc45)ccc23)c1]

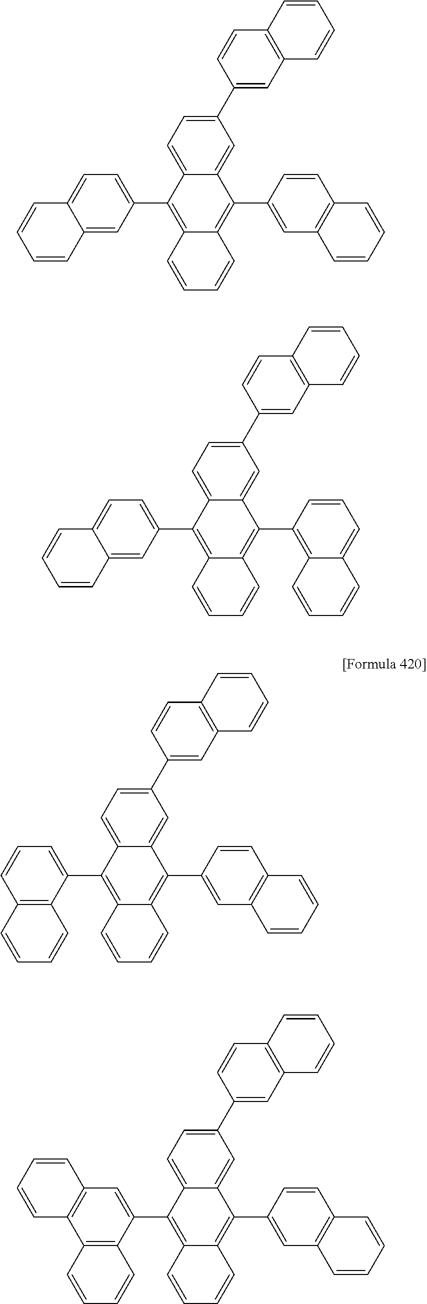

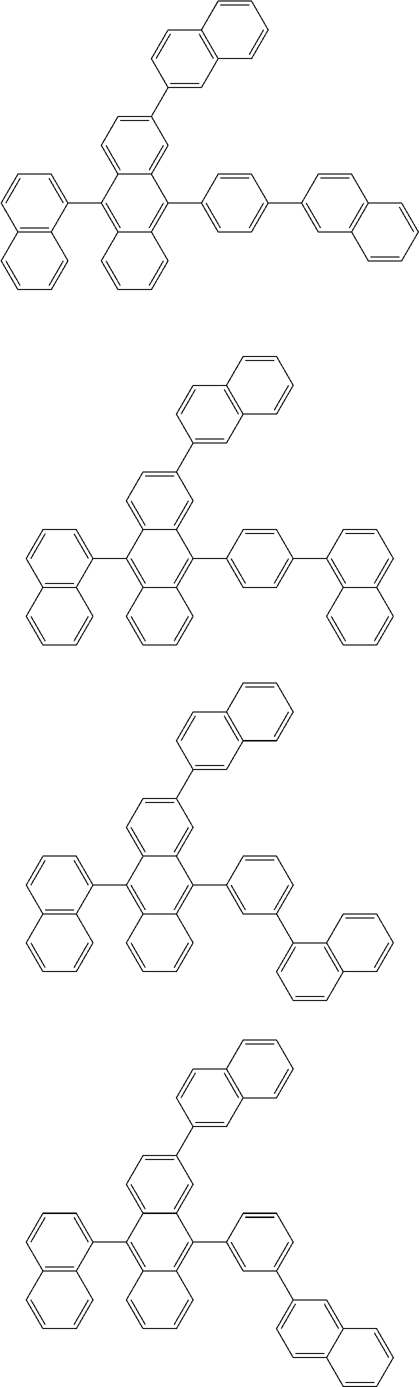

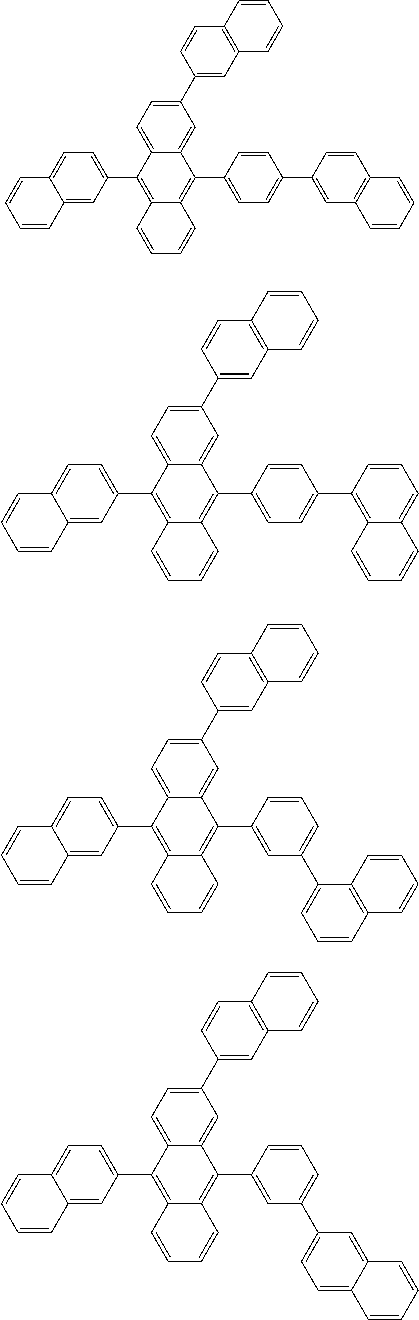

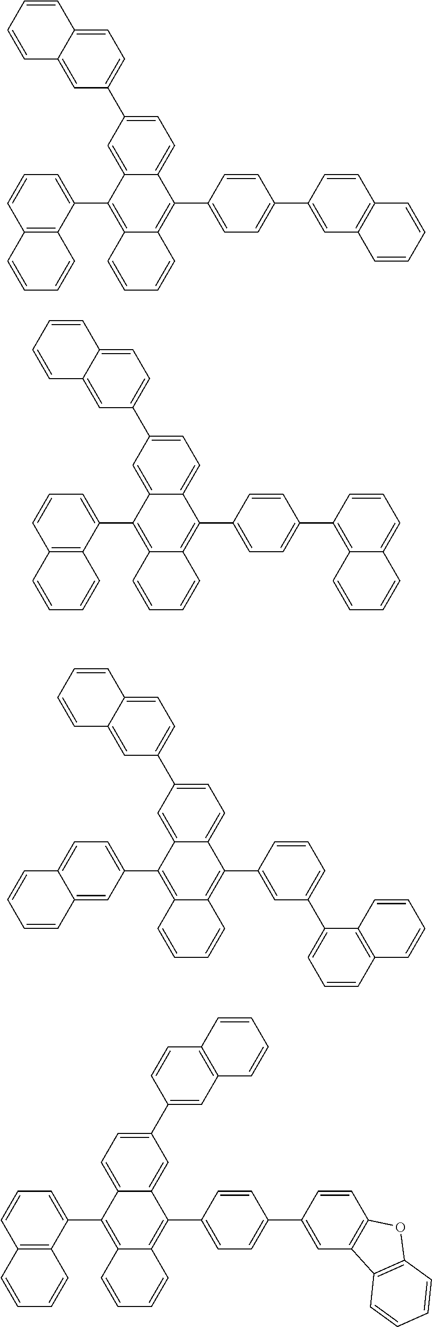

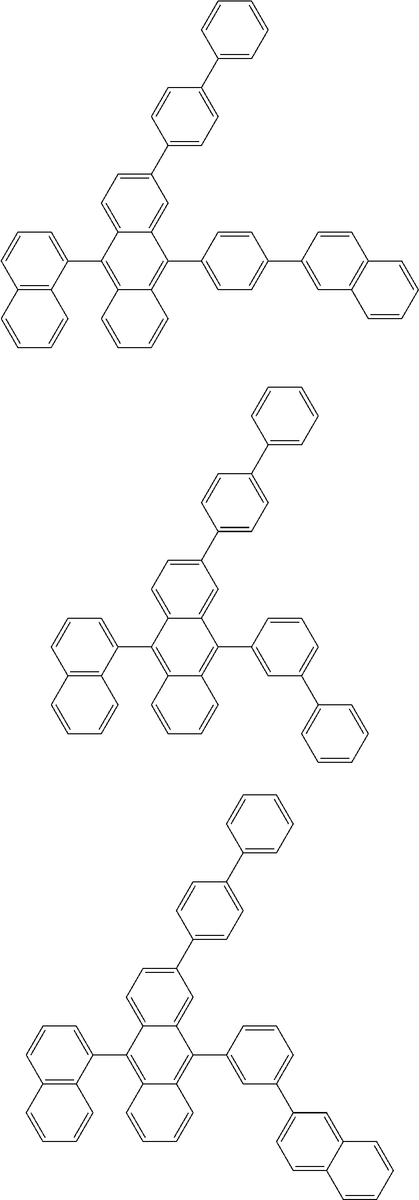

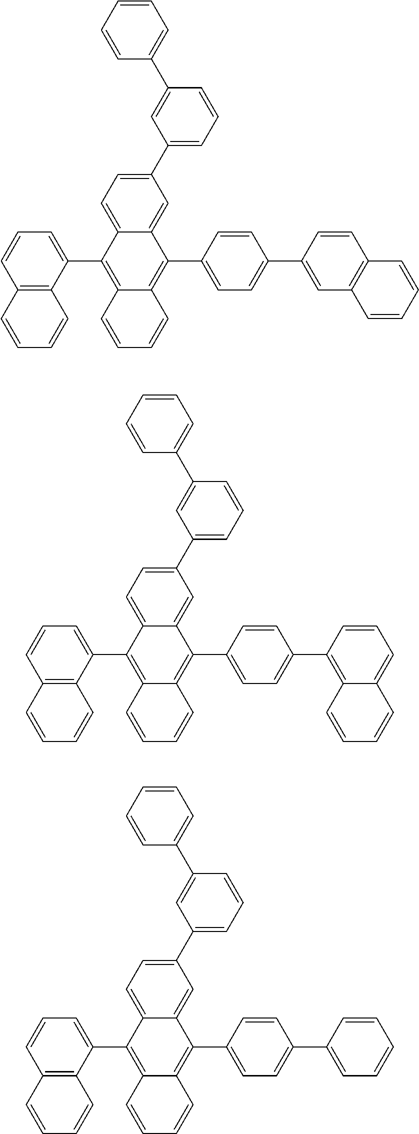

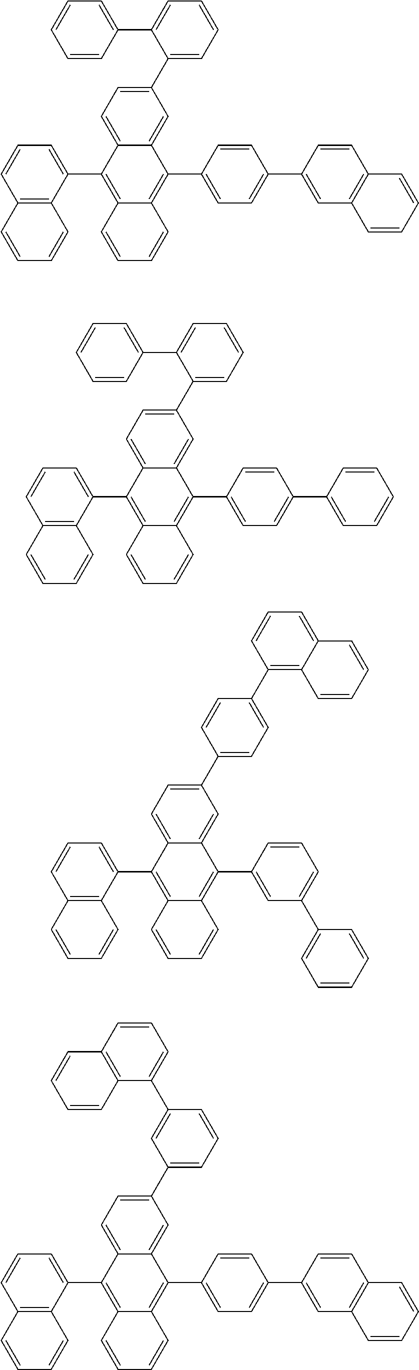

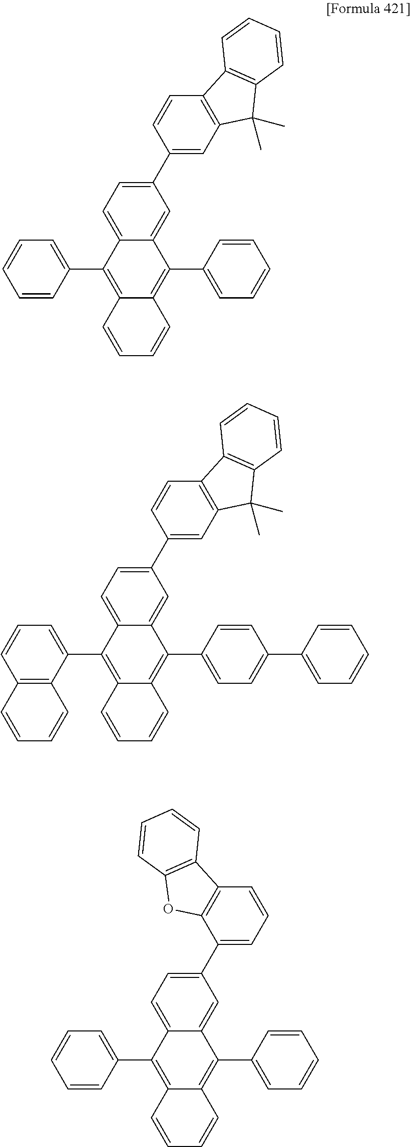

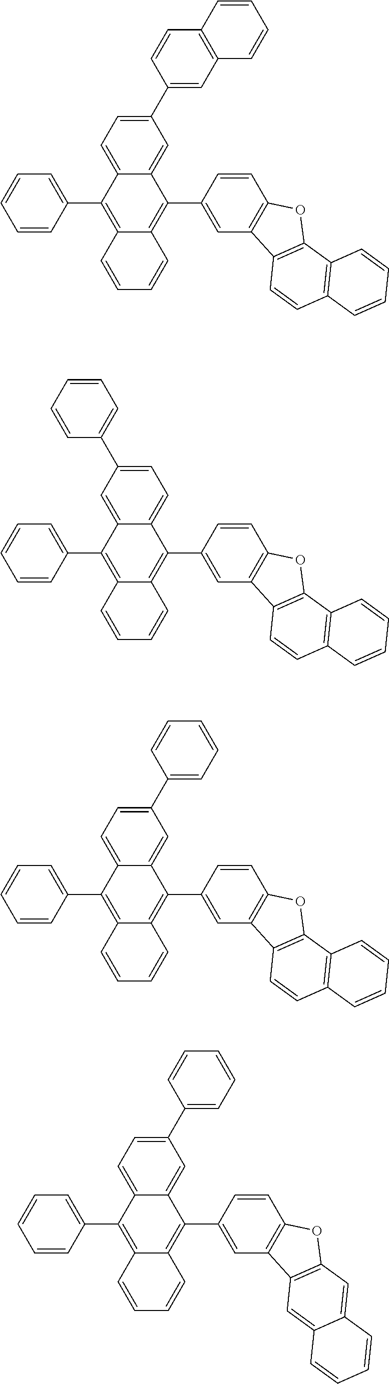 [SMILES: c1ccc(-c2c3ccccc3c(-c3ccc4oc5c6ccccc6ccc5c4c3)c3cc(-c4ccc5ccccc5c4)ccc23)cc1 ; c1ccc(-c2ccc3c(-c4ccc5oc6c7ccccc7ccc6c5c4)c4ccccc4c(-c4ccccc4)c3c2)cc1 ; c1ccc(-c2ccc3c(-c4ccccc4)c4ccccc4c(-c4ccc5oc6c7ccccc7ccc6c5c4)c3c2)cc1 ; c1ccc(-c2ccc3c(-c4ccccc4)c4ccccc4c(-c4ccc5oc6cc7ccccc7cc6c5c4)c3c2)cc1]

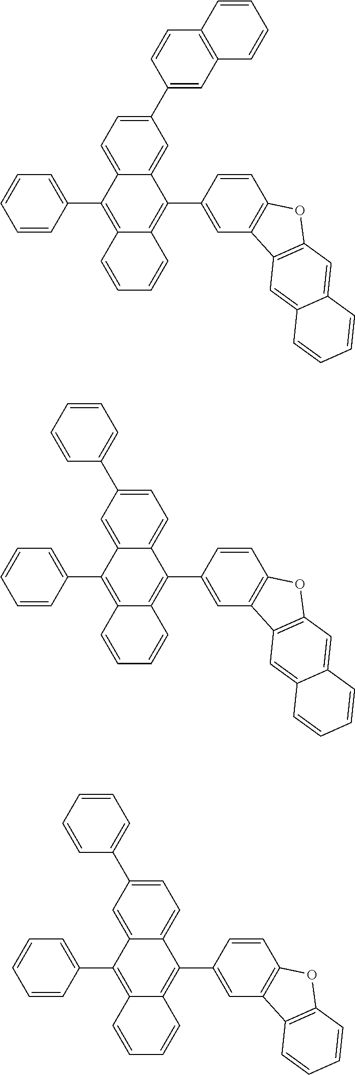 [SMILES: c1ccc(-c2c3ccccc3c(-c3ccc4oc5cc6ccccc6cc5c4c3)c3cc(-c4ccc5ccccc5c4)ccc23)cc1 ; c1ccc(-c2ccc3c(-c4ccc5oc6cc7ccccc7cc6c5c4)c4ccccc4c(-c4ccccc4)c3c2)cc1 ; c1ccc(-c2ccc3c(-c4ccc5oc6ccccc6c5c4)c4ccccc4c(-c4ccccc4)c3c2)cc1]

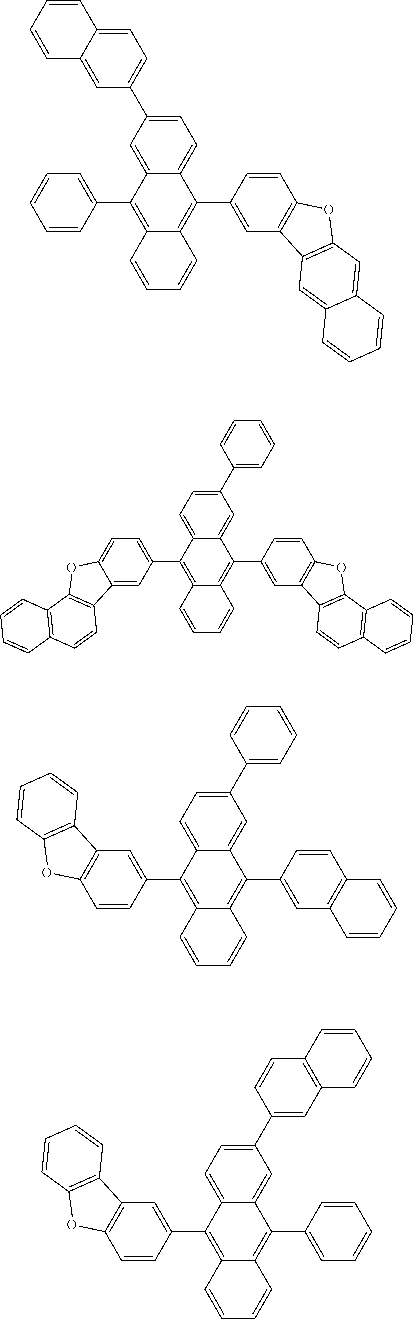 [SMILES: c1ccc(-c2c3ccccc3c(-c3ccc4oc5cc6ccccc6cc5c4c3)c3ccc(-c4ccc5ccccc5c4)cc23)cc1 ; c1ccc(-c2ccc3c(-c4ccc5oc6c7ccccc7ccc6c5c4)c4ccccc4c(-c4ccc5oc6c7ccccc7ccc6c5c4)c3c2)cc1 ; c1ccc(-c2ccc3c(-c4ccc5oc6ccccc6c5c4)c4ccccc4c(-c4ccc5ccccc5c4)c3c2)cc1 ; c1ccc(-c2c3ccccc3c(-c3ccc4oc5ccccc5c4c3)c3ccc(-c4ccc5ccccc5c4)cc23)cc1]

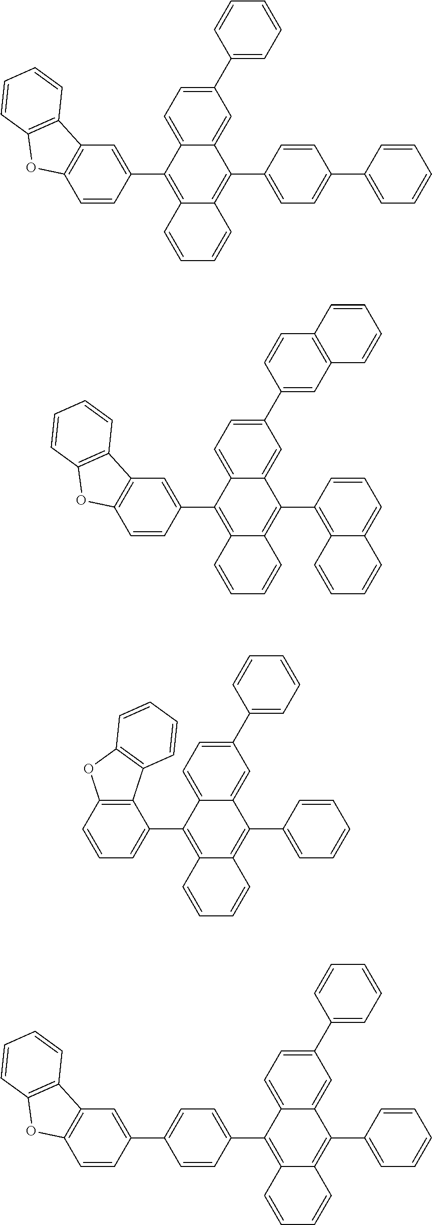 [SMILES: c1ccc(-c2ccc(-c3c4ccccc4c(-c4ccc5oc6ccccc6c5c4)c4ccc(-c5ccccc5)cc34)cc2)cc1 ; c1ccc2cc(-c3ccc4c(-c5ccc6oc7ccccc7c6c5)c5ccccc5c(-c5cccc6ccccc56)c4c3)ccc2c1 ; c1ccc(-c2ccc3c(-c4cccc5oc6ccccc6c45)c4ccccc4c(-c4ccccc4)c3c2)cc1 ; c1ccc(-c2ccc3c(-c4ccc(-c5ccc6oc7ccccc7c6c5)cc4)c4ccccc4c(-c4ccccc4)c3c2)cc1]

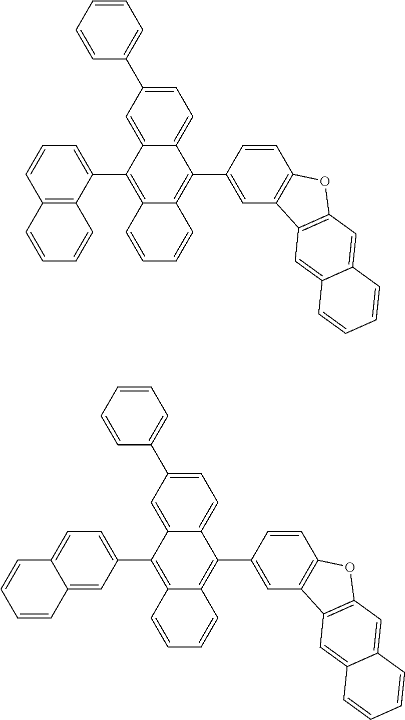 [SMILES: c1ccc(-c2ccc3c(-c4ccc5oc6cc7ccccc7cc6c5c4)c4ccccc4c(-c4cccc5ccccc45)c3c2)cc1 ; c1ccc(-c2ccc3c(-c4ccc5oc6cc7ccccc7cc6c5c4)c4ccccc4c(-c4ccc5ccccc5c4)c3c2)cc1]

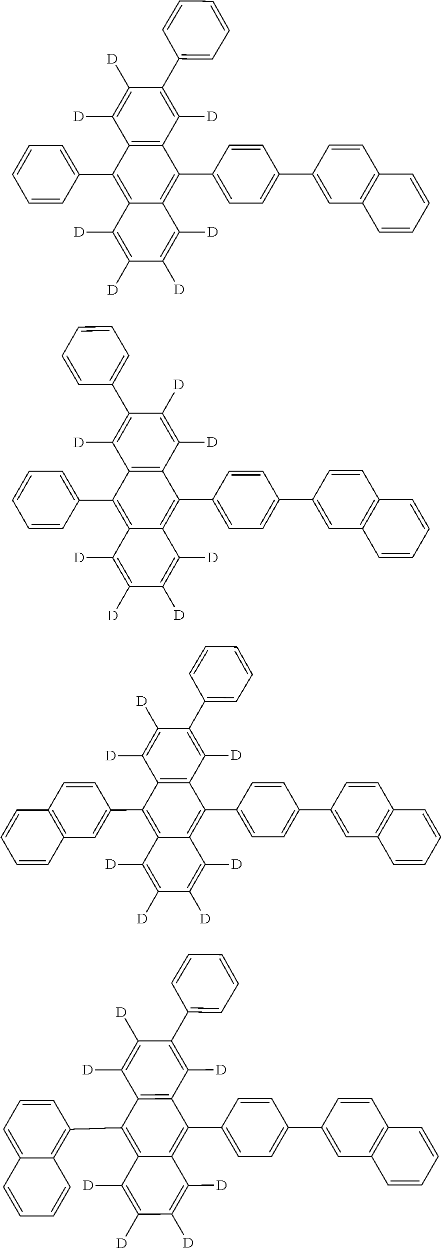

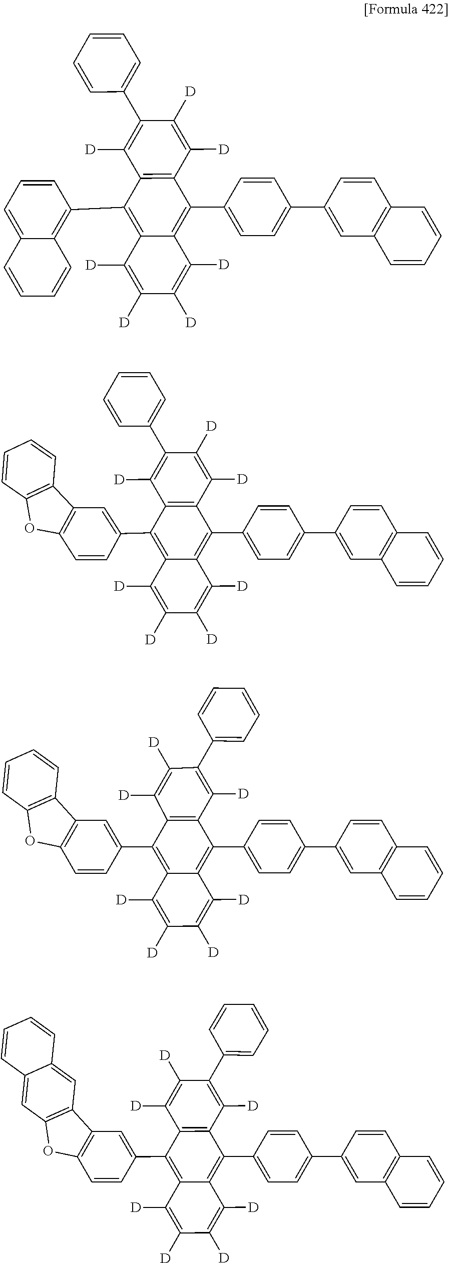 [SMILES: [2H]c1c([2H])c([2H])c2c(-c3cccc4ccccc34)c3c([2H])c(-c4ccccc4)c([2H])c([2H])c3c(-c3ccc(-c4ccc5ccccc5c4)cc3)c2c1[2H] ; [2H]c1c([2H])c([2H])c2c(-c3ccc4oc5ccccc5c4c3)c3c([2H])c(-c4ccccc4)c([2H])c([2H])c3c(-c3ccc(-c4ccc5ccccc5c4)cc3)c2c1[2H] ; [2H]c1c([2H])c([2H])c2c(-c3ccc(-c4ccc5ccccc5c4)cc3)c3c([2H])c(-c4ccccc4)c([2H])c([2H])c3c(-c3ccc4oc5ccccc5c4c3)c2c1[2H] ; [2H]c1c([2H])c([2H])c2c(-c3ccc(-c4ccc5ccccc5c4)cc3)c3c([2H])c(-c4ccccc4)c([2H])c([2H])c3c(-c3ccc4oc5cc6ccccc6cc5c4c3)c2c1[2H]]

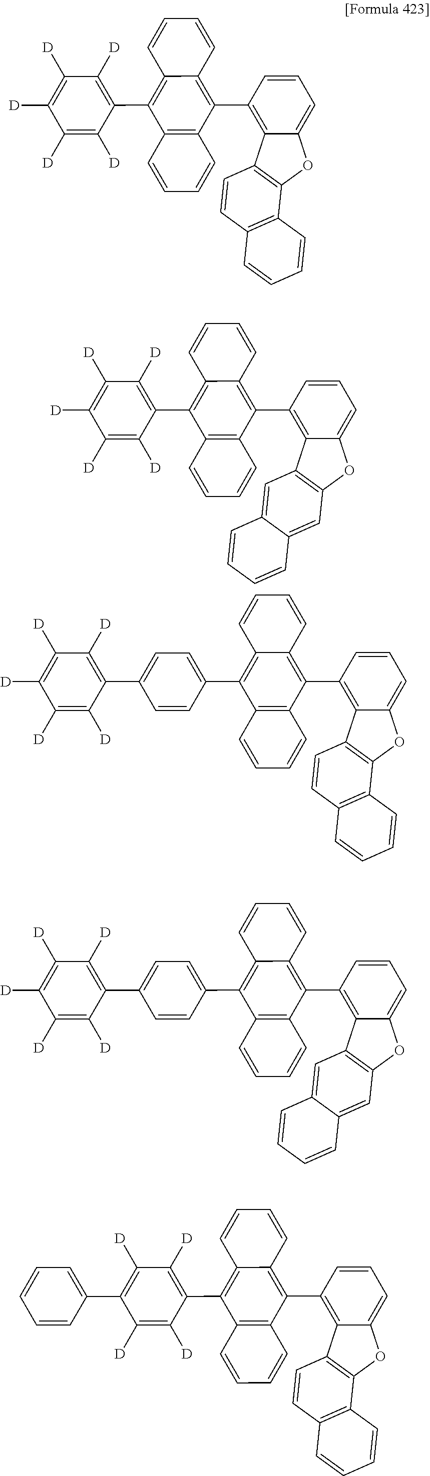

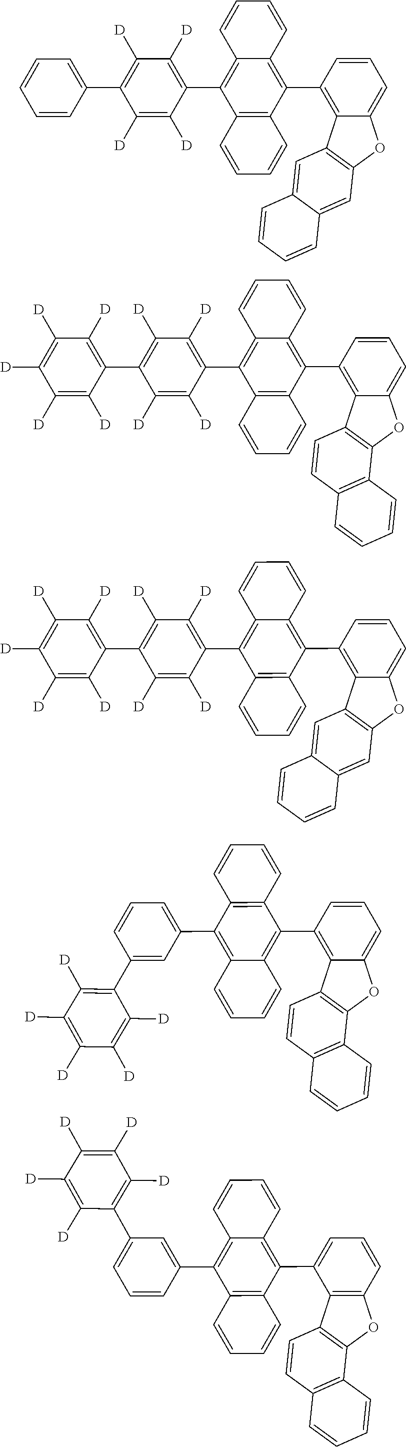

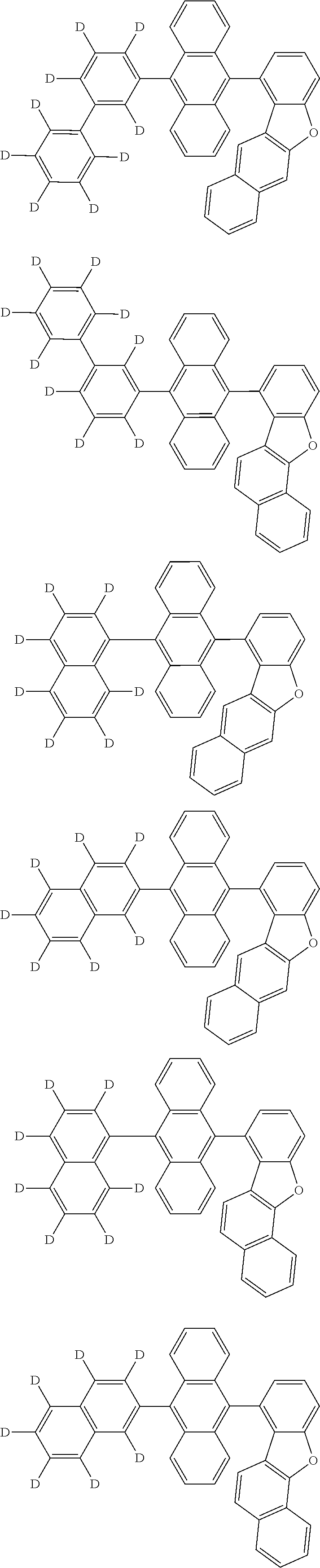

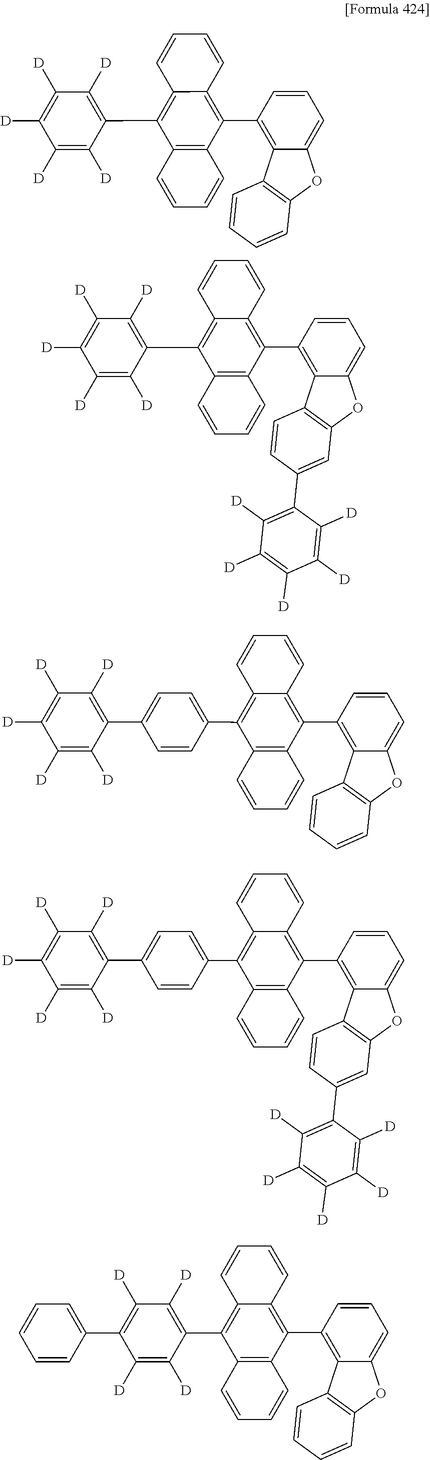

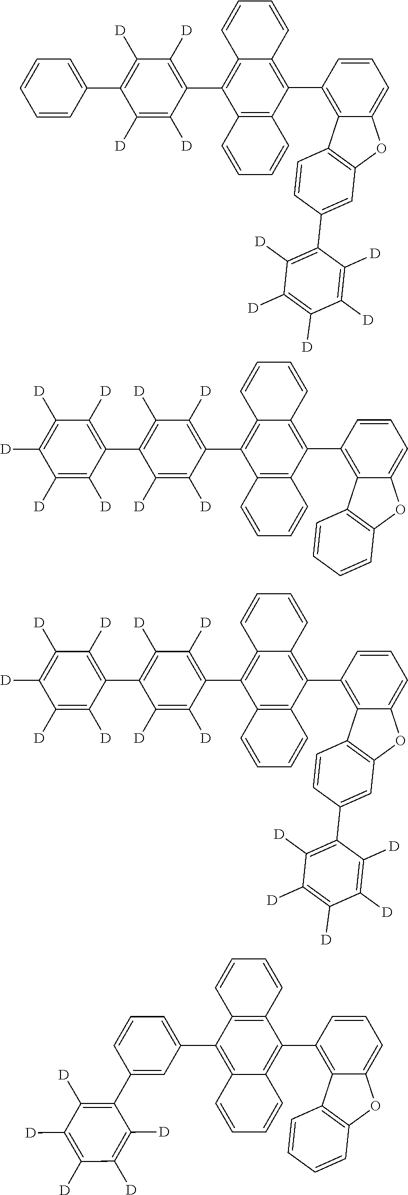

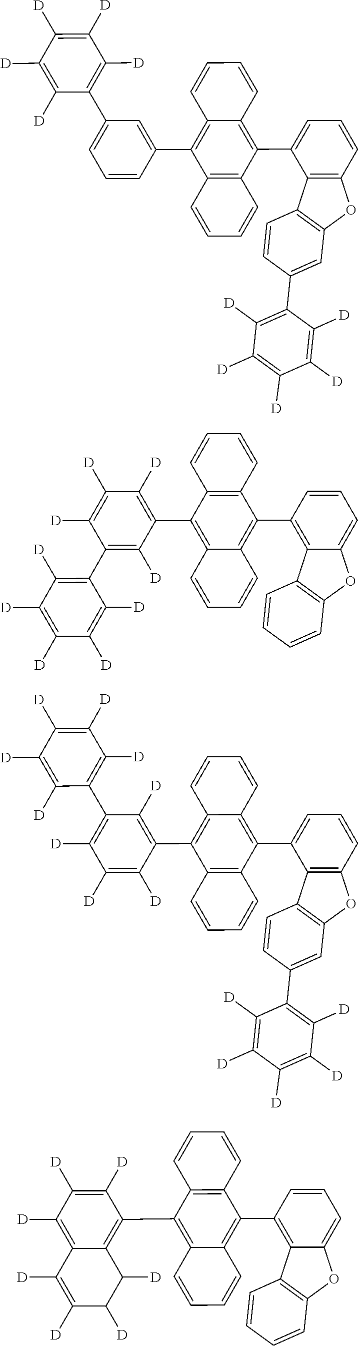

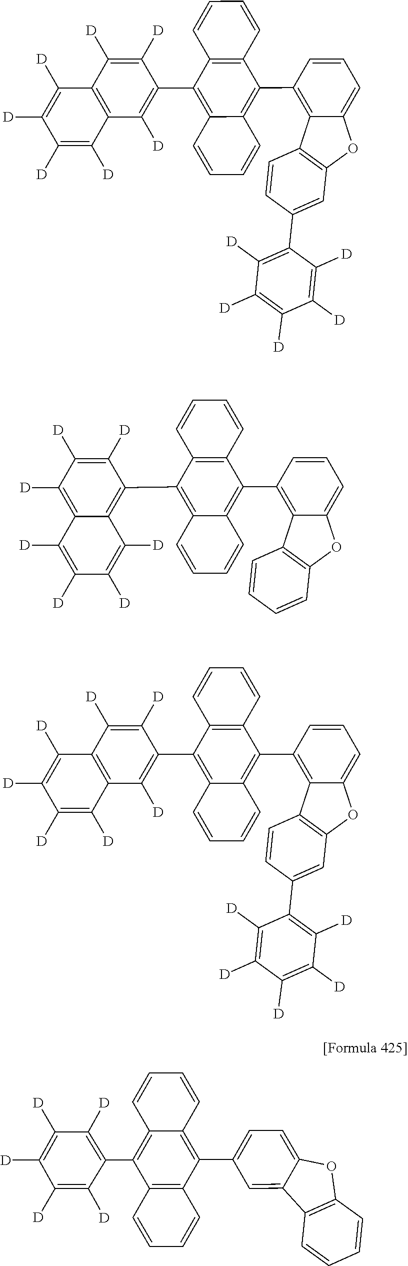 [SMILES: [2H]c1c([2H])c([2H])c(-c2ccc3c(c2)oc2cccc(-c4c5ccccc5c(-c5c([2H])c([2H])c6c([2H])c([2H])c([2H])c([2H])c6c5[2H])c5ccccc45)c23)c([2H])c1[2H] ; [2H]c1c([2H])c([2H])c2c(-c3c4ccccc4c(-c4cccc5oc6ccccc6c45)c4ccccc34)c([2H])c([2H])c([2H])c2c1[2H] ; [2H]c1c([2H])c([2H])c(-c2ccc3c(c2)oc2cccc(-c4c5ccccc5c(-c5c([2H])c([2H])c6c([2H])c([2H])c([2H])c([2H])c6c5[2H])c5ccccc45)c23)c([2H])c1[2H] ; [2H]c1c([2H])c([2H])c(-c2c3ccccc3c(-c3ccc4oc5ccccc5c4c3)c3ccccc23)c([2H])c1[2H]]

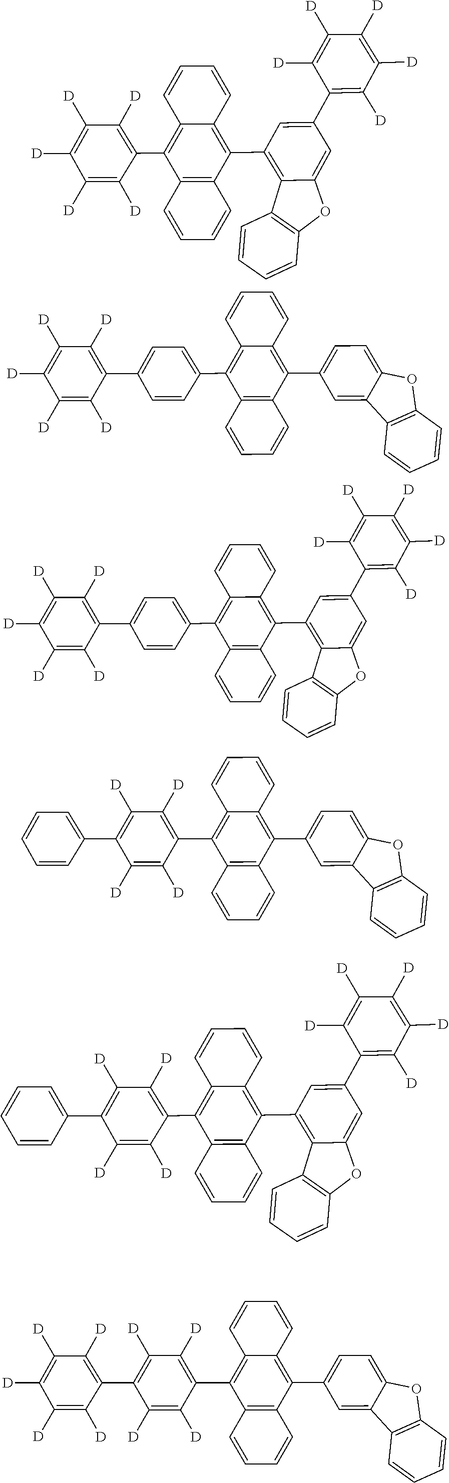

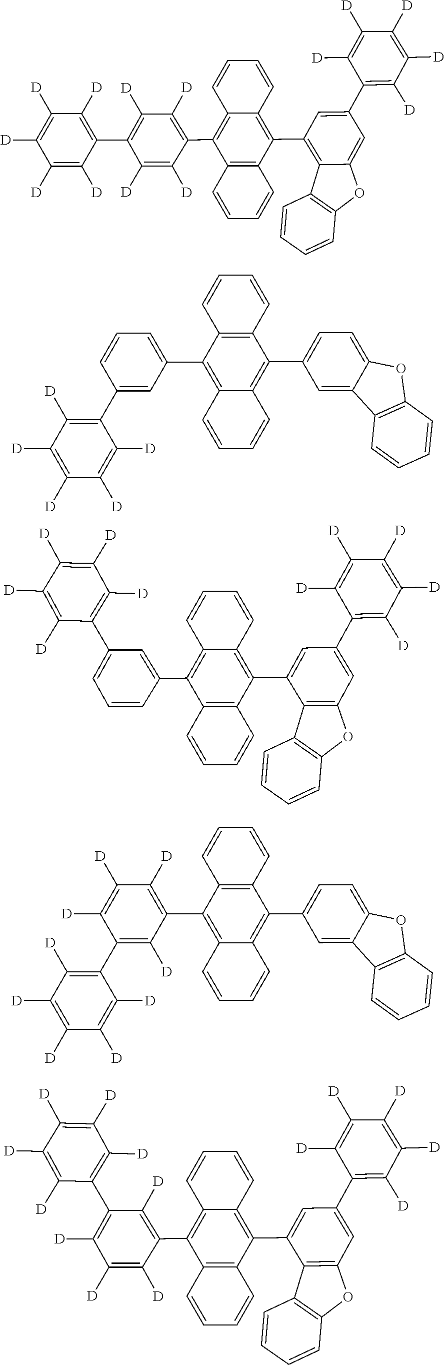

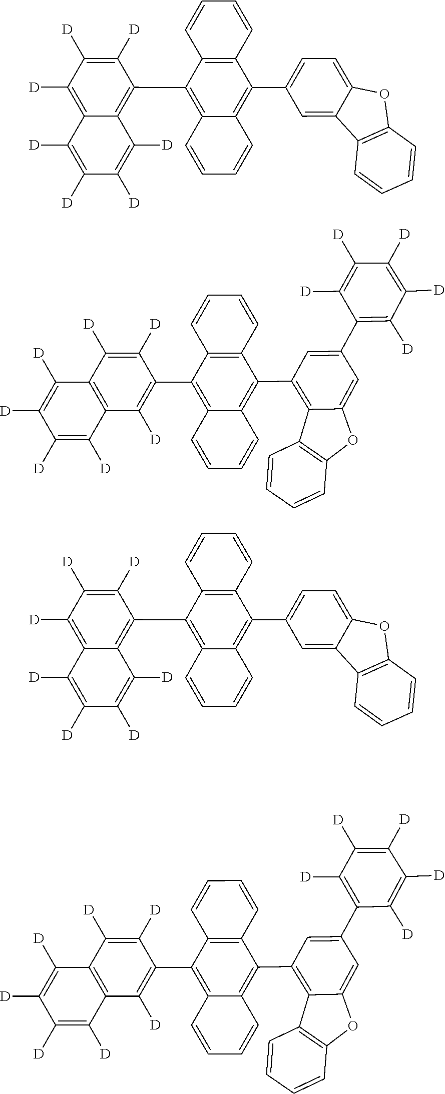

The organic electroluminescent element may comprise an anode, and organic layer, and a cathode.

The organic layer comprises a light-emitting layer. The light-emitting layer is composed of a single layer or a plurality of layers. In addition, the organic layer may comprise an electron transporting zone or a hole transporting zone.

The light-emitting layer comprises the first host compound, the second host compound, and the dopant compound.

In an embodiment, the light-emitting layer may be composed of a single layer. For example, the first host compound, the second host compound, and the dopant compound may be contained together in the single layer.

In an embodiment, the light-emitting layer may be composed of a plurality of layers. The light-emitting layer may comprise a first layer comprising the first host compound and a second layer comprising the second host compound.

The first layer is disposed on the anode side, and the second layer is disposed on the cathode side. The second layer is disposed between the first layer and the cathode.

The dopant compound may be contained in the first layer or may be contained in the second layer.

In an embodiment, the dopant compound may be contained in each of the first layer and the second layer. The light-emitting layer may comprise a first layer comprising the first host compound and the dopant compound, and a second layer comprising the second host compound and the dopant compound.

The configuration of the organic electroluminescent element of the second embodiment is further described in “Common Configuration of Each Embodiment” to be described later.

### Third Embodiment

An organic electroluminescent element according to the third embodiment of the present invention comprises an anode, a cathode, and an organic layer interposed between the anode and the cathode,
wherein the organic layer comprises:
a first host compound having a HOMO energy level of −5.5 eV or higher and a triplet energy level of 2.5 eV or lower,
a second host compound having a LUMO energy level of −4.0 eV to −3.0 eV,
a dopant compound, and
a third host compound having a triplet energy level greater than 1.5 eV to less than 1.9 eV,
wherein the first host compound and the second host compound are capable of recombining with each other to form an exciplex,
the exciplex has a triplet energy level of greater than 1.5 eV, and
the first host compound, the second host compound, and the dopant compound satisfy the following Relationships 1 to 4.

$${H}_{1} {S}_{1} > {DS}_{1} \qquad [ Relationship 1 ]$$

$${H}_{1} {T}_{1} > {DT}_{1} \qquad [ Relationship 2 ]$$

$${H}_{2} {S}_{1} > {DS}_{1} \qquad [ Relationship 3 ]$$

$${H}_{2} {T}_{1} > {DT}_{1} \qquad [ Relationship 4 ]$$

In Relationships 1 to 4,
H₁S₁ is a singlet energy level of the first host compound,
H₁T₁ is a triplet energy level of the first host compound,
H₂S₁ is a singlet energy level of the second host compound,
H₂T₁ is a triplet energy level of the second host compound,
DS₁ is a singlet energy level of the dopant compound, and
DT₁ is a triplet energy level of the dopant compound.

The first host compound, the second host compound, the dopant compound, and the exciplex formed by the recombination of the first host compound and the second host compound are as described above in the first embodiment.

As the organic layer further comprises the third host compound, the efficiency of the organic electroluminescent element can be further increased. As the energy band gap of the exciplex decreases, the turn-on voltage, as well as the efficiency, may decrease. However, by virtue of the third host compound, the turn-on voltage can be maintained low while a decrease in efficiency can be prevented.

For example, as the triplet energy level of the third host compound is greater than 1.5 eV to less than 1.9 eV, energy can be easily transferred from the exciplex to the third host compound. As a result, luminous efficiency can be enhanced by a TTA mechanism by virtue of the third host compound.

In an embodiment, the third host compound may satisfy the following Relationship 6.

$${ExpT}_{1} > {H}_{3} {T}_{1} \qquad [ Relationship 6 ]$$

in Relationship 6,
ExpT₁ is a triplet energy level of the exciplex formed by the recombination of the first host compound and the second host compound with each other, and
H₃T₁ is a triplet energy level of the third host compound.

As the third host compound satisfies the above Relationship 6, the energy of the exciplex diffuses to the third host compound having a lower triplet energy level, so that a TTA phenomenon can take place in the third host compound. As a result, energy is finally transferred to the dopant compound, so that the efficiency of the organic electroluminescent element can be enhanced.

The triplet energy level of the third host compound may be 1.6 eV or more, 1.7 eV or more, 1.8 eV or more, but it is not limited thereto.

The singlet energy level of the third host compound may be 2.7 eV or more, 2.8 eV or more, and it may be 3.2 eV or less, 3.1 eV or less, 3.0 eV or less, but it is not limited thereto.

The singlet energy level of the third host compound may be greater than the singlet energy level of the dopant compound. As a result, back energy transfer between the third host compound and the dopant compound and a decrease in efficiency resulting therefrom can be prevented.

For example, the third host compound and the dopant compound may satisfy the following Relationship 7.

$${H}_{3} {S}_{1} > {DS}_{1} \qquad [ Relationship 7 ]$$

In Relationship 7, H₃S₁ is a singlet energy level of the third host compound, and DS₁ is a singlet energy level of the dopant compound.

As the third host compound, a compound having a triplet energy level and a singlet energy level in the above ranges and satisfying Relationship 7 may be appropriately selected.

The third host compound may be a compound comprising anthracene.

The third host compound may comprise a compound represented by the following Formula (4).

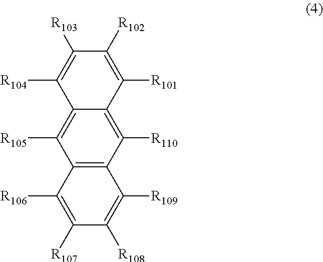

In Formula (4),
at least one of R₁₀₁ to R₁₁₀ is a group represented by the following Formula (5), and
R₁₀₁ to R₁₁₀ that are not the group represented by the following Formula (5) are each independently a hydrogen atom or a substituent R.

When two or more of the substituent R are present, the two or more of the substituent R are the same as or different from each other, and when two or more of the group represented by Formula (5) are present, the two or more of the group represented by Formula (5) are the same as or different from each other.

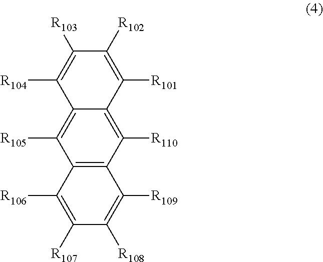

(In Formula (5),
L₁₀₁ is:
a single bond,
a substituted or unsubstituted arylene group having 6 to 50 ring carbon atoms, or
a substituted or unsubstituted divalent heterocyclic group having 5 to 50 ring atoms, and
Ar₁₀₁ is:
a substituted or unsubstituted aryl group having 6 to 50 ring carbon atoms, or a substituted or unsubstituted monovalent heterocyclic group having 5 to 50 ring atoms.)
the substituent R is:
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇),
a halogen atom,
a cyano group,
a nitro group,
a substituted or unsubstituted aryl group having 6 to 50 ring carbon atoms, or
a substituted or unsubstituted monovalent heterocyclic group having 5 to 50 ring atoms,
wherein R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted monovalent heterocyclic group having 5 to 50 ring atoms, and when two or more of R₉₀₁ to R₉₀₇ are present, the two or more of R₉₀₁ to R₉₀₇ are the same as or different from each other.

Specific examples of the third host compound include the following compounds, but it is not limited to the following exemplary compounds.

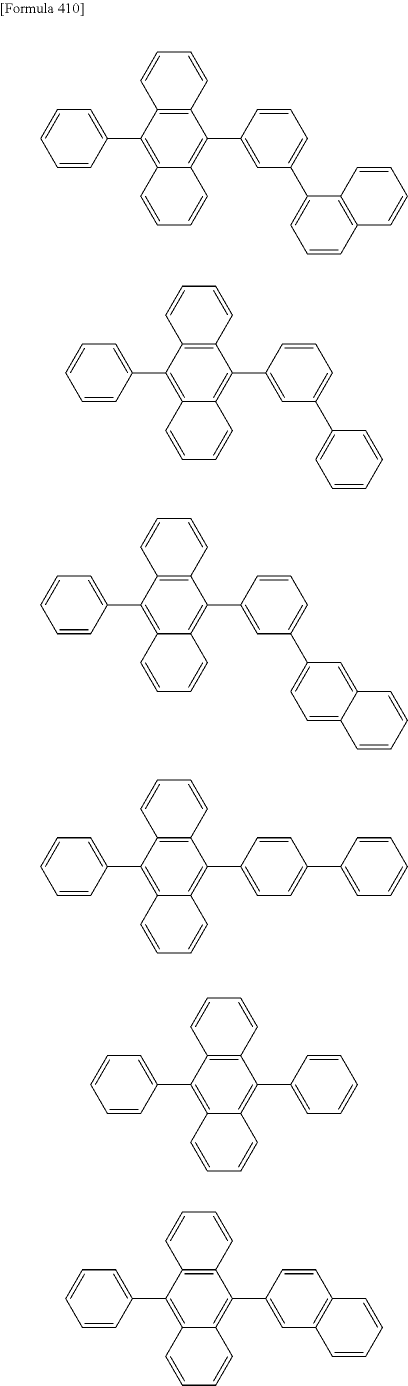

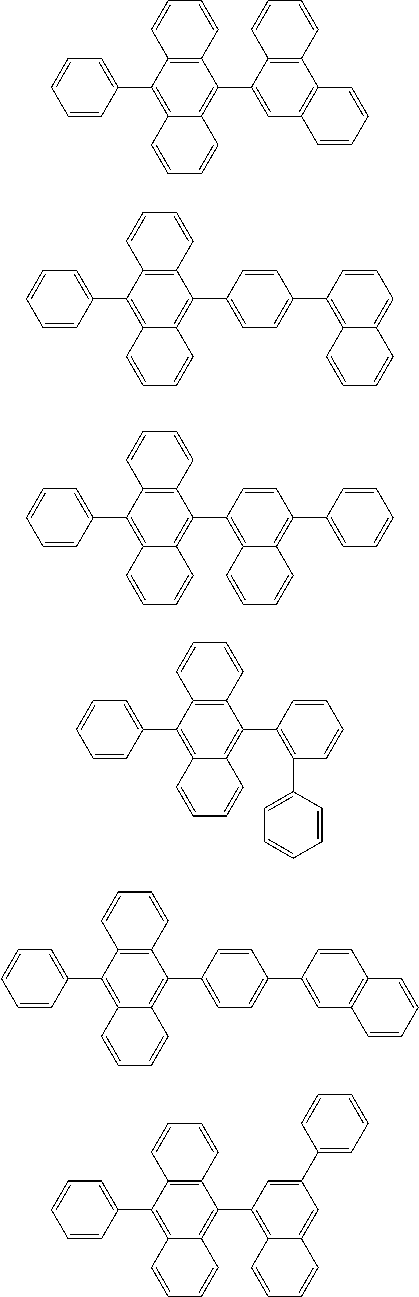

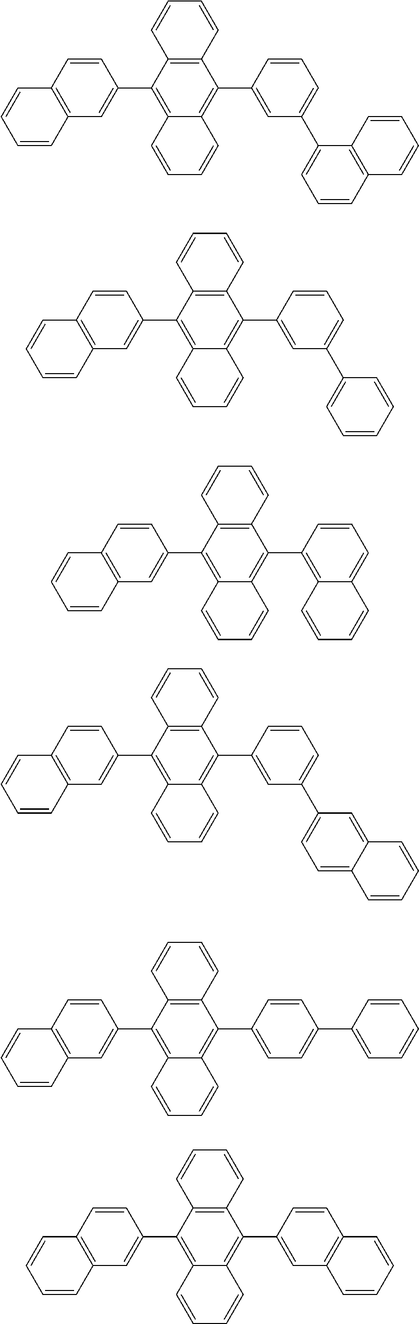

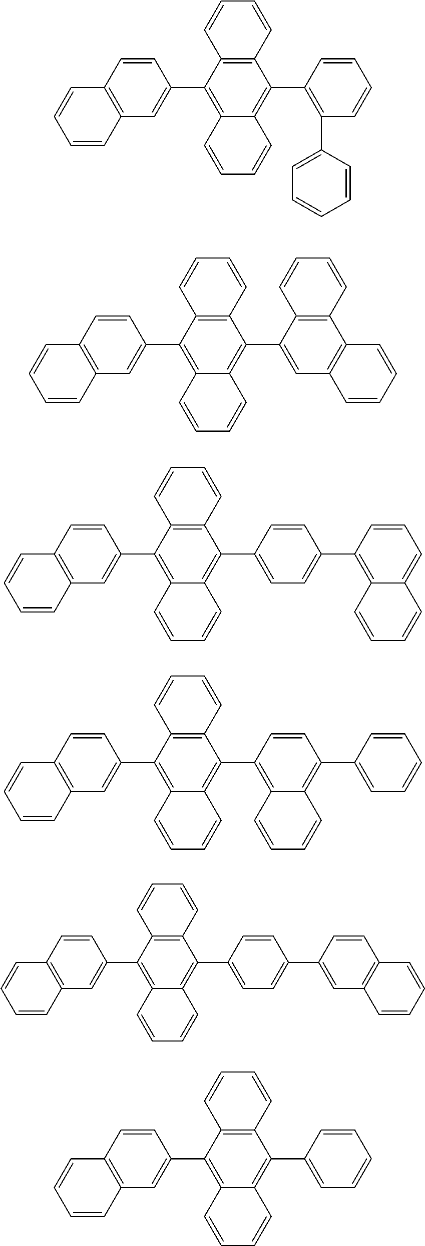

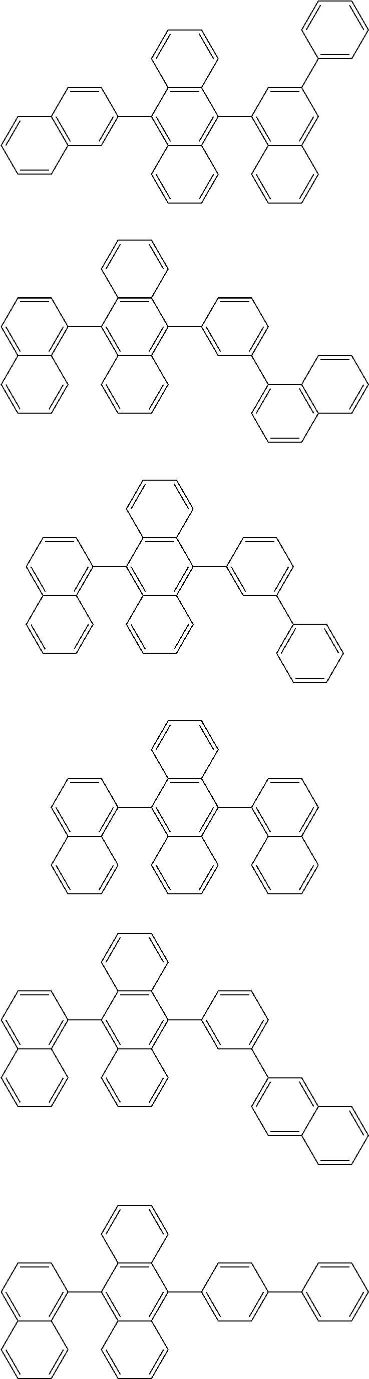

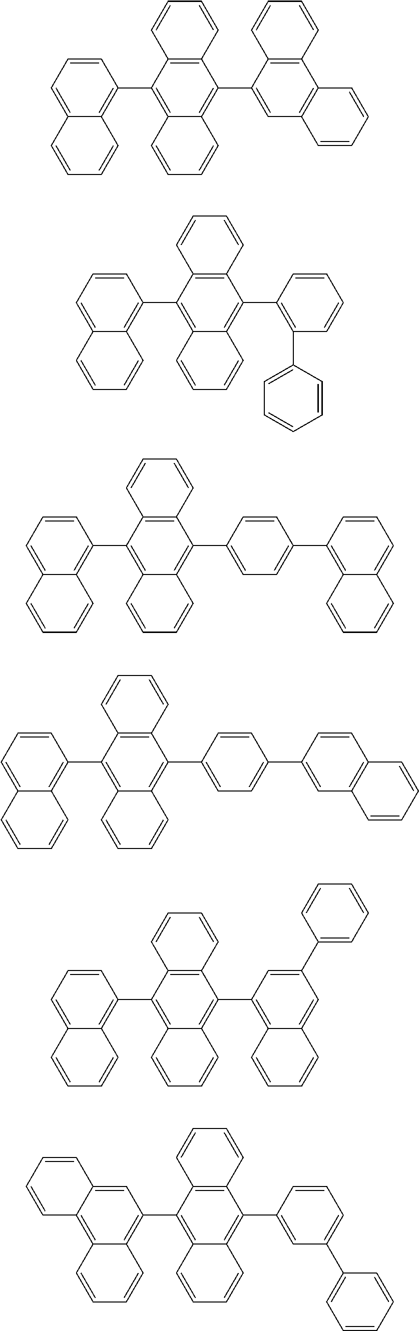

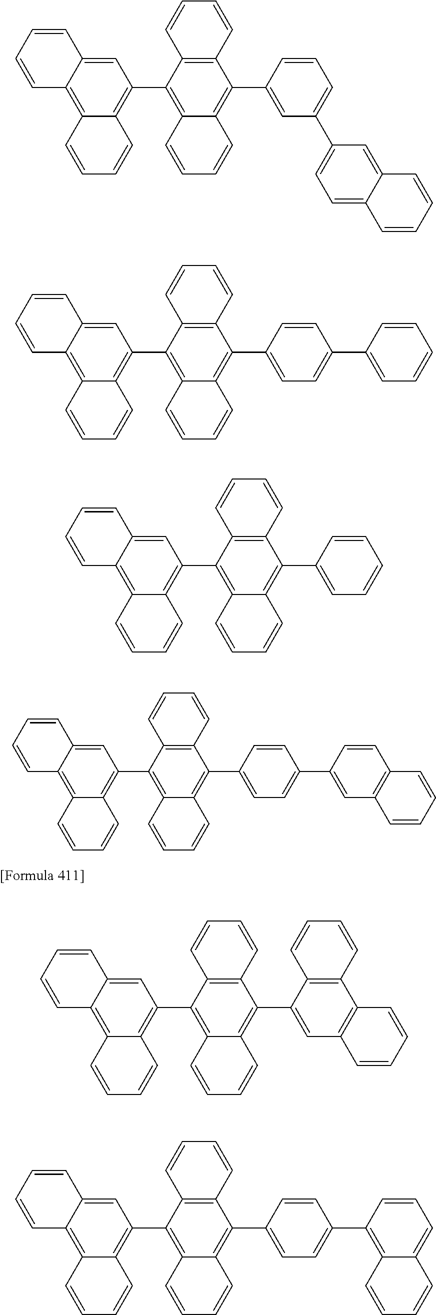

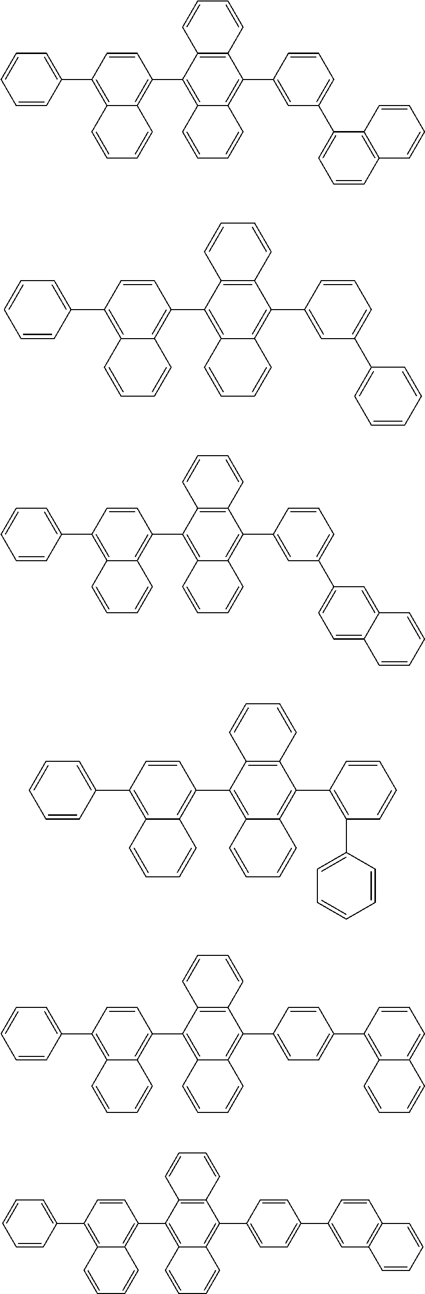

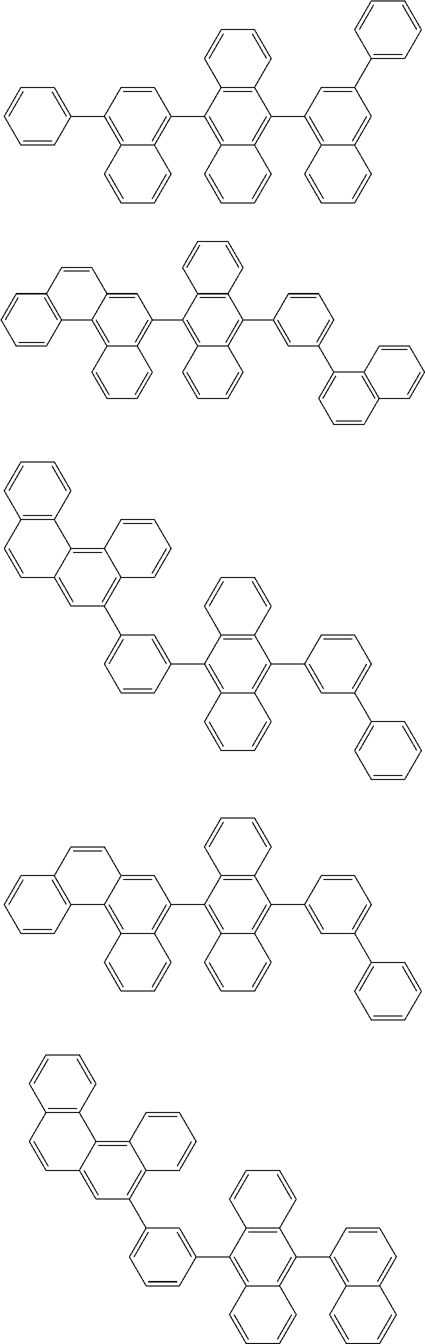

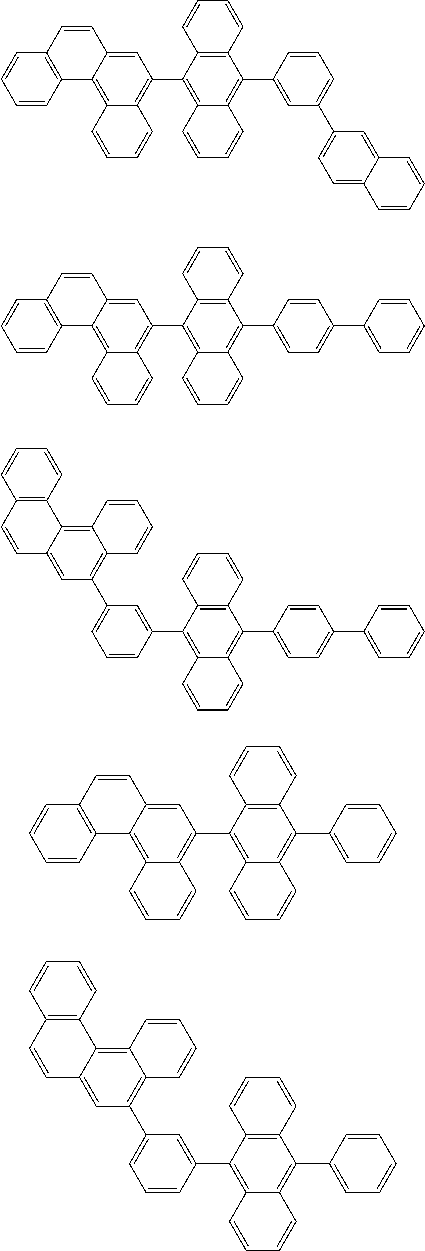

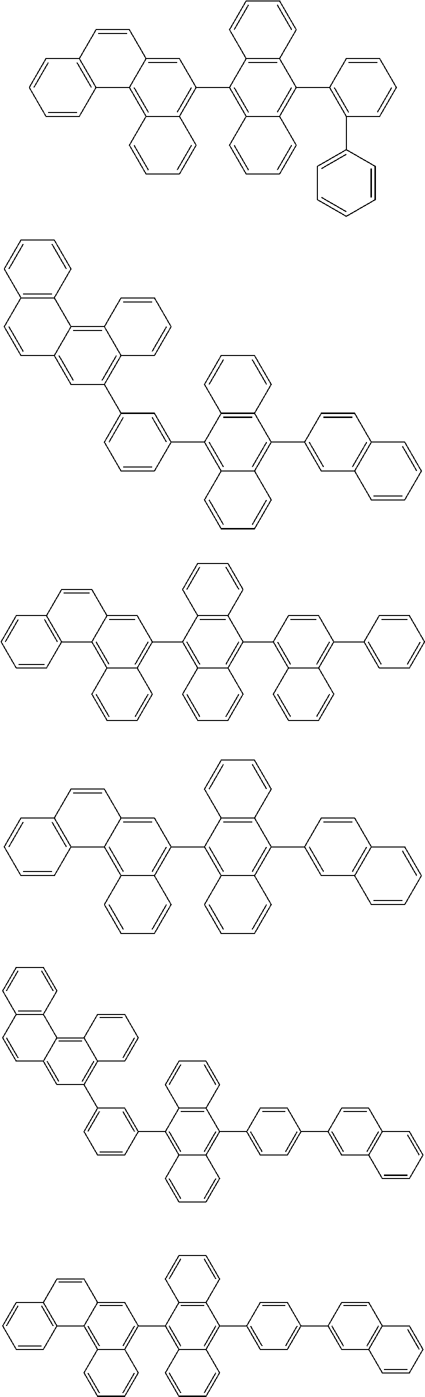

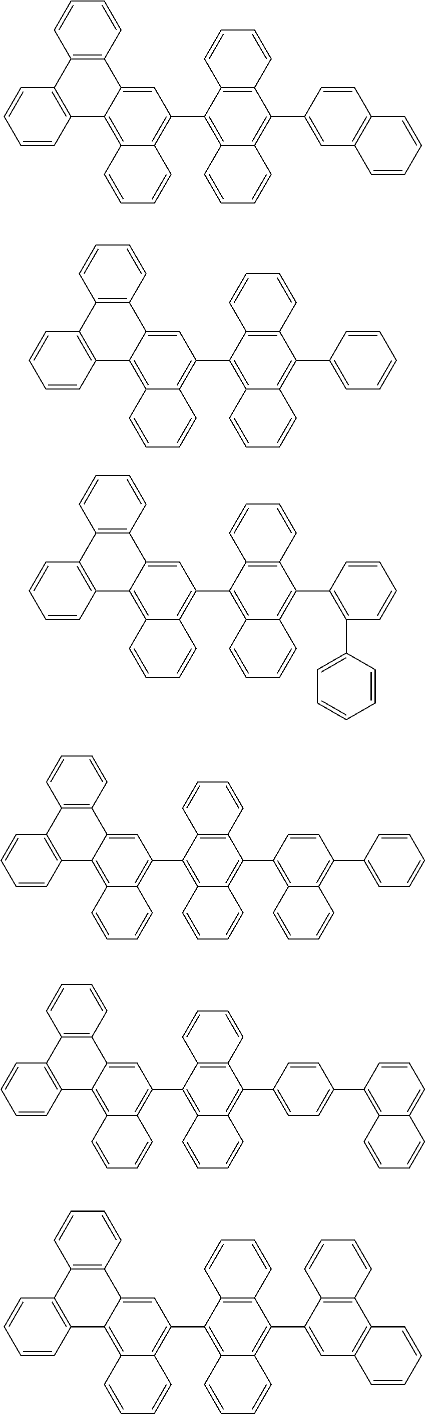

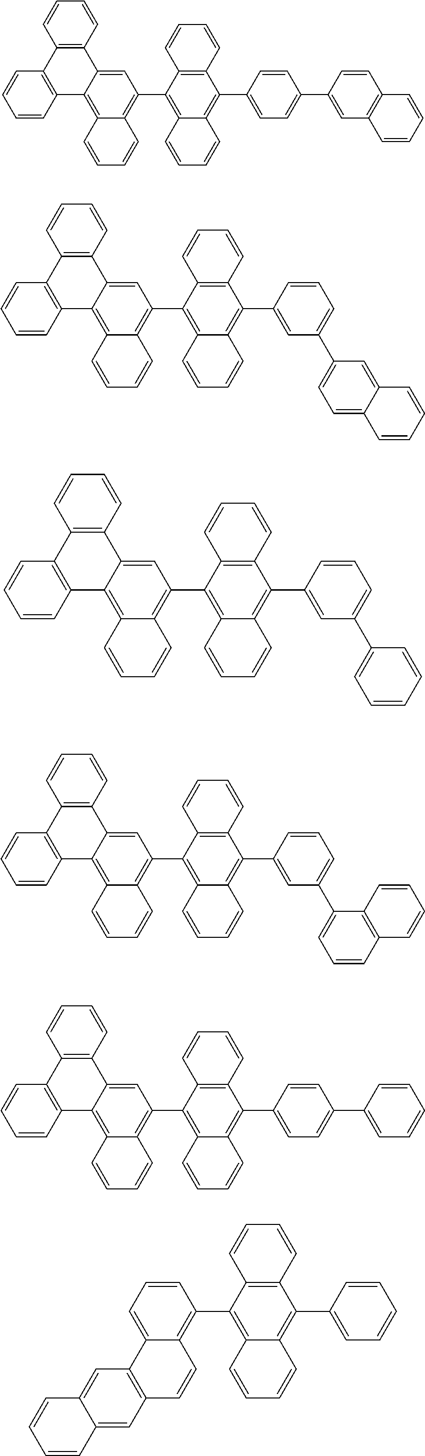

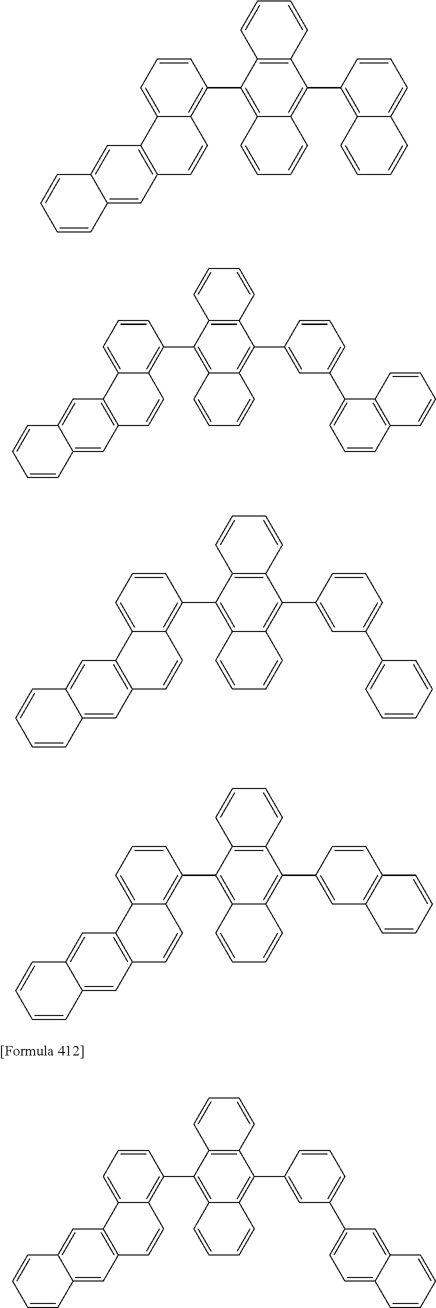

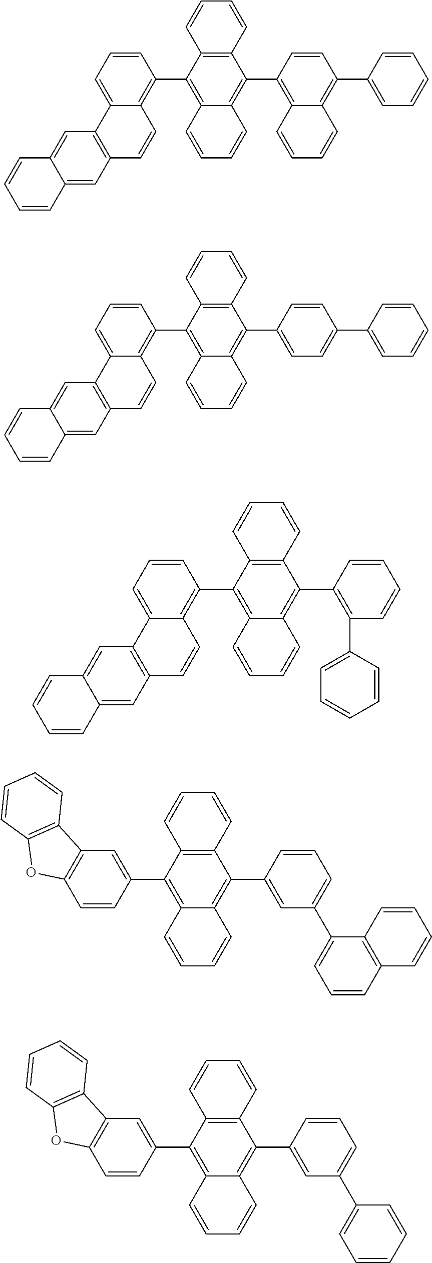

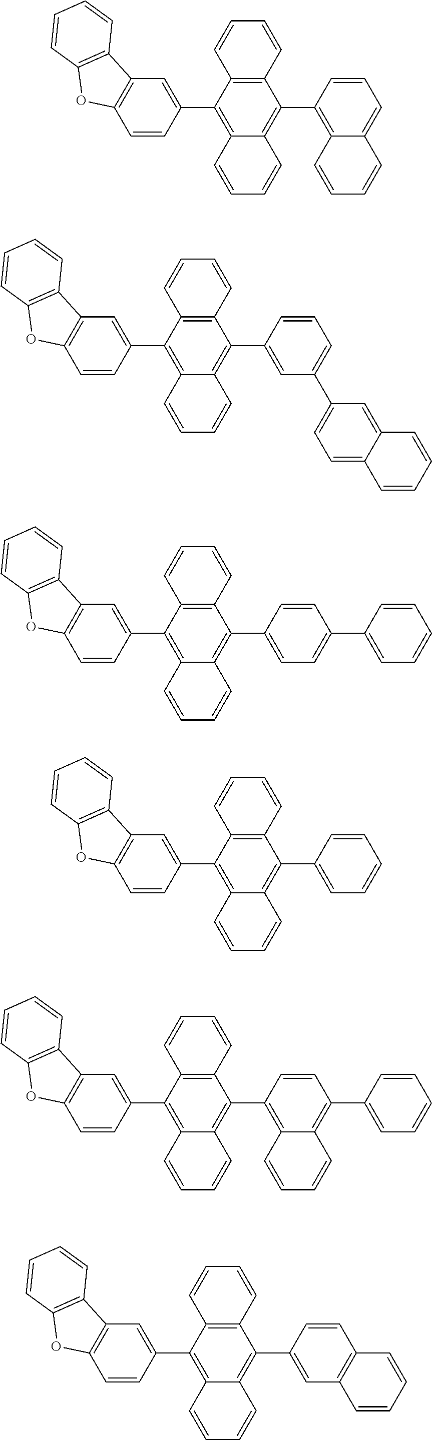 [SMILES: c1ccc2c(-c3c4ccccc4c(-c4ccc5oc6ccccc6c5c4)c4ccccc34)cccc2c1 ; c1cc(-c2ccc3ccccc3c2)cc(-c2c3ccccc3c(-c3ccc4oc5ccccc5c4c3)c3ccccc23)c1 ; c1ccc(-c2ccc(-c3c4ccccc4c(-c4ccc5oc6ccccc6c5c4)c4ccccc34)cc2)cc1 ; c1ccc(-c2c3ccccc3c(-c3ccc4oc5ccccc5c4c3)c3ccccc23)cc1 ; c1ccc(-c2ccc(-c3c4ccccc4c(-c4ccc5oc6ccccc6c5c4)c4ccccc34)c3ccccc23)cc1 ; c1ccc2cc(-c3c4ccccc4c(-c4ccc5oc6ccccc6c5c4)c4ccccc34)ccc2c1]

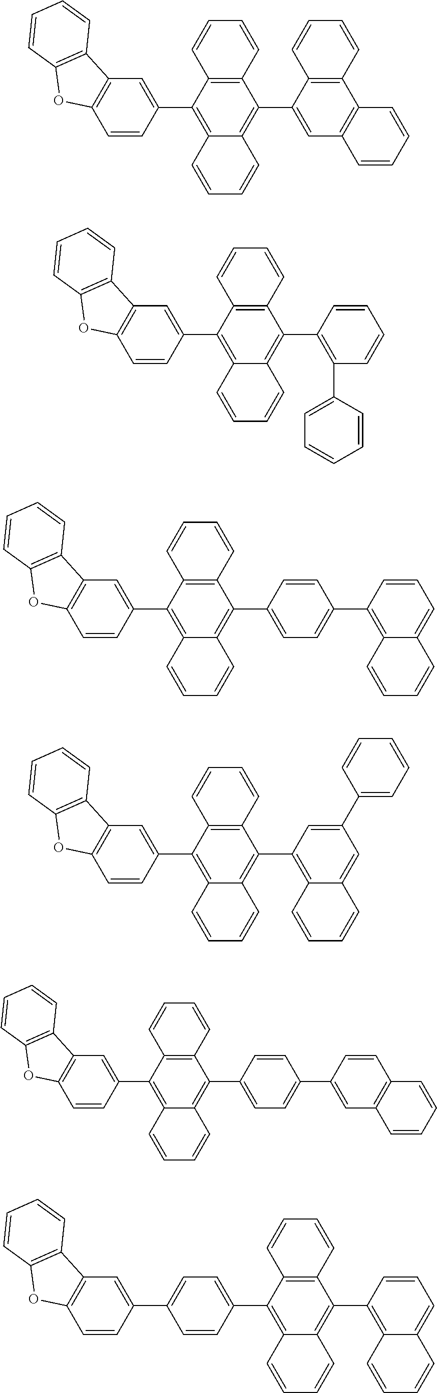

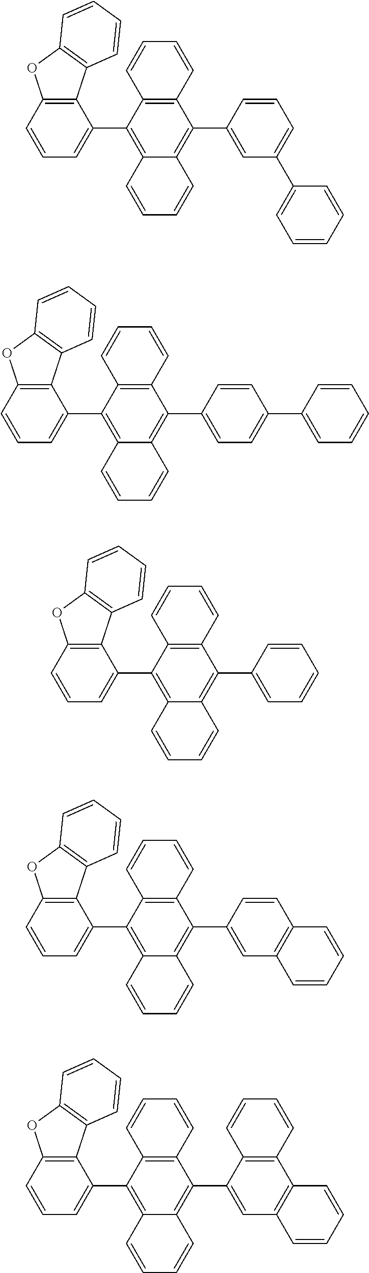

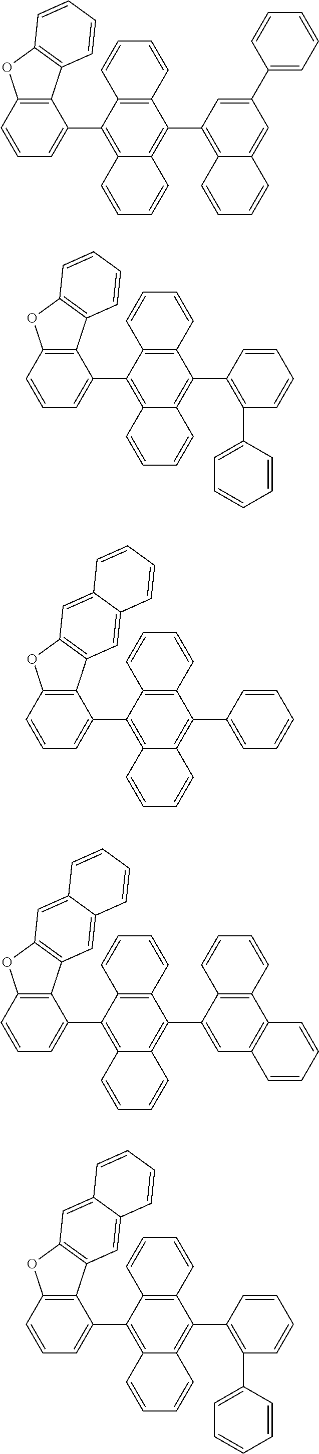

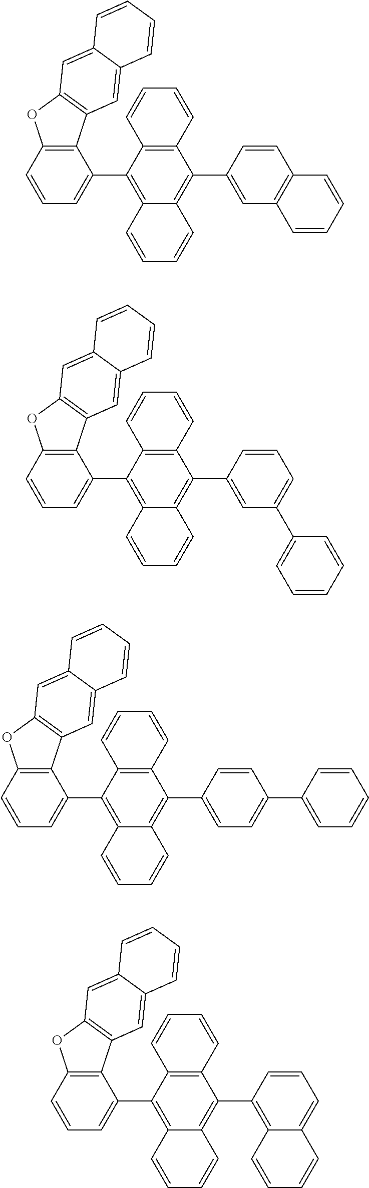

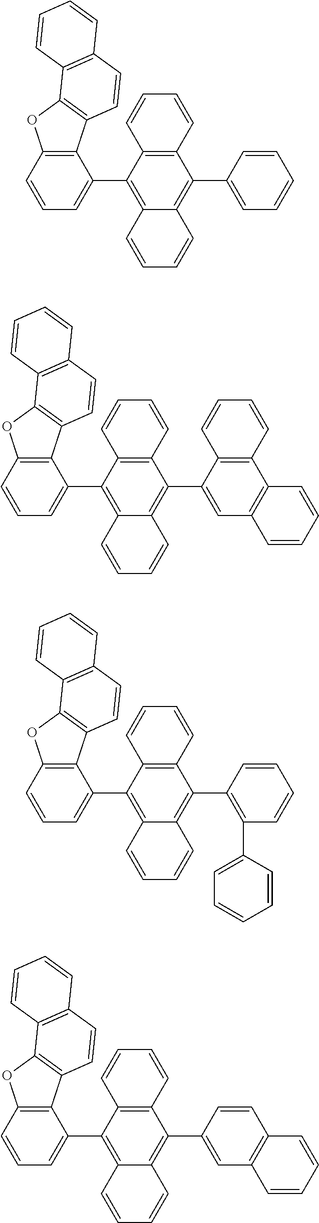 [SMILES: c1ccc(-c2c3ccccc3c(-c3cccc4oc5c6ccccc6ccc5c34)c3ccccc23)cc1 ; c1ccc2c(c1)cc(-c1c3ccccc3c(-c3cccc4oc5c6ccccc6ccc5c34)c3ccccc13)c1ccccc12 ; c1ccc(-c2ccccc2-c2c3ccccc3c(-c3cccc4oc5c6ccccc6ccc5c34)c3ccccc23)cc1 ; c1ccc2cc(-c3c4ccccc4c(-c4cccc5oc6c7ccccc7ccc6c45)c4ccccc34)ccc2c1]

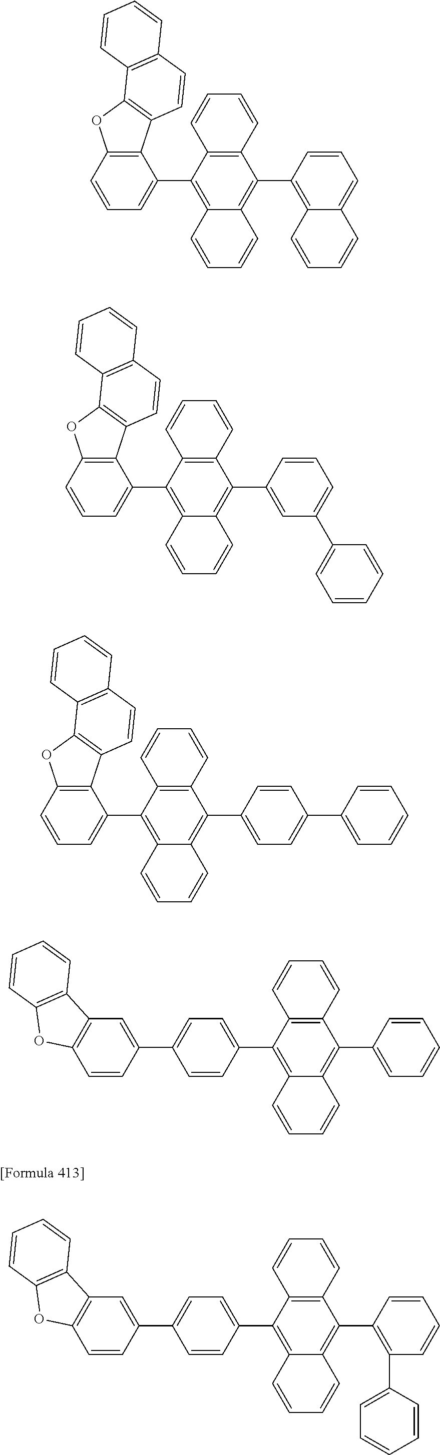 [SMILES: c1ccc2c(-c3c4ccccc4c(-c4cccc5oc6c7ccccc7ccc6c45)c4ccccc34)cccc2c1 ; c1ccc(-c2cccc(-c3c4ccccc4c(-c4cccc5oc6c7ccccc7ccc6c45)c4ccccc34)c2)cc1 ; c1ccc(-c2ccc(-c3c4ccccc4c(-c4cccc5oc6c7ccccc7ccc6c45)c4ccccc34)cc2)cc1 ; c1ccc(-c2c3ccccc3c(-c3ccc(-c4ccc5oc6ccccc6c5c4)cc3)c3ccccc23)cc1 ; c1ccc(-c2ccccc2-c2c3ccccc3c(-c3ccc(-c4ccc5oc6ccccc6c5c4)cc3)c3ccccc23)cc1]

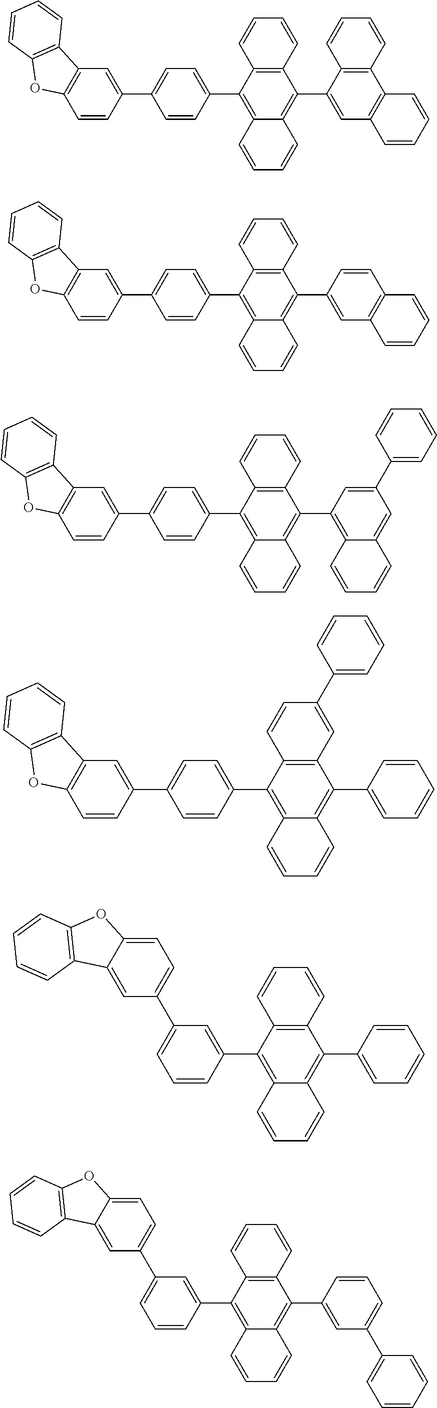

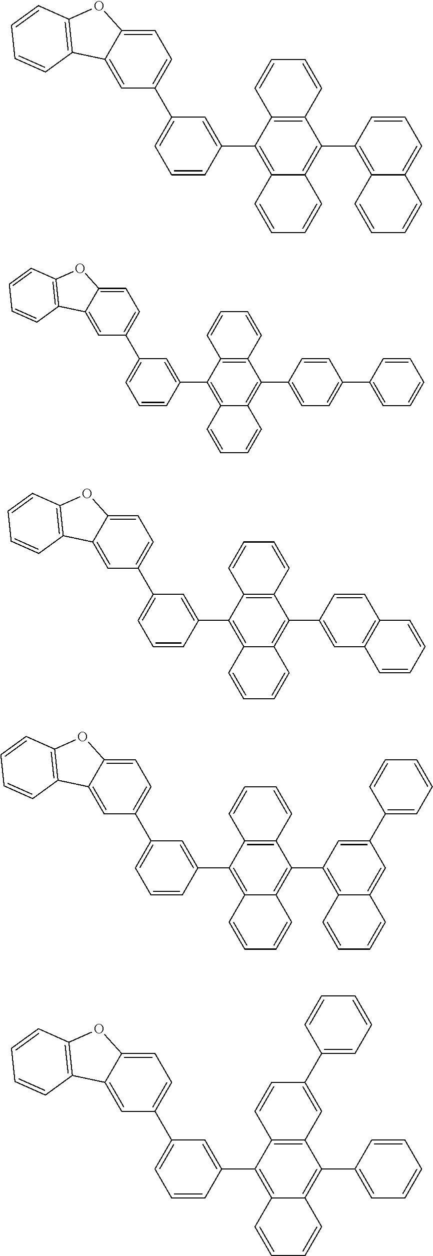 [SMILES: c1cc(-c2ccc3oc4ccccc4c3c2)cc(-c2c3ccccc3c(-c3cccc4ccccc34)c3ccccc23)c1 ; c1ccc(-c2ccc(-c3c4ccccc4c(-c4cccc(-c5ccc6oc7ccccc7c6c5)c4)c4ccccc34)cc2)cc1 ; c1cc(-c2ccc3oc4ccccc4c3c2)cc(-c2c3ccccc3c(-c3ccc4ccccc4c3)c3ccccc23)c1 ; c1ccc(-c2cc(-c3c4ccccc4c(-c4cccc(-c5ccc6oc7ccccc7c6c5)c4)c4ccccc34)c3ccccc3c2)cc1 ; c1ccc(-c2ccc3c(-c4cccc(-c5ccc6oc7ccccc7c6c5)c4)c4ccccc4c(-c4ccccc4)c3c2)cc1]

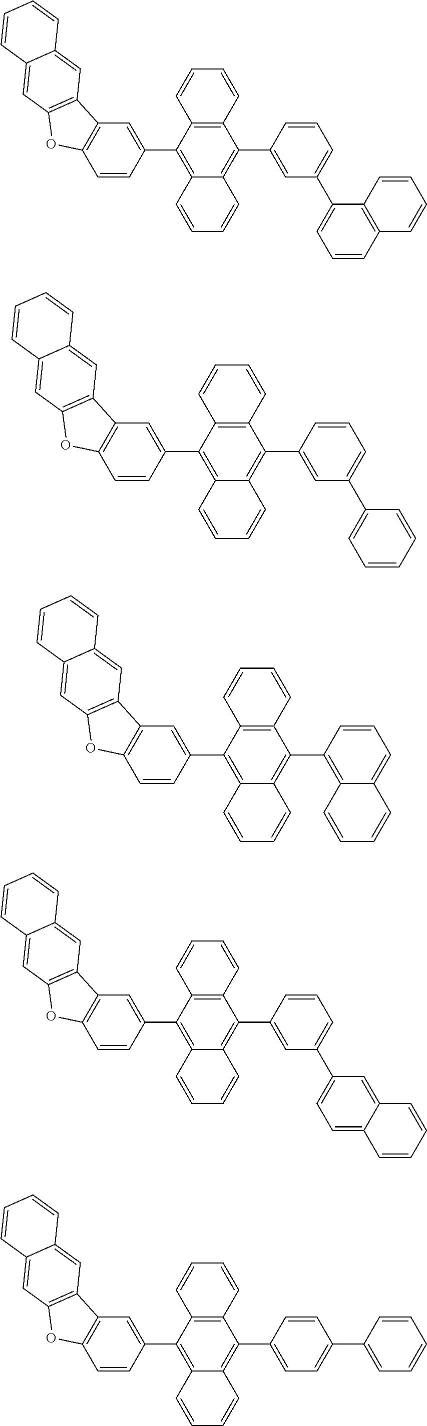 [SMILES: c1cc(-c2cccc3ccccc23)cc(-c2c3ccccc3c(-c3ccc4oc5cc6ccccc6cc5c4c3)c3ccccc23)c1 ; c1ccc(-c2cccc(-c3c4ccccc4c(-c4ccc5oc6cc7ccccc7cc6c5c4)c4ccccc34)c2)cc1 ; c1ccc2cc3c(cc2c1)oc1ccc(-c2c4ccccc4c(-c4cccc5ccccc45)c4ccccc24)cc13 ; c1cc(-c2ccc3ccccc3c2)cc(-c2c3ccccc3c(-c3ccc4oc5cc6ccccc6cc5c4c3)c3ccccc23)c1 ; c1ccc(-c2ccc(-c3c4ccccc4c(-c4ccc5oc6cc7ccccc7cc6c5c4)c4ccccc34)cc2)cc1]

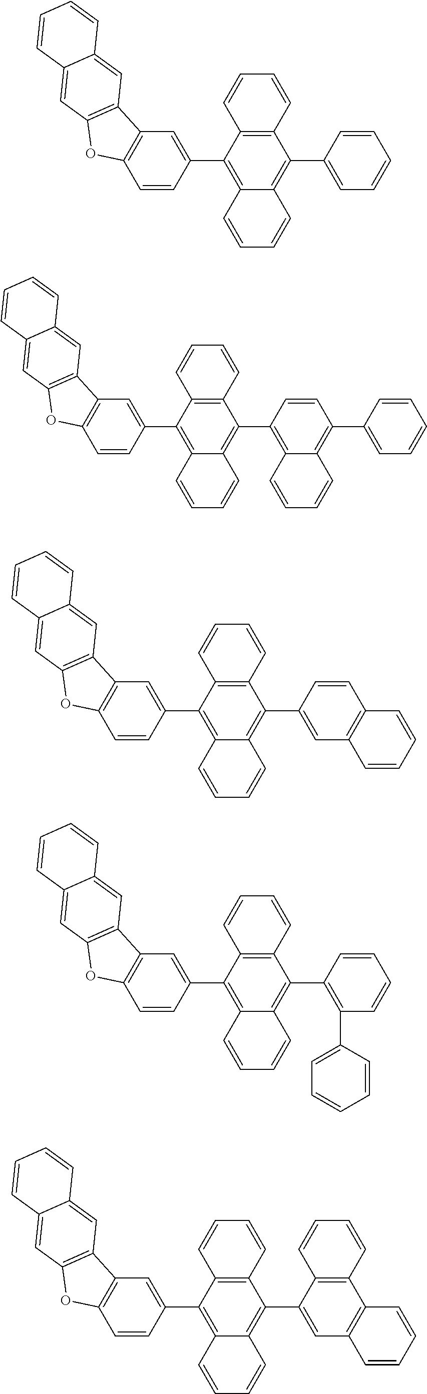 [SMILES: c1ccc(-c2c3ccccc3c(-c3ccc4oc5cc6ccccc6cc5c4c3)c3ccccc23)cc1 ; c1ccc(-c2ccc(-c3c4ccccc4c(-c4ccc5oc6cc7ccccc7cc6c5c4)c4ccccc34)c3ccccc23)cc1 ; c1ccc2cc(-c3c4ccccc4c(-c4ccc5oc6cc7ccccc7cc6c5c4)c4ccccc34)ccc2c1 ; c1ccc(-c2ccccc2-c2c3ccccc3c(-c3ccc4oc5cc6ccccc6cc5c4c3)c3ccccc23)cc1 ; c1ccc2cc3c(cc2c1)oc1ccc(-c2c4ccccc4c(-c4cc5ccccc5c5ccccc45)c4ccccc24)cc13]

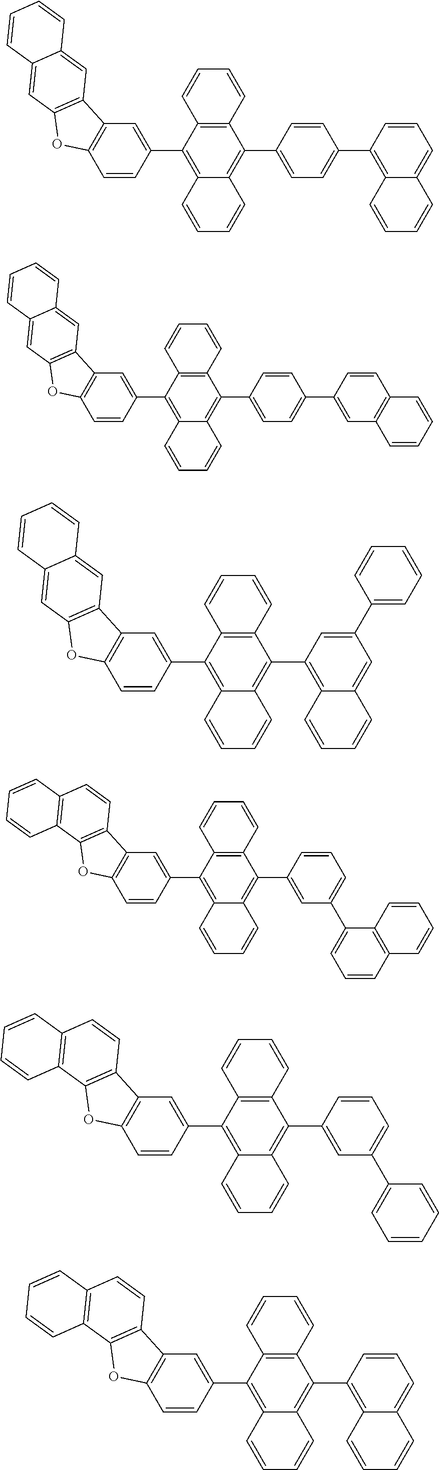 [SMILES: c1ccc2cc3c(cc2c1)oc1ccc(-c2c4ccccc4c(-c4ccc(-c5cccc6ccccc56)cc4)c4ccccc24)cc13 ; c1ccc2cc(-c3ccc(-c4c5ccccc5c(-c5ccc6oc7cc8ccccc8cc7c6c5)c5ccccc45)cc3)ccc2c1 ; c1ccc(-c2cc(-c3c4ccccc4c(-c4ccc5oc6cc7ccccc7cc6c5c4)c4ccccc34)c3ccccc3c2)cc1 ; c1cc(-c2cccc3ccccc23)cc(-c2c3ccccc3c(-c3ccc4oc5c6ccccc6ccc5c4c3)c3ccccc23)c1 ; c1ccc(-c2cccc(-c3c4ccccc4c(-c4ccc5oc6c7ccccc7ccc6c5c4)c4ccccc34)c2)cc1 ; c1ccc2c(-c3c4ccccc4c(-c4ccc5oc6c7ccccc7ccc6c5c4)c4ccccc34)cccc2c1]

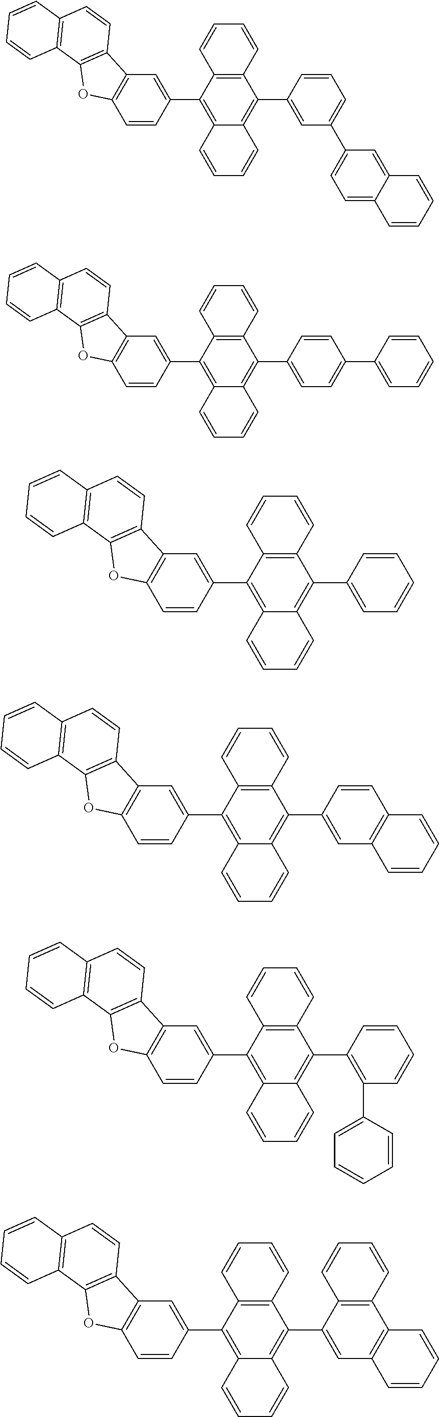 [SMILES: c1cc(-c2ccc3ccccc3c2)cc(-c2c3ccccc3c(-c3ccc4oc5c6ccccc6ccc5c4c3)c3ccccc23)c1 ; c1ccc(-c2ccc(-c3c4ccccc4c(-c4ccc5oc6c7ccccc7ccc6c5c4)c4ccccc34)cc2)cc1 ; c1ccc(-c2c3ccccc3c(-c3ccc4oc5c6ccccc6ccc5c4c3)c3ccccc23)cc1 ; c1ccc2cc(-c3c4ccccc4c(-c4ccc5oc6c7ccccc7ccc6c5c4)c4ccccc34)ccc2c1 ; c1ccc(-c2ccccc2-c2c3ccccc3c(-c3ccc4oc5c6ccccc6ccc5c4c3)c3ccccc23)cc1 ; c1ccc2c(c1)cc(-c1c3ccccc3c(-c3ccc4oc5c6ccccc6ccc5c4c3)c3ccccc13)c1ccccc12]

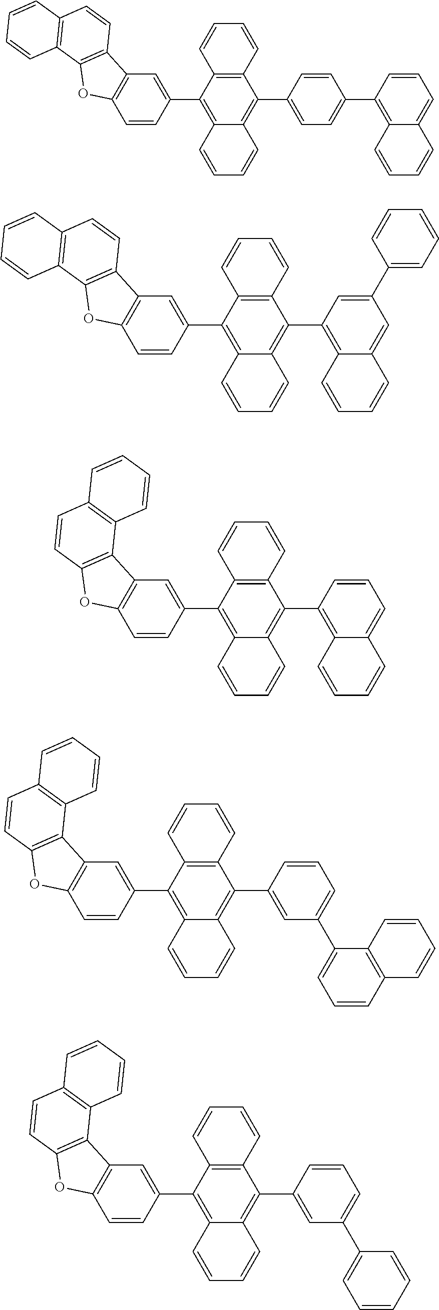

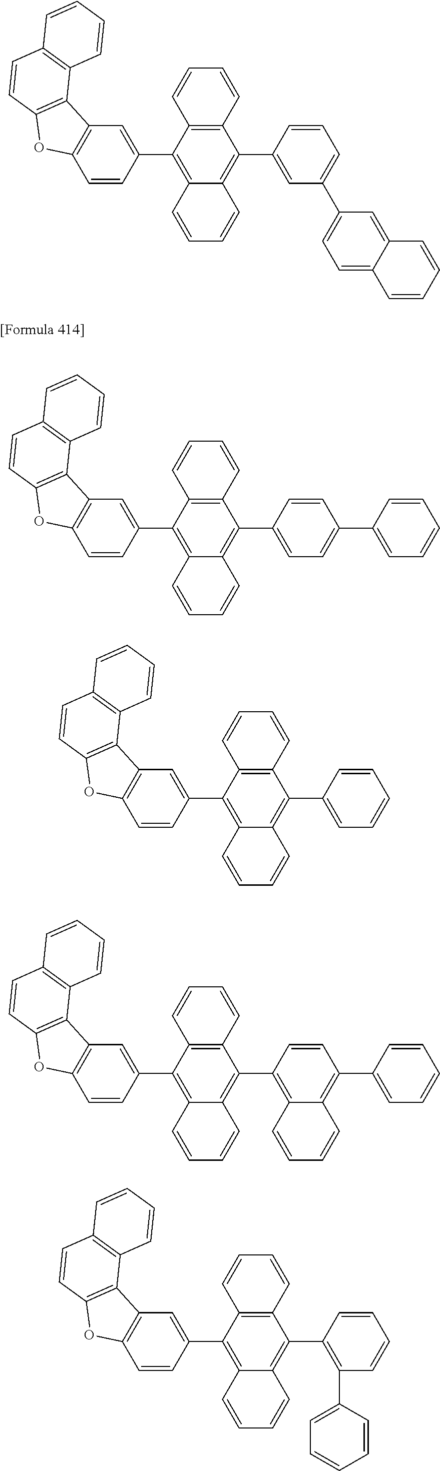 [SMILES: c1cc(-c2ccc3ccccc3c2)cc(-c2c3ccccc3c(-c3ccc4oc5ccc6ccccc6c5c4c3)c3ccccc23)c1 ; c1ccc(-c2ccc(-c3c4ccccc4c(-c4ccc5oc6ccc7ccccc7c6c5c4)c4ccccc34)cc2)cc1 ; c1ccc(-c2c3ccccc3c(-c3ccc4oc5ccc6ccccc6c5c4c3)c3ccccc23)cc1 ; c1ccc(-c2ccc(-c3c4ccccc4c(-c4ccc5oc6ccc7ccccc7c6c5c4)c4ccccc34)c3ccccc23)cc1 ; c1ccc(-c2ccccc2-c2c3ccccc3c(-c3ccc4oc5ccc6ccccc6c5c4c3)c3ccccc23)cc1]

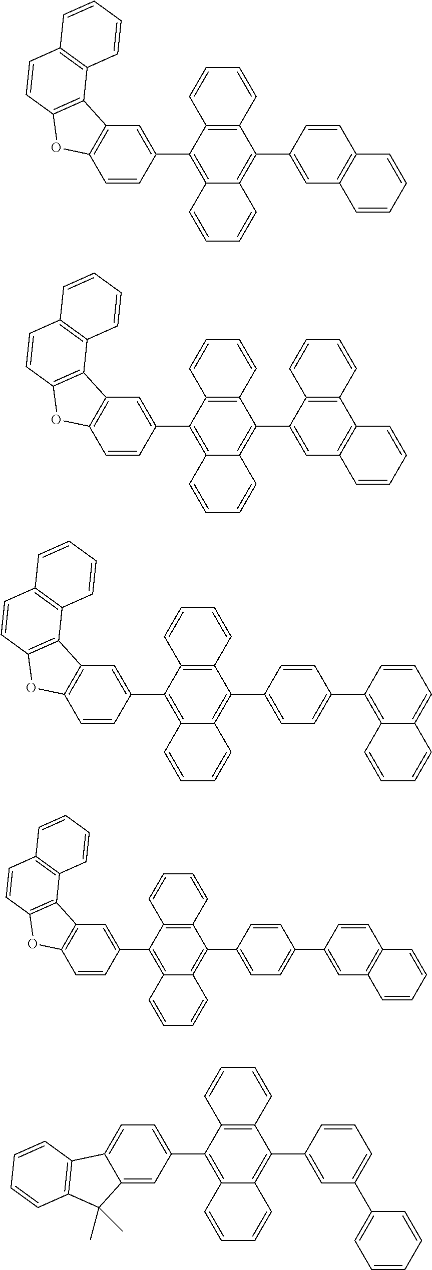

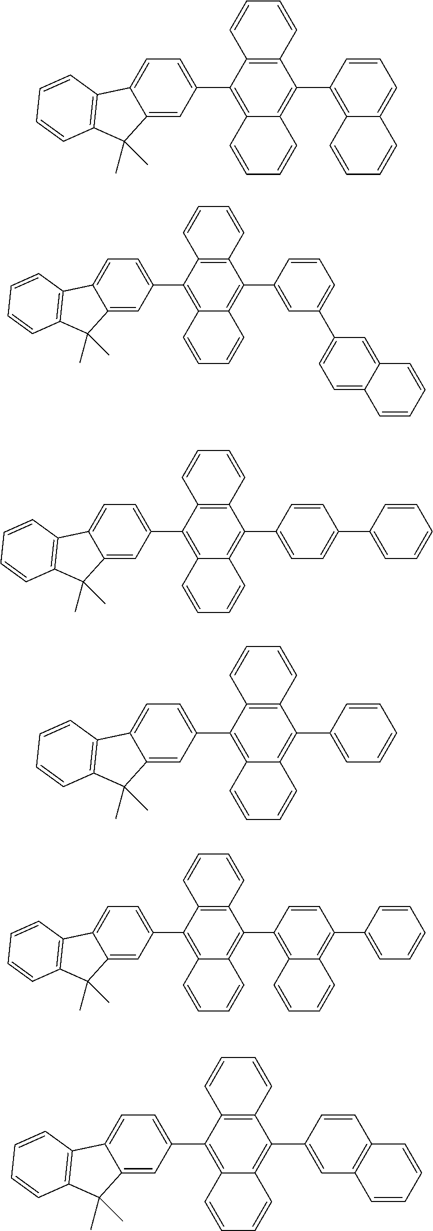

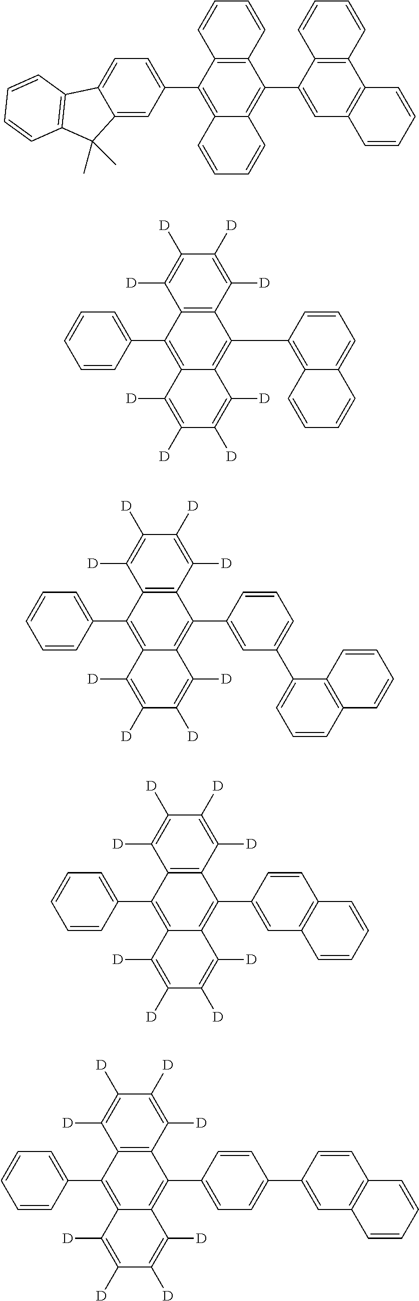

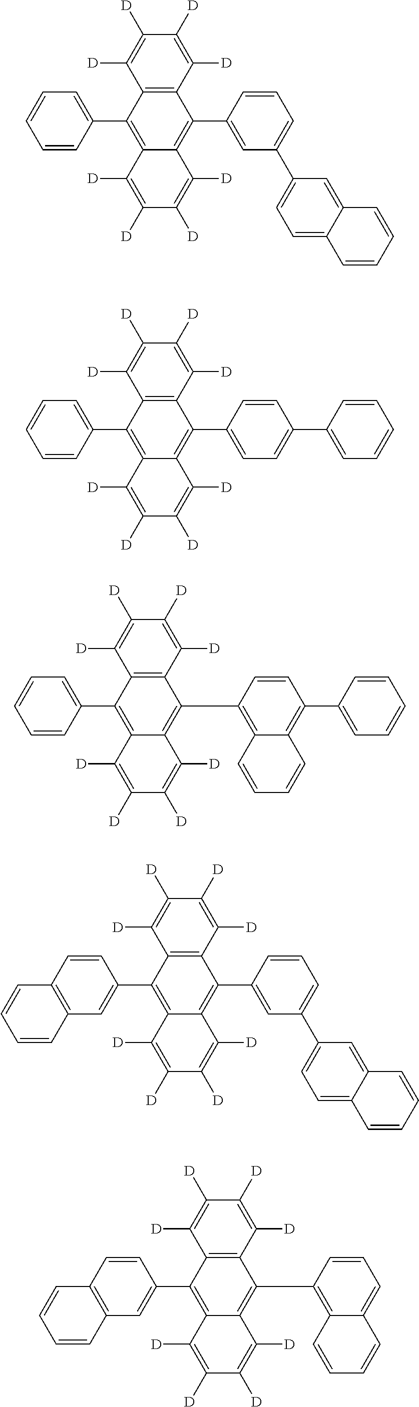

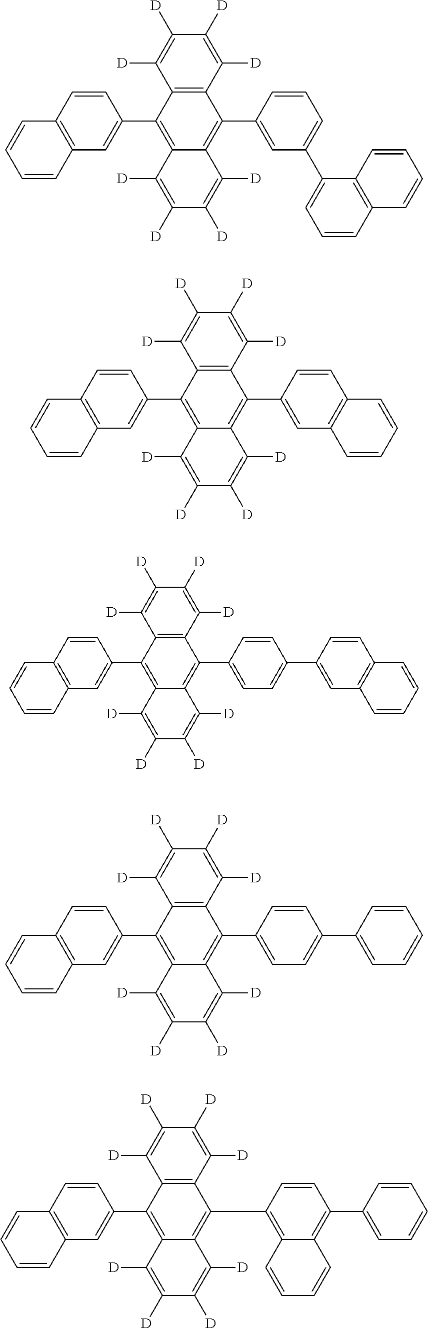

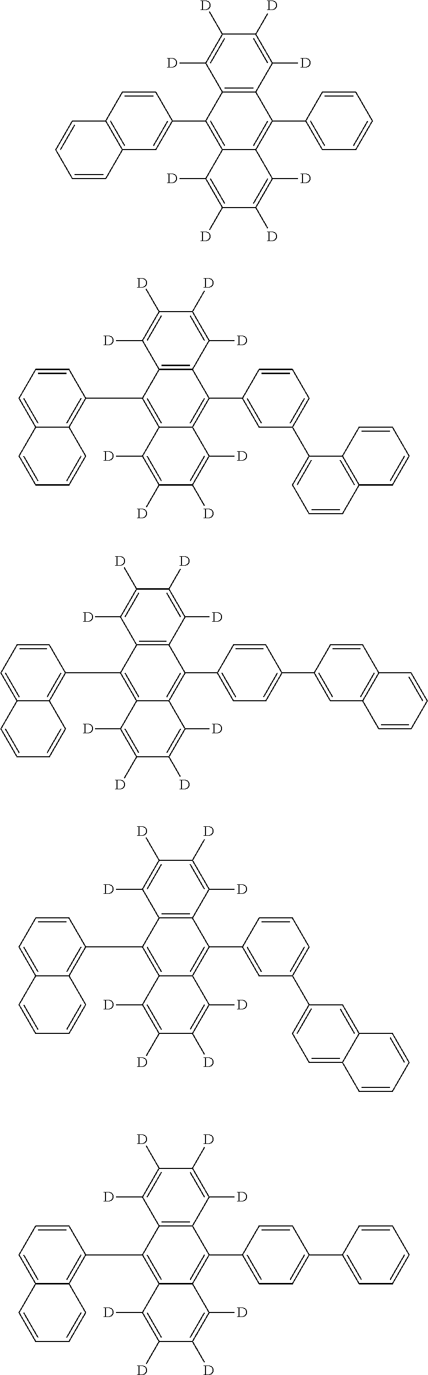

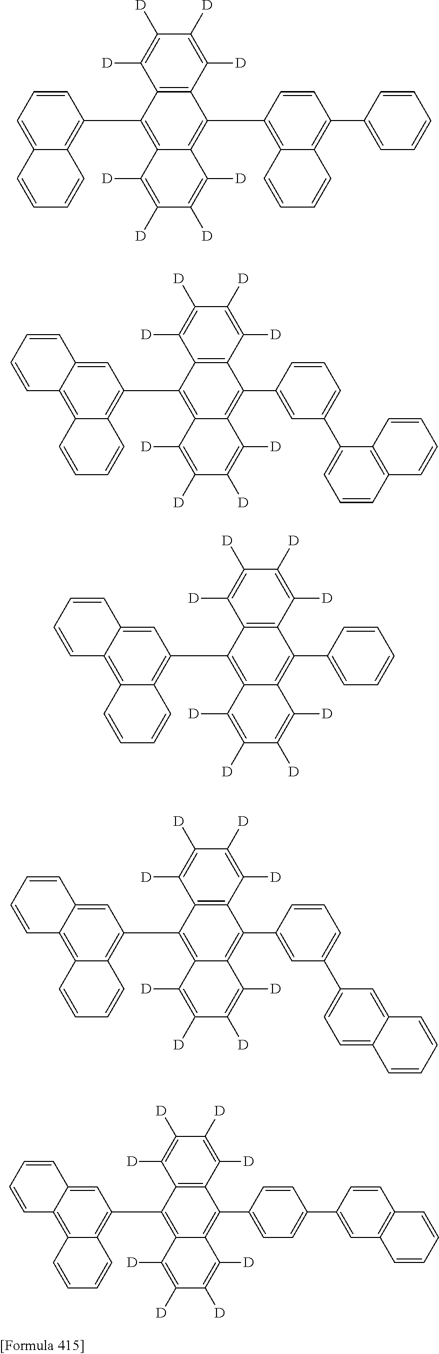

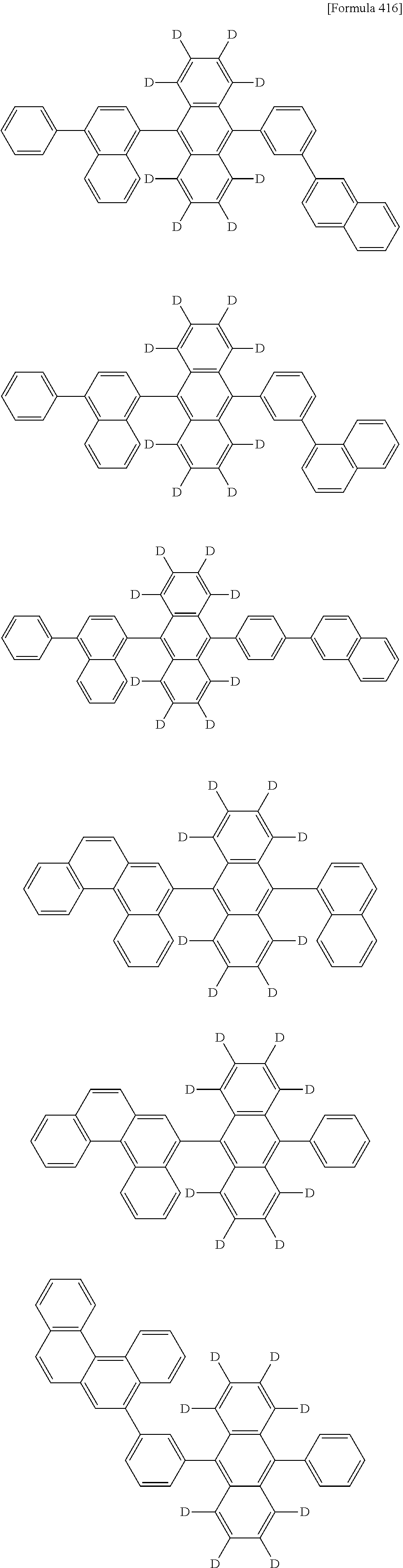

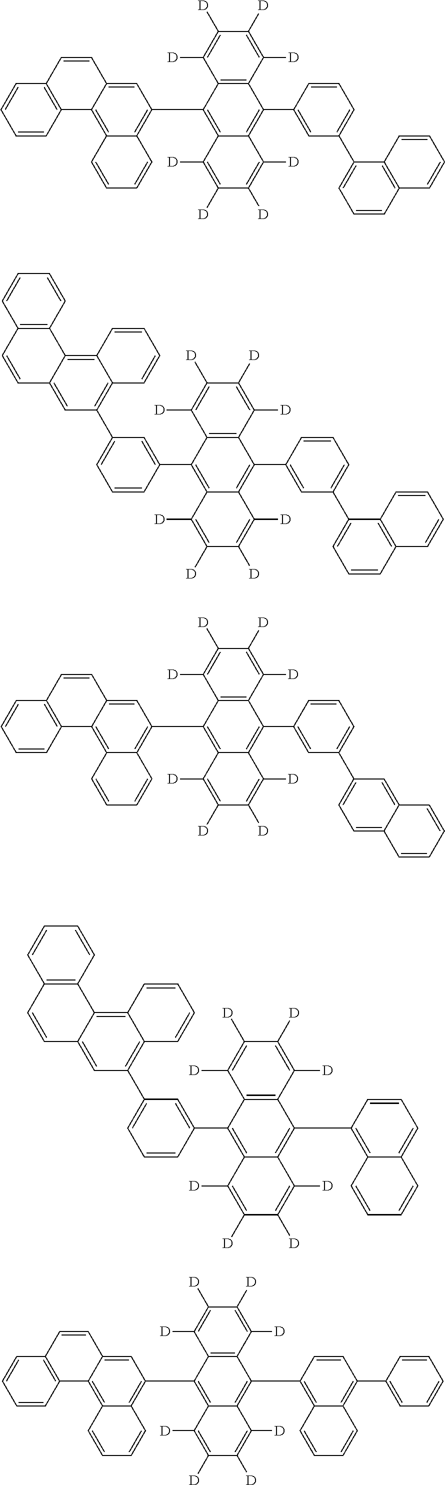

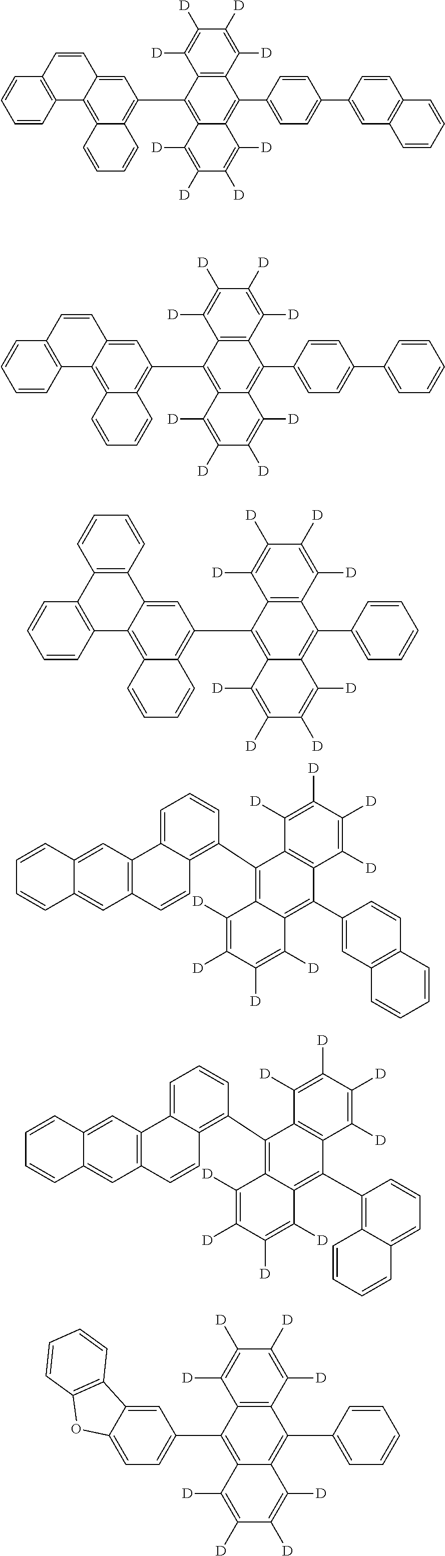

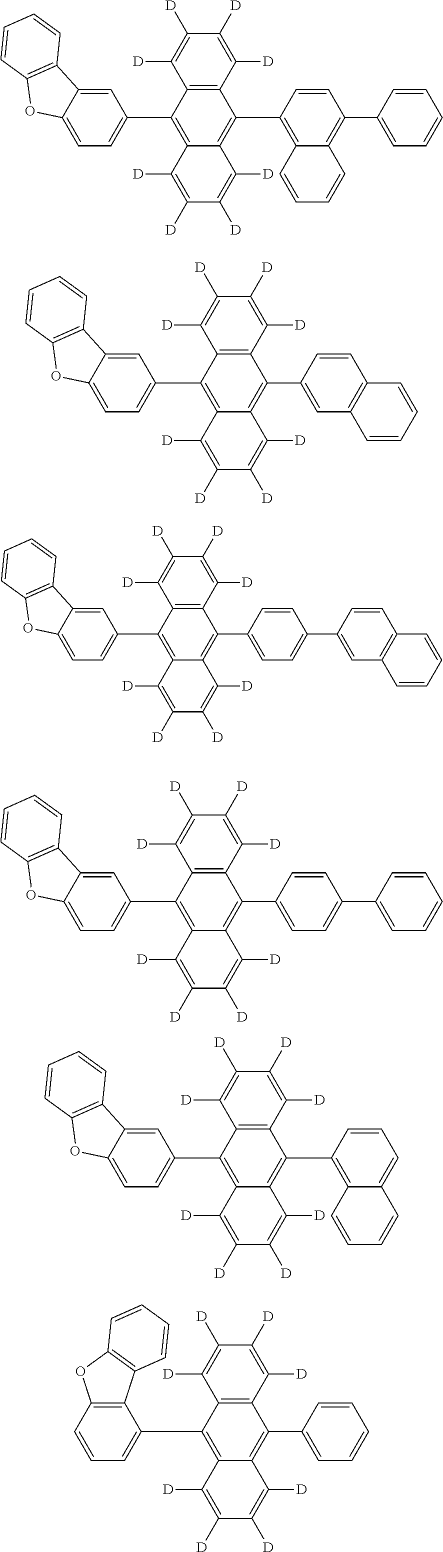

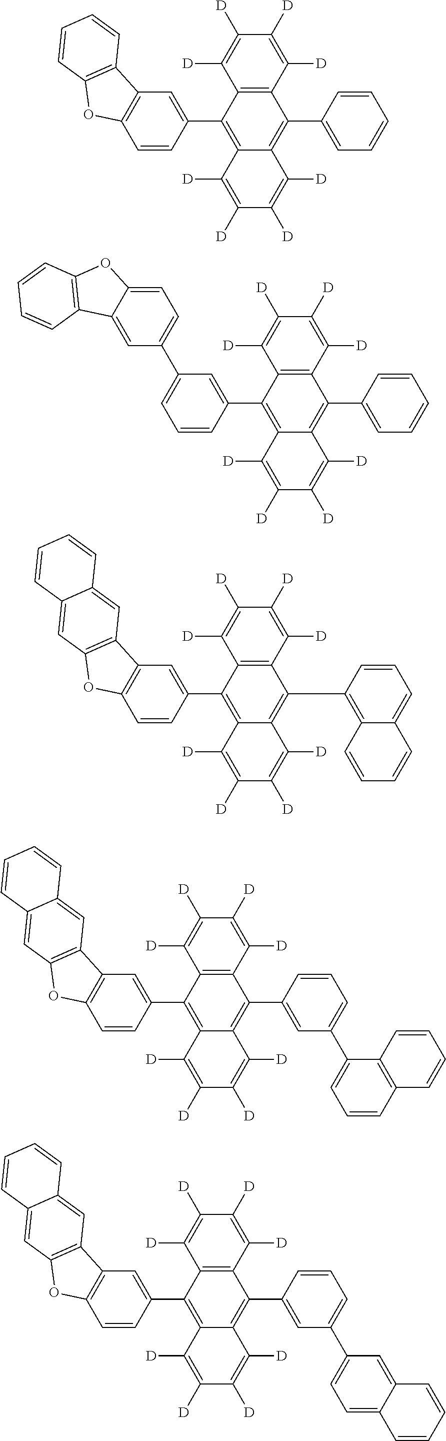

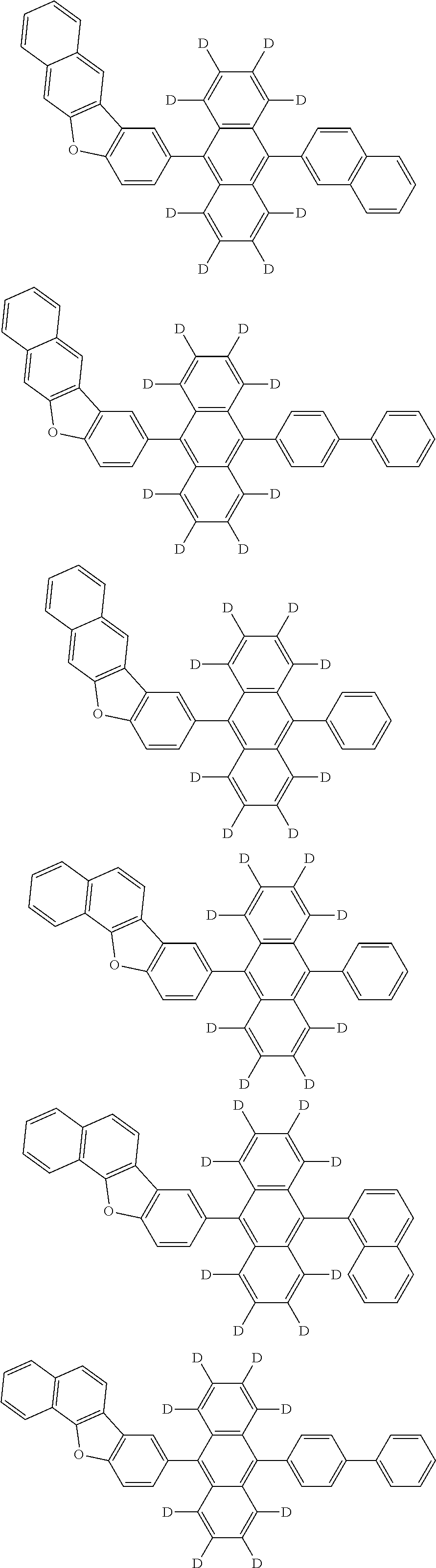

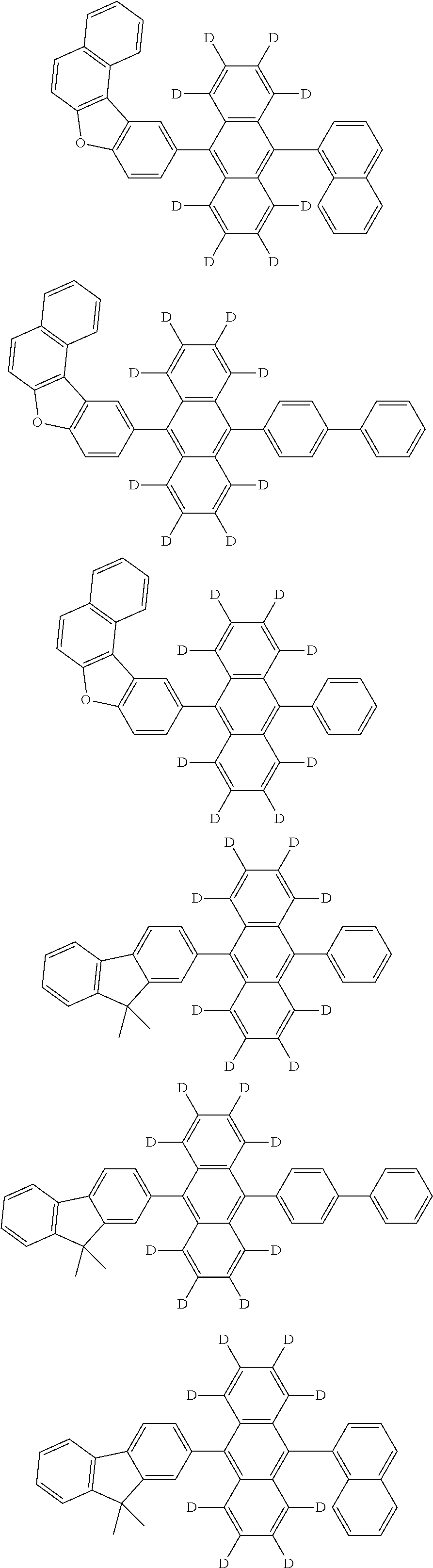

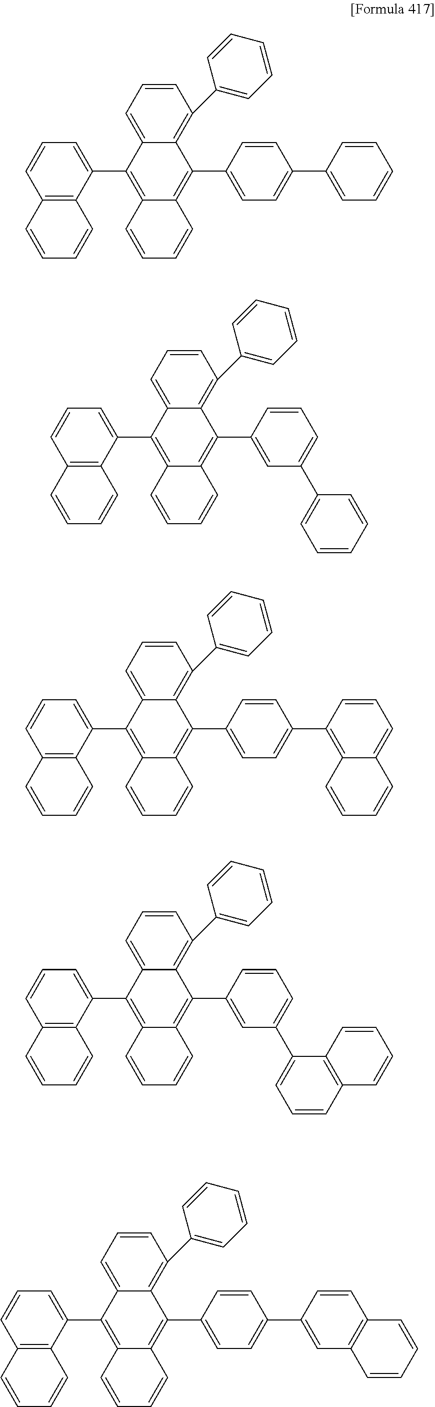

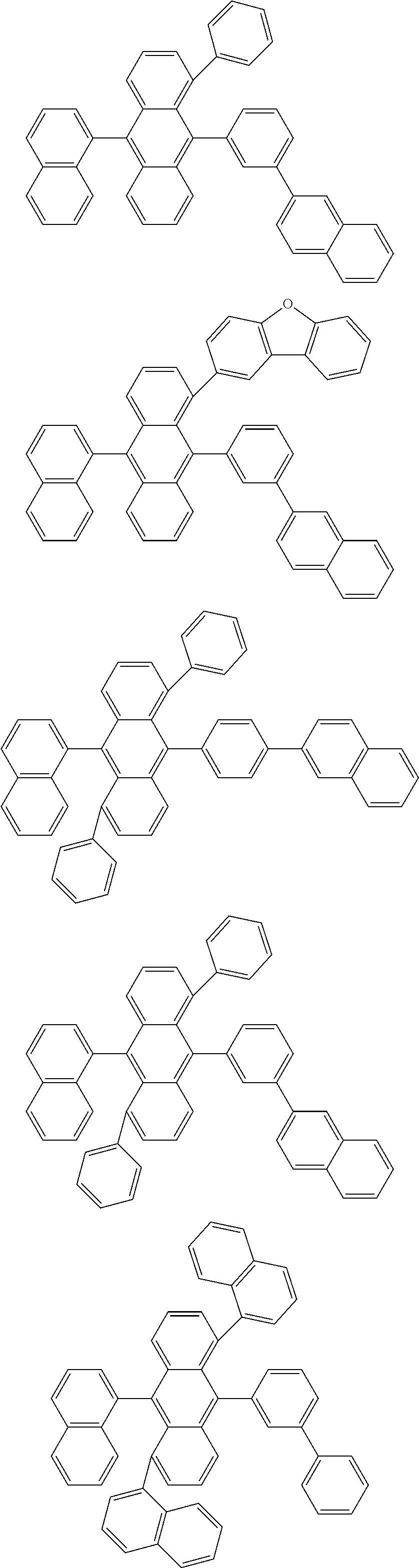

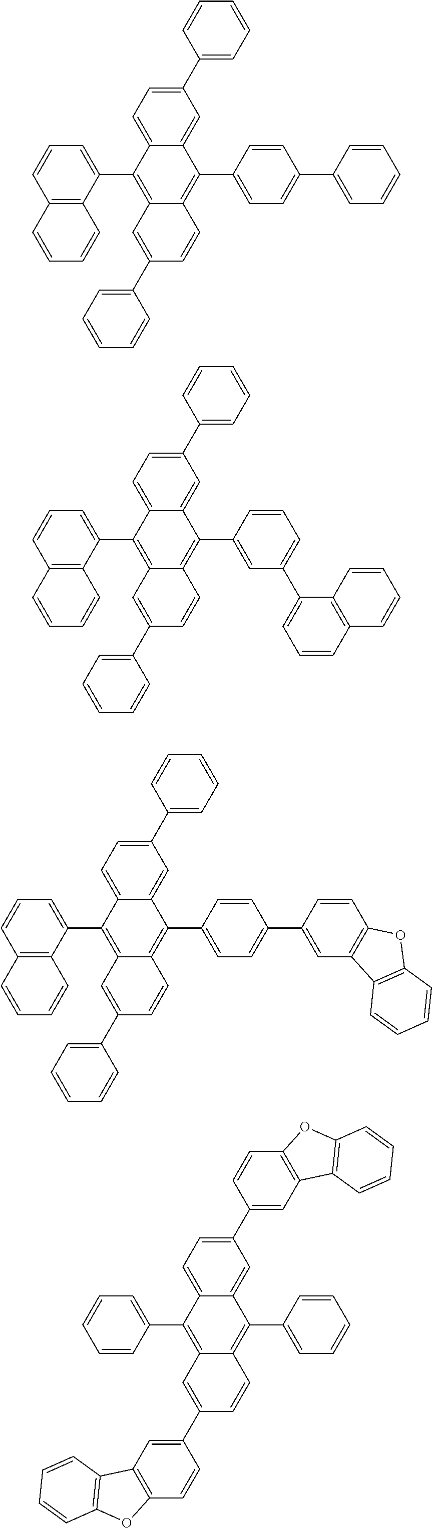

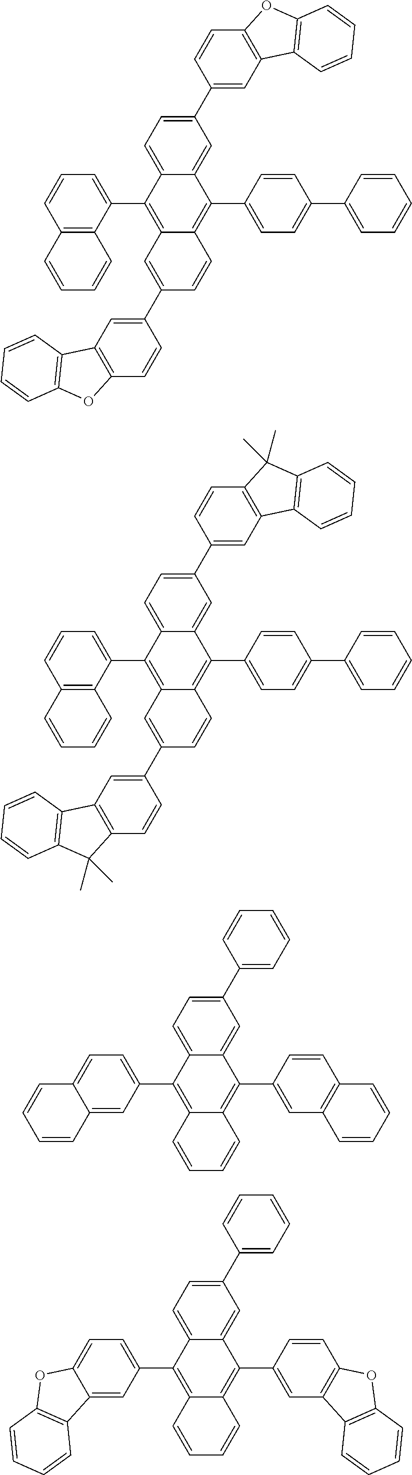

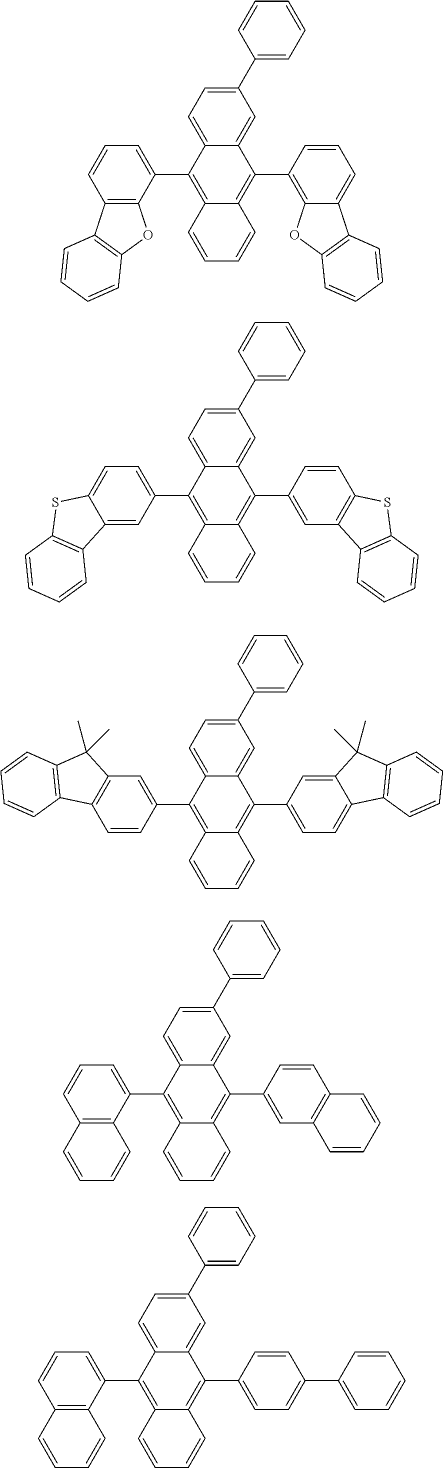

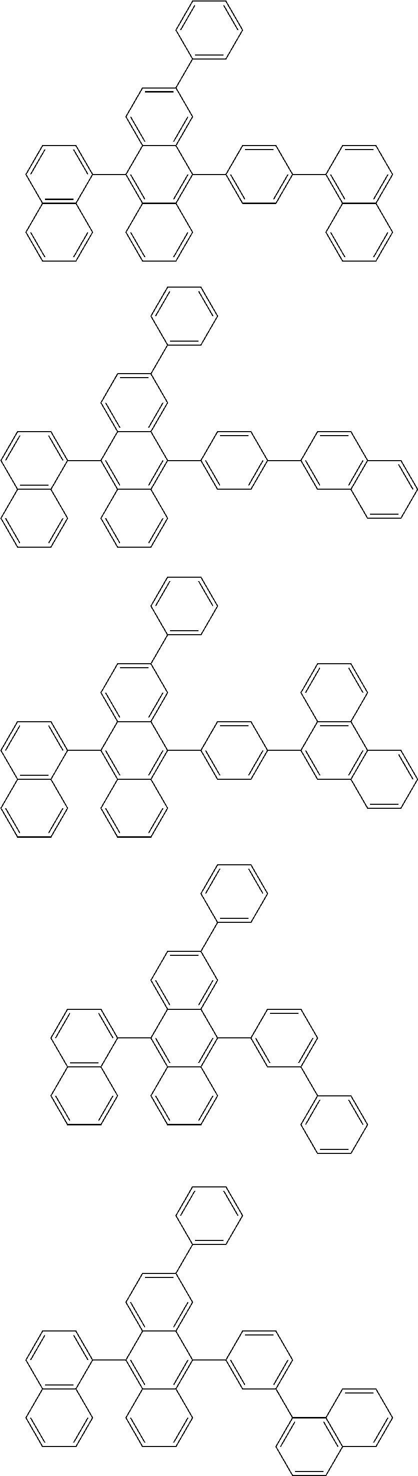

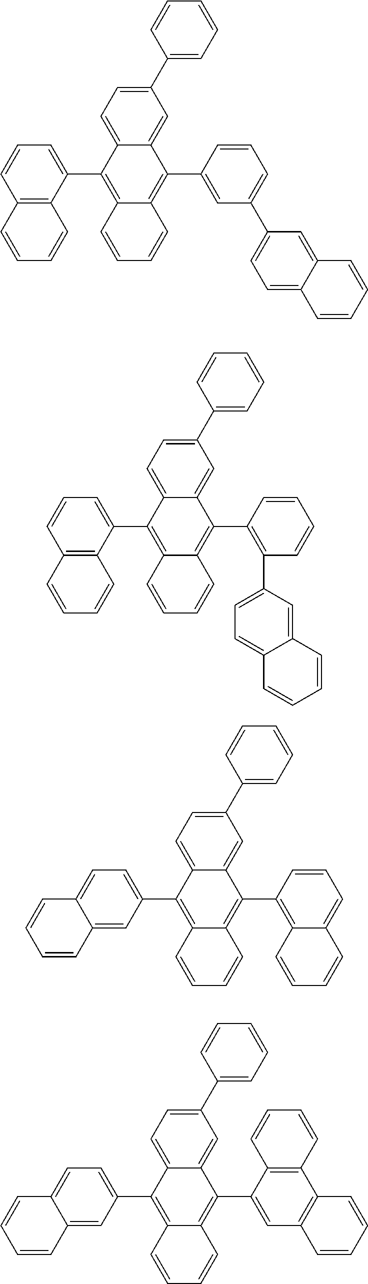

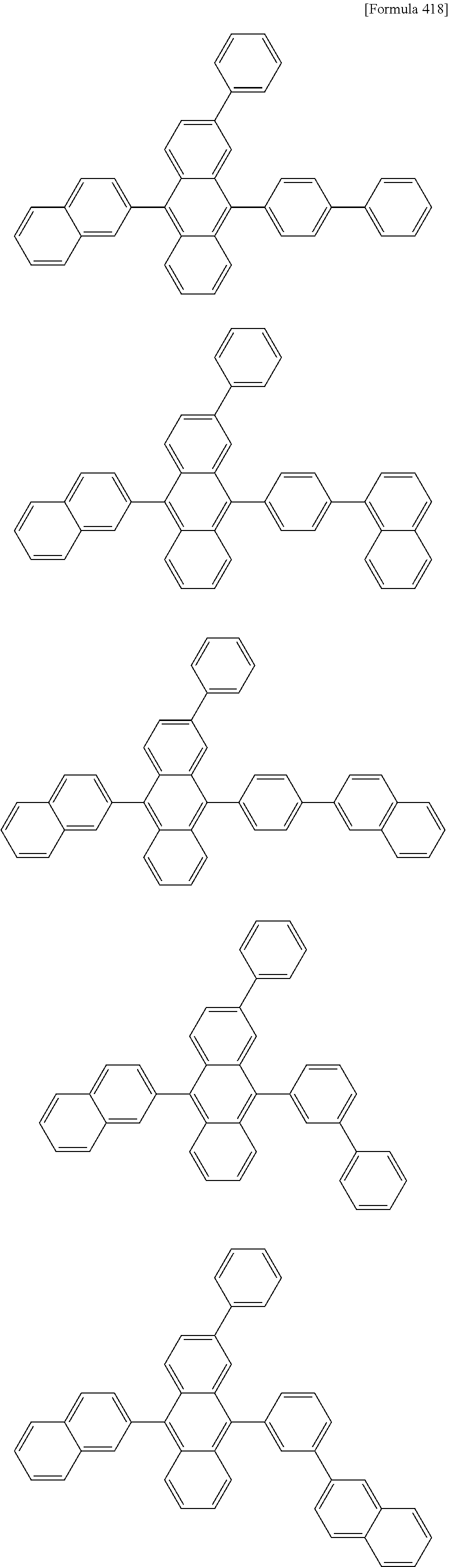

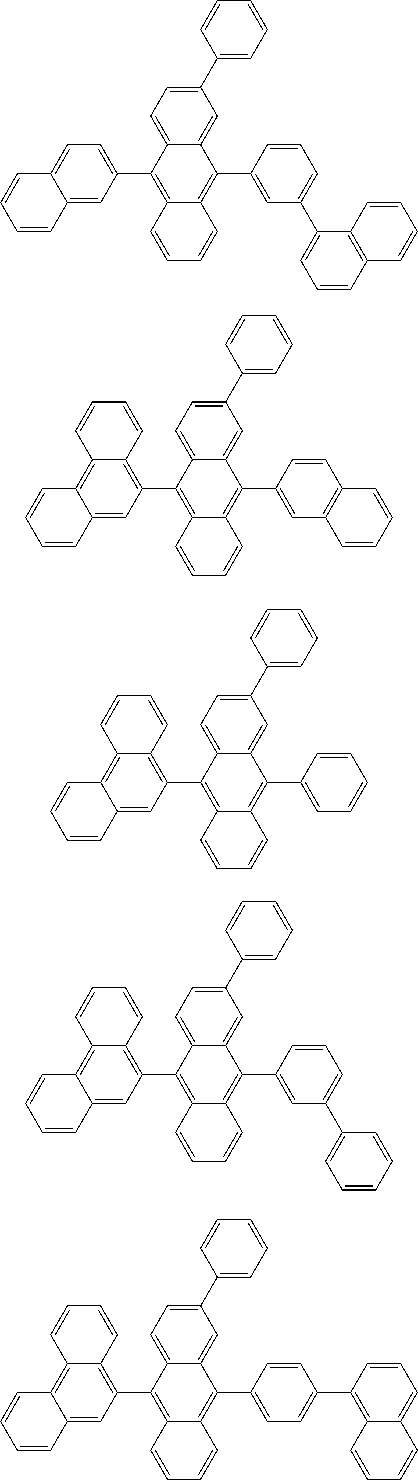

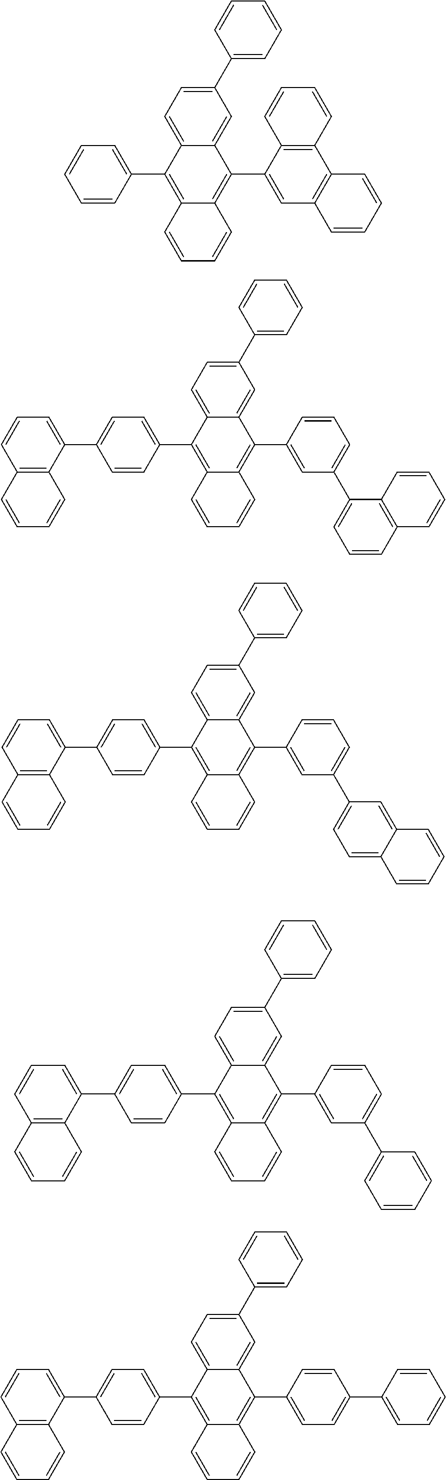

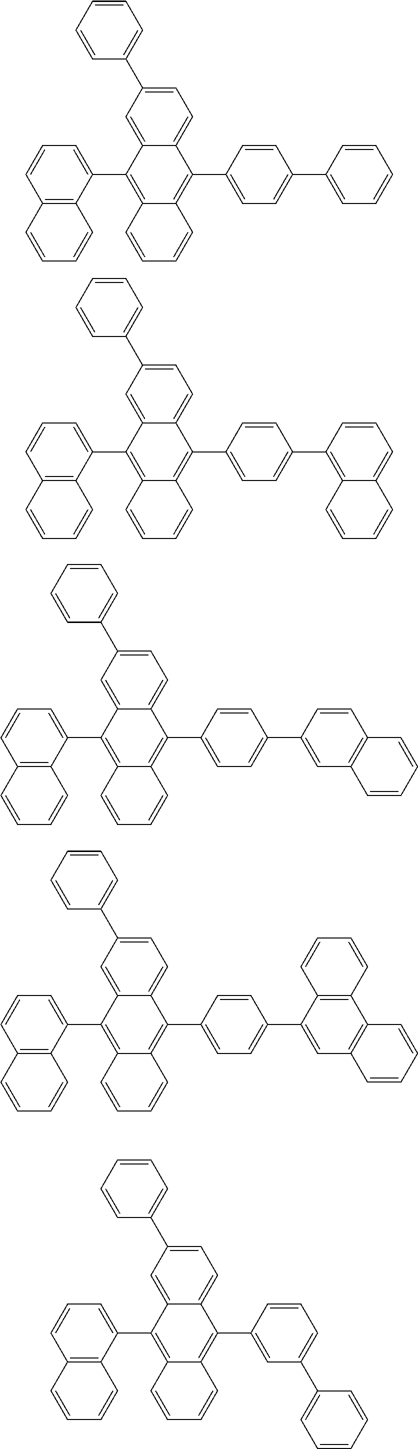

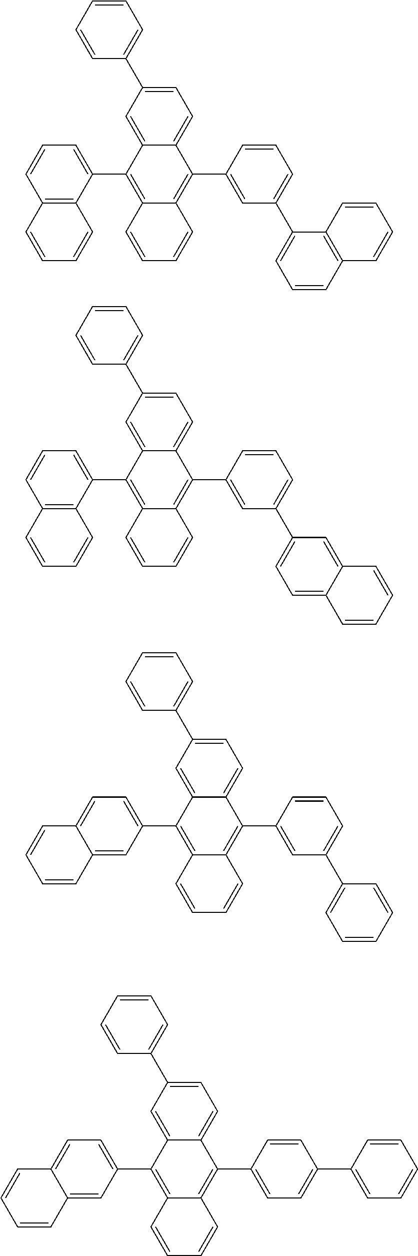

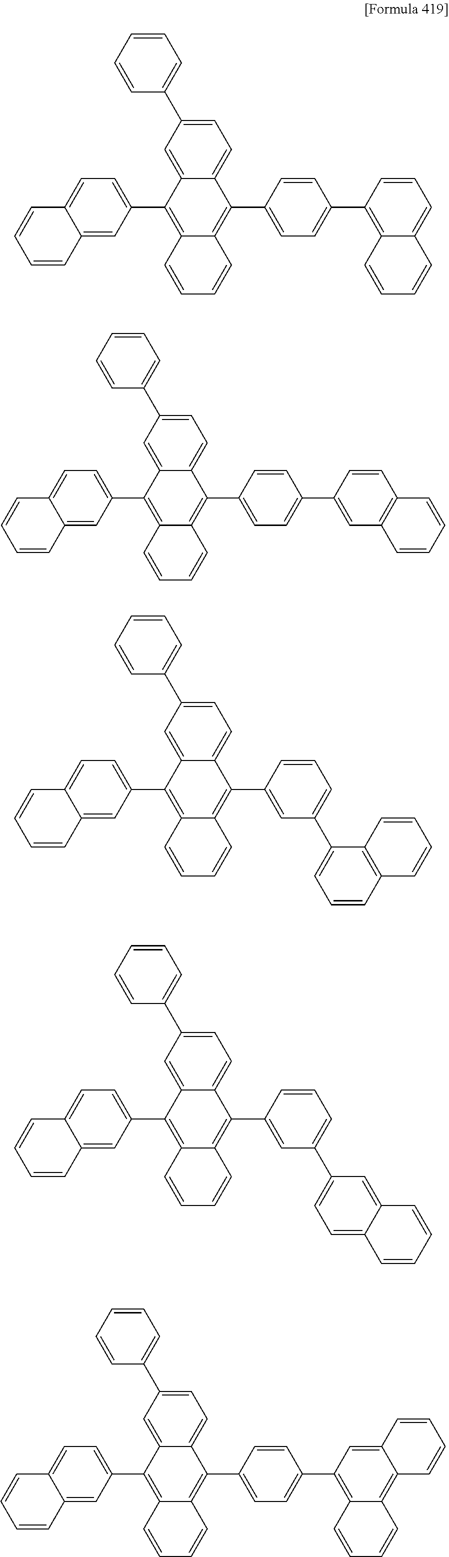

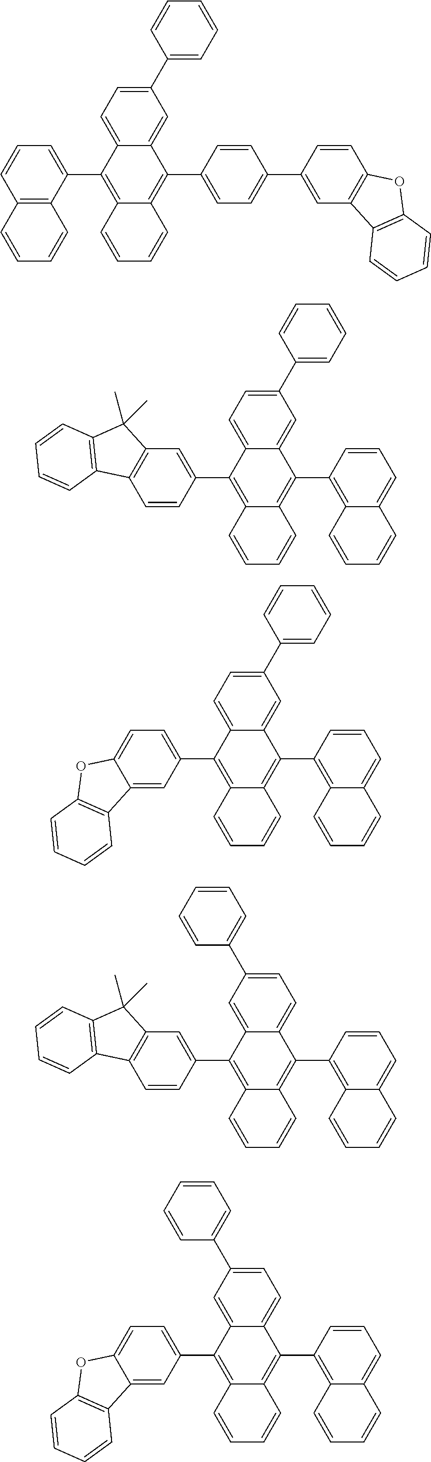

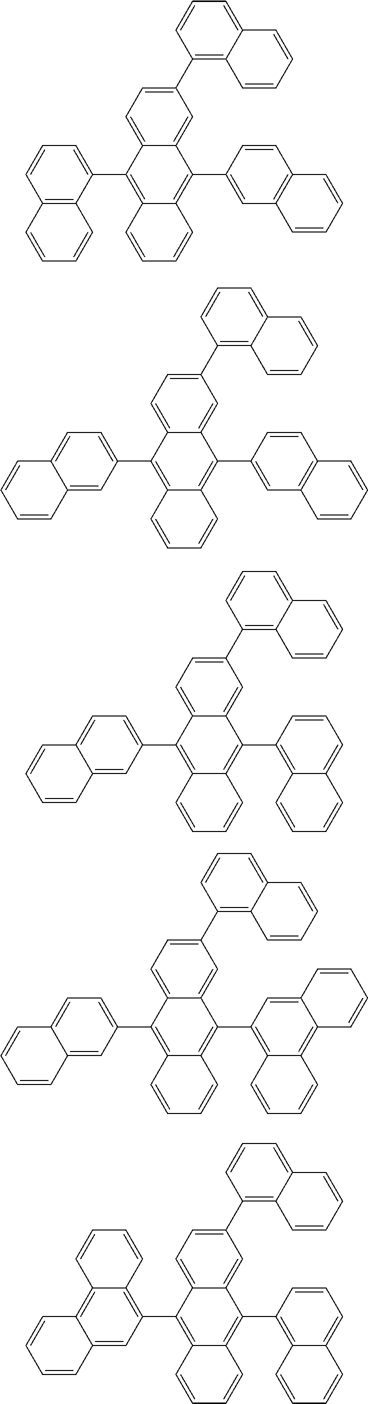

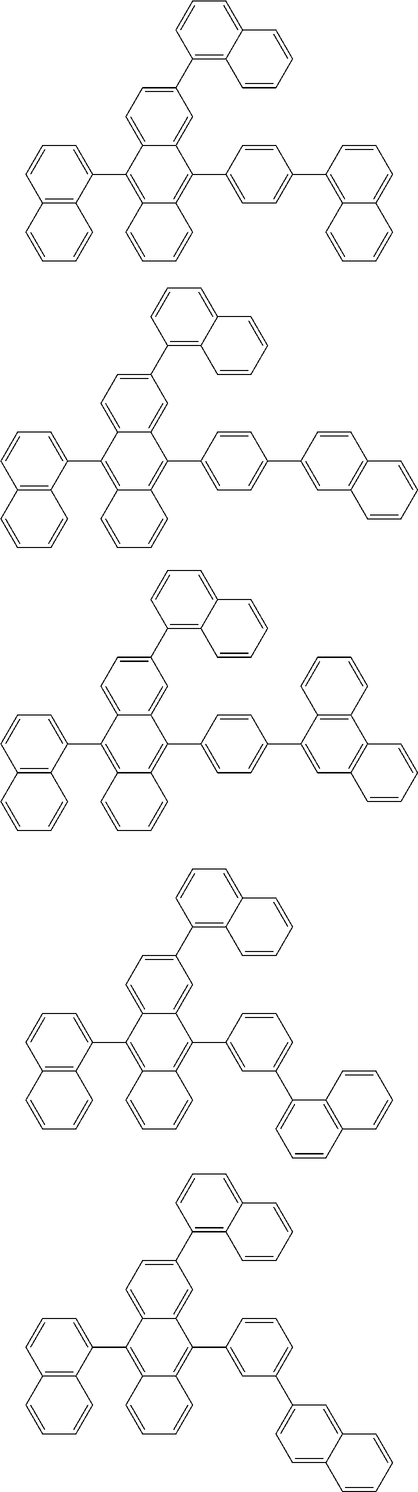

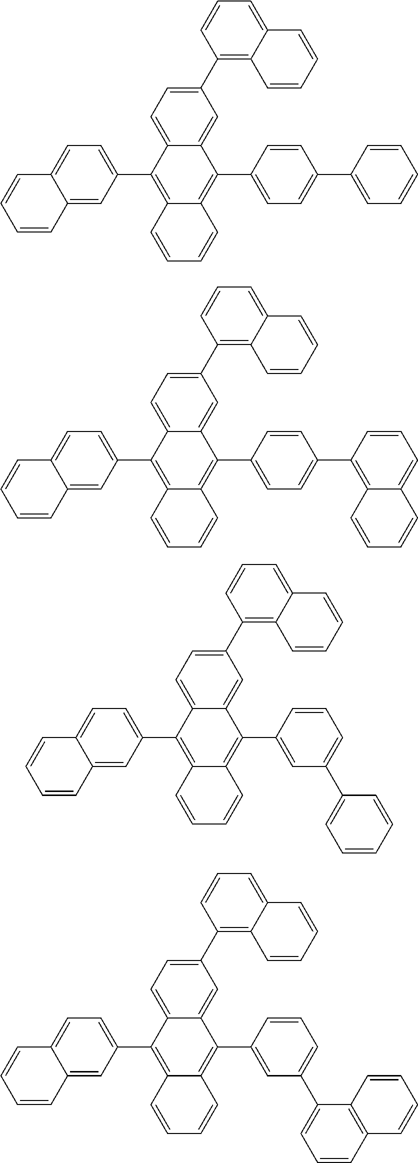

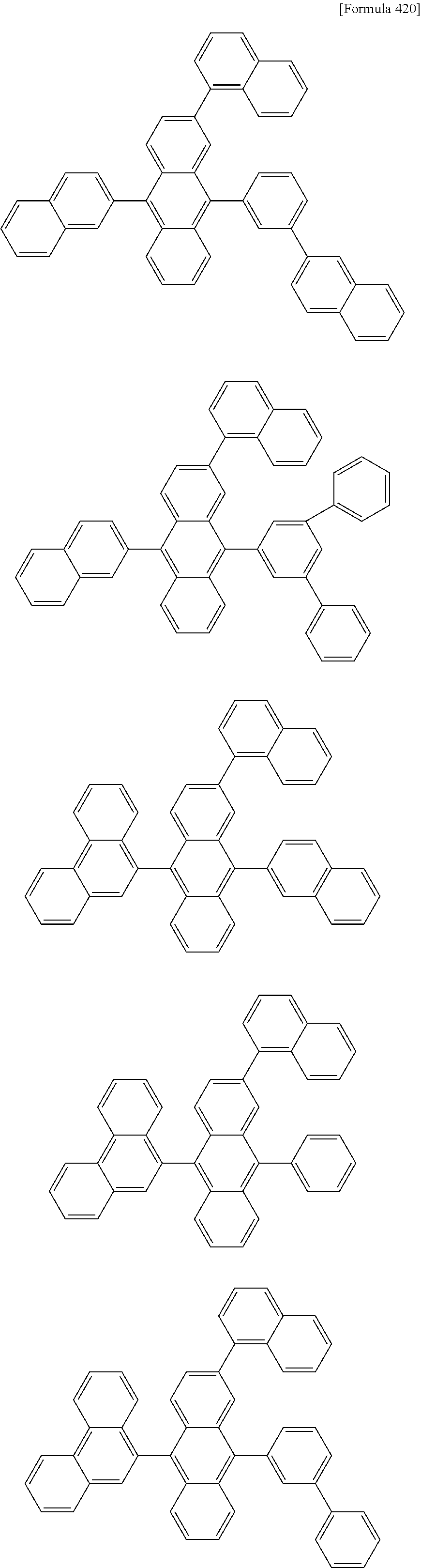

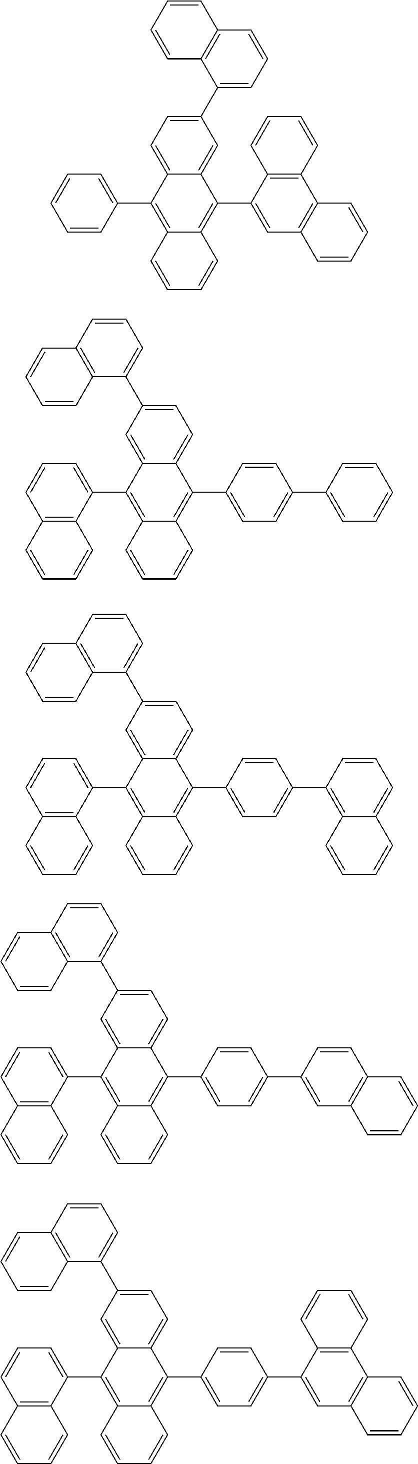

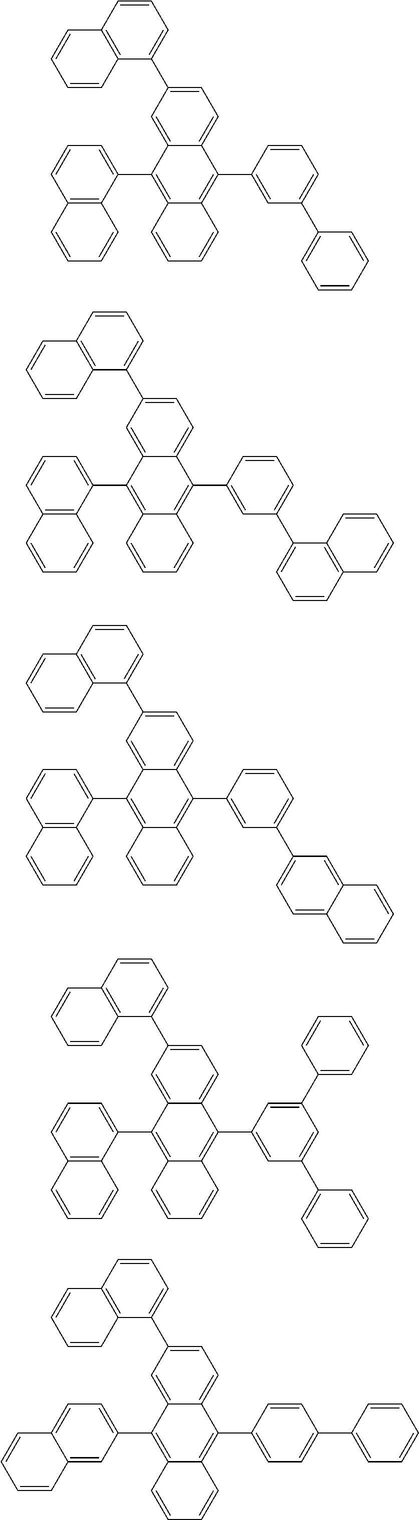

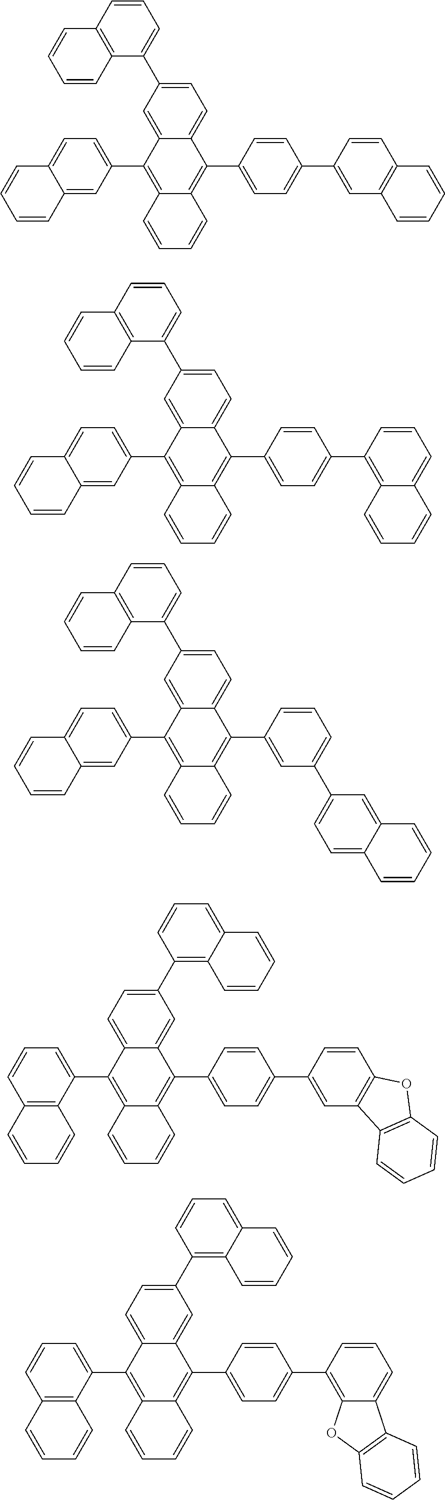

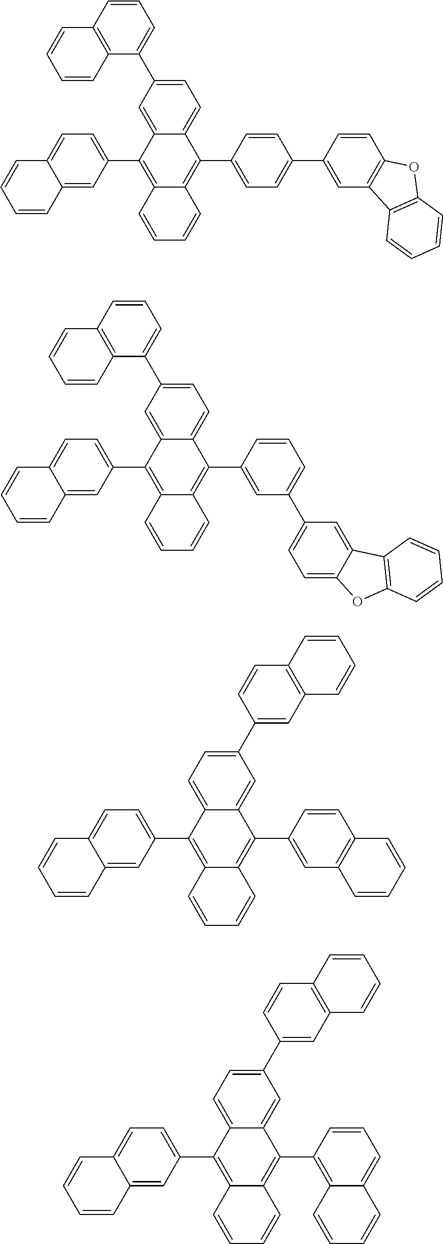

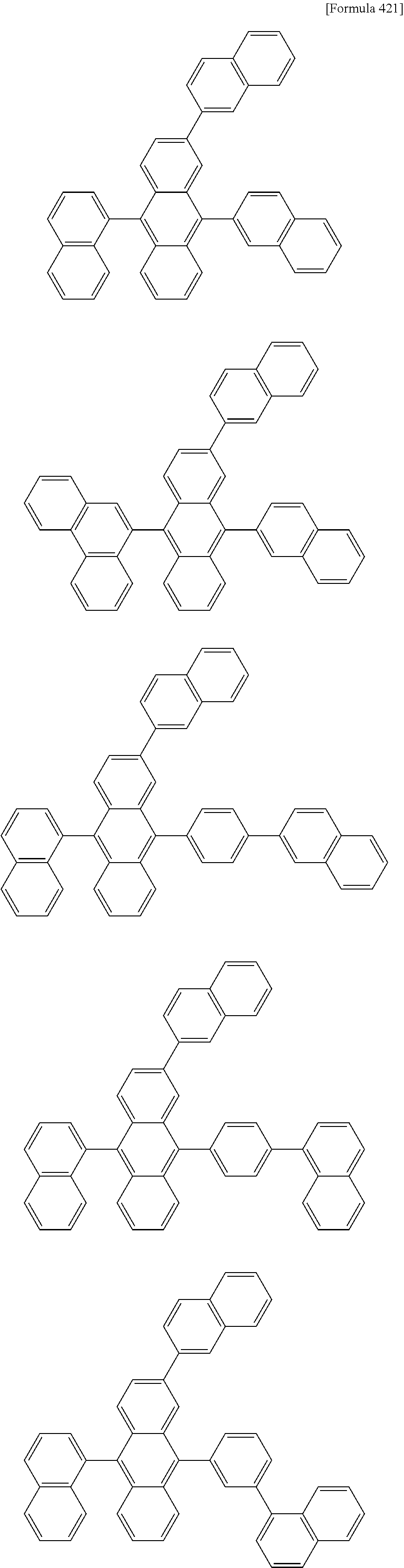

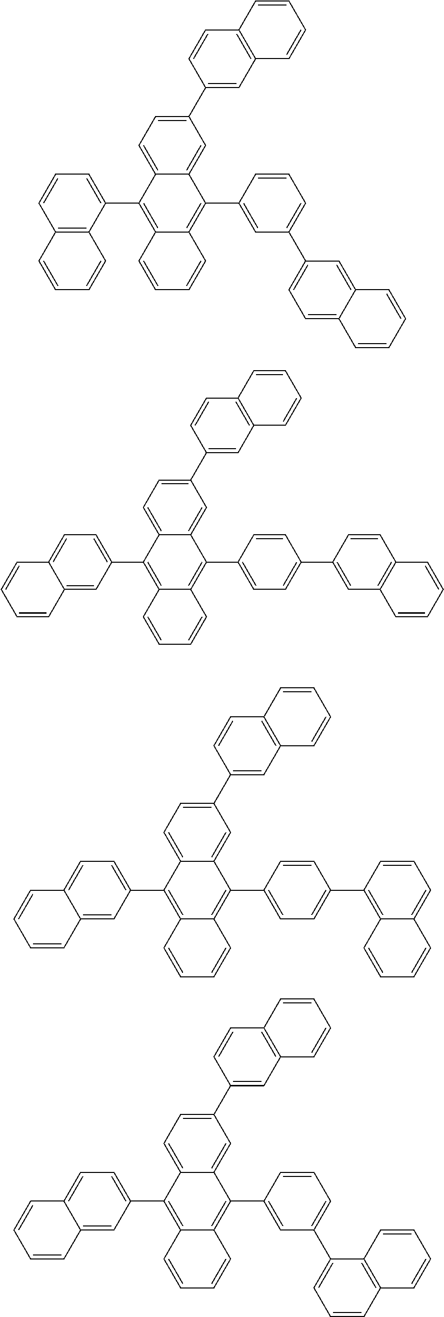

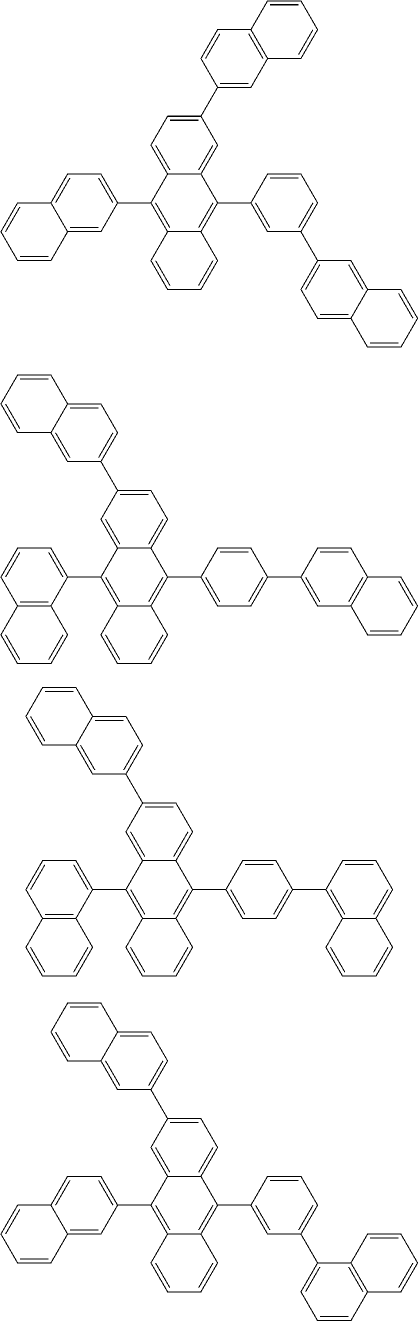

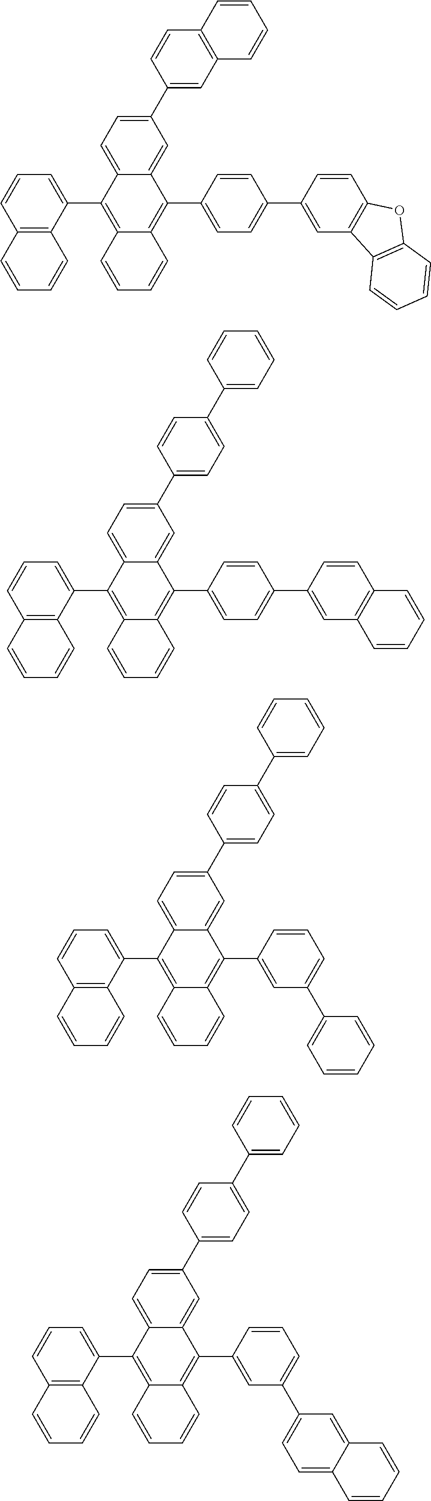

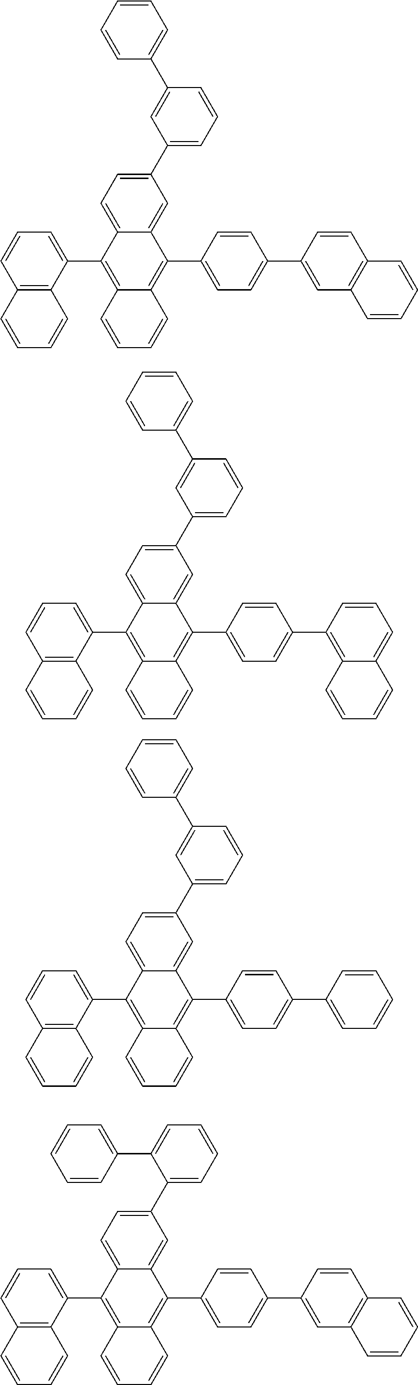

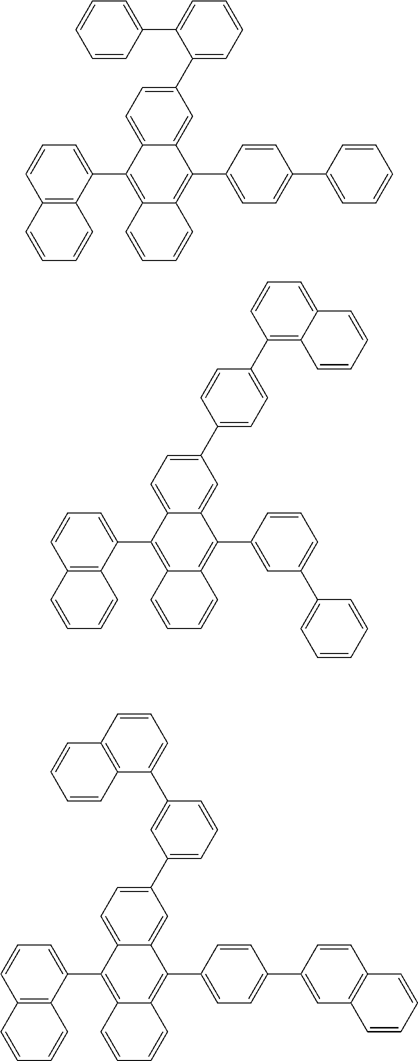

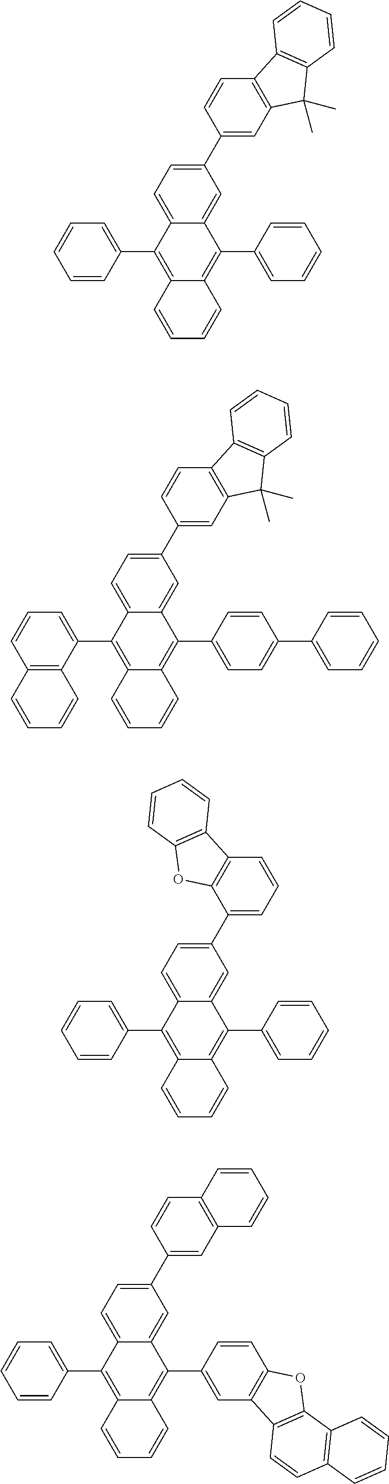

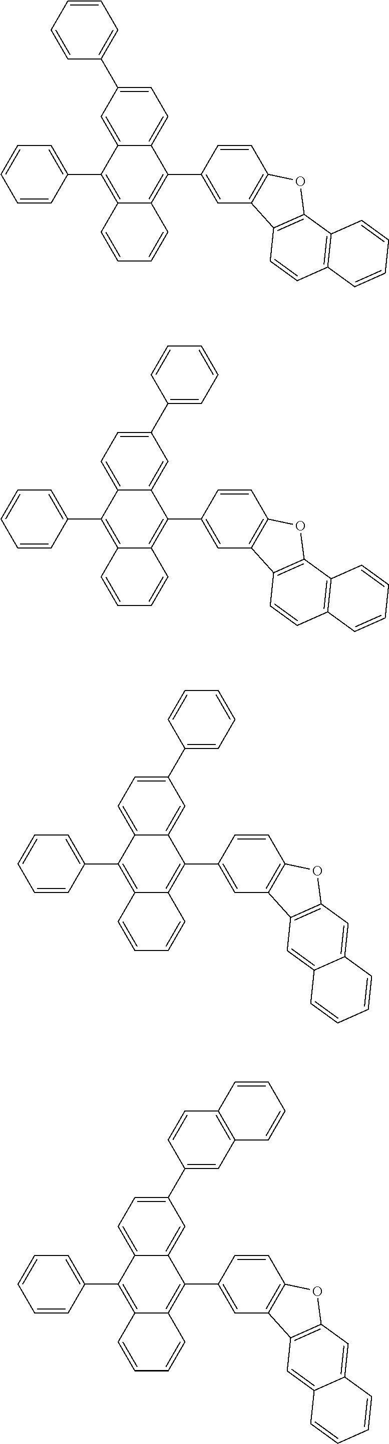 [SMILES: c1ccc(-c2ccc3c(-c4ccc5oc6c7ccccc7ccc6c5c4)c4ccccc4c(-c4ccccc4)c3c2)cc1 ; c1ccc(-c2ccc3c(-c4ccccc4)c4ccccc4c(-c4ccc5oc6c7ccccc7ccc6c5c4)c3c2)cc1 ; c1ccc(-c2ccc3c(-c4ccccc4)c4ccccc4c(-c4ccc5oc6cc7ccccc7cc6c5c4)c3c2)cc1 ; c1ccc(-c2c3ccccc3c(-c3ccc4oc5cc6ccccc6cc5c4c3)c3cc(-c4ccc5ccccc5c4)ccc23)cc1]

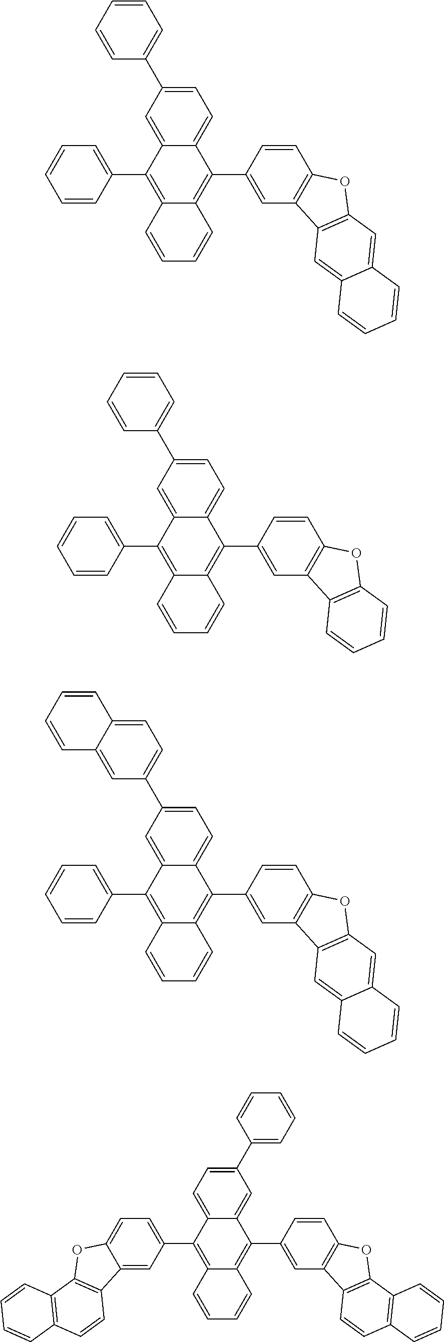 [SMILES: c1ccc(-c2ccc3c(-c4ccc5oc6cc7ccccc7cc6c5c4)c4ccccc4c(-c4ccccc4)c3c2)cc1 ; c1ccc(-c2ccc3c(-c4ccc5oc6ccccc6c5c4)c4ccccc4c(-c4ccccc4)c3c2)cc1 ; c1ccc(-c2c3ccccc3c(-c3ccc4oc5cc6ccccc6cc5c4c3)c3ccc(-c4ccc5ccccc5c4)cc23)cc1 ; c1ccc(-c2ccc3c(-c4ccc5oc6c7ccccc7ccc6c5c4)c4ccccc4c(-c4ccc5oc6c7ccccc7ccc6c5c4)c3c2)cc1]

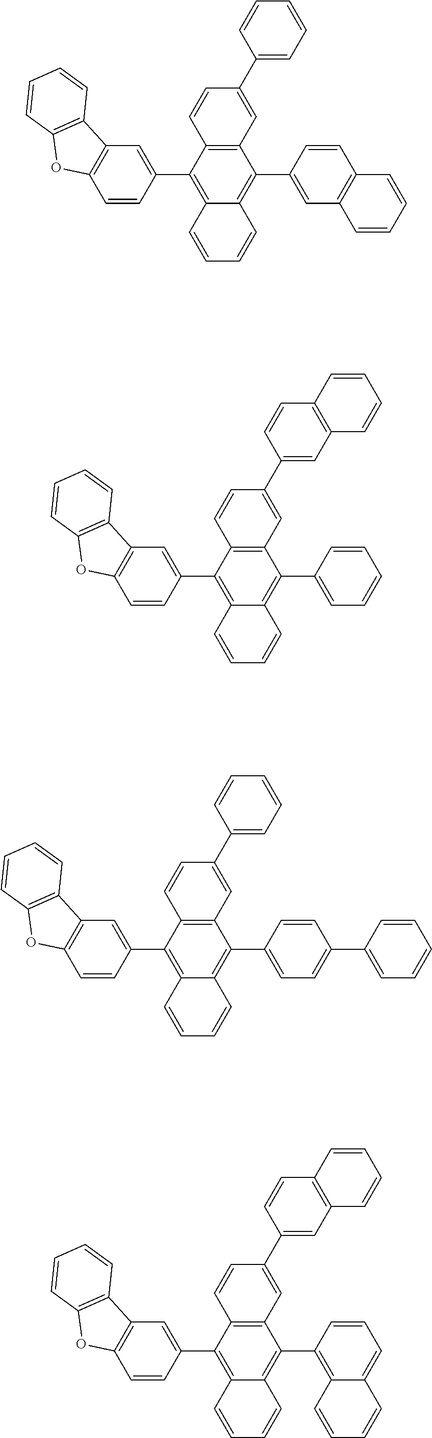 [SMILES: c1ccc(-c2ccc3c(-c4ccc5oc6ccccc6c5c4)c4ccccc4c(-c4ccc5ccccc5c4)c3c2)cc1 ; c1ccc(-c2c3ccccc3c(-c3ccc4oc5ccccc5c4c3)c3ccc(-c4ccc5ccccc5c4)cc23)cc1 ; c1ccc(-c2ccc(-c3c4ccccc4c(-c4ccc5oc6ccccc6c5c4)c4ccc(-c5ccccc5)cc34)cc2)cc1 ; c1ccc2cc(-c3ccc4c(-c5ccc6oc7ccccc7c6c5)c5ccccc5c(-c5cccc6ccccc56)c4c3)ccc2c1]

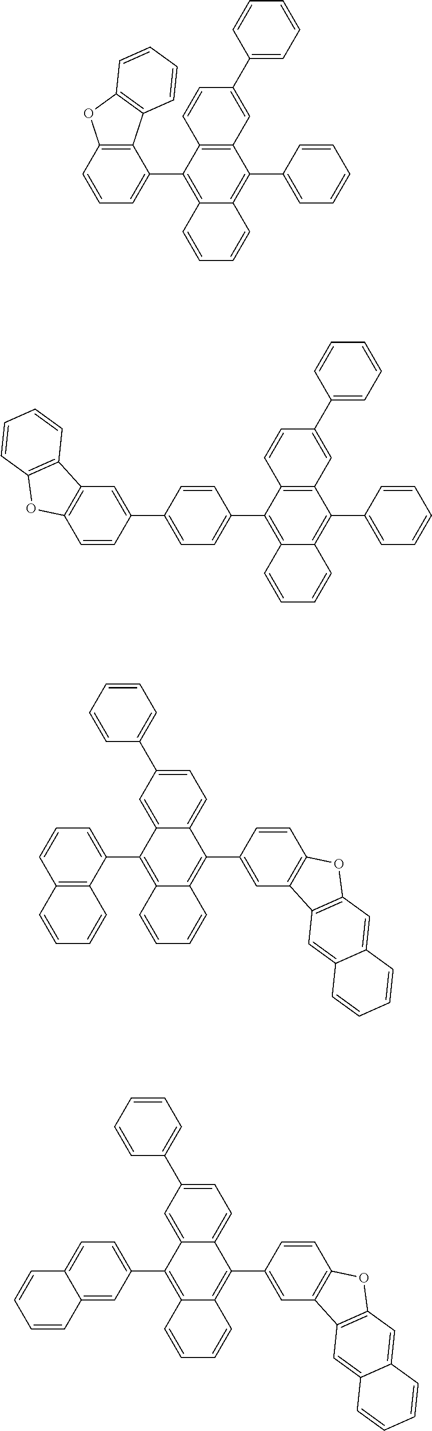 [SMILES: c1ccc(-c2ccc3c(-c4cccc5oc6ccccc6c45)c4ccccc4c(-c4ccccc4)c3c2)cc1 ; c1ccc(-c2ccc3c(-c4ccc(-c5ccc6oc7ccccc7c6c5)cc4)c4ccccc4c(-c4ccccc4)c3c2)cc1 ; c1ccc(-c2ccc3c(-c4ccc5oc6cc7ccccc7cc6c5c4)c4ccccc4c(-c4cccc5ccccc45)c3c2)cc1 ; c1ccc(-c2ccc3c(-c4ccc5oc6cc7ccccc7cc6c5c4)c4ccccc4c(-c4ccc5ccccc5c4)c3c2)cc1]

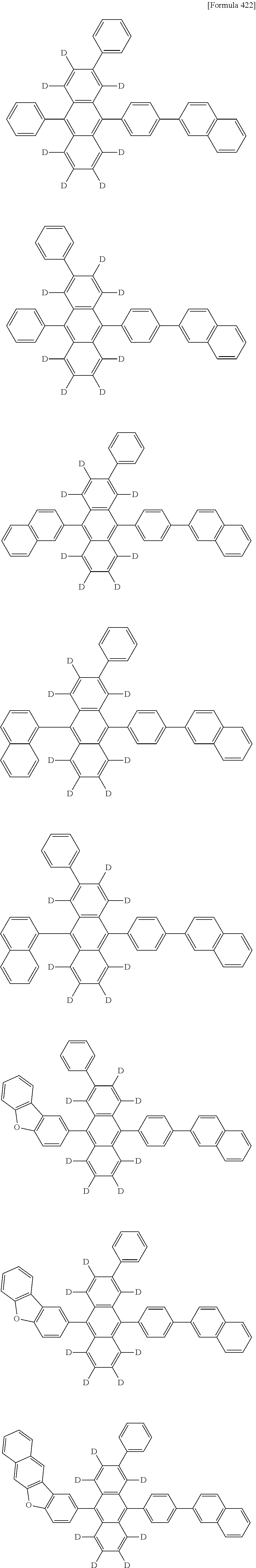

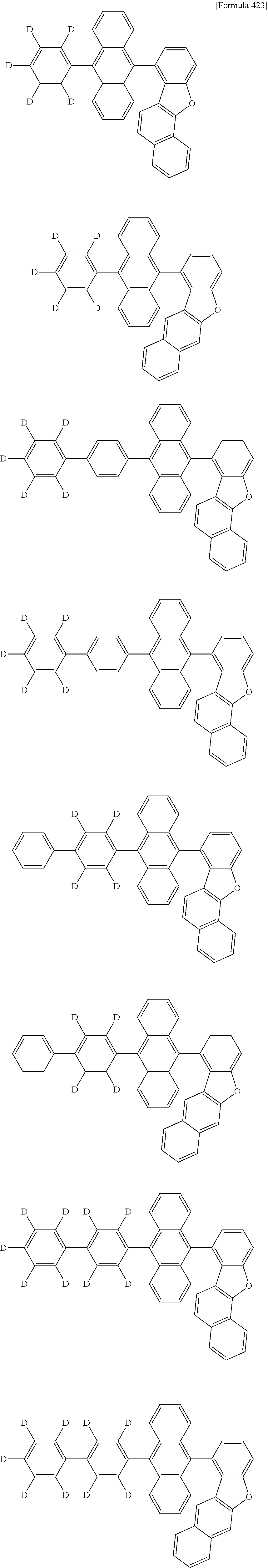

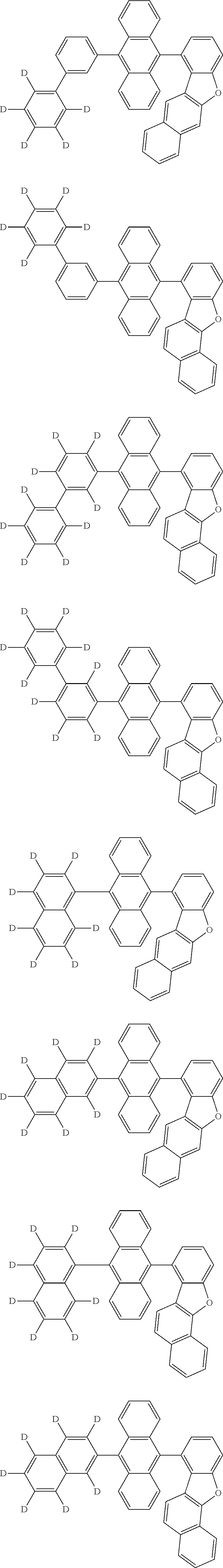

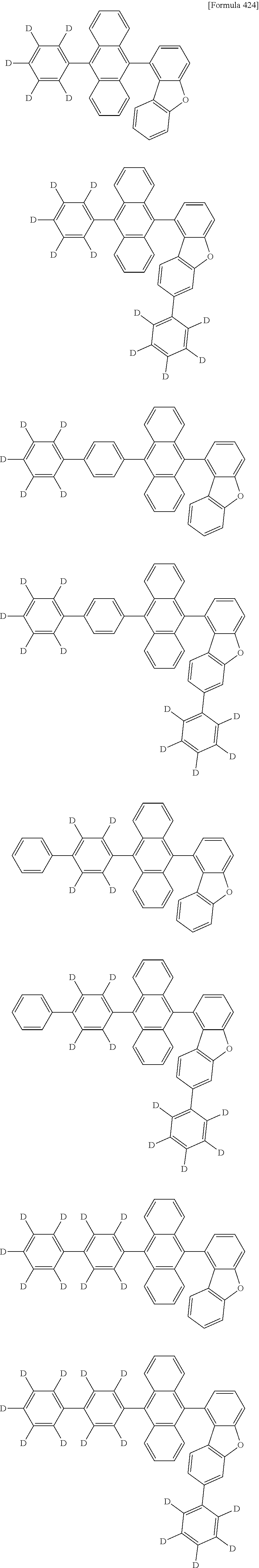

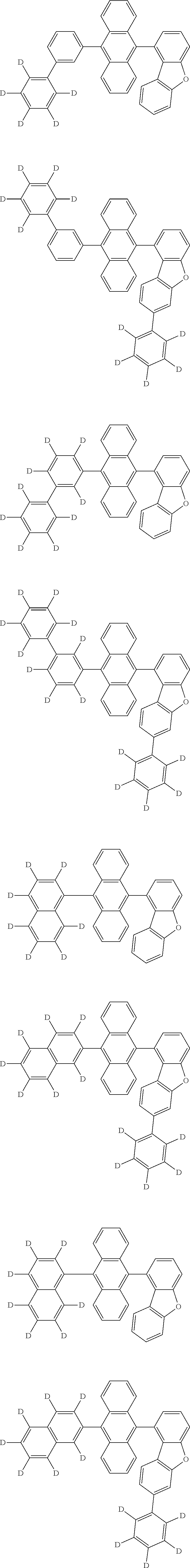

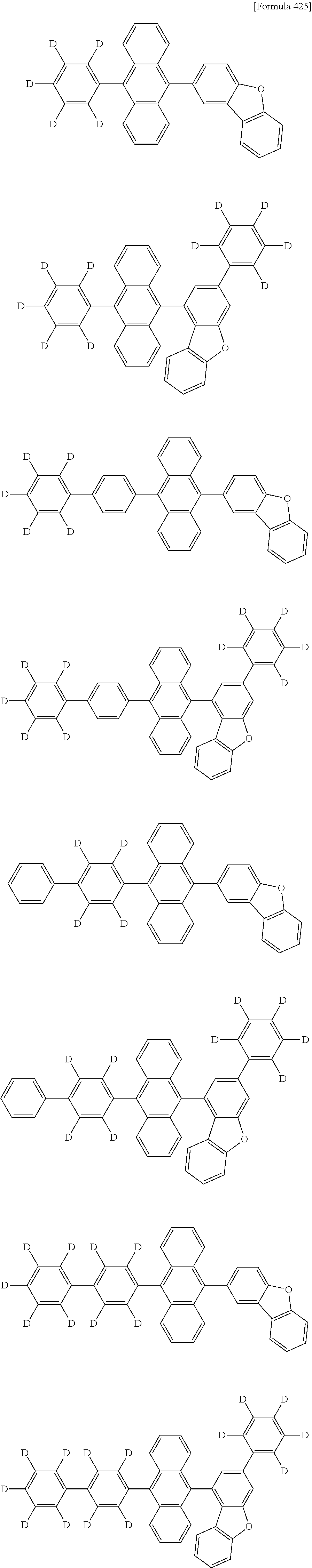

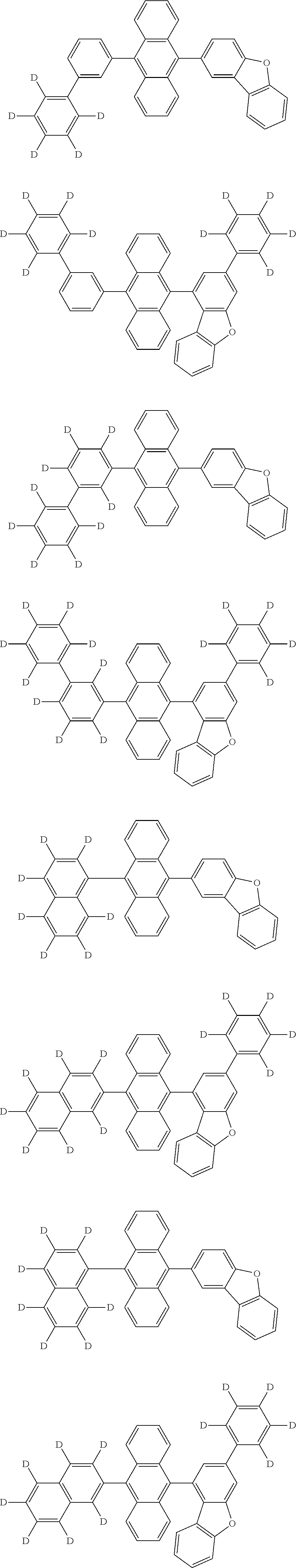

The organic electroluminescent element may comprise an anode, an organic layer, and a cathode.

The organic layer comprises a light-emitting layer. The light-emitting layer is composed of a single layer or a plurality of layers. In addition, the organic layer may comprise an electron transporting zone or a hole transporting zone.

The light-emitting layer comprises the first host compound, the second host compound, the third host compound, and the dopant compound.

The light-emitting layer may be composed of a single layer. For example, the first host compound, the second host compound, the third host compound, and the dopant compound may be contained together in the single layer.

The light-emitting layer may be composed of a plurality of layers.

In an embodiment, the light-emitting layer is formed of a plurality of layers, and it may comprise a first layer comprising the first host compound and the second host compound; and an intermediate layer comprising the third host compound.

The first layer is disposed on the anode side, and the intermediate layer is disposed on the cathode side. For example, the intermediate layer is disposed between the first layer and the cathode.

The dopant compound may be contained in the first layer or may be contained in the intermediate layer. Preferably, the dopant compound may be contained in the intermediate layer to be doped in the third host compound.

In another embodiment, the light-emitting layer is composed of a plurality of layers, and it may comprise a first layer comprising the first host compound and the dopant compound; a second layer comprising the second host compound; and an intermediate layer comprising the third host compound.

The first layer is disposed on the anode side, the second layer is disposed between the first layer and the cathode, and the intermediate layer is interposed between the first layer and the second layer.

The film thickness of the intermediate layer may be 10 nm or less. Preferably, the film thickness of the intermediate layer may be 8 nm or less, or 5 nm or less, more preferably 3 nm or less. Further, the film thickness of the intermediate layer may be 1 nm or more, or 2 nm or more, but it is not limited thereto.

The configuration of the organic electroluminescent element of the third embodiment is further described in “Common Configuration of Each Embodiment” to be described later.

### Common Configuration of Each Embodiment

A schematic configuration of an organic electroluminescent element according to an embodiment of the present invention will be described with reference to the drawings.

FIG. 3 is a schematic diagram illustrating an example of a configuration of an organic electroluminescent element according to an embodiment of the present invention. Referring to FIG. 3, the organic electroluminescent element (10) comprises a substrate (20), an anode (30), a cathode (50), and an organic layer (40) disposed between the anode (30) and the cathode (50).

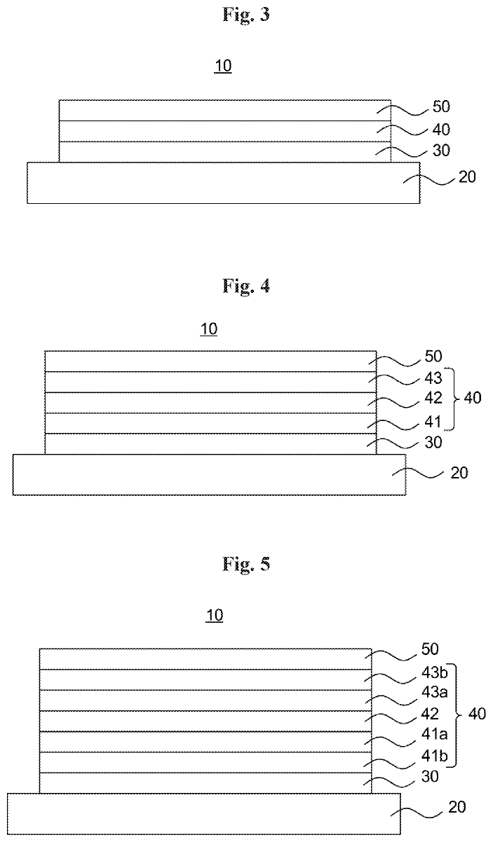

FIG. 4 is a schematic diagram illustrating an example of a configuration of an organic electroluminescent element according to another embodiment of the present invention. Referring to FIG. 4, the organic electroluminescent element (10) comprises a substrate (20), an anode (30), a cathode (50), and an organic layer (40) disposed between the anode (30) and the cathode (50). The organic layer (40) comprises a hole transporting zone (41), a light-emitting layer (42), and an electron transporting zone (43). The hole transporting zone (41) is disposed between the anode (30) and the light-emitting layer (42), and the electron transporting zone (43) is disposed between the cathode (50) and the light-emitting layer (42).

FIG. 5 is a schematic diagram illustrating an example of a configuration of an organic electroluminescent element according to another embodiment of the present invention. Referring to FIG. 5, the organic electroluminescent element (10) comprises a substrate (20), an anode (30), a cathode (50), and an organic layer (40) disposed between the anode (30) and the cathode (50). The organic layer (40) comprises a hole transporting zone (41), a light-emitting layer (42), and an electron transporting zone (43). The hole transporting zone (41) comprises a hole injecting layer (41b) and a hole transporting layer (41a). The electron transporting zone (43) comprises an electron transporting layer (43a) and an electron injecting layer (43b). The hole injecting layer (41b) is disposed between the anode (30) and the hole transporting layer (41a), and the hole transporting layer (41a) is disposed between the hole injecting layer (41b) and the light-emitting layer (42). The electron injecting layer (43b) is disposed between the cathode (50) and the electron transporting layer (43a), and the electron transporting layer (43a) is disposed between the electron injecting layer (43b) and the light-emitting layer (42).

In FIGS. 3 to 5, the light-emitting layer (42) comprises at least one light-emitting layer. The light-emitting layer (42) may be composed of a single layer, or it may be composed of a plurality of layers.

The organic electroluminescent element according to an aspect of the present invention may be a monochromatic light-emitting element of a fluorescent or phosphorescent light emission type, it may be a white light-emitting element of a fluorescent/phosphorescent hybrid type, it may be a simple type having a single light-emitting unit, or it may be a tandem-type having a plurality of light-emitting units. Preferably, it is a fluorescent emitting element.

Meanwhile, the “light-emitting unit” described in the present specification refers to a minimum unit that comprises an organic layer, wherein at least one layer of the organic layer is a light-emitting layer, and that emits light by recombination of injected holes and electrons.

In addition, the “light-emitting layer” described in the present specification is an organic layer having a light-emitting function. The light-emitting layer is, for example, a phosphorescent light-emitting layer, a fluorescent light-emitting layer, or the like, and it may be a single layer or a plurality of layers.

For example, as typical device configurations of a simple type organic EL element, the following device configurations may be exemplified.

### (1) Anode/Light-Emitting Unit/Cathode

Typical layer configurations of a simple type light-emitting unit are shown below. Layers in parentheses are optional layers.
(a) (hole injecting layer/) hole transporting layer/fluorescent light-emitting layer (/electron transporting layer/electron injecting layer)
(b) (hole injecting layer/) hole transporting layer/phosphorescent light-emitting layer (/electron transporting layer/electron injecting layer)
(c) (hole injecting layer/) hole transporting layer/first fluorescent light-emitting layer/second fluorescent light-emitting layer (/electron transporting layer/electron injecting layer)
(d) (hole injecting layer/) hole transporting layer/first phosphorescent light-emitting layer/second phosphorescent light-emitting layer (/electron transporting layer/electron injecting layer)
(e) (hole injecting layer/) hole transporting layer/phosphorescent light-emitting layer/space layer/fluorescent light-emitting layer (/electron transporting layer/electron injecting layer)
(f) (hole injecting layer/) hole transporting layer/first phosphorescent light-emitting layer/second phosphorescent light-emitting layer/space layer/fluorescent light-emitting layer (/electron transporting layer/electron injecting layer)
(g) (hole injecting layer/) hole transporting layer/first phosphorescent light-emitting layer/space layer/second phosphorescent light-emitting layer/space layer/fluorescent light-emitting layer (/electron transporting layer/electron injecting layer)
(h) (hole injecting layer/) hole transporting layer/phosphorescent light-emitting layer/space layer/first fluorescent light-emitting layer/second fluorescent light-emitting layer (/electron transporting layer/electron injecting layer)
(i) (hole injecting layer/) hole transporting layer/electron blocking layer/fluorescent light-emitting layer (/electron transporting layer/electron injecting layer)
(j) (hole injecting layer/) hole transporting layer/electron blocking layer/phosphorescent light-emitting layer (/electron transporting layer/electron injecting layer)
(k) (hole injecting layer/) hole transporting layer/exciton blocking layer/fluorescent light-emitting layer (/electron transporting layer/electron injecting layer)
(l) (hole injecting layer/) hole transporting layer/exciton blocking layer/phosphorescent light-emitting layer (/electron transporting layer/electron injecting layer)
(m) (hole injecting layer/) first hole-transport layer/second hole-transport layer/fluorescent light-emitting layer (/electron-transport layer/electron injecting layer)
(n) (hole injecting layer/) first hole transporting layer/second hole transporting layer/fluorescent light-emitting layer (/first electron transporting layer/second electron transporting layer/electron injecting layer)
(o) (hole injecting layer/) first hole transporting layer/second hole transporting layer/phosphorescent light-emitting layer (/electron transporting layer/electron injecting layer)
(p) (hole injecting layer/) first hole transporting layer/second hole transporting layer/phosphorescent light-emitting layer (/first electron transporting layer/second electron transporting layer/electron injecting layer)
(q) (hole injecting layer/) hole transporting layer/fluorescent light-emitting layer/hole blocking layer (/electron transporting layer/electron injecting layer/electron injecting layer)
(r) (hole injecting layer/) hole transporting layer/phosphorescent light-emitting layer/hole blocking layer (/electron transporting layer/electron injecting layer)
(s) (hole injecting layer/) hole transporting layer/fluorescent light-emitting layer/exciton blocking layer (/electron transporting layer/electron injecting layer)
(t) (hole injecting layer/) hole transporting layer/phosphorescent light-emitting layer/exciton blocking layer (/electron transporting layer/electron injecting layer)

Each of the phosphorescent or fluorescent light-emitting layers may exhibit different emission colors from each other. Specifically, in the light-emitting unit (d), a layer configuration such as (hole injecting layer/) hole transporting layer/first phosphorescent light-emitting layer (red emission)/second phosphorescent light-emitting layer (green emission)/space layer/fluorescent light-emitting layer (blue emission)/electron transporting layer may be exemplified.

Meanwhile, an electron blocking layer may be provided as appropriate between the light-emitting layer and the hole transporting layer or the space layer, respectively. In addition, a hole blocking layer may be provided as appropriate between the light-emitting layer and the electron-transport layer, respectively. As an electron blocking layer or a hole blocking layer is provided, electrons or holes can be confined within the light-emitting layer, so that the probability of charge recombination in the light-emitting layer can be increased, and the luminous efficiency can be enhanced.

As typical device configurations of a tandem-type organic EL element, the following device configurations may be exemplified.

### (2) Anode/First Light-Emitting Unit/Intermediate Layer/Second Light-Emitting Unit/Cathode

Here, the first light-emitting unit and the second light-emitting unit may each independently be selected, for example, from the light-emitting units described above.

The intermediate layer is generally also referred to as an intermediate electrode, an intermediate conductive layer, a charge generation layer, an electron extraction layer, a connection layer, or an intermediate insulating layer. A known material configuration that supplies electrons to the first light-emitting unit and holes to the second light-emitting unit may be used.

### (Substrate)

The organic electroluminescent element may comprise a substrate. The substrate may be used as a support for organic electroluminescent irradiation. As the substrate, for example, a plate of glass, quartz, plastic, or the like may be used. In addition, a flexible substrate may be used as the substrate of the organic electroluminescent element. As the flexible substrate, for example, plastic substrates made of polycarbonate, polyarylate, polyethersulfone, polypropylene, polyester, polyvinyl fluoride, polyvinyl chloride, or the like may be exemplified. In addition, an inorganic vapor deposition film may be used as the substrate of the organic electroluminescent element.

### (Anode)

An anode is formed on the substrate. It is preferable to use, for the anode, a metal, an alloy, an electrically conductive compound, or a mixture thereof having a large work function (e.g., 4.0 eV or more). Specifically, for the anode, for example, indium tin oxide (ITO), indium tin oxide containing silicon or silicon oxide, indium zinc oxide, indium oxide containing tungsten oxide and zinc oxide, graphene, or the like may be used. In addition, gold (Au), platinum (Pt), nickel (Ni), tungsten (W), chromium (Cr), molybdenum (Mo), iron (Fe), cobalt (Co), copper (Cu), palladium (Pd), titanium (Ti), or nitrides of such metals (e.g., titanium nitride) may be used for the anode.

The materials described above may be formed into a film by a sputtering method. For example, indium zinc oxide may be formed by a sputtering method by using a target to which 1% by weight to 10% by weight of zinc oxide is added to indium oxide, and indium oxide containing tungsten oxide and zinc oxide may be formed by a sputtering method by using a target containing 0.5% by weight to 5% by weight of tungsten oxide and 0.1% by weight to 1% by weight of zinc oxide with respect to indium oxide. In addition, it may be formed by a vacuum deposition method, a coating method, an ink jet method, a spin coating method, or the like.

When a hole injecting layer is formed in contact with the anode, since the hole injecting layer is formed using a material that facilitates hole injection regardless of the work function of the anode, materials generally used as electrode materials (for example, metals, alloys, electrically conductive compounds, and mixtures thereof, and elements belonging to Group 1 or Group 2 of the Periodic Table of the Elements) may be used for the anode.

In such a case, for the anode, materials having a small work function, namely, elements belonging to Group 1 or Group 2 of the Periodic Table of the Elements, that is, alkali metals such as lithium (Li) and cesium (Cs), alkaline earth metals such as magnesium (Mg), calcium (Ca), and strontium (Sr), and alloys comprising them (e.g., MgAg, AlLi), rare earth metals such as europium (Eu) and ytterbium (Yb), and alloys comprising them may also be used.

Meanwhile, when an anode is formed using an alkali metal, an alkaline earth metal, and an alloy comprising them, a vacuum deposition method or a sputtering method may be used. In addition, when silver paste or the like is used, a coating method, an ink jet method, or the like may be used.

### (Cathode)

It is preferable to use, for a cathode, a metal, an alloy, an electrically conductive compound, or a mixture thereof having a small work function (specifically, 3.8 eV or less). Specific examples of such cathode materials include elements belonging to Group 1 or Group 2 of the Periodic Table of the Elements, that is, alkali metals such as lithium (Li) and cesium (Cs), alkaline earth metals such as magnesium (Mg), calcium (Ca), and strontium (Sr), and alloys comprising them (e.g., MgAg, AlLi), rare earth metals such as europium (Eu) and ytterbium (Yb), and alloys comprising them.

Meanwhile, when a cathode is formed using an alkali metal, an alkaline earth metal, and an alloy comprising them, a vacuum deposition method or a sputtering method may be used. In addition, when silver paste or the like is used, a coating method, an ink jet method, or the like may be used.

When an electron injecting layer is provided on one side of the cathode, various conductive materials such as A1, Ag, ITO, graphene, indium tin oxide containing silicon or silicon oxide, or the like may be used to form the cathode, regardless of the magnitude of the work function. These conductive materials may be formed into a film by using a sputtering method, an ink jet method, a spin coating method, or the like.

### (Hole Transporting Zone)

The organic layer comprises a hole transporting zone disposed between the anode and the light-emitting layer.

The hole transporting zone comprises at least one or more layers having a hole transport function. The hole transporting zone may comprise a hole injecting layer, a hole transporting layer, an electron blocking layer, or the like.

The hole transporting zone may be composed of a single layer, or it may be composed of a plurality of layers.

In an embodiment, the hole transporting zone comprises a hole transporting layer.

The hole transporting layer comprises a material having high hole transporting capabilities (hole transporting material). The hole transporting layer may comprise a hole transporting material alone or in plural combinations. As the hole transporting material, for example, aromatic amine compounds, carbazole derivatives, anthracene derivatives, or the like may be used.

As the aromatic amine compound, for example, 4,4′-bis[N-(1-naphthyl)-N-phenylamino]biphenyl (abbreviated as NPB), N,N′-bis(3-methylphenyl)-N,N′-diphenyl-[1,1′-biphenyl]-4,4′-diamine (abbreviated as TPD), 4-phenyl-4′-(9-phenylfluoren-9-yl)triphenylamine (abbreviated as BAFLP), 4,4′-bis[N-(9,9-dimethylfluoren-2-yl)-N-phenylamino]biphenyl (abbreviated as DFLDPBi), 4,4′,4″-tris(N,N-diphenylamino)triphenylamine (abbreviated as TDATA), 4,4′,4″-tris[N-(3-methylphenyl)-N-phenylamino]triphenylamine (abbreviated as MTDATA), and 4,4′-bis[N-(spiro-9,9′-bifluoren-2-yl)-N-phenylamino]biphenyl (abbreviated as BSPB) may be exemplified. These aromatic amine compounds have a hole mobility of 10-6 cm²/Vs or more.

As the carbazole derivative, for example, 4,4′-di(9-carbazolyl) biphenyl (abbreviated as CBP), 9-[4-(9-carbazolyl)phenyl]-10-phenylanthracene (abbreviated as CzPA), and 9-phenyl-3-[4-(10-phenyl-9-anthryl)phenyl]-9H-carbazole (abbreviated as PCzPA) may be exemplified.

As the anthracene derivative, for example, 2-t-butyl-9,10-di(2-naphthyl) anthracene (abbreviated as t-BuDNA), 9,10-di(2-naphthyl) anthracene (abbreviated as DNA), and 9,10-diphenylanthracene (abbreviated as DPAnth) may be exemplified.

Polymer compounds such as poly(N-vinylcarbazole) (abbreviated as PVK) and poly(4-vinyltriphenylamine) (abbreviated as PVTPA) may also be used.

However, as long as it is a compound having higher hole transporting capabilities than electron transporting capabilities, compounds other than those described above may be used as the hole transporting material.

The hole transporting layer may have a single-layer structure or may have a multilayer structure comprising two or more layers. For example, the hole transporting layer may have a two-layer structure comprising a first hole transporting layer (anode side) and a second hole transporting layer (cathode side).

In an embodiment, the hole transporting zone comprises a hole transporting layer and a hole injecting layer.

The hole injecting layer comprises a material having high hole injection capabilities (hole injecting material). The hole injecting material may be used alone or in plural combinations in the hole injecting layer.

As the hole injecting material, molybdenum oxide, titanium oxide, vanadium oxide, rhenium oxide, ruthenium oxide, chromium oxide, zirconium oxide, hafnium oxide, tantalum oxide, silver oxide, tungsten oxide, manganese oxide, or the like may be used.

Examples of the hole injecting layer material also include aromatic amine compounds, which are low-molecular-weight organic compounds, such as 4,4′,4″-tris(N,N-diphenylamino)triphenylamine (abbreviated as TDATA), 4,4′,4″-tris[N-(3-methylphenyl)-N-phenylamino]triphenylamine (abbreviated as MTDATA), 4,4′-bis[N-(4-diphenylaminophenyl)-N-phenylamino]biphenyl (abbreviated as DPAB), 4,4′-bis(N-{4-[N′-(3-methylphenyl)-N′-phenylamino]phenyl}-N-phenylamino) biphenyl (abbreviated as DNTPD), 1,3,5-tris[N-(4-diphenylaminophenyl)-N-phenylamino]benzene (abbreviated as DPA3B), 3-[N-(9-phenylcarbazol-3-yl)-N-phenylamino]-9-phenylcarbazole (abbreviated as PCzPCA1), 3,6-bis[N-(9-phenylcarbazol-3-yl)-N-phenylamino]-9-phenylcarbazole (abbreviated as PCzPCA2), and 3-[N-(1-naphthyl)-N-(9-phenylcarbazol-3-yl)amino]-9-phenylcarbazole (abbreviated as PCzPCN1).

As the hole injecting material, polymer compounds (oligomers, dendrimers, polymers, etc.) may also be used. For example, polymer compounds such as poly(N-vinylcarbazole) (abbreviated as PVK), poly(4-vinyltriphenylamine) (abbreviated as PVTPA), poly[N-(4-{N′-[4-(4-diphenylamino)phenyl]phenyl-N′-phenylamino}phenyl) methacrylamide] (abbreviated as PTPDMA), and poly[N,N′-bis(4-butylphenyl)-N,N′-bis(phenyl)benzidine] (abbreviated as Poly-TPD) may be exemplified. In addition, polymer compounds, such as poly(3,4-ethylenedioxythiophene)/poly(styrenesulfonic acid) (PEDOT/PSS) and polyaniline/poly(styrenesulfonic acid) (PAni/PSS), to which acids have been added, may also be used as the hole injection material.

### (Electron Transporting Zone)

The organic layer comprises an electron transporting zone disposed between the cathode and the light-emitting layer.

The electron transporting zone comprises at least one or more layers having an electron transporting function. The electron transporting zone may comprise an electron injecting layer, an electron transporting layer, a hole blocking layer, or the like.

The electron transporting zone may be composed of a single layer, or it may be composed of a plurality of layers.

In an embodiment, the electron transporting zone comprises an electron transporting layer.

The electron transporting layer comprises a material having high electron transporting capabilities (electron transporting material). As the electron transporting material used in the electron transporting layer, for example,
(1) metal complexes such as aluminum complexes, beryllium complexes, and zinc complexes,
(2) heteroaromatic compounds such as imidazole derivatives, benzimidazole derivatives, azine derivatives, carbazole derivatives, and phenanthroline derivatives, and
(3) polymer compounds may be used.

As the metal complex, for example, tris(8-quinolinolato)aluminum (III) (abbreviated as Alq), tris(4-methyl-8-quinolinolato)aluminum (abbreviated as Almq3), bis(10-hydroxybenzo[h]quinolinato) beryllium (abbreviated as BeBq₂), bis(2-methyl-8-quinolinolato) (4-phenylphenolato)aluminum (III) (abbreviated as BAlq), bis(8-quinolinolato)zinc(II) (abbreviated as Znq), bis[2-(2-benzoxazolyl)phenolato]zinc(II) (abbreviated as ZnPBO), bis[2-(2-benzothiazolyl)phenolato]zinc(II) (abbreviated as ZnBTZ), and (8-quinolinolato) lithium (abbreviated as Liq) may be exemplified.

As the heteroaromatic compound, for example, 2-(4-biphenylyl)-5-(4-tert-butylphenyl)-1,3,4-oxadiazole (abbreviated as PBD), 1,3-bis[5-(p-tert-butylphenyl)-1,3,4-oxadiazol-2-yl]benzene (abbreviated as OXD-7), 3-(4-tert-butylphenyl)-4-phenyl-5-(4-biphenylyl)-1,2,4-triazole (abbreviated as TAZ), 3-(4-tert-butylphenyl)-4-(4-ethylphenyl)-5-(4-biphenylyl)-1,2,4-triazole (abbreviated as p-EtTAZ), bathophenanthroline (abbreviated as BPhen), bathocuproine (abbreviated as BCP), and 4,4′-bis(5-methylbenzoxazol-2-yl) stilbene (abbreviated as BzOs) may be exemplified.

As the polymer compound, for example, poly[(9,9-dihexylfluorene-2,7-diyl)-co-(pyridine-3,5-diyl)] (abbreviated as PF-Py) and poly[(9,9-dioctylfluorene-2,7-diyl)-co-(2,2′-bipyridine-6,6′-diyl)] (abbreviated as PF-BPy) may be exemplified.

These materials have an electron mobility of 10-6 cm²/Vs or more. Meanwhile, as long as it is a material having higher electron transporting capabilities than hole transporting capabilities, materials other than those described above may be used for the electron transporting layer.

The electron transporting layer may be a single layer or a multilayer comprising two or more layers. For example, the electron transporting layer may be a layer comprising a first electron transporting layer (anode side) and a second electron transporting layer (cathode side). Two or more electron transporting layers are each formed of the electron transporting materials described above.

In an embodiment, the electron transporting zone comprises an electron transporting layer and an electron injecting layer.

The electron injecting layer comprises a material having high electron injecting capabilities.

For the electron injecting layer, alkali metals, alkaline earth metals, or compounds thereof such as lithium (Li), cesium (Cs), calcium (Ca), lithium fluoride (LiF), cesium fluoride (CsF), calcium fluoride (CaF₂), and lithium oxide (LiOₓ) may be used. In addition, a material having electron transporting capabilities to which an alkali metal, an alkaline earth metal, or a compound thereof is added, specifically, Alq to which magnesium (Mg) is added, may also be used. Meanwhile, in such a case, electron injection from the cathode can be performed more efficiently.

Alternatively, for the electron injecting layer, a composite material formed by mixing an organic compound and an electron donor may be used. Such a composite material is excellent in electron injectioning capabilities and electron transporting capabilities since the organic compound receives electrons from the electron donor. In such a case, the organic compound is preferably a material excellent in transporting received electrons, specifically, for example, the materials constituting the electron transporting layer (such as metal complexes and heteroaromatic compounds) described above may be used. As the electron donor, any material that exhibits electron donating capabilities to the organic compound may be used. Specifically, alkali metals, alkaline earth metals, and rare earth metals are preferable, and examples include lithium, cesium, magnesium, calcium, erbium, and ytterbium. In addition, alkali metal oxides and alkaline earth metal oxides are preferable, and examples include lithium oxide, calcium oxide, and barium oxide. In addition, Lewis bases such as magnesium oxide may also be used. In addition, organic compounds such as tetrathiafulvalene (abbreviated as TTF) may also be used.

### (Blocking Layer)

The organic layer may comprise blocking layers such as an electron blocking layer, a hole blocking layer, and an exciton blocking layer. The blocking layer may be disposed adjacent to the light-emitting layer. The electron blocking layer is a layer that prevents electrons from moving from the light-emitting layer to the hole transporting layer. The hole blocking layer is a layer that prevents holes from moving from the light-emitting layer to the electron transporting layer. The exciton blocking layer may prevent excitons generated in the light-emitting layer from diffusing to surrounding layers, thereby playing a role in confining excitons within the light-emitting layer.

### (Insulating Layer)

Since an organic electroluminescent element applies an electric field to a thin film, pixel defects due to leakage or shorts are likely to occur. To prevent this, a thin-film insulating layer may be inserted between a pair of electrodes.

Specific examples of materials used for the insulating layer include aluminum oxide, lithium fluoride, lithium oxide, cesium fluoride, cesium oxide, magnesium oxide, magnesium fluoride, calcium oxide, calcium fluoride, aluminum nitride, titanium oxide, silicon oxide, germanium oxide, silicon nitride, boron nitride, molybdenum oxide, ruthenium oxide, and vanadium oxide. Mixtures of the above may be used for the insulating layer, and a laminate of a plurality of layers comprising these materials may also be used.

### (Space Layer)

For example, when a fluorescent light-emitting layer and a phosphorescent light-emitting layer are laminated, a space layer is provided between both layers for the purpose of preventing diffusion of excitons generated in the phosphorescent light-emitting layer to the fluorescent light-emitting layer and adjusting carrier balance. The space layer may also be provided between a plurality of phosphorescent light-emitting layers.

Since the space layer is provided between a plurality of light-emitting layers, it is preferably formed of a material having both electron-transporting capabilities and hole transporting capabilities. In addition, from the viewpoint of preventing diffusion of triplet energy in adjacent phosphorescent light-emitting layers, it is preferable that its triplet energy is 2.6 eV or more.

As materials used for the space layer, the same materials as those used for the hole transporting layer described above may be exemplified.

### (Layer Formation Method)

The method of forming each layer of the organic electroluminescent element is not particularly limited unless otherwise specified. Known methods, such as a dry film formation method and a wet film formation method, may be used as the method of forming each layer. Specific examples of the dry film formation method include a vacuum deposition method, a sputtering method, a plasma method, and an ion plating method. Specific examples of the wet film formation method include various coating methods such as a spin coating method, a dipping method, a flow coating method, and an ink jet method.

### (Film Thickness)

The film thickness of each layer of the organic electroluminescent element is not particularly limited unless otherwise specified. If the film thickness is too small, defects such as pinholes may easily occur, whereby sufficient luminance may not be obtained. On the other hand, if the film thickness is too large, a high driving voltage is required, which may reduce efficiency. From such a viewpoint, the film thickness is usually preferably 1 nm to 10 μm, more preferably 1 nm to 0.2 μm.

### <Electronic Device>

An electronic device according to an aspect of the present invention comprises the organic electroluminescent element of any one of the embodiments described above.

Examples of the electronic device include display devices and light-emitting devices. Specific examples of the electronic device include display components such as organic EL panel modules; display devices such as televisions, mobile phones, smartphones, tablets, and personal computers; and light-emitting devices such as lighting and vehicular lighting equipment.

### EXAMPLE

Hereinafter, the present invention will be described in more detail with reference to examples. However, the present invention is not limited to the following examples.

The structures of compounds used in the manufacture of organic electroluminescent elements according to the examples and comparative examples are shown below.

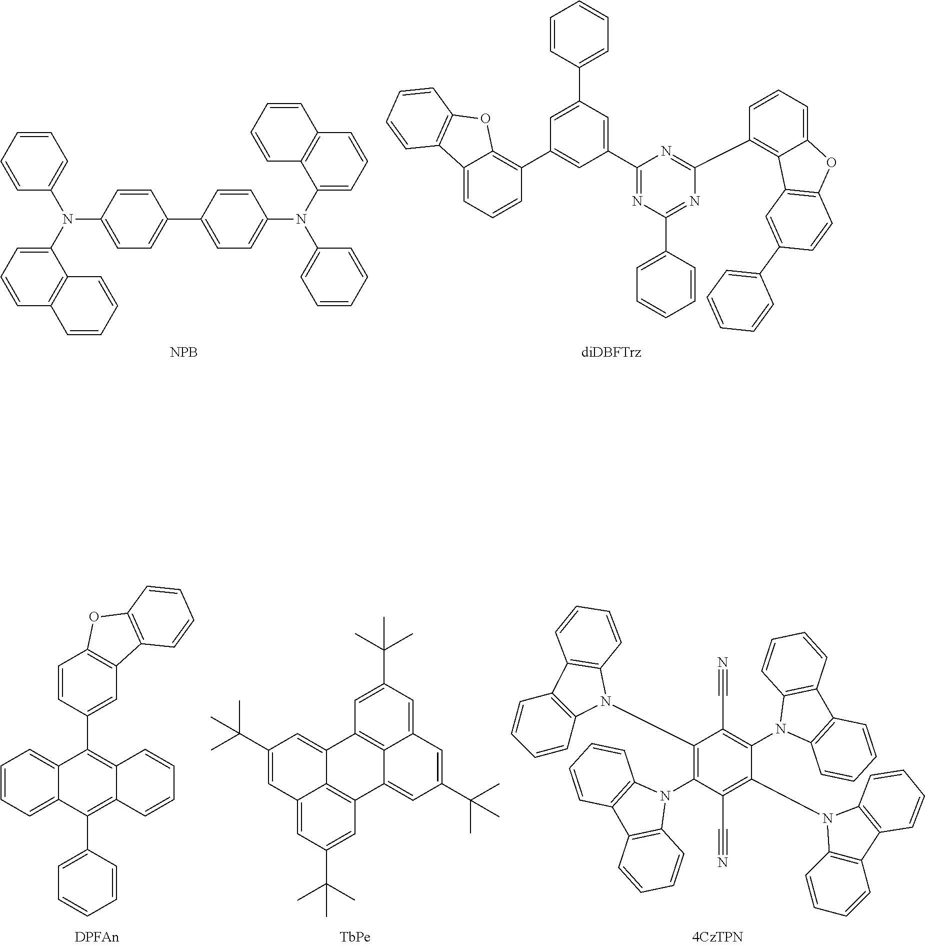

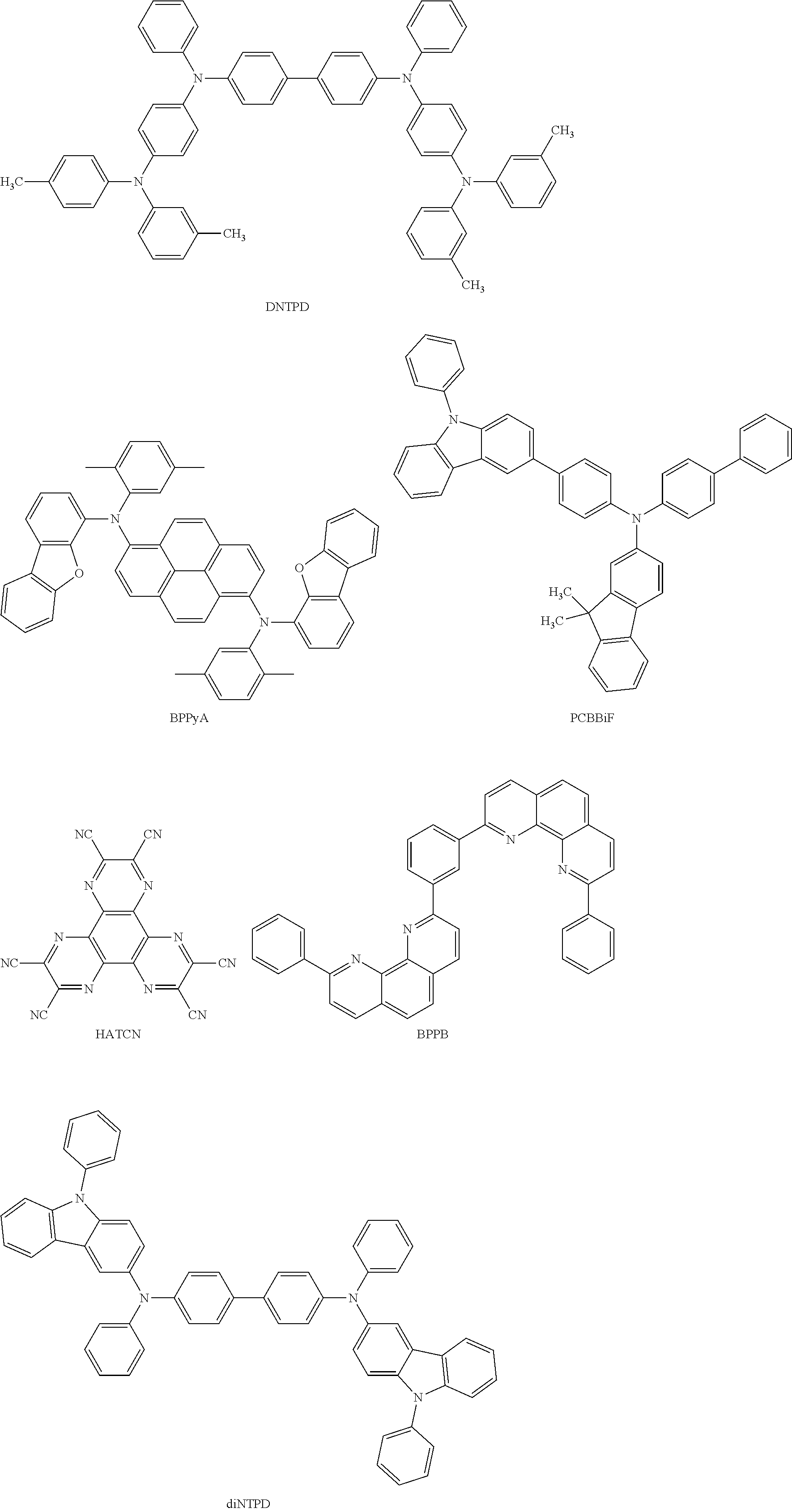

In the above compounds, compound NPB and compound diNTPD are first host compounds according to an embodiment of the present invention, compound diDBFTrz is a second host compound according to an embodiment of the present invention, compound DPFAn is a third host compound or a second host compound according to an embodiment of the present invention, and compound BPPyA and compound TbPe are dopant compounds according to an embodiment of the present invention.

The HOMO level, LUMO level, triplet energy level, singlet energy level of the compounds, and the energy band gap (E_{g}) of the exciplex formed by the recombination of the first host compound and the second host compound were measured, and the photon energy (Eₚ) was calculated by Equation F5. The calculated Eₚ value was taken as the triplet energy level (ExpT₁) of the exciplex. The evaluation results are shown in Table 1 below.

TABLE 1

| | NPB | diDBFTrz | DPFAn | BPPyA | TbPe |
|---|---|---|---|---|---|
| Type | First host | Second host | Third host | Dopant | |
| HOMO level (eV) | −5.4 | −6.4 | −5.9 | −5.4 | −5.4 |
| LUMO level (eV) | −2.4 | −3.1 | −3.0 | −2.7 | −2.7 |
| T₁ (eV) | 2.3 | 2.84 | 1.87 | 1.9 | 1.54 |
| S₁ (eV) | 3.1 | 3.3 | 2.9 | 2.74 | 2.68 |

| | | |
|---|---|---|
| Eₚ (eV) | 2.04 | — |
| E_{g} (eV) | 2.3 | — |

### <Method for Measuring Energy Levels>

### (Triplet Energy Level)

The triplet energy level of a measurement object (a compound or a material) was measured by the following method.

A compound to be measured was dissolved in toluene to a concentration of 10 μmoles/L, and a sample was prepared by encapsulating the solution in a quartz cell. For the sample, a phosphorescence spectrum (vertical axis: phosphorescence emission intensity, horizontal axis: wavelength) was measured at a low temperature (e.g., 77 K), a tangent was drawn to the ascent on the short wavelength side of the phosphorescence spectrum, and the triplet energy level T₁ (unit: eV) was calculated from the conversion equation (F1) based on the wavelength value λ_{edge} (unit: nm) at the intersection of the tangent and the horizontal axis.

$${T}_{1} [ eV ] = 1 , 23 \; 9 \text{.85} / {λ}_{edge} \qquad Conversion Equation ( F1 )$$

The tangent to the ascent on the short wavelength side of the phosphorescence spectrum was drawn by the following method. First, when moving on the spectrum curve from the short wavelength side of the phosphorescence spectrum to the maximum on the shortest wavelength side among the maxima of the spectrum, the tangent at each point on the curve toward the long wavelength side was considered. The tangent increases in slope as the curve ascends (i.e., as the vertical axis increases). The tangent drawn at the point where this slope value took a maximum value (i.e., the tangent at the inflection point) was taken as the tangent to the ascent on the short wavelength side of the phosphorescence spectrum.

Meanwhile, a maximum point having a peak intensity of 15% or less of the maximum peak intensity of the spectrum was not included in the maximum on the shortest wavelength side, and the tangent drawn at the point closest to the maximum on the shortest wavelength side where the slope value took a maximum value was taken as the tangent to the ascent on the short wavelength side of the phosphorescence spectrum.

As a device for measuring a phosphorescence spectrum, a spectrofluorometer main body from Hitachi High-Tech (device name: F-4500) may be used.

### (Singlet Energy Level)

The singlet energy level of a measurement object (a compound or a material) was measured by the following method.

A compound to be measured was dissolved in toluene to a concentration of 10 μmoles/L, and a sample was prepared by encapsulating the solution in a quartz cell. For the sample, an emission spectrum (vertical axis: emission intensity, horizontal axis: wavelength) was measured at room temperature (e.g., 300 K). A tangent was drawn to the ascent on the short wavelength side of the emission spectrum, and the singlet energy level S₁ (unit: eV) was calculated by substituting the wavelength value λ_{edge} (unit: nm) at the intersection of the tangent and the horizontal axis into the Conversion Equation (F2).

$${S}_{1} [ eV ] = 1 , 23 \; 9 \text{.85} / {λ}_{edge} \qquad Conversion Equation ( F2 )$$

The tangent to the ascent on the short wavelength side of the emission spectrum was drawn by the following method. First, when moving on the spectrum curve in the short wavelength direction from the maximum on the shortest wavelength side among the maxima of the emission spectrum, the tangent at each point on the curve was considered. The tangent repeatedly increases and then decreases in slope as the curve ascends (i.e., as the value on the vertical axis increases). The tangent drawn at the point where the slope value took a minimum value on the shortest wavelength side was taken as the tangent to the ascent on the short wavelength side of the emission spectrum.

As a device for measuring the emission spectrum, a spectrofluorometer (device name: F-7000) from Hitachi may be exemplified.

### (HOMO Level and LUMO Level)

The value of the HOMO energy level (unit: eV) of a measurement object (compound or material) was calculated by Equation (F3).

$$HOMO = - 1.4 \times ( Eox - Efc ) - 4.6 eV \qquad Equation ( F3 )$$

In Equation (F3), Eox and Efc are as follows.
Eox: first oxidation potential (CV, positive scan)
Efc: first oxidation potential of ferrocene (CV, positive scan), (ca. +0.55 V vs Ag/AgCl)

The LUMO level was calculated using the measured HOMO value and E_{g} value.

Specifically, the value of the LUMO energy level (unit: eV) of an object (a compound or a material) was obtained by Equation (F4).

$$LUMO = HOMO - {E}_{g} \qquad Equation ( F4 )$$

In Equation (F4), E_{g} refers to the energy band gap (unit: eV) of the object.

The E_{g} was measured as follows. For a 10 μmoles/L toluene solution of a measurement object, an absorption spectrum (vertical axis: absorption intensity, horizontal axis: wavelength) was measured at room temperature (300 K) using a spectrophotometer from Hitachi (device name: U3310). A tangent was drawn to the descending point on the long wavelength side of the absorption spectrum, and the wavelength value λ_{edge} (unit: nm) at the intersection where the tangent and the horizontal axis meet was substituted into the Equation E_{g} [eV]=1,239.85/λ_{edge} to calculate E_{g}.

In the measurement of the HOMO energy level and LUMO energy level, the redox potential was measured through cyclic voltammetry. The sample solution used for measuring the redox potential was prepared by dissolving the measurement object and a supporting electrolyte in a solvent. The concentration of the measurement object in the sample solution was 1.0 mmole/L, and the concentration of the supporting electrolyte was 100 mmoles/L. N,N-dimethylformamide (DMF) was used as the solvent. Tetrabutylammonium hexafluorophosphate (TBHP) was used as the supporting electrolyte. A glassy carbon electrode was used as the working electrode, and a platinum (Pt) electrode was used as the counter electrode.

As to the measurement of the redox potential, Reference 1 (M. E. Thompson, et al., Organic Electronics, 6 (2005), p. 11-20) and Reference 2 (Organic Electronics, 10 (2009), p. 515-520) may be referred to.

As an electrochemical analyzer used for measuring the redox potential, for example, CHI630B from ALS, or CHI852D from ALS may be used.

### (Triplet Energy Level of Exciplex)

The photon energy (Ep) was calculated by the following Equation (F5), and this was regarded as the triplet energy level of the exciplex formed by the recombination of the first host compound and the second host compound.

$${E}_{p} = 0.8 \times {E}_{g} + 0.2 \qquad Equation ( F5 )$$

In Equation (F5), Eₚ is the photon energy. E_{g} is the energy band gap of the exciplex, which is calculated as the gap between the HOMO energy level of the first host compound and the LUMO energy level of the second host compound.

### <Evaluation of Organic Electroluminescent Elements>

### (Measurement of Turn-on Voltage (Vₒₙ))

The turn-on voltage was obtained by measuring the voltage (unit: V) when a voltage was applied to an organic electroluminescent element such that the luminance was 1 nit.

### (Measurement of External Quantum Efficiency (EQEₘₐₓ), Power Efficiency, and Maximum Electroluminescence Peak Wavelength)

The spectroradiance spectrum was measured with a spectroradiometer CS-2000 (Konica Minolta) when a voltage was applied to an organic electroluminescent element such that the current density was 10 mA/cm².

Assuming that Lambertian radiation was performed, the external quantum efficiency EQE (unit: %) was calculated from the obtained spectroradiance spectrum.

In addition, the power efficiency (unit: lm/W) was calculated from the obtained spectroradiance spectrum.

In addition, the maximum electroluminescence peak wavelength (unit: nm) was obtained from the obtained spectroradiance spectrum.

### (CIE1931 Chromaticity Specification)

The CIE1931 chromaticity coordinates (x, y) were measured with a spectroradiometer CS-2000 (Konica Minolta) when a voltage was applied to an organic electroluminescent element such that the current density was 1 mA/cm².

### <Manufacture of Organic Electroluminescent Elements>

Organic electroluminescent elements were manufactured as follows.

### Example 1

A glass substrate (Korea Electronics Technology Institute) provided with an ITO (indium tin oxide) transparent electrode (anode) was cut to a size of 50 mm×50 mm×0.7 mm, cleaned using acetone, isopropyl alcohol, and distilled water for 10 minutes each, and then cleaned by irradiating ultraviolet light for 10 minutes and exposing to ozone. The film thickness of the ITO transparent electrode was set to 150 nm.

The glass substrate with the ITO transparent electrode, upon cleaning, was mounted on a substrate holder of a vacuum deposition apparatus. First, compound HATCN was deposited on the surface on the side where the transparent electrode was formed so as to cover the transparent electrode, thereby forming a hole injecting layer having a film thickness of 7 nm.

Compound PCBBiF was deposited on the hole injecting layer to form a hole transporting layer having a film thickness of 68 nm.

Compound NPB and compound diDBFTrz were co-deposited on the hole transporting layer to form a first light-emitting layer having a film thickness of 10 nm. The mass ratio of compound NPB and compound diDBFTrz in the first light-emitting layer was set to 1:1.

Compound DPFAn and compound TbPe were co-deposited on the first light-emitting layer to form a second light-emitting layer having a film thickness of 15 nm. The proportion of compound DPFAn in the second light-emitting layer was set to 95% by mass, and the proportion of compound TbPe was set to 5% by mass.

Compound BPPB was deposited on the second light-emitting layer to form an electron transporting layer having a film thickness of 25 nm.

Compound Liq was deposited on the electron transporting layer to form an electron injecting layer having a film thickness of 1.5 nm. Liq is an abbreviation for (8-quinolinolato) lithium.

Metal A1 was deposited on the electron injecting layer to form a cathode having a film thickness of 90 nm.

The element configuration of Example 1 is schematically represented as follows.

ITO (150 nm)/HATCN (7 nm)/PCBBiF (68 nm)/NPB: diDBFTrz (50%: 50%) (10 nm)/DPFAn: TbPe (95%: 5%) (15 nm)/BPPB (25 nm)/Liq (1.5 nm)/A1 (90 nm)

As to the element configuration of Example 1, numbers expressed as percentages in the same parentheses (e.g., 50%: 50%) indicate the ratio (% by mass) between the compounds contained in the same layer. Hereinafter, the same notation is used.

### Comparative Example 1

The organic electroluminescent element of Comparative Example 1 was manufactured in the same manner as in Example 1, except that compound 4CzTPN, which is a TADF material, was used instead of NPB: diDBFTrz (50%: 50%) in Example 1.

TADF (thermally activated delayed fluorescence) refers to a phenomenon that enables 100% fluorescence emission by moving 75% of triplet excitons that are annihilated through reverse intersystem crossing to 25% of singlet excitons that emit light. A TADF material refers to a material in which the difference between the singlet energy level and the triplet energy level in the excited state is small, so that the movement of excitons through reverse intersystem crossing is easy.

The element configuration of Comparative Example 1 is schematically represented as follows.

ITO (150 nm)/HATCN (7 nm)/PCBBiF (68 nm)/4CzTPN (10 nm)/DPFAn: TbPe (95%: 5%) (15 nm)/BPPB (25 nm)/Liq (1.5 nm)/A1 (90 nm)

### Comparative Example 2

The organic electroluminescent element of Comparative Example 2 was manufactured in the same manner as in Example 1, except that the first light-emitting layer in Example 1 was not formed, and the second light-emitting layer was formed with a film thickness of 25 nm.

The element configuration of Comparative Example 2 is schematically represented as follows.

ITO (150 nm)/HATCN (7 nm)/PCBBiF (68 nm)/DPFAn: TbPe (95%: 5%) (25 nm)/BPPB (25 nm)/Liq (1.5 nm)/A1 (90 nm)

### <Evaluation of Organic Electroluminescent Elements>

For the manufactured organic EL elements, turn-on voltage (Vₒₙ), external quantum efficiency (EQEₘₐₓ), power efficiency, and maximum electroluminescence peak wavelength were measured. The evaluation results are shown in Table 2.

TABLE 2

| | Ex. 1 | C. Ex. 1 | C. Ex. 2 |
|---|---|---|---|
| Type of the first light-emitting | Exciplex | TADF | x |
| layer | | | |
| Vₒₙ (V) | 2.30 | 2.57 | 2.70 |
| EQEₘₐₓ (%) | 1.31 | 0.69 | 5.50 |
| Power efficiency (@ 100 nit) | 2.54 | 0.60 | 6.24 |
| (lm/W) | | | |
| Maximum electroluminescence | 465 | 464 | 464 |
| peak wavelength (nm) | | | |

Referring to the results in Table 2 above, the turn-on voltage of the element of Example 1 having an exciplex layer was lower than the turn-on voltage of the element of Comparative Example 1 having a TADF layer and the element of Comparative Example 2. Further, the turn-on voltage of the element of Comparative Example 2 was remarkably high by 0.4 V or more relative to the turn-on voltage of the element of Example 1. As a result, it is understood that the power consumption of the element would increase significantly.

In addition, the power efficiency of the element of Example 1 was 4.2 times higher than the power efficiency of the element of Comparative Example 1 comprising a TADF material. It was confirmed that the turn-on voltage was lower, and the maximum luminous efficiency was higher, when an exciplex material was inserted in the light-emitting layer, than when a TADF material was inserted.

Therefore, the element of Example 1 can provide both low voltage characteristics and efficiency in an excellently balanced manner. For example, luminous efficiency and power efficiency suitable for use as a fluorescent light-emitting element can be provided while power consumption can be reduced. In contrast, the element of Comparative Example 1 had a somewhat high turn-on voltage, and the internal quantum efficiency and power efficiency were poor, making it unsuitable for a fluorescent light-emitting element. The element of Comparative Example 2 had an excessively high turn-on voltage, making it substantially difficult to operate as a fluorescent light-emitting element.

### Example 2

A glass substrate (Korea Electronics Technology Institute) provided with an ITO (indium tin oxide) transparent electrode (anode) was cut to a size of 50 mm×50 mm×0.7 mm, cleaned using acetone, isopropyl alcohol, and distilled water for 10 minutes each, and then cleaned by irradiating ultraviolet light for 10 minutes and exposing to ozone. The film thickness of the ITO transparent electrode was set to 150 nm.

The glass substrate with the ITO transparent electrode, upon cleaning, was mounted on a substrate holder of a vacuum deposition apparatus. First, compound HATCN was deposited on the surface on the side where the transparent electrode was formed so as to cover the transparent electrode, thereby forming a hole injecting layer having a film thickness of 7 nm.

Compound PCBBiF was deposited on the hole injecting layer to form a hole transporting layer having a film thickness of 68 nm.

Compound NPB and compound BPPyA were co-deposited on the hole transporting layer to form a first light-emitting layer having a film thickness of 20 nm. The proportion of compound NPB in the first light-emitting layer was set to 95% by mass, and the proportion of compound BPPyA was set to 5% by mass.

Compound diDBFTrz was deposited on the first light-emitting layer to form a second light-emitting layer having a film thickness of 5 nm.

Compound BPPB was deposited on the second light-emitting layer to form an electron transporting layer having a film thickness of 25 nm.

Compound Liq was deposited on the electron transporting layer to form an electron injecting layer having a film thickness of 1.5 nm.

Metal A1 was deposited on the electron injecting layer to form a cathode having a film thickness of 90 nm.

The element configuration of Example 2 is schematically represented as follows. ITO (150 nm)/HATCN (7 nm)/PCBBiF (68 nm)/NPB: BPPyA (95%: 5%) (20 nm)/diDBFTrz (5 nm)/BPPB (25 nm)/Liq (1.5 nm)/A1 (90 nm)

### Comparative Example 3

The organic electroluminescent element of Comparative Example 3 was manufactured in the same manner as in Example 2, except that compound DNTPD was used instead of compound NPB in Example 2.

The element configuration of Comparative Example 3 is schematically represented as follows.

ITO (150 nm)/HATCN (7 nm)/PCBBiF (68 nm)/DNTPD: BPPyA (95%: 5%) (20 nm)/diDBFTrz (5 nm)/BPPB (25 nm)/Liq (1.5 nm)/A1 (90 nm)

### <Evaluation of Organic Electroluminescent Elements>

For the organic electroluminescent elements of Example 2 and Comparative Example 3, the HOMO level and triplet energy level (T₁) of the first host compound, the energy band gap (E_{g}) of the exciplex formed by the recombination of the first host compound and the second host compound, turn-on voltage (Vₒₙ), and external quantum efficiency (EQEₘₐₓ) were each measured. The evaluation results are shown in Table 3.

TABLE 3

| | Ex. 2 | C. Ex. 3 |
|---|---|---|
| Third host compound | NPB | DNTPD |

| | | | |
|---|---|---|---|
| Energy level | HOMO level (eV) | −5.4 | −5.2 |
| | T₁ (eV) | 2.3 | 2.7 |
| | E_{g} (eV) | 2.3 | 2.1 |
| Element | Vₒₙ (V) | 2.30 | 2.15 |
| characteristics | EQEₘₐₓ (%) | 1.80 | 0.73 |

Referring to the results in Table 3 above, the HOMO level of compound DNTPD was higher than the HOMO level of compound NPB, so that the energy gap with the LUMO level (−3.1 eV) of compound diDBFTrz was somewhat low. As a result, the turn-on voltage of the element of Comparative Example 3 was somewhat lower than that of Example 2.

On the other hand, the maximum luminous efficiency of Example 2 was 2.5 times higher than the maximum luminous efficiency of Comparative Example 3. Since the T₁ of compound NPB, in which the dopant compound was doped, was similar to the E_{g} of the exciplex, so that the T₁ of the exciplex could diffuse to the compound NPB, and the luminous efficiency could be enhanced by TTA-UC. On the other hand, the T₁ of the exciplex was difficult to diffuse to the compound DNTPD having a high T₁, so that the luminous efficiency of the element was low.

Therefore, the element of Example 2 can provide internal quantum efficiency and power efficiency suitable for use as, for example, a fluorescent light-emitting element while providing a low turn-on voltage. In contrast, the element of Comparative Example 3 had a somewhat low turn-on voltage, while the internal quantum efficiency was excessively low, making it unsuitable for a fluorescent light-emitting element.

### Example 3

A glass substrate (Korea Electronics Technology Institute) provided with an ITO (indium tin oxide) transparent electrode (anode) was cut to a size of 50 mm×50 mm×0.7 mm, cleaned using acetone, isopropyl alcohol, and distilled water for 10 minutes each, and then cleaned by irradiating ultraviolet light for 10 minutes and exposing to ozone. The film thickness of the ITO transparent electrode was set to 150 nm.

The glass substrate with the ITO transparent electrode, upon cleaning, was mounted on a substrate holder of a vacuum deposition apparatus. First, compound HATCN was deposited on the surface on the side where the transparent electrode was formed so as to cover the transparent electrode, thereby forming a hole injecting layer having a film thickness of 7 nm.

Compound PCBBiF was deposited on the hole injecting layer to form a hole transporting layer having a film thickness of 68 nm.

Compound NPB and compound BPPyA were co-deposited on the hole transporting layer to form a first light-emitting layer having a film thickness of 20 nm. The proportion of compound NPB in the first light-emitting layer was set to 95% by mass, and the proportion of compound BPPyA was set to 5% by mass.

Compound DPFAn was deposited on the first light-emitting layer to form an intermediate layer having a film thickness of 3 nm.

Compound diDBFTrz was deposited on the intermediate layer to form a second light-emitting layer having a film thickness of 5 nm.

Compound BPPB was deposited on the second light-emitting layer to form an electron transporting layer having a film thickness of 25 nm.

Compound Liq was deposited on the electron transporting layer to form an electron injecting layer having a film thickness of 1.5 nm.

Metal A1 was deposited on the electron injecting layer to form a cathode having a film thickness of 90 nm.

The element configuration of Example 3 is schematically represented as follows.

ITO (150 nm)/HATCN (7 nm)/PCBBiF (68 nm)/NPB: BPPyA (95%: 5%) (20 nm)/DPFAn (3 nm)/diDBFTrz (5 nm)/BPPB (25 nm)/Liq (1.5 nm)/A1 (90 nm)

### <Evaluation of Organic Electroluminescent Elements>

For the organic electroluminescent elements of Examples 2 and 3, turn-on voltage (Vₒₙ), external quantum efficiency (EQEₘₐₓ), power efficiency, and maximum electroluminescence peak wavelength were measured, respectively. The evaluation results are shown in Table 4.

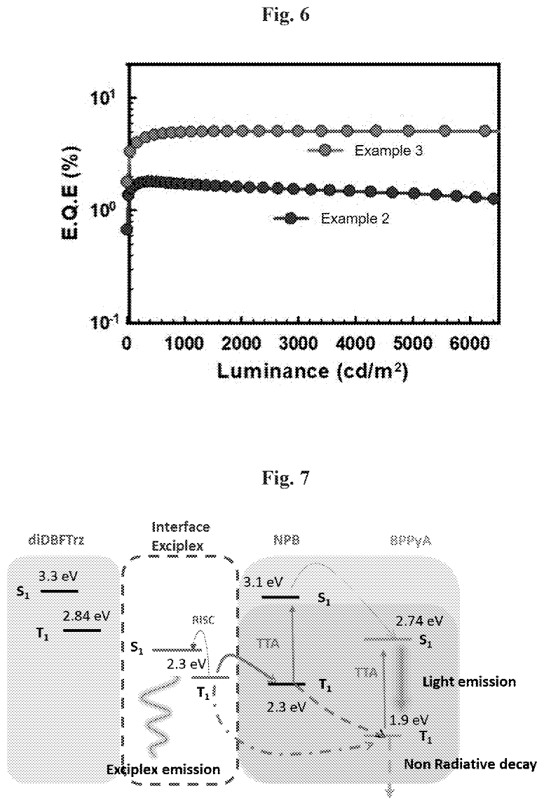

FIG. 6 is a graph showing luminous efficiency as a function of luminance in the organic electroluminescent elements of Example 2 and Example 3.

TABLE 4

| | Ex. 2 | Ex. 3 |
|---|---|---|
| Vₒₙ (V) | 2.30 | 2.49 |
| EQEₘₐₓ (%) | 1.80 | 5.10 |
| Power efficiency (lm/W) | 2.03 | 3.91 |
| Maximum electroluminescence | 458 | 458 |
| peak wavelength (nm) | | |

Referring to Table 4 and FIG. 6, in the element of Example 3, in which a third host compound (intermediate layer) was inserted between the first host compound (first light-emitting layer) and the second host compound (second light-emitting layer), the turn-on voltage increased by 0.19 V, as a light-emitting layer was added, while the maximum luminous efficiency of the element increased by 2.8 times, and the power efficiency also improved by 1.9 times, relative to the element of Example 2, which did not comprise the intermediate layer.

FIG. 7 is a diagram illustrating an example of energy levels and energy transfer relationships of respective compounds in the light-emitting layer of the organic electroluminescent element of Example 2.

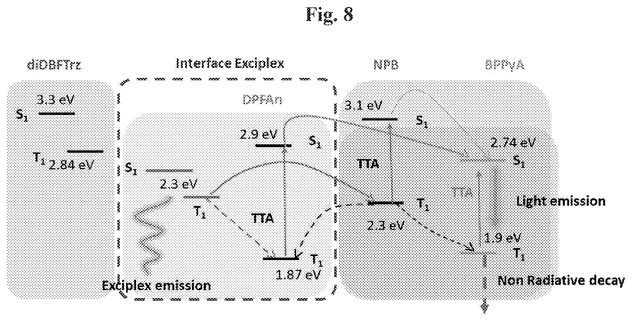

FIG. 8 is a diagram illustrating an example of energy levels and energy transfer relationships of respective compounds in the light-emitting layer of the organic electroluminescent element of Example 3.

Referring to FIGS. 7 and 8, in Example 3, as the third host compound (DPFAn) having a low T₁ was inserted at the interface between the first host compound (NPB) and the second host compound (diDBFTrz), a path, through which TTA-UC could occur, was added.

For example, together with the Dexter energy transfer path from the triplet energy level of the exciplex to the triplet energy level of the first host compound, a Dexter energy transfer path from the triplet energy level of the exciplex to the triplet energy level of the third host compound could be added. Thereafter, it is understood that energy was transferred to the singlet energy level of the dopant by TTA-UC of the third host compound, thereby enhancing luminous efficiency and power efficiency.

### Example 4

A glass substrate (Korea Electronics Technology Institute) provided with an ITO (indium tin oxide) transparent electrode (anode) was cut to a size of 50 mm×50 mm×0.7 mm, cleaned using acetone, isopropyl alcohol, and distilled water for 10 minutes each, and then cleaned by irradiating ultraviolet light for 10 minutes and exposing to ozone. The film thickness of the ITO transparent electrode was set to 150 nm.

The glass substrate with the ITO transparent electrode, upon cleaning, was mounted on a substrate holder of a vacuum deposition apparatus. First, compound HATCN was deposited on the surface on the side where the transparent electrode was formed so as to cover the transparent electrode, thereby forming a hole injecting layer having a film thickness of 7 nm.

Compound PCBBiF was deposited on the hole injecting layer to form a hole transporting layer having a film thickness of 68 nm.

Compound diNTPD and compound BPPyA were co-deposited on the hole transporting layer to form a first light-emitting layer having a film thickness of 15 nm. The proportion of compound diNTPD in the first light-emitting layer was set to 95% by mass, and the proportion of compound BPPyA was set to 5% by mass.

Compound DPFAn and compound BPPyA were co-deposited on the first light-emitting layer to form a second light-emitting layer having a film thickness of 10 nm. The proportion of compound DPFAn in the second light-emitting layer was set to 95% by mass, and the proportion of compound BPPyA was set to 5% by mass.

Compound BPPB was deposited on the second light-emitting layer to form an electron transporting layer having a film thickness of 25 nm.

Compound Liq was deposited on the electron transporting layer to form an electron injecting layer having a film thickness of 1.5 nm.

Metal A1 was deposited on the electron injecting layer to form a cathode having a film thickness of 90 nm.

The element configuration of Example 4 is schematically represented as follows.

ITO (150 nm)/HATCN (7 nm)/PCBBiF (68 nm)/diNTPD: BPPyA (95%: 5%) (15 nm)/DPFAn: BPPyA (95%: 5%) (10 nm)/BPPB (25 nm)/Liq (1.5 nm)/A1 (90 nm)

The HOMO level, LUMO level, triplet energy level, singlet energy level of the compounds, and the energy band gap (E_{g}) of the exciplex formed by the recombination of the first host compound and the second host compound were measured, and the photon energy (Eₚ) was calculated by Equation F5. The calculated Eₚ value was taken as the triplet energy level (ExpT₁) of the exciplex. The evaluation results are shown in Table 5 below.

TABLE 5

| | diNTPD | DPFAn | BPPyA |
|---|---|---|---|
| Type | First host | Second host | Dopant |
| HOMO level (eV) | −5.18 | −5.9 | −5.4 |
| LUMO level (eV) | −2.18 | −3.0 | −2.7 |
| T₁ (eV) | 2.43 | 1.87 | 1.9 |
| S₁ (eV) | 3.00 | 2.9 | 2.74 |

| | | |
|---|---|---|
| Eₚ (eV) | 1.94 | — |
| E_{g} (eV) | 2.18 | — |

### <Evaluation of Organic Electroluminescent Elements>

For the organic electroluminescent element of Example 4, turn-on voltage (Vₒₙ), external quantum efficiency (EQEₘₐₓ), maximum electroluminescence peak wavelength, and CIE chromaticity were measured. The evaluation results are shown in Table 6.

TABLE 6

| | Ex. 4 |
|---|---|
| Vₒₙ (V) | 2.46 |
| EQEₘₐₓ (%) | 6.10 |
| Maximum electroluminescence | 458 |
| peak wavelength (nm) | |
| CIE (x, y) | (0.13, 0.13) |

Referring to Table 6 above, in the element of Example 4, the first light-emitting layer was formed by co-depositing the first host compound and the dopant compound, and the second light-emitting layer was formed by co-depositing the second host compound and the dopant compound. In the element of Example 4, the turn-on voltage increased by about 0.16 V, while the maximum luminous efficiency of the element increased by about 3.4 times, relative to the element of Example 2.

### EXPLANATION OF REFERENCE NUMERALS

10: organic electroluminescent element
20: substrate
30: anode
40: organic layer
50: cathode
41: hole transporting zone
42: light-emitting layer
43: electron transporting zone
41b: hole injecting layer
41a: hole transporting layer
43b: electron injecting layer
43a: electron transporting layer

1. An organic electroluminescent element, comprising: an anode, a cathode, and an organic layer interposed between the anode and the cathode, wherein
the organic layer comprises:
a first host compound having a HOMO energy level of −5.5 eV or higher and a triplet energy level of 2.5 eV or lower,
a second host compound having a LUMO energy level of −4.0 eV to −3.0 eV, and
a dopant compound,
the first host compound and the second host compound are capable of recombining with each other to form an exciplex,
the exciplex has a triplet energy level of greater than 1.5 eV, and
the first host compound, the second host compound, and the dopant compound satisfy the following Relationships 1 to 4:
$${H}_{1} {S}_{1} > {DS}_{1} \qquad Relationship 1$$
$${H}_{1} {T}_{1} > {DT}_{1} \qquad Relationship 2$$
$${H}_{2} {S}_{1} > {DS}_{1} \qquad Relationship 3$$
$${H}_{2} {T}_{1} > {DT}_{1} \qquad Relationship 4$$
where,
H₁S₁ is a singlet energy level of the first host compound,
H₁T₁ is a triplet energy level of the first host compound,
H₂S₁ is a singlet energy level of the second host compound,
H₂T₁ is a triplet energy level of the second host compound,
DS₁ is a singlet energy level of the dopant compound, and
DT₁ is a triplet energy level of the dopant compound.

2. The organic electroluminescent element of claim 1, wherein the dopant compound comprises a fluorescent compound.

3. The organic electroluminescent element of claim 1, wherein the dopant compound has an emission peak wavelength in a solution state of 430 nm to 480 nm.

4. The organic electroluminescent element of claim 1, wherein a gap between the HOMO energy level of the first host compound and the LUMO energy level of the second host compound is greater than 1.6 eV.

5. The organic electroluminescent element of claim 1, wherein the first host compound comprises an amine compound.

6. The organic electroluminescent element of claim 1, wherein the first host compound comprises at least one of compounds represented by the following Formulae (2a) to (2d): 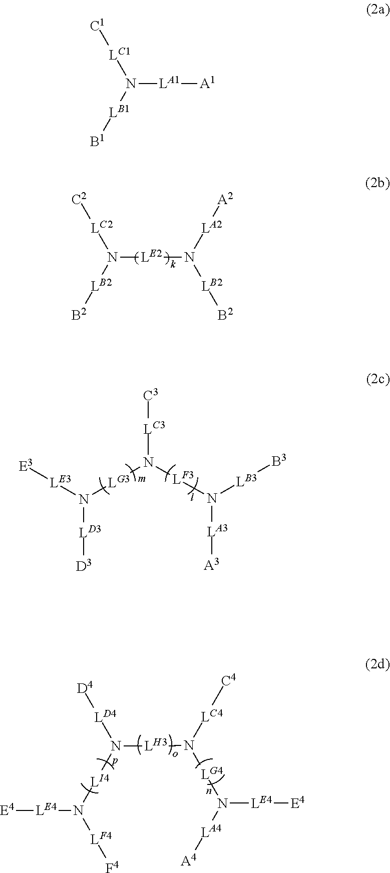
where
L^{A1}, L^{B1}, L^{C1}, L^{A2}, L^{B2}, L^{C2}, L^{D2}, L^{A3}, L^{B3}, L^{C3}, L^{D3}, L^{E3}, L^{A4}, L^{B4}, L^{C4}, L^{D4}, L^{E4}, and L^{F4} are each independently a single bond, a substituted or unsubstituted arylene group having 6 to 50 ring carbon atoms, or a substituted or unsubstituted divalent heterocyclic group having 5 to 50 ring atoms,
k, l, m, n, o, and p are each independently 1, 2, 3, or 4,
when k, l, m, n, o, and p are 1, L^{E2}, L^{F3}, L^{G3}, L^{G4}, L^{H4}, and L¹⁴ are each independently a substituted or unsubstituted arylene group having 6 to 50 ring carbon atoms, or a substituted or unsubstituted divalent heterocyclic group having 5 to 50 ring atoms,
when k, l, m, n, o, and p are 2, 3, or 4, a plurality of L^{E2}, L^{F3}, L^{G3}, L^{G4}, L^{H4}, and L¹⁴ are the same as or different from each other,
when k, l, m, n, o, and p are 2, 3, or 4, a plurality of L^{E2}, L^{F3}, L^{G3}, L^{G4}, L^{H4}, and L^{I4} bond to each other to form a substituted or unsubstituted monocyclic or fused ring, or do not bond to each other,
L^{E2}, L^{F3}, L^{G3}, L^{G4}, L^{H4}, and L^{I4} that do not form the substituted or unsubstituted monocyclic ring and do not form the substituted or unsubstituted fused ring are a substituted or unsubstituted arylene group having 6 to 50 ring carbon atoms, or a substituted or unsubstituted divalent heterocyclic group having 5 to 50 ring atoms,
A¹, B¹, C¹, A², B², C², D², A³, B³, C³, D³, E³, A⁴, B⁴, C⁴, D⁴, E⁴, and F⁴ are each independently a substituted or unsubstituted aryl group having 6 to 50 ring carbon atoms, a substituted or unsubstituted heterocyclic group having 5 to 50 ring atoms, or —Si(R′₉₀₁)(R′₉₀₂)(R′₉₀₃),
R′₉₀₁, R′₉₀₂, and R′₉₀₃ are each independently a substituted or unsubstituted aryl group having 6 to 50 ring carbon atoms,
when two or more of R′₉₀₁ are present, the two or more of R′₉₀₁ are the same as or different from each other,
when two or more of R′₉₀₂ are present, the two or more of R′₉₀₂ are the same as or different from each other, and
when two or more of R′₉₀₃ are present, the two or more of R′₉₀₃ are the same as or different from each other.

7. The organic electroluminescent element of claim 1, wherein the second host compound comprises an azine group.

8. The organic electroluminescent element of claim 1, wherein the second host compound comprises at least one of compounds represented by the following Formulae (3a) and (3b): 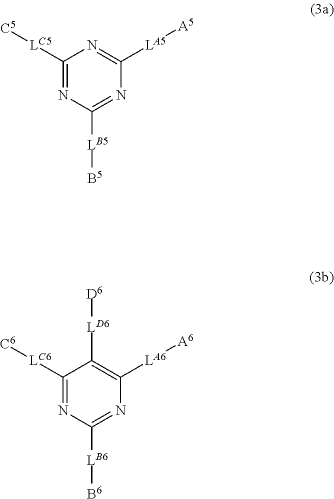
where
L^{A5}, L^{B5}, L^{C5}, L^{A6}, L^{B6}, L^{C6}, and L^{D6} are each independently a single bond, a substituted or unsubstituted arylene group having 6 to 50 ring carbon atoms, or a substituted or unsubstituted divalent heterocyclic group having 5 to 50 ring atoms,
A⁵, B⁵, C⁵, A⁶, B⁶, C⁶, and D⁶ are each independently a substituted or unsubstituted aryl group having 6 to 50 ring carbon atoms, a substituted or unsubstituted heterocyclic group having 5 to 50 ring atoms, or —Si(R′₉₀₄)(R′₉₀₅)(R′₉₀₆),
R′₉₀₄, R′₉₀₅, and R′₉₀₆ are each independently a substituted or unsubstituted aryl group having 6 to 50 ring carbon atoms,
when two or more of R′₉₀₄ are present, the two or more of R′₉₀₄ are the same as or different from each other,
when two or more of R′₉₀₅ are present, the two or more of R′₉₀₅ are the same as or different from each other, and
when two or more of R′₉₀₆ are present, the two or more of R′₉₀₆ are the same as or different from each other.

9. An organic electroluminescent element, comprising: an anode, a cathode, and an organic layer interposed between the anode and the cathode, wherein
the organic layer comprises:
a first host compound having a HOMO energy level of −5.5 eV or higher and a triplet energy level of 2.5 eV or lower,
a second host compound having a LUMO energy level of −4.0 eV to −3.0 eV, and
a dopant compound,
the first host compound and the second host compound are capable of recombining with each other to form an exciplex,
the exciplex has a triplet energy level of greater than 1.5 eV, and
the first host compound, the second host compound, and the dopant compound satisfy the following Relationships 1 to 3 and 5:
$${H}_{1} {S}_{1} > {DS}_{1} \qquad Relationship 1$$
$${H}_{1} {T}_{1} > {DT}_{1} \qquad Relationship 2$$
$${H}_{2} {S}_{1} > {DS}_{1} \qquad Relationship 3$$
$${DT}_{1} > {H}_{2} {T}_{1} \qquad Relationship 5$$
where
H₁S₁ is a singlet energy level of the first host compound,
H₁T₁ is a triplet energy level of the first host compound,
H₂S₁ is a singlet energy level of the second host compound,
H₂T₁ is a triplet energy level of the second host compound,
DS₁ is a singlet energy level of the dopant compound, and
DT₁ is a triplet energy level of the dopant compound.

10. The organic electroluminescent element of claim 9, wherein the first host compound comprises an amine compound.

11. The organic electroluminescent element of claim 9, wherein the second host compound is a compound comprising anthracene.

12. An organic electroluminescent element, comprising: an anode, a cathode, and an organic layer interposed between the anode and the cathode, wherein
the organic layer comprises:
a first host compound having a HOMO energy level of −5.5 eV or higher and a triplet energy level of 2.5 eV or lower,
a second host compound having a LUMO energy level of −4.0 eV to −3.0 eV,
a dopant compound, and
a third host compound having a triplet energy level greater than 1.5 eV to less than 1.9 eV,
the first host compound and the second host compound are capable of recombining with each other to form an exciplex,
the exciplex has a triplet energy level of greater than 1.5 eV, and
the first host compound, the second host compound, and the dopant compound satisfy the following Relationships 1 to 4:
$${H}_{1} {S}_{1} > {DS}_{1} \qquad Relationship 1$$
$${H}_{1} {T}_{1} > {DT}_{1} \qquad Relationship 2$$
$${H}_{2} {S}_{1} > {DS}_{1} \qquad Relationship 3$$
$${H}_{2} {T}_{1} > {DT}_{1} \qquad Relationship 4$$
where
H₁S₁ is a singlet energy level of the first host compound,
H₁T₁ is a triplet energy level of the first host compound,
H₂S₁ is a singlet energy level of the second host compound,
H₂T₁ is a triplet energy level of the second host compound,
DS₁ is a singlet energy level of the dopant compound, and
DT₁ is a triplet energy level of the dopant compound.

13. The organic electroluminescent element of claim 12, wherein the dopant compound comprises a fluorescent compound.

14. The organic electroluminescent element of claim 12, wherein the dopant compound has an emission peak wavelength in a solution state of 430 nm to 480 nm.

15. The organic electroluminescent element of claim 12, wherein a gap between the HOMO energy level of the first host compound and the LUMO energy level of the second host compound is greater than 1.6 eV.

16. The organic electroluminescent element of claim 12, wherein the first host compound comprises an amine compound.

17. The organic electroluminescent element of claim 12, wherein the first host compound comprises at least one of compounds represented by the following Formulae (2a) to (2d): 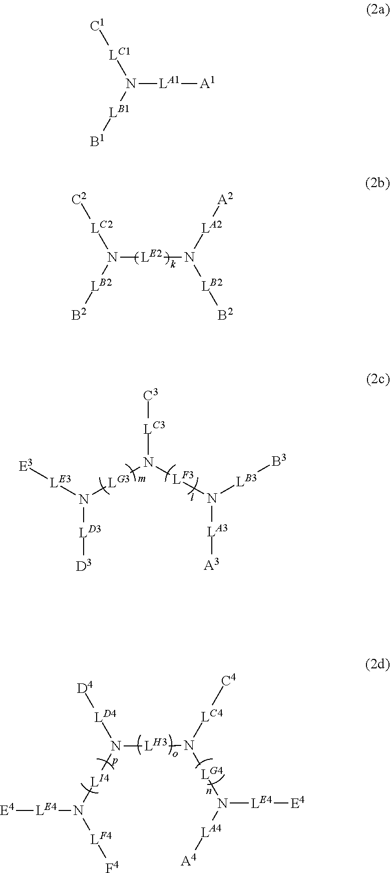
where
L^{A1}, L^{B1}, L^{C1}, L^{A2}, L^{B2}, L^{C2}, L^{D2}, L^{A3}, L^{B3}, L^{C3}, L^{D3}, L^{E3}, L^{A4}, L^{B4}, L^{C4}, L^{D4}, L^{E4}, and L^{F4} are each independently a single bond, a substituted or unsubstituted arylene group having 6 to 50 ring carbon atoms, or a substituted or unsubstituted divalent heterocyclic group having 5 to 50 ring atoms,
k, l, m, n, o, and p are each independently 1, 2, 3, or 4,
when k, l, m, n, o, and p are 1, L^{E2}, L^{F3}, L^{G3}, L^{G4}, L^{H4}, and L^{I4} are each independently a substituted or unsubstituted arylene group having 6 to 50 ring carbon atoms, or a substituted or unsubstituted divalent heterocyclic group having 5 to 50 ring atoms,
when k, l, m, n, o, and p are 2, 3, or 4, a plurality of L^{E2}, L^{F3}, L^{G3}, L^{G4}, L^{H4}, and L^{I4} are the same as or different from each other,
when k, l, m, n, o, and p are 2, 3, or 4, a plurality of L^{E2}, L^{F3}, L^{G3}, L^{G4}, L^{H4}, and L^{I4} bond to each other to form a substituted or unsubstituted monocyclic or fused ring, or do not bond to each other,
L^{E2}, L^{F3}, L^{G3}, L^{G4}, L^{H4}, and L^{I4} that do not form the substituted or unsubstituted monocyclic ring and do not form the substituted or unsubstituted fused ring are a substituted or unsubstituted arylene group having 6 to 50 ring carbon atoms, or a substituted or unsubstituted divalent heterocyclic group having 5 to 50 ring atoms,
A¹, B¹, C¹, A², B², C², D², A³, B³, C³, D³, E³, A⁴, B⁴, C⁴, D⁴, E⁴, and F⁴ are each independently a substituted or unsubstituted aryl group having 6 to 50 ring carbon atoms, a substituted or unsubstituted heterocyclic group having 5 to 50 ring atoms, or —Si(R′₉₀₁)(R′₉₀₂)(R′₉₀₃),
R′₉₀₁, R′₉₀₂, and R′₉₀₃ are each independently a substituted or unsubstituted aryl group having 6 to 50 ring carbon atoms,
when two or more of R′₉₀₁ are present, the two or more of R′₉₀₁ are the same as or different from each other,
when two or more of R′₉₀₂ are present, the two or more of R′₉₀₂ are the same as or different from each other, and
when two or more of R′₉₀₃ are present, the two or more of R′₉₀₃ are the same as or different from each other.

18. The organic electroluminescent element of claim 12, wherein the second host compound comprises an azine group.

19. The organic electroluminescent element of claim 12, wherein the second host compound is at least one of compounds represented by the following Formulae (3a) and (3b): 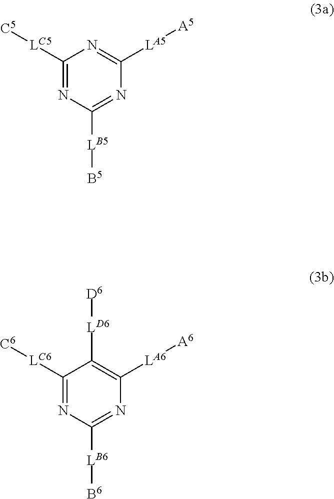
where
L^{A5}, L^{B5}, L^{C5}, L^{A6}, L^{B6}, L^{C6}, and L^{D6} are each independently a single bond, a substituted or unsubstituted arylene group having 6 to 50 ring carbon atoms, or a substituted or unsubstituted divalent heterocyclic group having 5 to 50 ring atoms,
A⁵, B⁵, C⁵, A⁶, B⁶, C⁶, and D⁶ are each independently a substituted or unsubstituted aryl group having 6 to 50 ring carbon atoms, a substituted or unsubstituted heterocyclic group having 5 to 50 ring atoms, or —Si(R′₉₀₄)(R′₉₀₅)(R′₉₀₆),
R′₉₀₄, R′₉₀₅, and R′₉₀₆ are each independently a substituted or unsubstituted aryl group having 6 to 50 ring carbon atoms,
when two or more of R′₉₀₄ are present, the two or more of R′₉₀₄ are the same as or different from each other,
when two or more of R′₉₀₅ are present, the two or more of R′₉₀₅ are the same as or different from each other, and
when two or more of R′₉₀₆ are present, the two or more of R′₉₀₆ are the same as or different from each other.

20. The organic electroluminescent element of claim 12, wherein the third host compound satisfies the following Relationship 6:
$${ExpT}_{1} > {H}_{3} {T}_{1} \qquad Relationship 6$$
where
ExpT₁ is a triplet energy level of the exciplex formed by the first host compound and the second host compound recombining with each other, and
H₃T₁ is a triplet energy level of the third host compound.

21. The organic electroluminescent element of claim 12, wherein the third host compound is a compound comprising anthracene.

22. The organic electroluminescent element of claim 12, wherein the third host compound comprises a compound represented by the following Formula (4): 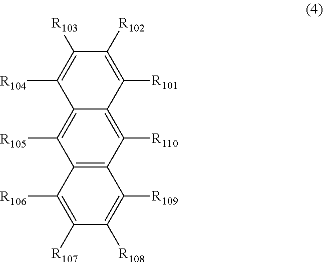
where
at least one of R₁₀₁ to R₁₁₀ is a group represented by the following Formula (5), and R₁₀₁ to R₁₁₀ that are not the group represented by the following Formula (5) are each independently a hydrogen atom or a substituent R,
when two or more of the substituent R are present, the two or more of the substituent R are the same as or different from each other, and
when two or more of the group represented by the Formula (5) are present, the two or more of the group represented by the Formula (5) are the same as or different from each other, 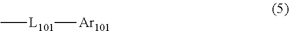
where
L₁₀₁ is a single bond, a substituted or unsubstituted arylene group having 6 to 50 ring carbon atoms, or a substituted or unsubstituted divalent heterocyclic group having 5 to 50 ring atoms, and
Ar₁₀₁ is a substituted or unsubstituted aryl group having 6 to 50 ring carbon atoms, or a substituted or unsubstituted monovalent heterocyclic group having 5 to 50 ring atoms,
the substituent R is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, —Si(R₉₀₁)(R₉₀₂)(R₉₀₃), —O—(R₉₀₄), —S—(R₉₀₅), —N(R₉₀₆)(R₉₀₇), a halogen atom, a cyano group, a nitro group, a substituted or unsubstituted aryl group having 6 to 50 ring carbon atoms, or a substituted or unsubstituted monovalent heterocyclic group having 5 to 50 ring atoms,
R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted monovalent heterocyclic group having 5 to 50 ring atoms, and
when two or more of R₉₀₁ to R₉₀₇ are present, the two or more of R₉₀₁ to R₉₀₇ are the same as or different from each other.

23. The organic electroluminescent element of claim 1, wherein
the organic layer comprises a light-emitting layer composed of a single layer or a plurality of layers, and
the light-emitting layer comprises the first host compound, the second host compound, and the dopant compound.

24. The organic electroluminescent element of claim 23, wherein
the organic layer comprises a light-emitting layer composed of a plurality of layers, and
the light-emitting layer comprises:
a first layer comprising the first host compound and the dopant compound; and
a second layer disposed between the first layer and the cathode and comprising the second host compound.

25. The organic electroluminescent element of claim 9, wherein
the organic layer comprises a light-emitting layer composed of a plurality of layers, and
the light-emitting layer comprises:
a first layer comprising the first host compound and the dopant compound; and
a second layer disposed between the first layer and the cathode and comprising the second host compound and the dopant compound.

26. The organic electroluminescent element of claim 12, wherein
the organic layer comprises a light-emitting layer composed of a plurality of layers, and
the light-emitting layer comprises:
a first layer comprising the first host compound and the second host compound; and
an intermediate layer disposed between the first layer and the cathode and comprising the third host compound.

27. The organic electroluminescent element of claim 26, wherein the intermediate layer comprises the dopant compound doped into the third host compound.

28. The organic electroluminescent element of claim 26, wherein the organic layer further comprises at least one of a hole transporting zone disposed between the anode and the first layer, and an electron transporting zone disposed between the intermediate layer and the cathode.

29. The organic electroluminescent element of claim 12, wherein
the organic layer comprises a light-emitting layer composed of a plurality of layers, and
the light-emitting layer comprises:
a first layer comprising the first host compound and the dopant compound;
a second layer disposed between the first layer and the cathode and comprising the second host compound; and
an intermediate layer disposed between the first layer and the second layer and comprising the third host compound.

30. The organic electroluminescent element of claim 29, wherein the organic layer further comprises at least one of a hole transporting zone disposed between the anode and the first layer, and an electron transporting zone disposed between the second layer and the cathode.

31. An electronic device, comprising: the organic electroluminescent element according to claim 1.
